(19) United States
(12) Patent Application Publication
(10) Pub. No.: US 2026/0150494 A1
(43) Pub. Date: May 28, 2026

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Renjie Zheng, Beijing (CN); Zhihao Cui, Beijing (CN); Wantian Xu, Beijing (CN); Xingxing Chai, Beijing (CN); Lei Zhao, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 19/392,897

(22) Filed: Nov. 18, 2025

(30) Foreign Application Priority Data
Nov. 22, 2024 (CN) 202411682538.5

(51) Int. Cl. H10K 50/18; H10K 50/11; H10K 85/40; H10K 85/60

(52) U.S. Cl. CPC H10K 50/181; H10K 50/11; H10K 85/40; H10K 85/626; H10K 85/633; H10K 85/656

(57) ABSTRACT

Provided are an organic electroluminescent material and a device comprising the same. The organic electroluminescent material is a compound having a structure of Formula 1, and the compound can be used in an organic electroluminescent device, for example, as an electron blocking material. The application of these compounds in organic electroluminescent devices can reduce the device voltage, increase the device efficiency, and especially greatly improve the device lifetime, thereby providing better device comprehensive performance. Further provided are an organic electroluminescent device comprising the compound and a compound composition comprising the compound.

### CROSS-REFERENCE TO RELATED APPLICATION(S)

This application claims priority to Chinese Patent Application No. 202411682538.5 filed on Nov. 22, 2024, the disclosure of which is incorporated herein by reference in its entirety.

### TECHNICAL FIELD

The present disclosure relates to compounds for organic electronic devices such as organic electroluminescent devices. In particular, the present disclosure relates to a compound having a structure of Formula 1, an organic electroluminescent device comprising the compound and a compound composition comprising the compound.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well-defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have a more saturated emitting color, higher efficiency, and longer device lifetime.

The efficiency, lifetime, and other properties of organic electroluminescent devices are critically related to the balance of charge carriers concentration in the emissive layer. The equilibrium of the carrier concentration in the emissive layer can be more rationally regulated through molecular structure designs of charge transport materials and carrier blocking materials. Compounds having a spiroacridine structural fragment can be used as hole transport materials, electron blocking materials (emissive auxiliary materials) or host materials in electroluminescent devices, and some reports have been documented in this regard.

CN110818635A discloses a compound having a structure of

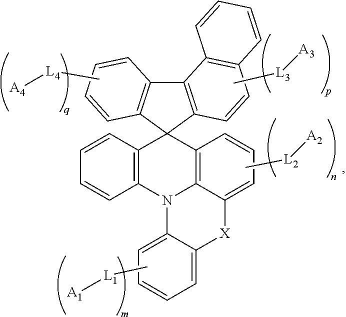

where L₁ to L₄ each independently represent one or more of a single bond, a carbonyl group, an aromatic hydrocarbyl group having 6 to 18 carbon atoms or an aromatic heterocyclic group having 5 to 18 carbon atoms; m, n, p and q are each independently an integer from 0 to 4, and m, n, p and q are not simultaneously 0; A₁ to A₄ each independently represent one or more of Ar₁ to Ar₄,

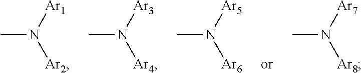

Ar₁ to Ar₈ each independently represent one or more of an aromatic hydrocarbyl group having 6 to 30 carbon atoms and optionally substituted with one or more R₁ or an aromatic heterocyclic group having 5 to 30 carbon atoms and optionally substituted with one or more R₁; X represents C(R₁)₂, O, S, SO₂, P(═O)R₁, Si(R₁)₂, Ge(R₁)₂, NR₁, a single bond or a non-bonding bond. Furthermore, this application discloses a compound

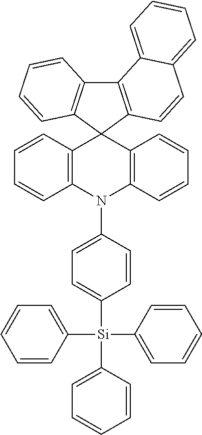 [SMILES: c1ccc([Si](c2ccccc2)(c2ccccc2)c2ccc(N3c4ccccc4C4(c5ccccc5-c5c4ccc4ccccc54)c4ccccc43)cc2)cc1]

among numerous specific structures. However, this application does not disclose or teach that the substituent-L₂-A₂ on an acridine ring can be joined to form a ring, nor does it disclose or teach the specific advantages of compounds with additional fused rings on the acridine ring and the impact of these compounds on device performance. Additionally, while the compound disclosed in this application is used as a host material and applied to electroluminescent devices, the impact of the compound when used as other materials on device performance is not disclosed or taught. WO2014017844A1 discloses a compound having a structure of

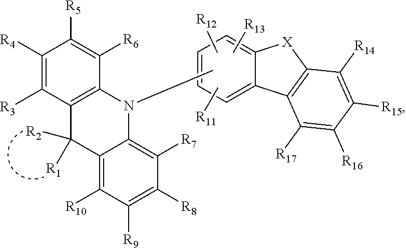

where X is selected from C, O, P, S, Se or Si, and also discloses compounds

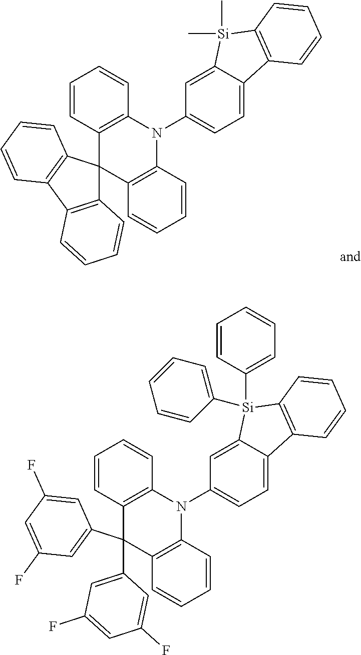 [SMILES: C[Si]1(C)c2ccccc2-c2ccc(N3c4ccccc4C4(c5ccccc5-c5ccccc54)c4ccccc43)cc21 ; Fc1cc(F)cc(C2(c3cc(F)cc(F)c3)c3ccccc3N(c3ccc4c(c3)[Si](c3ccccc3)(c3ccccc3)c3ccccc3-4)c3ccccc32)c1]

among specific structures. The silicon-containing structural fragments in the silicon-containing compound disclosed in this application are all silafluorene fragments, and the acridine/spiroacridine structural fragments do not possess additional fused ring structures. However, this application does not disclose or teach compounds containing fused spiroacridine structures and aryl/heteroaryl silicon-based structural fragments and the impact of these compounds on device performance. Additionally, while the compound disclosed in this application is used as a host material and applied to electroluminescent devices, the impact of the compound when used as other materials on device performance is not disclosed or taught.

CN114790170A discloses a compound having a structure of

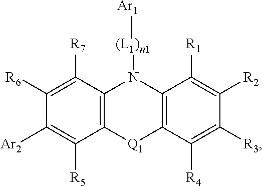

where Ar₁ is substituted or unsubstituted aryl having 6 to 30 ring-forming carbon atoms or substituted or unsubstituted heteroaryl having 2 to 30 ring-forming carbon atoms, Ar₂ has a structure represented by

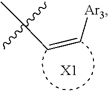

and Q₁ is O, S, SO, SO₂, Se, CO, C(R₁₁)(R₁₂), Si(R₁₁)(R₁₂), Ge(R₁₁)(R₁₂), B(R₁₃), N(R₁₄), P(R₁₅), PO(R₁₆), PS(R₁₇) or a group represented by Formula 3 which is

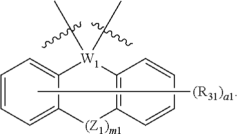

Among the numerous specific structures disclosed, the silicon-containing compounds only include

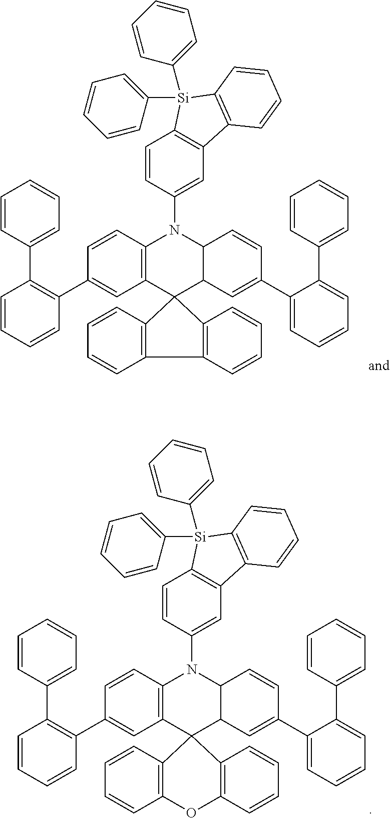 [SMILES: C1=CC2C(C=C1c1ccccc1-c1ccccc1)C1(c3ccccc3-c3ccccc31)c1cc(-c3ccccc3-c3ccccc3)ccc1N2c1ccc2c(c1)-c1ccccc1[Si]2(c1ccccc1)c1ccccc1 ; C1=CC2C(C=C1c1ccccc1-c1ccccc1)C1(c3ccccc3Oc3ccccc31)c1cc(-c3ccccc3-c3ccccc3)ccc1N2c1ccc2c(c1)-c1ccccc1[Si]2(c1ccccc1)c1ccccc1]

The silicon-containing structural fragments in the silicon-containing compounds disclosed in this application are all silafluorene fragments, and the acridine/spiroacridine structural fragments do not possess additional fused ring structures. This application primarily focuses on the impact of Q₁ and/or Ar₁ on device performance and does not focus on the specific advantages of compounds containing fused acridine spirocyclic structures and aryl/heteroaryl silicon-based structural fragments and the impact of these compounds on device performance.

With the growing performance demands for organic electroluminescent devices in the industry, OLED materials with superior characteristics such as lower voltage, higher efficiency and longer lifetime still require further in-depth research and development.

### SUMMARY

The present disclosure aims to provide a series of compounds represented by Formula 1, which feature a fused acridine spirocyclic structural fragment connected at a specific position to an aryl/heteroaryl silicon-based structural fragment, to solve at least part of the above problems. These compounds can be used in organic electroluminescent devices, for example, as electron blocking materials. The application of these compounds in organic electroluminescent devices can reduce the device voltage, increase the device efficiency, and especially greatly improve the device lifetime, thereby providing better device comprehensive performance.

According to an embodiment of the present disclosure, a compound is disclosed, which has a structure represented by Formula 1:

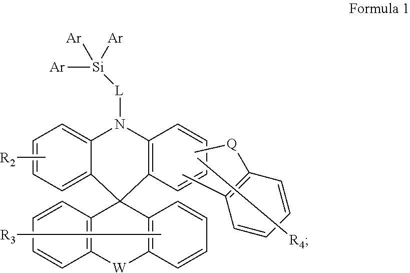

wherein Ar is, at each occurrence identically or differently, selected from substituted or unsubstituted aryl having 6 to 30 carbon atoms, substituted or unsubstituted heteroaryl having 3 to 30 carbon atoms or a combination thereof;
L is selected from arylene having 6 to 30 carbon atoms, heteroarylene having 3 to 30 carbon atoms or a combination thereof; wherein the arylene and the heteroarylene are unsubstituted or can be substituted with one or more groups R₁;
Q is selected from CR′R″, SiR′R″, NR_{N}, O or S;
W is selected from a single bond, O, S, CR′R″, SiR′R″ or NR_{N};
R₂, R₃ and R₄ represent, at each occurrence identically or differently, mono-substitution, multiple substitutions or non-substitution;
R₁, R₂, R₃, R₄, R′, R″ and R_{N} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁, R₂, R₃, R₄, R′, R″ and R_{N} can be optionally joined to form a ring.

According to another embodiment of the present disclosure, an organic electroluminescent device is disclosed, which comprises an anode, a cathode and an organic layer disposed between the anode and the cathode, wherein the organic layer comprises the compound described in the above embodiment.

According to another embodiment of the present disclosure, a compound composition is further disclosed, which comprises the compound described in the above embodiment.

The present disclosure discloses a series of compounds represented by Formula 1, which feature a fused acridine spirocyclic structural fragment connected at a specific position to an aryl/heteroaryl silicon-based structural fragment. The application of these compounds in organic electroluminescent devices can improve the performance of the organic electroluminescent devices. For example, these compounds can reduce the device voltage, increase the device efficiency, and especially greatly improve the device lifetime, thereby enhancing device comprehensive performance.

### BRIEF DESCRIPTION OF DRAWINGS

FIG. 1 is a schematic diagram of an organic light-emitting apparatus that may include a compound and a compound composition disclosed herein.

FIG. 2 is a schematic diagram of another organic light-emitting apparatus that may include a compound and a compound composition disclosed herein.

### DETAILED DESCRIPTION

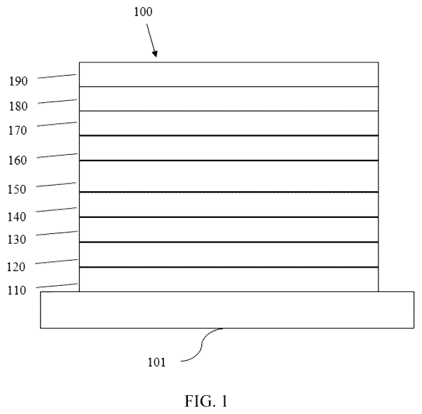

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg: Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

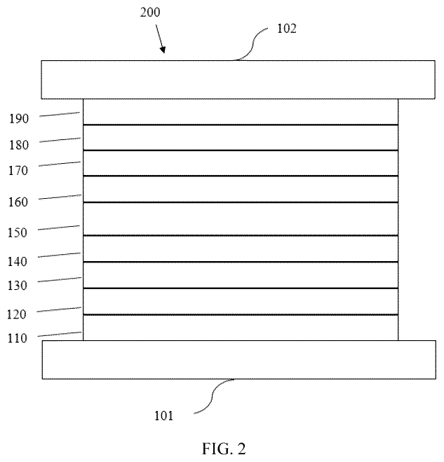

An OLED can be encapsulated by a barrier layer. FIG. 2 schematically shows an organic light-emitting device 200 without limitation. FIG. 2 differs from FIG. 1 in that the organic light-emitting device includes a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e., P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AEs-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in a small AEs-T. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, a n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h] quinoxaline, dibenzo[f,h] quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g., phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to their enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions etc.), which means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

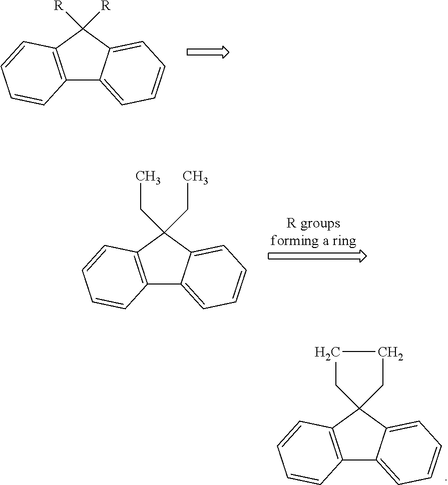

The expression that adjacent substituents can be optionally joined to form a ring is also intended to mean that two substituents bonded to carbon atoms which are directly bonded to each other are joined to each other via a chemical bond to form a ring, which can be exemplified by the following formula:

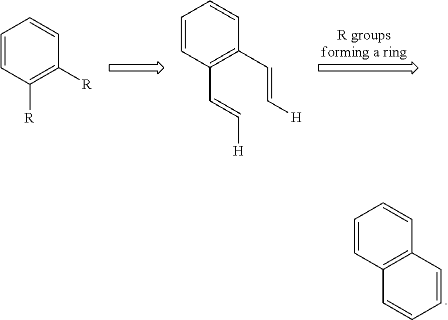

The expression that adjacent substituents can be optionally joined to form a ring is also intended to mean that two substituents bonded to further distant carbon atoms are joined to each other via a chemical bond to form a ring, which can be exemplified by the following formula:

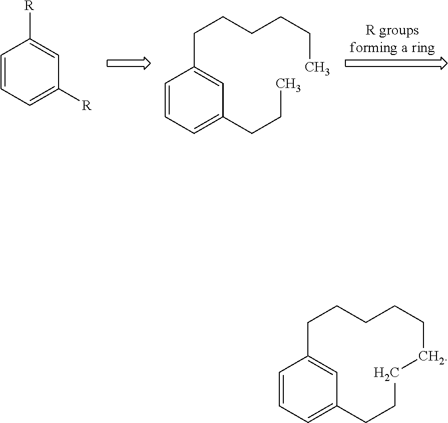

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

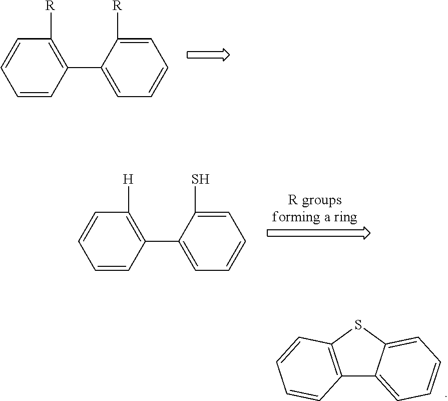

According to an embodiment of the present disclosure, a compound is disclosed, which has a structure represented by Formula 1:

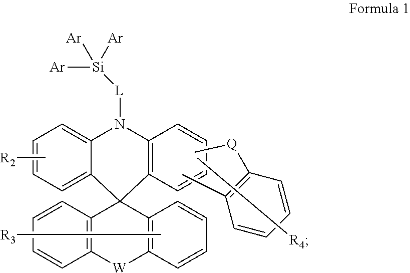

wherein Ar is, at each occurrence identically or differently, selected from substituted or unsubstituted aryl having 6 to 30 carbon atoms, substituted or unsubstituted heteroaryl having 3 to 30 carbon atoms or a combination thereof;
L is selected from arylene having 6 to 30 carbon atoms, heteroarylene having 3 to 30 carbon atoms or a combination thereof; wherein the arylene and the heteroarylene are unsubstituted or can be substituted with one or more groups R₁;
Q is selected from CR′R″, SiR′R″, NR_{N}, O or S;
W is selected from a single bond, O, S, CR′R″, SiR′R″ or NR_{N};
R₂, R₃ and R₄ represent, at each occurrence identically or differently, mono-substitution, multiple substitutions or non-substitution;
R₁, R₂, R₃, R₄, R′, R″ and R_{N} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁, R₂, R₃, R₄, R′, R″ and R_{N} can be optionally joined to form a ring.

In the present disclosure, the expression that adjacent substituents R₁, R₂, R₃, R₄, R′, R″ and Rx can be optionally joined to form a ring is intended to mean that any one or more of groups of adjacent substituents, such as two substituents R₁, two substituents R₂, two substituents R₃, two substituents R₄, substituents R′ and R″, substituents R₂ and R₃, substituents R₃ and R₄, and substituents R₄ and Rx, can be joined to form a ring. Obviously, it is also possible that none of these substituents are joined to form a ring.

According to an embodiment of the present disclosure, when W is selected from a single bond, any adjacent substituents R₁ and R₂ cannot be joined to form a ring.

According to an embodiment of the present disclosure, when W is selected from a single bond, any adjacent substituents R₃ cannot be joined to form a ring.

According to an embodiment of the present disclosure, any adjacent substituents R₁ and R₂ cannot be joined to form a ring.

According to an embodiment of the present disclosure, any adjacent substituents R₃ cannot be joined to form a ring.

According to an embodiment of the present disclosure, Ar and L cannot be joined to form a ring.

According to an embodiment of the present disclosure, R₂ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof, wherein the substituted or unsubstituted aryl having 6 to 30 carbon atoms does not include biphenyl-2-yl.

According to an embodiment of the present disclosure, the L is selected from substituted or unsubstituted arylene having 6 to 20 carbon atoms, substituted or unsubstituted heteroarylene having 3 to 20 carbon atoms or a combination thereof.

According to an embodiment of the present disclosure, the L is selected from substituted or unsubstituted phenylene, substituted or unsubstituted biphenylylene, substituted or unsubstituted naphthylene, substituted or unsubstituted fluorenylidene, substituted or unsubstituted silafluorenylene, substituted or unsubstituted dibenzofurylene, substituted or unsubstituted dibenzothienylene or a combination thereof.

According to an embodiment of the present disclosure, the L is selected from substituted or unsubstituted phenylene.

According to an embodiment of the present disclosure, the compound has a structure represented by Formula 2:

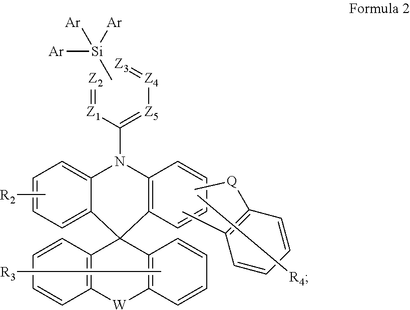

wherein Ar is, at each occurrence identically or differently, selected from substituted or unsubstituted aryl having 6 to 30 carbon atoms, substituted or unsubstituted heteroaryl having 3 to 30 carbon atoms or a combination thereof;
Z₁ to Z₅ are, at each occurrence identically or differently, selected from C, CR₁ or N, and at least one of Z₁ to Z₅ is C and joined to Si;
Q is selected from CR′R″, SiR′R″, NR_{N}, O or S;
W is selected from a single bond, O, S, CR′R″, SiR′R″ or NR_{N};
R₂, R₃ and R₄ represent, at each occurrence identically or differently, mono-substitution, multiple substitutions or non-substitution;
R₁, R₂, R₃, R₄, R′, R″ and R_{N} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁, R₂, R₃, R₄, R′, R″ and R_{N} can be optionally joined to form a ring.

According to an embodiment of the present disclosure, the W is selected from a single bond, O, S or CR′R″.

According to an embodiment of the present disclosure, the W is selected from a single bond.

According to an embodiment of the present disclosure, the compound has a structure represented by any one of Formula 2-1, Formula 2-2, Formula 2-3, Formula 2-4, Formula 2-5 and Formula 2-6:

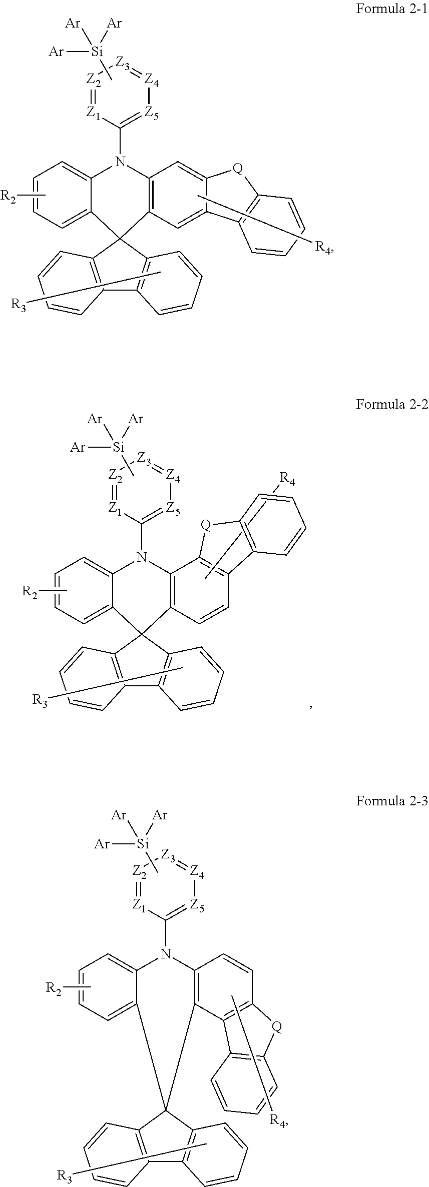

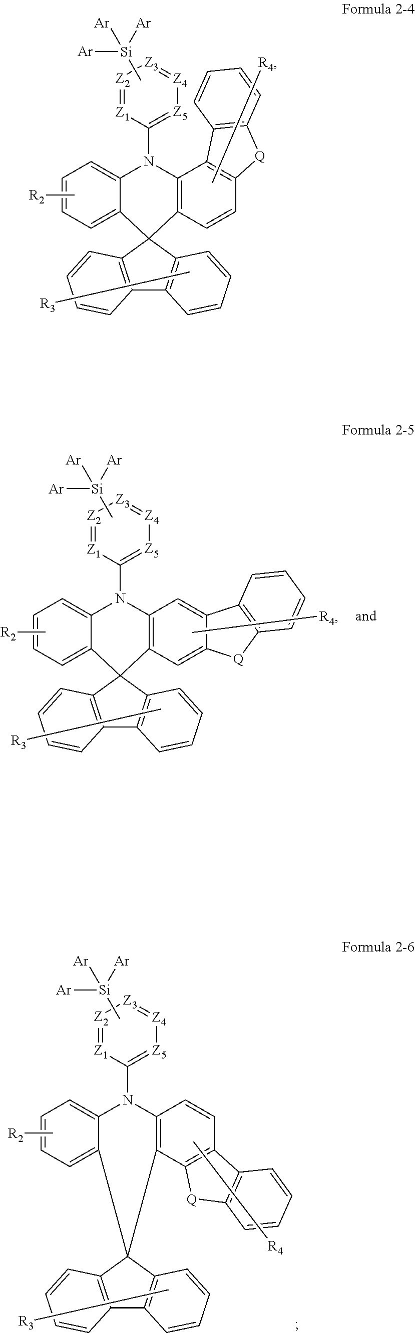

wherein Ar is, at each occurrence identically or differently, selected from substituted or unsubstituted aryl having 6 to 30 carbon atoms, substituted or unsubstituted heteroaryl having 3 to 30 carbon atoms or a combination thereof;
Z₁ to Zs are, at each occurrence identically or differently, selected from C, CR₁ or N, and at least one of Z₁ to Zs is C and joined to Si;
Q is selected from CR′R″, SiR′R″, NR_{N}, O or S;
R₂, R₃ and R₄ represent, at each occurrence identically or differently, mono-substitution, multiple substitutions or non-substitution;
R₁, R₂, R₃, R₄, R′, R″ and Ry are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁, R₂, R₃, R₄, R′, R″ and R_{N} can be optionally joined to form a ring.

According to an embodiment of the present disclosure, the compound has a structure represented by Formula 2-1, Formula 2-3, Formula 2-4 or Formula 2-5.

According to an embodiment of the present disclosure, the Q is selected from CR′R″.

According to an embodiment of the present disclosure, the Q is selected from CR′R″, and R′ and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, and combinations thereof.

According to an embodiment of the present disclosure, the Q is selected from CR′R″, and R′ and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, and combinations thereof.

According to an embodiment of the present disclosure, Z₂ or Z₃ is C and joined to Si.

According to an embodiment of the present disclosure, at least two adjacent substitutes R₂ are joined to form a ring.

According to an embodiment of the present disclosure, at least two adjacent substitutes R₂ are joined to form an aromatic ring or a heteroaromatic ring.

According to an embodiment of the present disclosure, the compound has a structure represented by Formula 3:

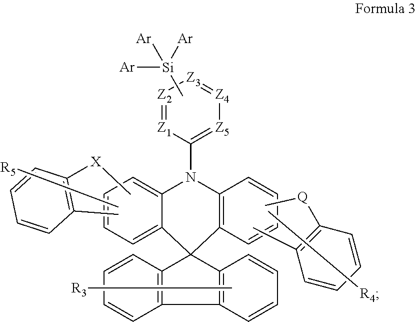

wherein Ar is, at each occurrence identically or differently, selected from substituted or unsubstituted aryl having 6 to 30 carbon atoms, substituted or unsubstituted heteroaryl having 3 to 30 carbon atoms or a combination thereof;
Z₁ to Zs are, at each occurrence identically or differently, selected from C, CR₁ or N, and at least one of Z₁ to Z₅ is C and joined to Si;
Q is selected from CR′R″, SiR′R″, NR_{N}, O or S;
X is selected from CR′R″, SiR′R″, NR_{N}, O or S;
R₁, R₃, R₄ and R₅ represent, at each occurrence identically or differently, mono-substitution, multiple substitutions or non-substitution;
R₁, R₃, R₄, R₅, R′, R″ and R_{N} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁, R₃, R₄, R₅, R′, R″ and R_{N} can be optionally joined to form a ring.

In the present disclosure, the expression that adjacent substituents R₁, R₃, R₄, R₅, R′, R″ and R_{N} can be optionally joined to form a ring is intended to mean that any one or more of groups of adjacent substituents, such as two substituents R₁, two substituents R₃, two substituents R₄, two substituents R₅, substituents R′ and R″, substituents R₁ and R₄, substituents R₁ and Rs, substituents R₃ and R₄, substituents R₃ and R₅, substituents R₄ and R_{N}, and substituents Rs and R_{N}, can be joined to form a ring. Obviously, it is also possible that none of these substituents are joined to form a ring.

According to an embodiment of the present disclosure, the compound has a structure represented by any one of Formula 3-1 to Formula 3-12:

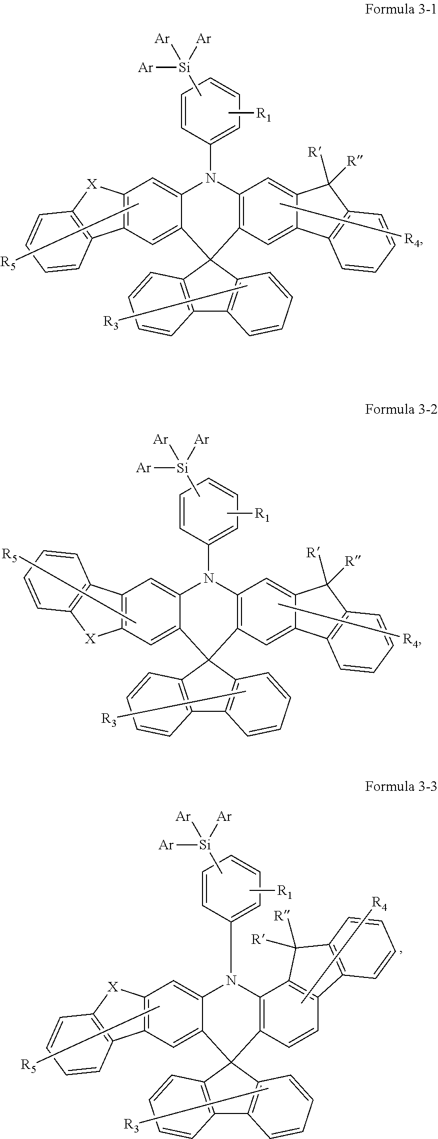

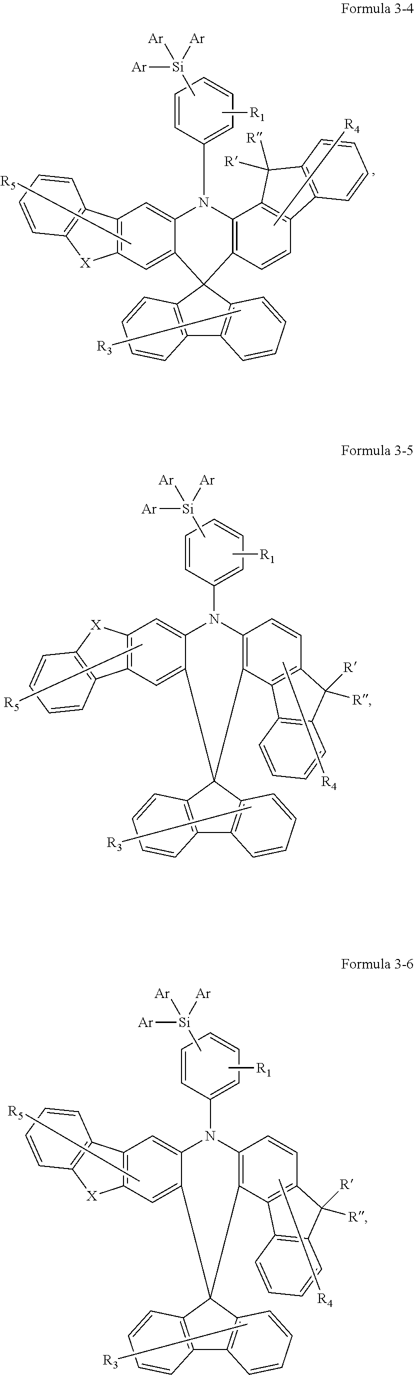

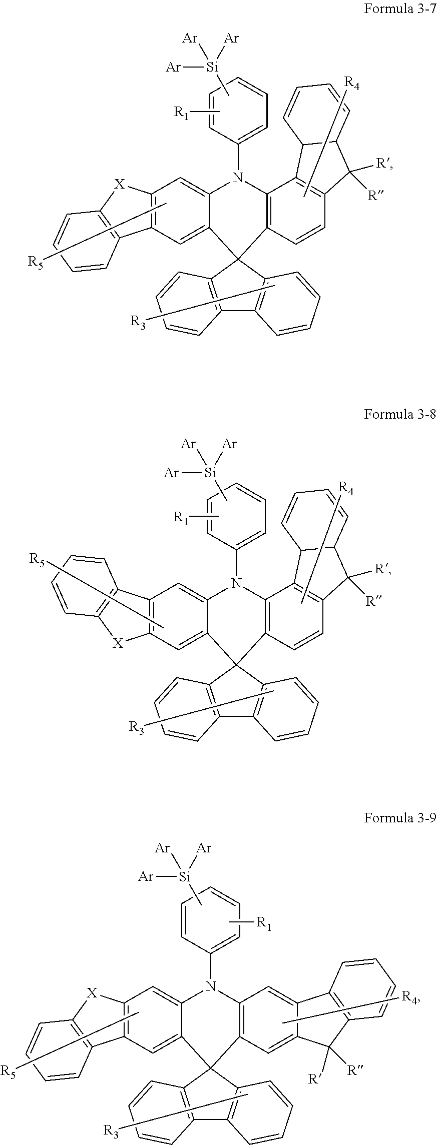

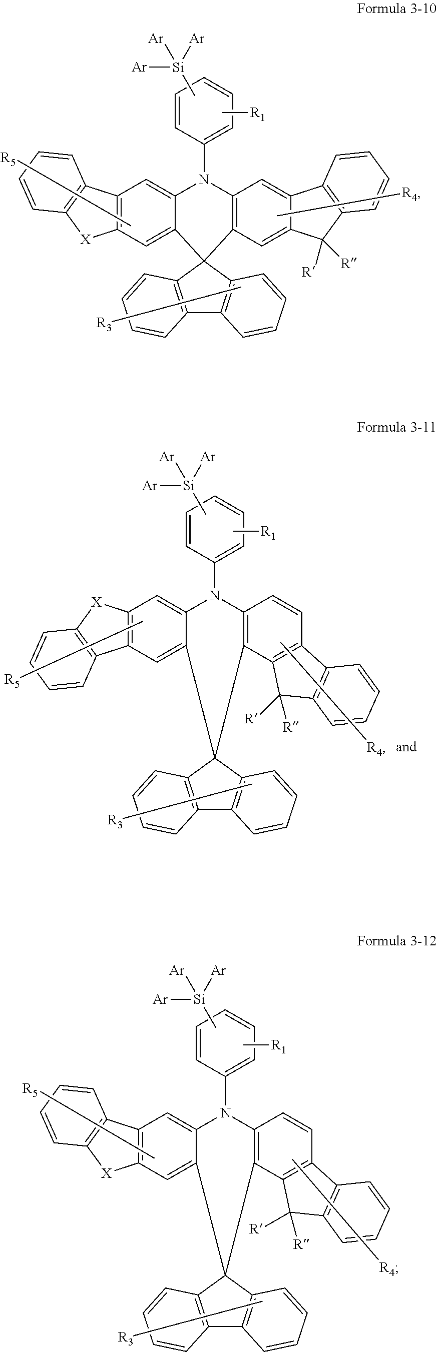

wherein Ar is, at each occurrence identically or differently, selected from substituted or unsubstituted aryl having 6 to 30 carbon atoms, substituted or unsubstituted heteroaryl having 3 to 30 carbon atoms or a combination thereof;
X is selected from CR′R″, SiR′R″, NR_{N}, O or S;
R₁, R₃, R₄ and R₅ represent, at each occurrence identically or differently, mono-substitution, multiple substitutions or non-substitution;
R₁, R₃, R₄, R₅, R′, R″ and R_{N} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁, R₃, R₄, R₅, R′, R″ and R_{N} can be optionally joined to form a ring.

According to an embodiment of the present disclosure, the compound has a structure represented by Formula 3-1, Formula 3-2, Formula 3-9 or Formula 3-10.

According to an embodiment of the present disclosure, the X is selected from CR′R″, NR_{N}, O or S.

According to an embodiment of the present disclosure, the X is selected from CR′R″.

According to an embodiment of the present disclosure, the X is selected from CR′R″, and R′ and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, and combinations thereof.

According to an embodiment of the present disclosure, the X is selected from CR′R″, and R′ and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, and combinations thereof.

According to an embodiment of the present disclosure, the compound has a structure represented by Formula 4:

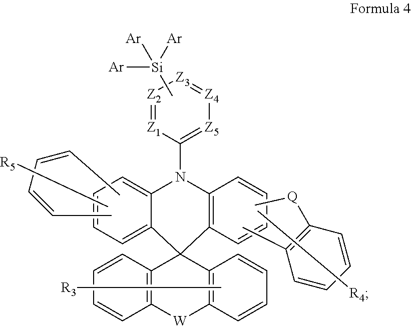

wherein Ar is, at each occurrence identically or differently, selected from substituted or unsubstituted aryl having 6 to 30 carbon atoms, substituted or unsubstituted heteroaryl having 3 to 30 carbon atoms or a combination thereof;
Z₁ to Z₅ are, at each occurrence identically or differently, selected from C, CR₁ or N, and at least one of Z₁ to Z₅ is C and joined to Si;
Q is selected from CR′R″, SiR′R″, NR_{N}, O or S;
W is selected from a single bond, O, S, CR′R″, SiR′R″ or NR_{N};
R₁, R₃, R₄ and R₅ represent, at each occurrence identically or differently, mono-substitution, multiple substitutions or non-substitution;
R₁, R₃, R₄, R₅, R′, R″ and R_{N} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁, R₃, R₄, R₅, R′, R″ and R_{N} can be optionally joined to form a ring.

According to an embodiment of the present disclosure, the Ar is, at each occurrence identically or differently, selected from substituted or unsubstituted aryl having 6 to 25 carbon atoms, substituted or unsubstituted heteroaryl having 3 to 25 carbon atoms or a combination thereof.

According to an embodiment of the present disclosure, the Ar is, at each occurrence identically or differently, selected from substituted or unsubstituted aryl having 6 to 18 carbon atoms, substituted or unsubstituted heteroaryl having 3 to 18 carbon atoms or a combination thereof.

According to an embodiment of the present disclosure, the Ar is, at each occurrence identically or differently, selected from substituted or unsubstituted phenyl, substituted or unsubstituted biphenyl, substituted or unsubstituted terphenyl, substituted or unsubstituted naphthyl, substituted or unsubstituted fluorenyl, substituted or unsubstituted silafluorenyl, substituted or unsubstituted dibenzofuryl, substituted or unsubstituted dibenzothienyl, substituted or unsubstituted dibenzoselenophenyl, substituted or unsubstituted carbazolyl, substituted or unsubstituted phenanthryl, substituted or unsubstituted anthryl, substituted or unsubstituted pyrenyl or a combination thereof.

According to an embodiment of the present disclosure, the Ar is, at each occurrence identically or differently, selected from substituted or unsubstituted phenyl.

According to an embodiment of the present disclosure, at least one of the Ar is, at each occurrence identically or differently, selected from substituted or unsubstituted aryl having 6 to 30 carbon atoms.

According to an embodiment of the present disclosure, at least one of the Ar is, at each occurrence identically or differently, selected from substituted or unsubstituted aryl having 6 to 25 carbon atoms.

According to an embodiment of the present disclosure, at least one of the Ar is, at each occurrence identically or differently, selected from substituted or unsubstituted aryl having 6 to 18 carbon atoms.

According to an embodiment of the present disclosure, at least one of Ar is, at each occurrence identically or differently, selected from substituted or unsubstituted phenyl, substituted or unsubstituted biphenyl, substituted or unsubstituted terphenyl, substituted or unsubstituted naphthyl, substituted or unsubstituted fluorenyl, substituted or unsubstituted phenanthryl, substituted or unsubstituted anthryl, substituted or unsubstituted pyrenyl or a combination thereof.

According to an embodiment of the present disclosure, the R₁, R₂, R₃, R₄, R′, R″ and R_{N} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heterocyclyl having 3 to 20 ring atoms, substituted or unsubstituted aryl having 6 to 30 carbon atoms, substituted or unsubstituted heteroaryl having 3 to 30 carbon atoms, and combinations thereof.

According to an embodiment of the present disclosure, the R₁, R₂, R₃, R₄, R′, R″ and R_{N} are, at each occurrence identically or differently, selected from the group consisting of: hydrogen, deuterium, halogen, substituted or unsubstituted alkyl having 1 to 20 carbon atoms, substituted or unsubstituted aryl having 6 to 30 carbon atoms, and combinations thereof.

According to an embodiment of the present disclosure, the R₁, R₃, R₄, R₅, R′, R″ and R_{N} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heterocyclyl having 3 to 20 ring atoms, substituted or unsubstituted aryl having 6 to 30 carbon atoms, substituted or unsubstituted heteroaryl having 3 to 30 carbon atoms, and combinations thereof.

According to an embodiment of the present disclosure, the R₁, R₃, R₄, R₅, R′, R″ and R_{N} are, at each occurrence identically or differently, selected from the group consisting of: hydrogen, deuterium, halogen, substituted or unsubstituted alkyl having 1 to 20 carbon atoms, substituted or unsubstituted aryl having 6 to 30 carbon atoms, and combinations thereof.

According to an embodiment of the present disclosure, the compound is selected from the group consisting of Compound 1 to Compound 470, wherein the specific structures of Compound 1 to Compound 470 are referred to claim 11.

According to an embodiment of the present disclosure, hydrogens in Compound 1 to Compound 470 can be partially or fully substituted with deuterium.

According to an embodiment of the present disclosure, an organic electroluminescent device is disclosed, which comprises an anode, a cathode and an organic layer disposed between the anode and the cathode, wherein the organic layer comprises the compound described in any one of the above embodiments.

According to an embodiment of the present disclosure, the organic layer is an electron blocking layer, a hole injection layer, a hole transport layer or an emissive layer.

According to an embodiment of the present disclosure, the organic layer is an electron blocking layer, and the compound is an electron blocking material.

According to an embodiment of the present disclosure, the thickness of the electron blocking layer ranges from 1 nm to 800 nm.

According to an embodiment of the present disclosure, the organic layer is an emissive layer, and the compound is a host material.

According to an embodiment of the present disclosure, the emissive layer comprises a phosphorescent material.

According to an embodiment of the present disclosure, the organic electroluminescent device emits red light.

According to an embodiment of the present disclosure, the organic electroluminescent device emits green light.

According to an embodiment of the present disclosure, an organic electroluminescent device is disclosed, which comprises an anode, a cathode, a hole injection layer, a hole transport layer, an electron blocking layer and an emissive layer, wherein the electron blocking layer comprises the compound described in any one of the above embodiments.

According to an embodiment of the present disclosure, the electron blocking layer is in direct contact with the hole transport layer, and the electron blocking layer is in direct contact with the emissive layer.

According to an embodiment of the present disclosure, the hole transport layer comprises a hole transport material, and the hole transport material comprises a mono-triarylamine compound or a bis-triarylamine compound.

According to an embodiment of the present disclosure, a compound composition is disclosed, which comprises the compound described in any one of the above embodiments.

Combination with Other Materials

The materials described in the present disclosure for a particular layer in an organic light emitting device can be used in combination with various other materials present in the device. The combinations of these materials are described in more detail in U.S. patent application No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, compounds disclosed herein may be used in combination with a wide variety of light-emitting dopants, hosts, transporting layers, blocking layers, injection layers, electrodes, and other layers that may be present. The combination of these materials is described in detail in paragraphs 0080-0101 of U.S. patent application No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

### Material Synthesis Example

The method for preparing the compound of the present disclosure is not limited herein. Typically, the following compounds are used as examples without limitation, and the synthesis routes and preparation methods thereof are described below.

### Synthesis Example 1: Synthesis of Compound 1

### Step 1: Synthesis of Intermediate A

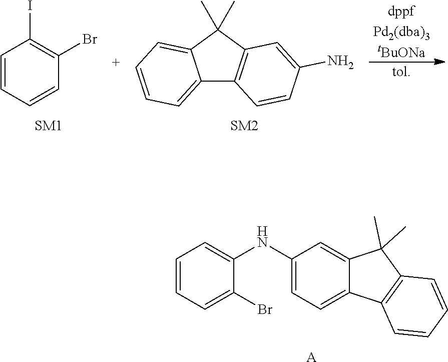

Under an N₂ atmosphere, Intermediate SM1 (27 g, 95.6 mmol), Intermediate SM2 (20 g, 95.6 mmol), sodium tert-butoxide (18.4 g, 191.2 mmol), Pd₂(dba)₃ (1.75 g, 1.91 mmol), 1,1′-bis(diphenylphosphino) ferrocene (dppf) (3.18 g, 5.74 mmol) and toluene (1000 mL) were sequentially added to a 2000 mL reaction flask, heated to 120° C. and reacted for 3 hours. The reaction was monitored by TLC (thin layer chromatography) until completion, the reaction solution was cooled to room temperature, filtered through Celite, concentrated under reduced pressure and purified by column chromatography to obtain Intermediate A as a white solid (30 g, with a yield of 86.2%).

### Step 2: Synthesis of Intermediate B

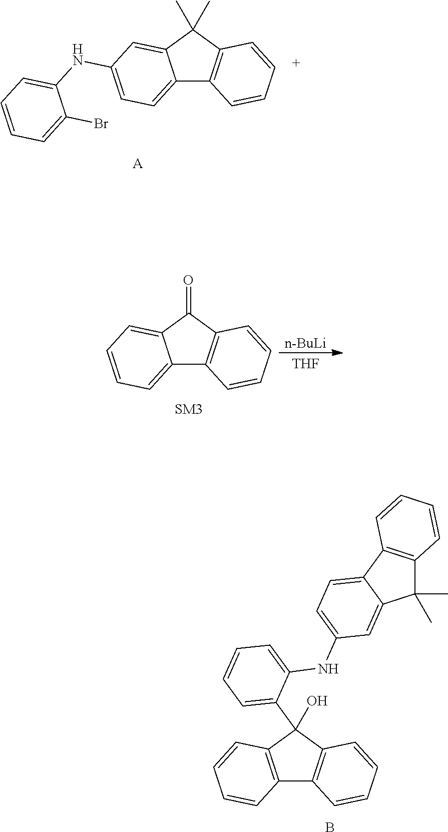

Under an N₂ atmosphere, Intermediate A (30 g, 82.35 mmol) and tetrahydrofuran (THF, 240 mL) were added to a 500 mL two-necked flask. The mixture was cooled to −75° C., then n-BuLi (73 mL, 182.5 mmol) was added dropwise and stirred for 1 hour, and a solution of Intermediate SM3 (14.8 g, 82.35 mmol) in THF (50 mL) was added dropwise. The reaction temperature was allowed to return to room temperature, and the reaction solution was stirred for 3 hours. The reaction was monitored by TLC until completion, the reaction was quenched with a suitable amount of dilute hydrochloric acid. The layers were separated, the aqueous phase was extracted with dichloromethane (DCM), and the organic phases were combined, concentrated under reduced pressure and purified by column chromatography to obtain Intermediate B as a solid (24 g, with a yield of 62.7%).

### Step 3: Synthesis of Intermediate C

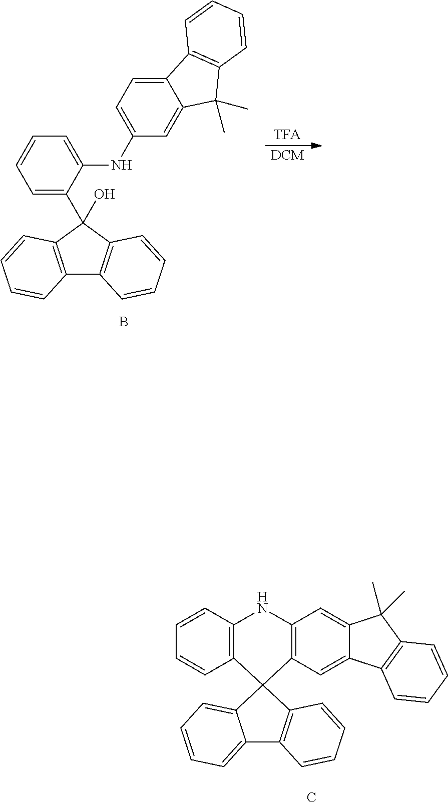

Under an N₂ atmosphere, Intermediate B (24 g, 51.5 mmol) and DCM (300 mL) were added to a 500 mL two-necked flask. At room temperature, trifluoroacetic acid (TFA, 24 mL) was added dropwise and stirred overnight at room temperature. The reaction was monitored by TLC until completion, the reaction solution was concentrated under reduced pressure and purified by column chromatography to obtain Intermediate C as a solid (21.3 g, with a yield of 92.2%).

### Step 4: Synthesis of Compound 1

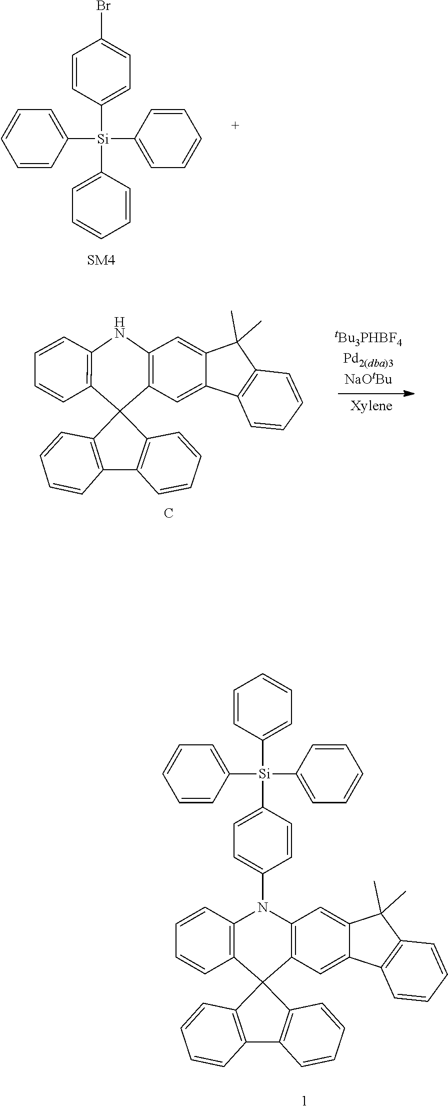

Under an N₂ atmosphere, Intermediate SM4 (6 g, 14.43 mmol), Intermediate C (6.45 g, 14.43 mmol), sodium tert-butoxide (2.76 g, 28.86 mmol), Pd₂(dba)₃ (264 mg, 0.288 mmol), ^{t}Bu₃PHBF₄ (417 mg, 1.44 mmol) and xylene (150 mL) were sequentially added to a 500 mL reaction flask and reacted at 145° C. overnight. The reaction was monitored by TLC until completion, the reaction temperature was allowed to return to room temperature, and the reaction solution was filtered through Celite, concentrated under reduced pressure and purified by column chromatography to obtain Compound 1 as a white solid (8.53 g, with a yield of 75.5%). The product was confirmed as the target product with a molecular weight of 781.32.

### Synthesis Example 2: Synthesis of Compound 2

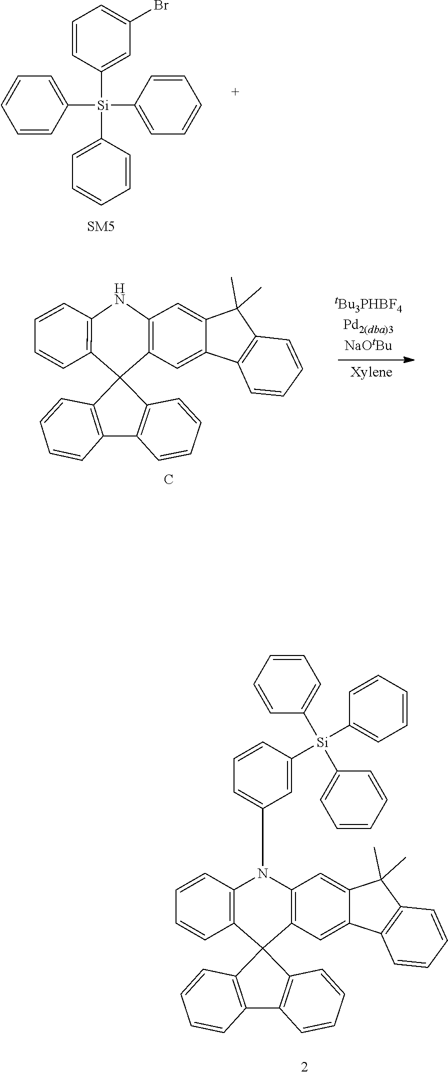

Under an N₂ atmosphere, Intermediate SM5 (2 g, 4.81 mmol), Intermediate C (2.15 g, 4.81 mmol), sodium tert-butoxide (0.92 g, 9.62 mmol), Pd₂(dba)₃ (88 mg, 0.096 mmol), ^{t}Bu₃PHBF₄ (139 mg, 0.48 mmol) and xylene (50 mL) were sequentially added to a 250 mL reaction flask and reacted at 145° C. overnight. The reaction was monitored by TLC until completion, the reaction temperature was allowed to return to room temperature, and the reaction solution was filtered through Celite, concentrated under reduced pressure and purified by column chromatography to obtain Compound 2 as a white solid (2.26 g, with a yield of 59.5%). The product was confirmed as the target product with a molecular weight of 781.32.

### Synthesis Example 3: Synthesis of Compound 5

### Step 1: Synthesis of Intermediate D

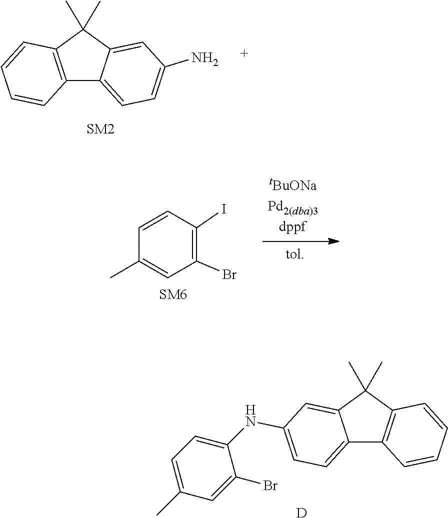

Under an N₂ atmosphere, Intermediate SM2 (14.07 g, 67.3 mmol), Intermediate SM6 (20 g, 67.3 mmol), sodium tert-butoxide (13.1 g, 136.4 mmol), Pd₂(dba)₃ (1.23 g, 1.35 mmol), dppf (3.73 g, 6.73 mmol) and toluene (673 mL) were sequentially added to a 2000 mL reaction flask, heated to 120° C. and reacted for 3 hours. The reaction was monitored by TLC until completion, the reaction temperature was allowed to return to room temperature, and the reaction solution was filtered through Celite, concentrated under reduced pressure and purified by column chromatography to obtain Intermediate D as a white solid (16.5 g, with a yield of 65%).

### Step 2: Synthesis of Intermediate E

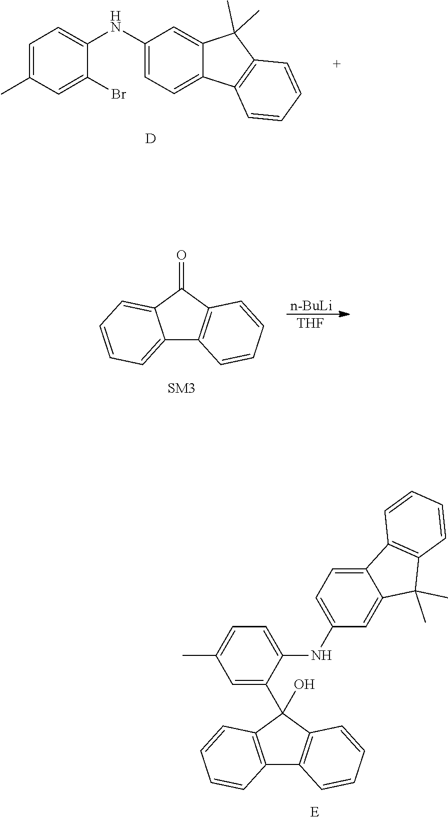

Under an N₂ atmosphere, Intermediate D (16.5 g, 43.6 mmol) and THF (130 mL) were added to a 500 mL two-necked flask. The mixture was cooled to −82° C., then n-BuLi (37 mL, 92.5 mmol) was added dropwise and stirred for 1 hour, and a solution of Intermediate SM3 (9.4 g, 52.3 mmol) in THF (20 mL) was added dropwise. The reaction temperature was allowed to return to room temperature, and the reaction solution was stirred for 3 hours. The reaction was monitored by TLC until completion, the reaction was quenched with a suitable amount of dilute hydrochloric acid. The layers were separated, the aqueous phase was extracted with DCM, and the organic phases were combined, concentrated under reduced pressure and purified by column chromatography to obtain Intermediate E as a solid (10.7 g, with a yield of 48.4%).

### Step 3: Synthesis of Intermediate F

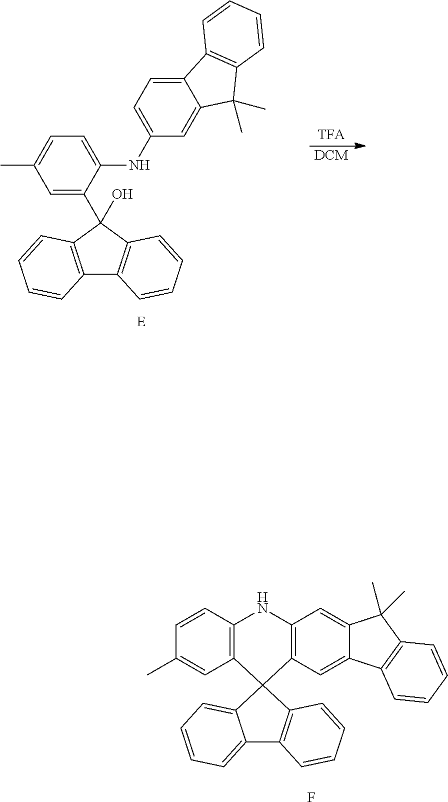

Under an N₂ atmosphere, Intermediate E (10.7 g, 22.3 mmol) and DCM (50 mL) were added to a 100 mL two-necked flask. At room temperature, TFA (11 mL) was added dropwise and stirred overnight at room temperature. The reaction was monitored by TLC until completion, the reaction solution was concentrated under reduced pressure and purified by column chromatography to obtain Intermediate F as a solid (10.3 g, with a yield of 100%).

### Step 4: Synthesis of Compound 5

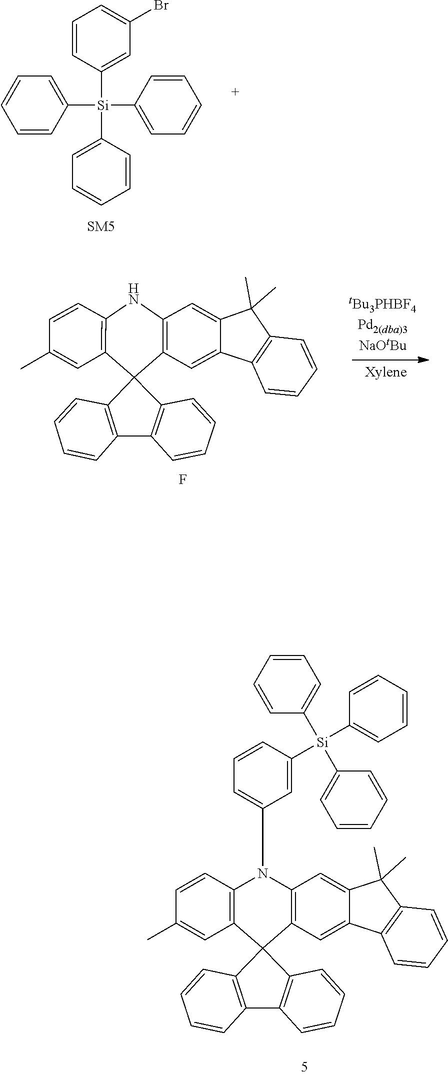

Under an N₂ atmosphere, Intermediate SM5 (3 g, 7.22 mmol), Intermediate F (3.34 g, 7.22 mmol), sodium tert-butoxide (1.39 g, 14.44 mmol), Pd₂(dba)₃ (132 mg, 0.144 mmol), ^{t}Bu₃PHBF₄ (210 mg, 0.722 mmol) and xylene (50 mL) were sequentially added to a 250 mL reaction flask and reacted at 145° C. overnight. The reaction was monitored by TLC until completion, the reaction temperature was allowed to return to room temperature, and the reaction solution was filtered through Celite, concentrated under reduced pressure and purified by column chromatography to obtain Compound 5 as a white solid (5 g, with a yield of 87%). The product was confirmed as the target product with a molecular weight of 795.33.

### Synthesis Example 4: Synthesis of Compound 4

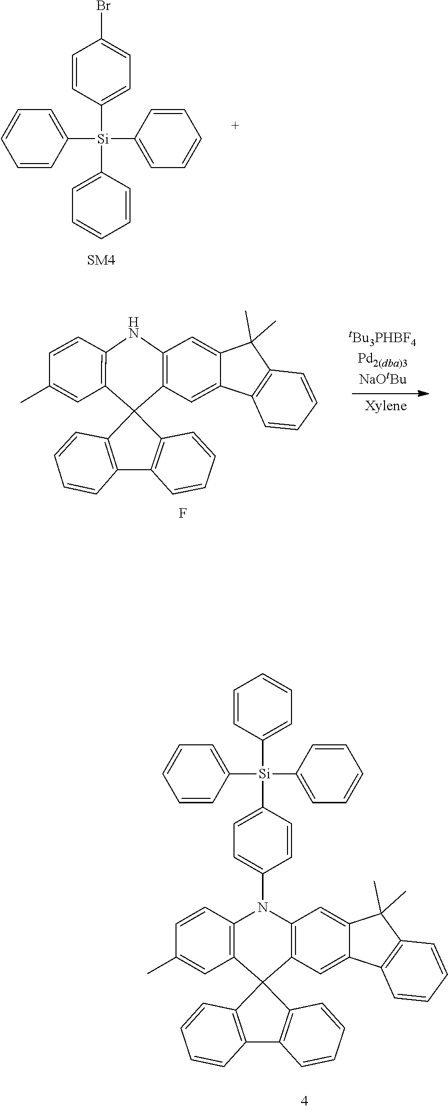

Under an N₂ atmosphere, Intermediate SM4 (2 g, 4.81 mmol), Intermediate F (2.22 g, 4.81 mmol), sodium tert-butoxide (0.92 g, 9.62 mmol), Pd₂(dba)₃ (88 mg, 0.096 mmol), ^{t}Bu₃PHBF₄ (139 mg, 0.48 mmol) and xylene (50 mL) were sequentially added to a 250 mL reaction flask and reacted at 145° C. overnight. The reaction was monitored by TLC until completion, the reaction temperature was allowed to return to room temperature, and the reaction solution was filtered through Celite, concentrated under reduced pressure and purified by column chromatography to obtain Compound 4 as a white solid (2.6 g, with a yield of 67.9%). The product was confirmed as the target product with a molecular weight of 795.33.

### Synthesis Example 5: Synthesis of Compound 9

### Step 1: Synthesis of Intermediate G

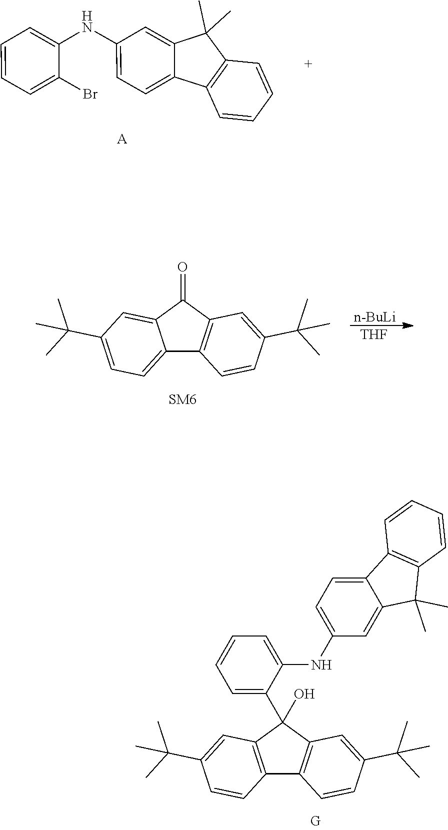

Under an N₂ atmosphere, Intermediate A (10 g, 27.4 mmol) and THF (80 mL) were added to a 500 mL two-necked flask. The mixture was cooled to −80° C., then n-BuLi (23 mL, 57.5 mmol) was added dropwise and stirred for 1 hour, and a solution of Intermediate SM6 (9.6 g, 32.9 mmol) in THF (10 mL) was added dropwise. The reaction temperature was allowed to return to room temperature, and the reaction solution was stirred for 3 hours. The reaction was monitored by TLC until completion, the reaction was quenched with a suitable amount of dilute hydrochloric acid. The layers were separated, the aqueous phase was extracted with DCM, and the organic phases were combined, concentrated under reduced pressure and purified by column chromatography to obtain Intermediate G as a solid (12.6 g, with a yield of 79.7%).

### Step 2: Synthesis of Intermediate H

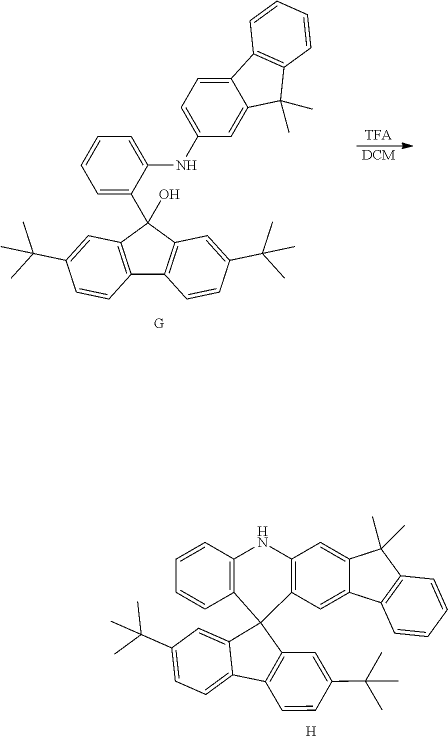

Under an N₂ atmosphere, Intermediate G (12.6 g, 21.8 mmol) and DCM (120 mL) were added to a 200 mL two-necked flask. At room temperature, TFA (13 mL) was added dropwise and stirred overnight at room temperature. The reaction was monitored by TLC until completion, the reaction solution was concentrated under reduced pressure and purified by column chromatography to obtain Intermediate H as a solid (11 g, with a yield of 91.67%).

### Step 3: Synthesis of Compound 9

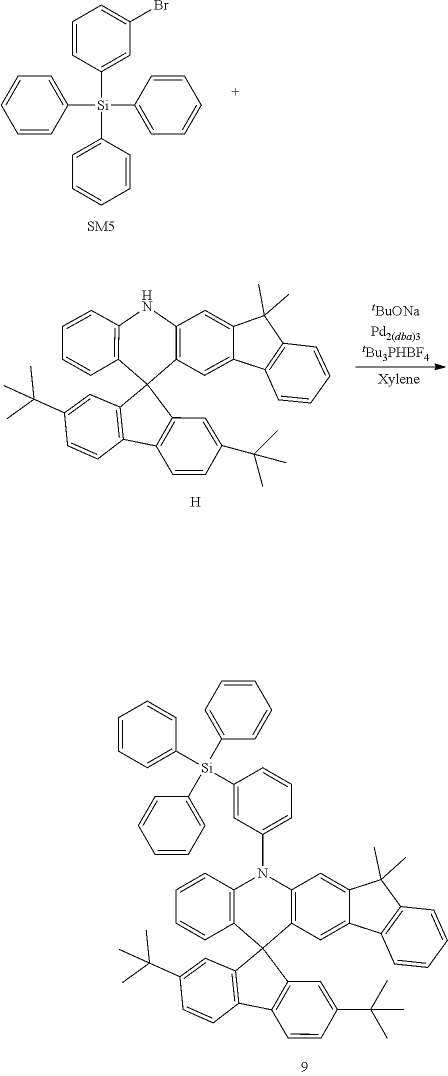

Under an N₂ atmosphere, Intermediate SM5 (3 g, 7.22 mmol), Intermediate H (3.97 g, 7.22 mmol), sodium tert-butoxide (1.39 g, 14.44 mmol), Pd₂(dba)₃ (132 mg, 0.144 mmol), ^{t}Bu₃PHBF₄ (210 mg, 0.722 mmol) and xylene (50 mL) were sequentially added to a 250 mL reaction flask and reacted at 145° C. overnight. The reaction was monitored by TLC until completion, the reaction temperature was allowed to return to room temperature, and the reaction solution was filtered through Celite, concentrated under reduced pressure and purified by column chromatography to obtain Compound 9 as a white solid (2.35 g, with a yield of 36.2%). The product was confirmed as the target product with a molecular weight of 893.44.

### Synthesis Example 6: Synthesis of Compound 198

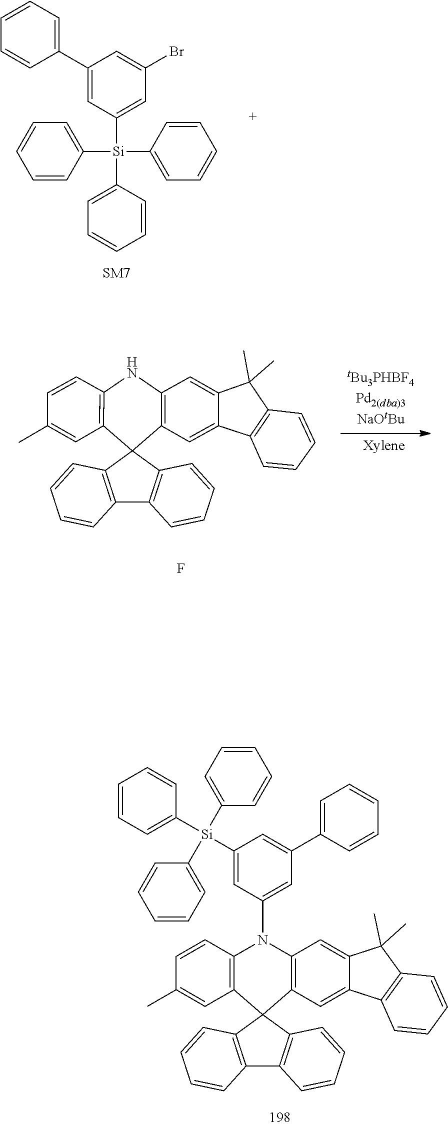

Under an N₂ atmosphere, Intermediate SM7 (2.36 g, 4.81 mmol), Intermediate F (2.22 g, 4.81 mmol), sodium tert-butoxide (0.92 g, 9.62 mmol), Pd₂(dba)₃ (88 mg, 0.096 mmol), ^{t}Bu₃PHBF₄ (139 mg, 0.48 mmol) and xylene (50 mL) were sequentially added to a 250 mL reaction flask and reacted at 145° C. overnight. The reaction was monitored by TLC until completion, the reaction temperature was allowed to return to room temperature, and the reaction solution was filtered through Celite, concentrated under reduced pressure and purified by column chromatography to obtain Compound 198 as a white solid (2.6 g, with a yield of 61.9%). The product was confirmed as the target product with a molecular weight of 871.36.

### Synthesis Example 7: Synthesis of Compound 12

### Step 1: Synthesis of Intermediate I

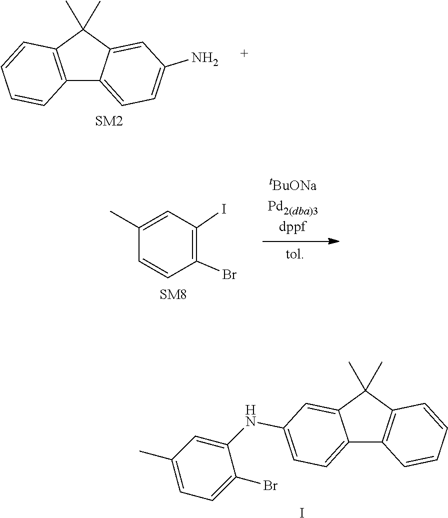

Under an N₂ atmosphere, Intermediate SM2 (14.07 g, 67.3 mmol), Intermediate SM8 (20 g, 67.3 mmol), sodium tert-butoxide (13.1 g, 136.4 mmol), Pd₂(dba)₃ (1.23 g, 1.35 mmol), dppf (3.73 g, 6.73 mmol) and toluene (673 mL) were sequentially added to a 2000 mL reaction flask, heated to 120° C. and reacted for 3 hours. The reaction was monitored by TLC until completion, the reaction solution was cooled to room temperature, filtered through Celite, concentrated under reduced pressure and purified by column chromatography to obtain Intermediate I as a white solid (16.5 g, with a yield of 65%).

### Step 2: Synthesis of Intermediate J

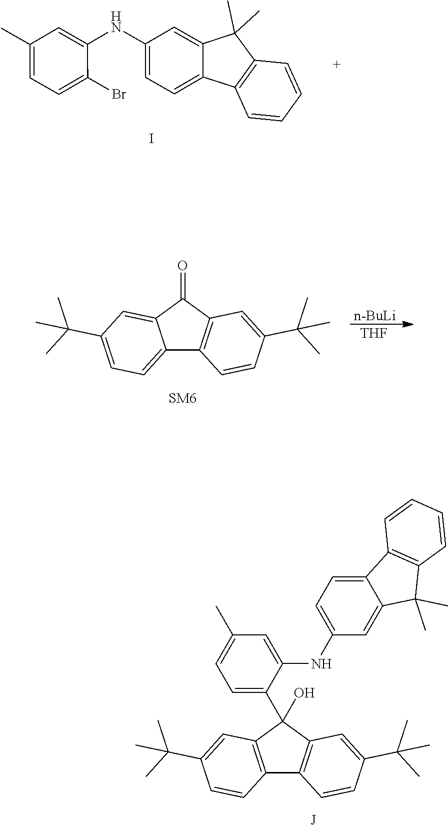

Under an N₂ atmosphere, Intermediate I (10.4 g, 27.4 mmol) and THF (80 mL) were added to a 500 mL two-necked flask. The mixture was cooled to −80° C., then n-BuLi (23 mL, 57.5 mmol) was added dropwise and stirred for 1 hour, and a solution of Intermediate SM6 (9.6 g, 32.9 mmol) in THF (10 mL) was added dropwise. The reaction temperature was allowed to return to room temperature, and the reaction solution was stirred for 3 hours. The reaction was monitored by TLC until completion, the reaction was quenched with a suitable amount of dilute hydrochloric acid. The layers were separated, the aqueous phase was extracted with DCM, and the organic phases were combined, concentrated under reduced pressure and purified by column chromatography to obtain Intermediate J as a solid (2.6 g, with a yield of 16%).

### Step 3: Synthesis of Intermediate K

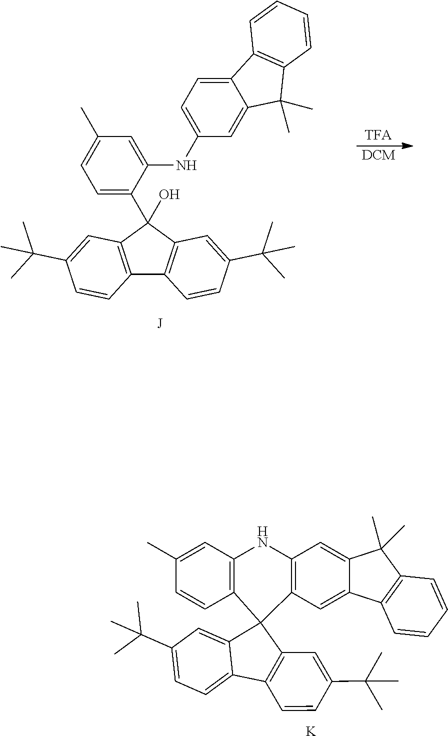

Under an N₂ atmosphere, Intermediate J (2.6 g, 4.4 mmol) and DCM (50 mL) were added to a 200 mL two-necked flask. At room temperature, TFA (5 mL) was added dropwise and stirred overnight at room temperature. The reaction was monitored by TLC until completion, the reaction solution was concentrated under reduced pressure and purified by column chromatography to obtain Intermediate K as a solid (2.52 g, with a yield of 100%).

### Step 4: Synthesis of Compound 12

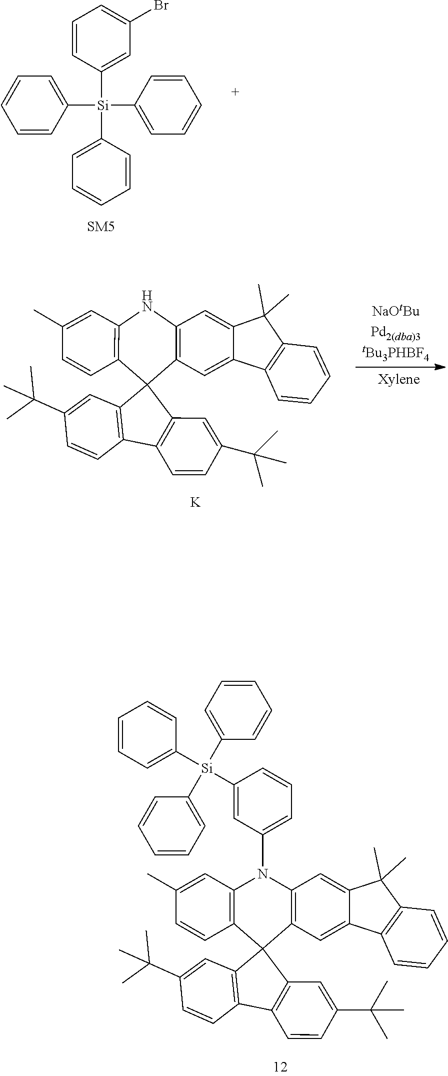

Under an N₂ atmosphere, Intermediate SM5 (1.82 g, 4.39 mmol), Intermediate K (2.6 g, 4.39 mmol), sodium tert-butoxide (0.92 g, 9.62 mmol), Pd₂(dba)₃ (88 mg, 0.096 mmol), ^{t}Bu₃PHBF₄ (139 mg, 0.48 mmol) and xylene (50 mL) were sequentially added to a 250 mL reaction flask and reacted at 145° C. overnight. The reaction was monitored by TLC until completion, the reaction temperature was allowed to return to room temperature, and the reaction solution was filtered through Celite, concentrated under reduced pressure and purified by column chromatography to obtain Compound 12 as a white solid (1.02 g, with a yield of 25.6%). The product was confirmed as the target product with a molecular weight of 907.46.

Those skilled in the art will appreciate that the above preparation methods are merely illustrative. Those skilled in the art can obtain other compound structures of the present disclosure through the modifications of the preparation methods.

The method for preparing an organic electroluminescent device is not limited. The preparation methods in the following device examples are merely examples and are not to be construed as limitations. Those skilled in the art can make reasonable improvements to the preparation methods in the following device examples based on the related art.

### Device Example

### Example 1: Preparation of an Organic Electroluminescent Device

Firstly, a glass substrate having a thickness of 0.7 mm and patterned with an indium tin oxide (ITO) anode with a thickness of 800 Å was washed with deionized water and a detergent, and then the ITO surface was treated with oxygen plasma and UV ozone. The substrate was then dried in a glovebox to remove moisture, mounted on a substrate holder and transferred into a vacuum chamber. The organic layers specified below were sequentially deposited on the anode layer by vacuum thermal evaporation at a rate of 0.01-10 Å/s and at a vacuum degree of about 10 6 Torr. Compound HT and Compound HI were co-deposited as a hole injection layer (HIL, with a weight ratio of 97:3, 100 Å). Compound HT was deposited as a hole transport layer (HTL, 1100 Å). Compound 1 of the present disclosure was deposited as an electron blocking layer (EBL, 550 Å). Compound H-1, Compound H-2 and Compound GD were co-deposited as an emissive layer (EML, with a weight ratio of 47:47:6, 400 Å). Compound HB was deposited as a hole blocking layer (HBL, 50 Å). Compound ET and Liq were co-deposited as an electron transport layer (ETL, with a weight ratio of 40:60, 350 Å). Liq with a thickness of 10 Å was deposited as an electron injection layer (EIL, 10 Å). Finally, the metallic aluminum was deposited as a cathode (1200 Å). The device was transferred back to the glovebox and encapsulated with a glass lid to complete the device.

Device Example 2: The preparation method in Device Example 2 was the same as the preparation method in Device Example 1, except that in the electron blocking layer (EBL), Compound 1 of the present disclosure was replaced with Compound 2 of the present disclosure.

Device Example 3: The preparation method in Device Example 3 was the same as the preparation method in Device Example 1, except that in the electron blocking layer (EBL), Compound 1 of the present disclosure was replaced with Compound 5 of the present disclosure.

Device Example 4: The preparation method in Device Example 4 was the same as the preparation method in Device Example 1, except that in the electron blocking layer (EBL), Compound 1 of the present disclosure was replaced with Compound 9 of the present disclosure.

Device Example 5: The preparation method in Device Example 5 was the same as the preparation method in Device Example 1, except that in the electron blocking layer (EBL), Compound 1 of the present disclosure was replaced with Compound 198 of the present disclosure.

Device Example 6: The preparation method in Device Example 6 was the same as the preparation method in Device Example 1, except that in the electron blocking layer (EBL), Compound 1 of the present disclosure was replaced with Compound 12 of the present disclosure.

Device Comparative Example 1: The preparation method in Device Comparative Example 1 was the same as the preparation method in Device Example 1, except that in the electron blocking layer (EBL), Compound 1 of the present disclosure was replaced with Compound EB-1.

Detailed structures and thicknesses of layers of the devices are shown in Table 1. A layer using more than one material is obtained by doping different compounds at their weight ratios as recorded.

TABLE 1
Part of device structures in Examples 1 to 6 and Comparative Example 1

| Device | | | | | | |
|---|---|---|---|---|---|---|
| No. | HIL | HTL | EBL | EML | HBL | ETL |
| Example 1 | Compound | Compound | Compound | Compound H- | Compound | Compound |
| | HT:Compound | HT | 1 | 1:Compound H- | HB | ET:Liq (40:60) |
| | HI | (1100 Å) | (550 Å) | 2:Compound GD | (50 Å) | (350 Å) |
| | (97:3) (100 Å) | | | (47:47:6) (400 Å) | | |
| Example 2 | Compound | Compound | Compound | Compound H- | Compound | Compound |
| | HT:Compound | HT | 2 | 1:Compound H- | HB | ET:Liq (40:60) |
| | HI | (1100 Å) | (550 Å) | 2:Compound GD | (50 Å) | (350 Å) |
| | (97:3) (100 Å) | | | (47:47:6) (400 Å) | | |
| Example 3 | Compound | Compound | Compound | Compound H- | Compound | Compound |
| | HT:Compound | HT | 5 | 1:Compound H- | HB | ET:Liq (40:60) |
| | HI | (1100 Å) | (550 Å) | 2:Compound GD | (50 Å) | (350 Å) |
| | (97:3) (100 Å) | | | (47:47:6) (400 Å) | | |
| Example 4 | Compound | Compound | Compound | Compound H- | Compound | Compound |
| | HT:Compound | HT | 9 | 1:Compound H- | HB | ET:Liq (40:60) |
| | HI | (1100 Å) | (550 Å) | 2:Compound GD | (50 Å) | (350 Å) |
| | (97:3) (100 Å) | | | (47:47:6) (400 Å) | | |
| Example 5 | Compound | Compound | Compound | Compound H- | Compound | Compound |
| | HT:Compound | HT | 198 | 1:Compound H- | HB | ET:Liq (40:60) |
| | HI | (1100 Å) | (550 Å) | 2:Compound GD | (50 Å) | (350 Å) |
| | (97:3) (100 Å) | | | (47:47:6) (400 Å) | | |
| Example 6 | Compound | Compound | Compound | Compound H- | Compound | Compound |
| | HT:Compound | HT | 12 | 1:Compound H- | HB | ET:Liq (40:60) |
| | HI | (1100 Å) | (550 Å) | 2:Compound GD | (50 Å) | (350 Å) |
| | (97:3) (100 Å) | | | (47:47:6) (400 Å) | | |
| Comparative | Compound | Compound | Compound | Compound H- | Compound | Compound |
| Example 1 | HT:Compound | HT | EB-1 | 1:Compound H- | HB | ET:Liq (40:60) |
| | HI | (1100 Å) | (550 Å) | 2:Compound GD | (50 Å) | (350 Å) |
| | (97:3) (100 Å) | | | (47:47:6) (400 Å) | | |

The structures of the materials used in the devices are as follows:

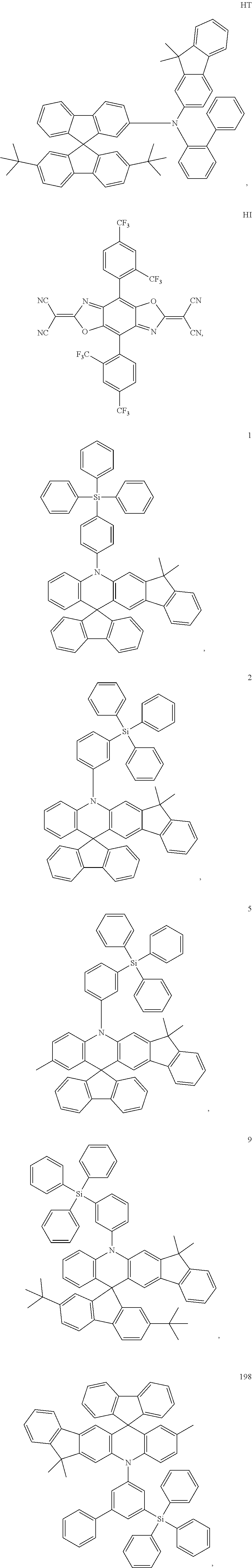

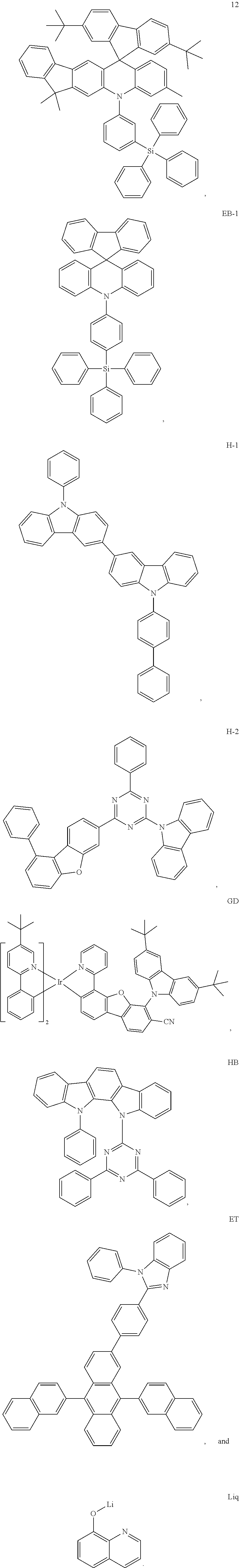

The CIE coordinates, maximum emission wavelength (max), voltage and power efficiency (PE) of Examples 1 to 6 and Comparative Example 1 were measured at a current density of 10 mA/cm². The lifetime (LT97) of Examples 1 to 6 and Comparative Example 1 was measured at a current density of 80 mA/cm². For a more intuitive comparison, the LT97 of Comparative Example 1 was defined as 1, and the LT97 values of Examples 1 to 6 were converted relative to Comparative Example 1. These data were recorded and shown in Table 2.

TABLE 2
Device data of Examples 1 to 6 and Comparative Example 1

| Device | | λₘₐₓ | Voltage | Power efficiency | |
|---|---|---|---|---|---|
| No. | CIE (x, y) | (nm) | (V) | (lm/W) | LT97 |
| Example 1 | (0.348, 0.627) | 531 | 3.50 | 75.0 | 220 |
| Example 2 | (0.350, 0.625) | 531 | 3.50 | 77.0 | 160 |
| Example 3 | (0.355, 0.622) | 531 | 3.40 | 73.0 | 400 |
| Example 4 | (0.351, 0.624) | 530 | 4.38 | 60.0 | 112 |
| Example 5 | (0.351, 0.624) | 531 | 3.36 | 76.2 | 190 |
| Example 6 | (0.351, 0.624) | 531 | 4.33 | 60.8 | 108 |
| Comparative | (0.350, 0.625) | 531 | 4.50 | 59.9 | 1 |
| Example 1 | | | | | |

### Discussion

As can be seen from the data in Table 2, the CIE coordinates and maximum emission wavelengths of Examples 1 to 6 and Comparative Example 1 remain essentially consistent.

Compared with Comparative Example 1, Example 1 exhibits a significant voltage reduction of 1 V, a substantial power efficiency increase of 25.2%, and, more importantly, an unexpected and remarkable lifetime enhancement of 219 times. Both Compound 1 of the present disclosure and Comparative Compound EB-1 possess a spiroacridine structural fragment and an aryl silicon structural fragment. The difference between them lies only in whether the acridine structural fragment has an additional specific fused structure. However, the performance differences between the resulting devices are very significant. This indicates that due to the specific fused acridine spirocyclic structural fragment, the compound of the present disclosure can significantly reduce the device voltage, substantially increase the device efficiency, and especially unexpectedly and dramatically improve the device lifetime, thereby providing better comprehensive performance in the device.

Examples 2 to 6 demonstrate the device performance of more compounds of the present disclosure. These compounds feature adjustments to the connection position between the fused acridine spirocyclic structural fragment and the silicon-based fragment and/or adjustments to the substituents on the fused acridine spirocyclic structural fragment or the silicon-based fragment. As can be seen from the data in Table 2, Examples 2 to 6 also exhibit excellent device performance. Compared with Comparative Example 1, Example 2 shows a voltage reduction of 1 V, a significant power efficiency increase of 28.5%, and a substantial lifetime improvement of 159 times; Example 3 shows a voltage reduction of 1.1 V, a significant power efficiency increase of 21.9%, and a particularly unexpected and remarkable lifetime improvement of 399 times; Example 4 shows a voltage reduction of 0.12 V, maintains power efficiency at a similarly high level, and achieves a substantial lifetime improvement of 111 times; Example 5 shows a voltage reduction of 1.14 V, a significant power efficiency increase of 27.2%, and a substantial lifetime improvement of 189 times; Example 6 shows a voltage reduction of 0.17 V, maintains power efficiency at a similarly high level, and achieves a substantial lifetime improvement of 107 times. The above results further confirm the excellent performance of the compounds of the present disclosure.

In summary, the application of the compounds represented by Formula 1 and having the specific structure according to the present disclosure in organic electroluminescent devices can significantly reduce the device voltage, increase the device efficiency, and especially improve the device lifetime, thereby providing better device comprehensive performance and demonstrating very promising application prospects.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. A compound, having a structure represented by Formula 1: 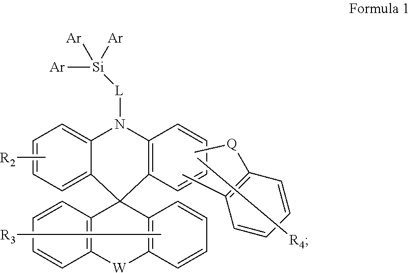
wherein Ar is, at each occurrence identically or differently, selected from substituted or unsubstituted aryl having 6 to 30 carbon atoms, substituted or unsubstituted heteroaryl having 3 to 30 carbon atoms or a combination thereof;
L is selected from arylene having 6 to 30 carbon atoms, heteroarylene having 3 to 30 carbon atoms or a combination thereof; wherein the arylene and the heteroarylene are unsubstituted or can be substituted with one or more groups R₁;
Q is selected from CR′R″, SiR′R″, NR_{N}, O or S;
W is selected from a single bond, O, S, CR′R″, SiR′R″ or NR_{N};
R₂, R₃ and R₄ represent, at each occurrence identically or differently, mono-substitution, multiple substitutions or non-substitution;
R₁, R₂, R₃, R₄, R′, R″ and R_{N} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁, R₂, R₃, R₄, R′, R″ and R_{N} can be optionally joined to form a ring.

2. The compound of claim 1, wherein the L is selected from substituted or unsubstituted arylene having 6 to 20 carbon atoms, substituted or unsubstituted heteroarylene having 3 to 20 carbon atoms or a combination thereof;
preferably, the L is selected from substituted or unsubstituted phenylene, substituted or unsubstituted biphenylylene, substituted or unsubstituted naphthylene, substituted or unsubstituted fluorenylidene, substituted or unsubstituted silafluorenylene, substituted or unsubstituted dibenzofurylene, substituted or unsubstituted dibenzothienylene or a combination thereof.

3. The compound of claim 1, wherein the compound has a structure represented by Formula 2: 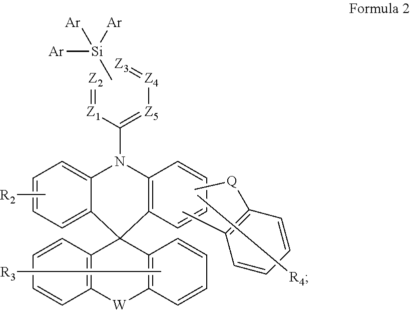
wherein Ar is, at each occurrence identically or differently, selected from substituted or unsubstituted aryl having 6 to 30 carbon atoms, substituted or unsubstituted heteroaryl having 3 to 30 carbon atoms or a combination thereof;
Z₁ to Z₅ are, at each occurrence identically or differently, selected from C, CR₁ or N, and at least one of Z₁ to Z₅ is C and joined to Si;
Q is selected from CR′R″, SiR′R″, NR_{N}, O or S;
W is selected from a single bond, O, S, CR′R″, SiR′R″ or NR_{N};
R₂, R₃ and R₄ represent, at each occurrence identically or differently, mono-substitution, multiple substitutions or non-substitution;
R₁, R₂, R₃, R₄, R′, R″ and R_{N} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁, R₂, R₃, R₄, R′, R″ and R_{N} can be optionally joined to form a ring.

4. The compound of claim 3, wherein the compound has a structure represented by any one of Formula 2-1, Formula 2-2, Formula 2-3, Formula 2-4, Formula 2-5 and Formula 2-6: 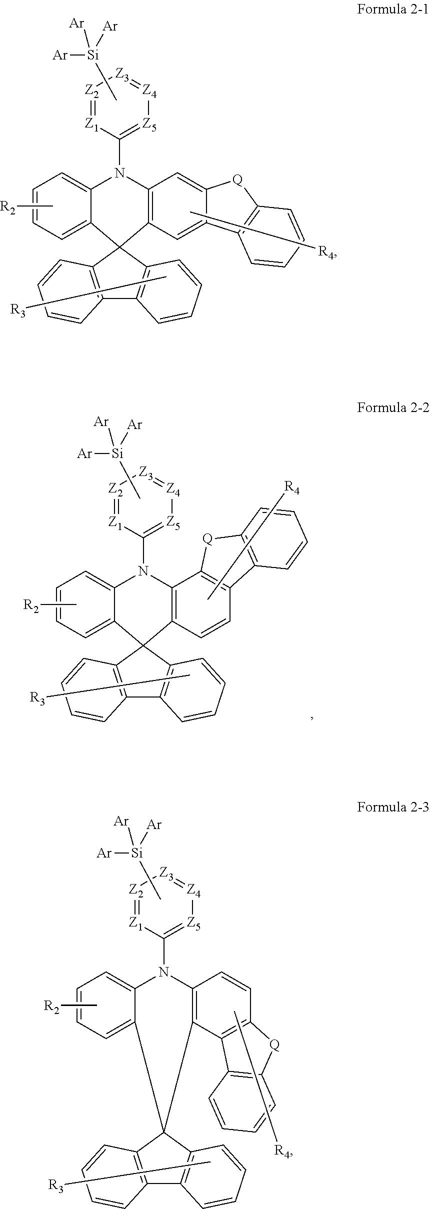 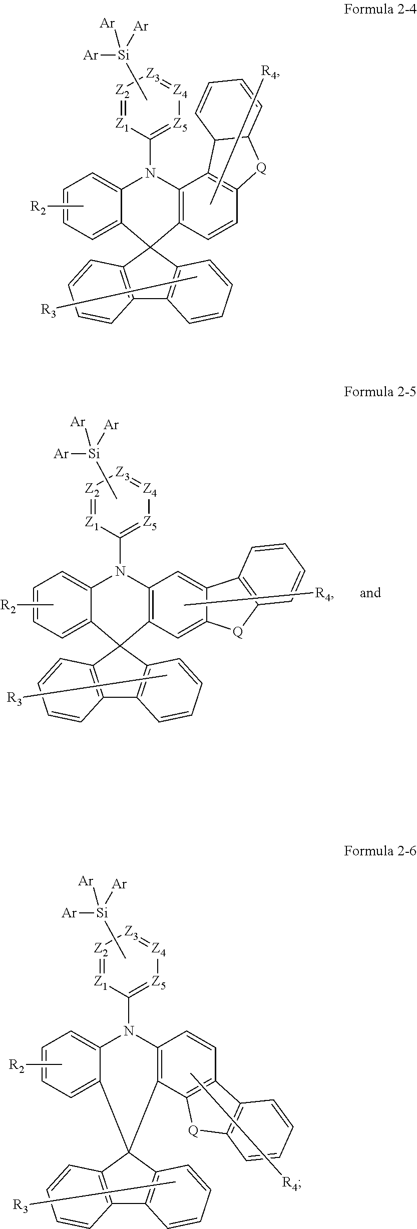
wherein Ar is, at each occurrence identically or differently, selected from substituted or unsubstituted aryl having 6 to 30 carbon atoms, substituted or unsubstituted heteroaryl having 3 to 30 carbon atoms or a combination thereof;
Z₁ to Z₅ are, at each occurrence identically or differently, selected from C, CR₁ or N, and at least one of Z₁ to Z₅ is C and joined to Si;
Q is selected from CR′R″, SiR′R″, NR_{N}, O or S;
R₂, R₃ and R₄ represent, at each occurrence identically or differently, mono-substitution, multiple substitutions or non-substitution;
R₁, R₂, R₃, R₄, R′, R″ and R_{N} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁, R₂, R₃, R₄, R′, R″ and R_{N} can be optionally joined to form a ring;
preferably, the compound has a structure represented by Formula 2-1, Formula 2-3, Formula 2-4 or Formula 2-5.

5. The compound of claim 4, wherein the Q is selected from CR′R″;
preferably, the R′ and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted alkylgermanyl having 3 to 20 carbon atoms, and combinations thereof;
more preferably, the R′ and R″ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, and combinations thereof.

6. The compound of claim 4, wherein the compound has a structure represented by any one of Formula 3-1 to Formula 3-12: 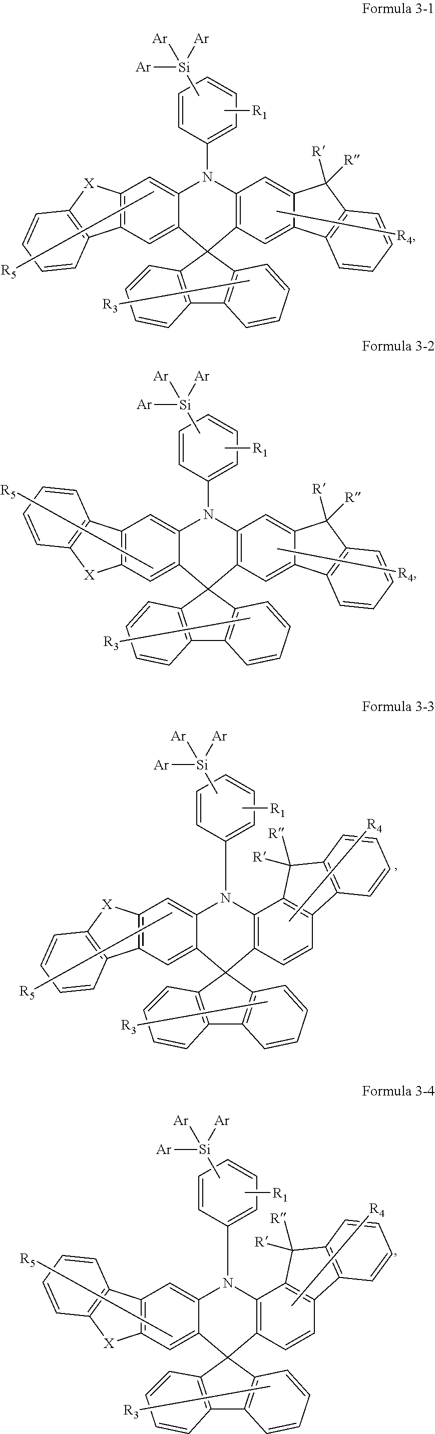 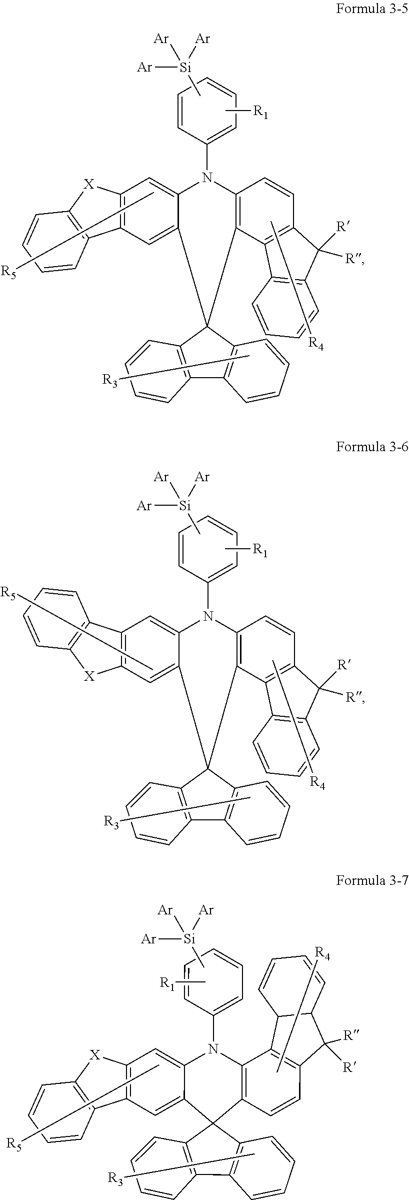 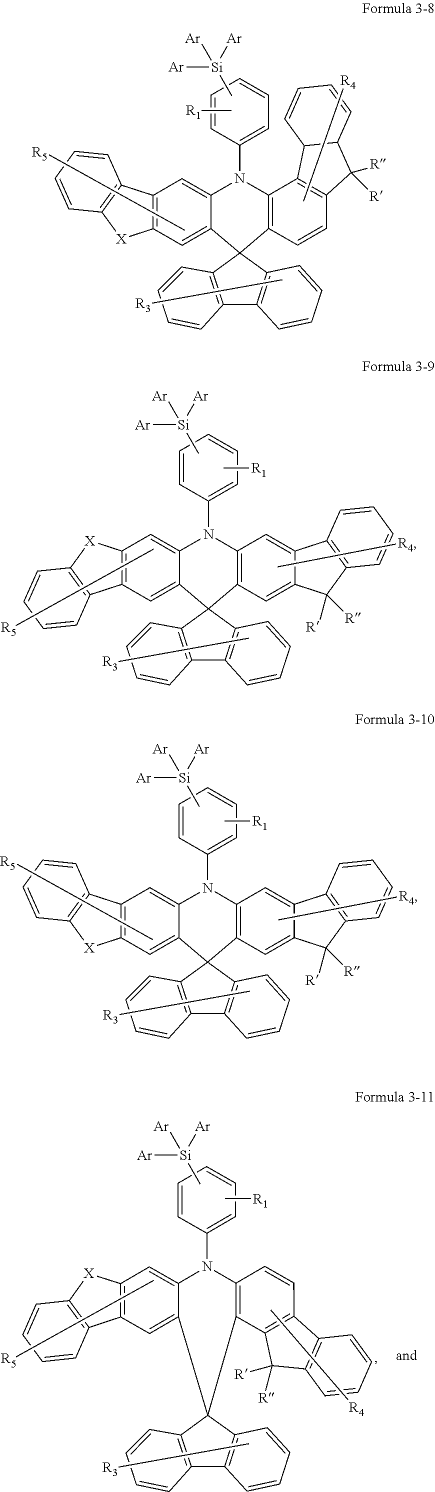 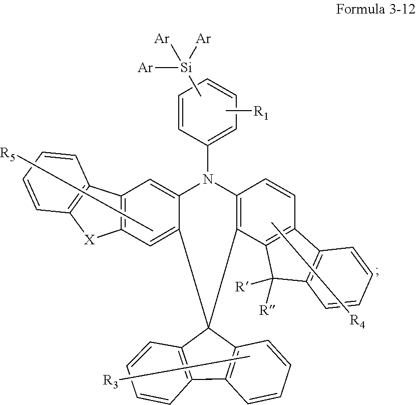
wherein Ar is, at each occurrence identically or differently, selected from substituted or unsubstituted aryl having 6 to 30 carbon atoms, substituted or unsubstituted heteroaryl having 3 to 30 carbon atoms or a combination thereof;
X is selected from CR′R″, SiR′R″, NR_{N}, O or S;
R₁, R₃, R₄ and R₅ represent, at each occurrence identically or differently, mono-substitution, multiple substitutions or non-substitution;
R₁, R₃, R₄, R₅, R′, R″ and R_{N} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R₁, R₃, R₄, R₅, R′, R″ and R_{N} can be optionally joined to form a ring;
preferably, the compound has a structure represented by Formula 3-1, Formula 3-2, Formula 3-9 or Formula 3-10.

7. The compound of claim 6, wherein the X is selected from CR′R″, NR_{N}, O or S;
preferably, the X is selected from CR′R″.

8. The compound of claim 1, wherein the Ar is, at each occurrence identically or differently, selected from substituted or unsubstituted aryl having 6 to 25 carbon atoms, substituted or unsubstituted heteroaryl having 3 to 25 carbon atoms or a combination thereof;
preferably, the Ar is, at each occurrence identically or differently, selected from substituted or unsubstituted aryl having 6 to 18 carbon atoms, substituted or unsubstituted heteroaryl having 3 to 18 carbon atoms or a combination thereof;
more preferably, the Ar is, at each occurrence identically or differently, selected from substituted or unsubstituted phenyl, substituted or unsubstituted biphenyl, substituted or unsubstituted terphenyl, substituted or unsubstituted naphthyl, substituted or unsubstituted fluorenyl, substituted or unsubstituted silafluorenyl, substituted or unsubstituted dibenzofuryl, substituted or unsubstituted dibenzothienyl, substituted or unsubstituted dibenzoselenophenyl, substituted or unsubstituted carbazolyl, substituted or unsubstituted phenanthryl, substituted or unsubstituted anthryl, substituted or unsubstituted pyrenyl or a combination thereof.

9. The compound of claim 1, wherein the R₁, R₂, R₃, R₄, R′, R″ and R_{N} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heterocyclyl having 3 to 20 ring atoms, substituted or unsubstituted aryl having 6 to 30 carbon atoms, substituted or unsubstituted heteroaryl having 3 to 30 carbon atoms, and combinations thereof;
preferably, the R₁, R₂, R₃, R₄, R′, R″ and R_{N} are, at each occurrence identically or differently, selected from the group consisting of: hydrogen, deuterium, halogen, substituted or unsubstituted alkyl having 1 to 20 carbon atoms, substituted or unsubstituted aryl having 6 to 30 carbon atoms, and combinations thereof.

10. The compound of claim 6, wherein the R₁, R₃, R₄, R₅, R′, R″ and R_{N} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heterocyclyl having 3 to 20 ring atoms, substituted or unsubstituted aryl having 6 to 30 carbon atoms, substituted or unsubstituted heteroaryl having 3 to 30 carbon atoms, and combinations thereof;
preferably, the R₁, R₃, R₄, R₅, R′, R″ and R_{N} are, at each occurrence identically or differently, selected from the group consisting of: hydrogen, deuterium, halogen, substituted or unsubstituted alkyl having 1 to 20 carbon atoms, substituted or unsubstituted aryl having 6 to 30 carbon atoms, and combinations thereof.

11. The compound of claim 1, wherein the compound is selected from the group consisting of Compound 1 to Compound 470: 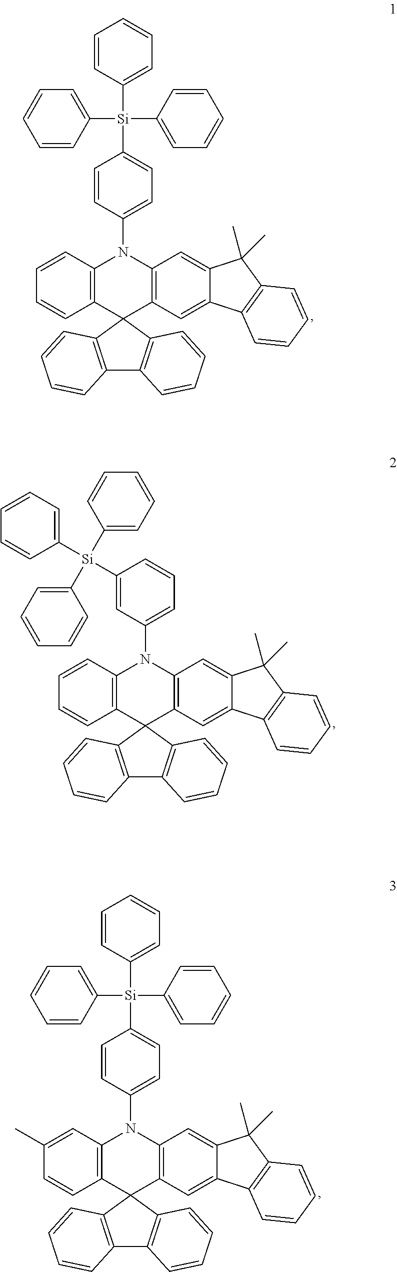 [SMILES: CC1(C)c2ccccc2-c2cc3c(cc21)N(c1ccc([Si](c2ccccc2)(c2ccccc2)c2ccccc2)cc1)c1ccccc1C31c2ccccc2-c2ccccc21 ; CC1(C)c2ccccc2-c2cc3c(cc21)N(c1cccc([Si](c2ccccc2)(c2ccccc2)c2ccccc2)c1)c1ccccc1C31c2ccccc2-c2ccccc21 ; Cc1ccc2c(c1)N(c1ccc([Si](c3ccccc3)(c3ccccc3)c3ccccc3)cc1)c1cc3c(cc1C21c2ccccc2-c2ccccc21)-c1ccccc1C3(C)C] 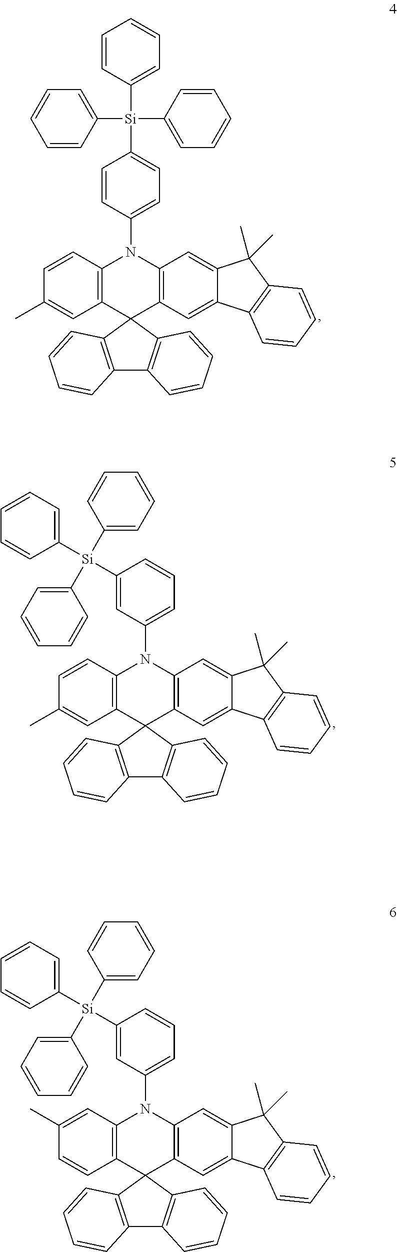 [SMILES: Cc1ccc2c(c1)C1(c3ccccc3-c3ccccc31)c1cc3c(cc1N2c1ccc([Si](c2ccccc2)(c2ccccc2)c2ccccc2)cc1)C(C)(C)c1ccccc1-3 ; Cc1ccc2c(c1)C1(c3ccccc3-c3ccccc31)c1cc3c(cc1N2c1cccc([Si](c2ccccc2)(c2ccccc2)c2ccccc2)c1)C(C)(C)c1ccccc1-3 ; Cc1ccc2c(c1)N(c1cccc([Si](c3ccccc3)(c3ccccc3)c3ccccc3)c1)c1cc3c(cc1C21c2ccccc2-c2ccccc21)-c1ccccc1C3(C)C] 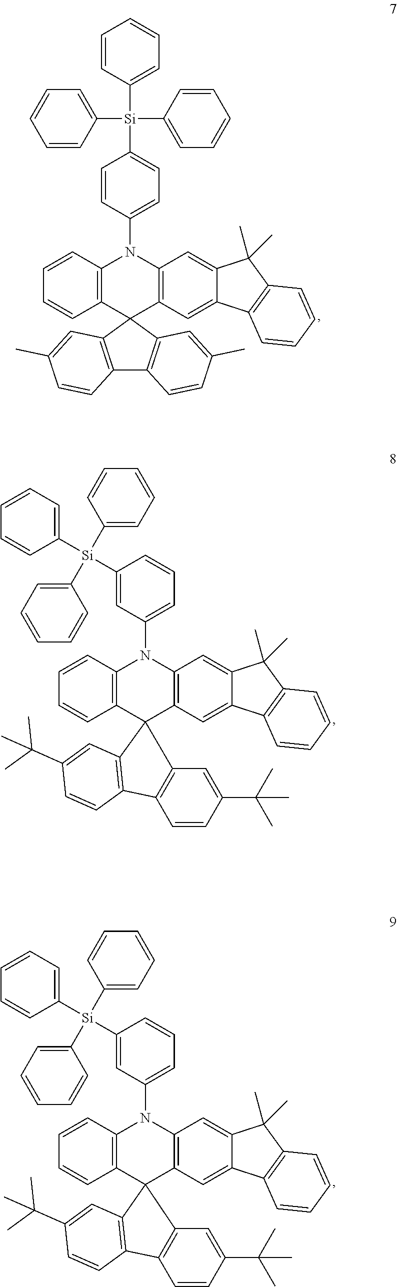 [SMILES: Cc1ccc2c(c1)C1(c3cc(C)ccc3-2)c2ccccc2N(c2ccc([Si](c3ccccc3)(c3ccccc3)c3ccccc3)cc2)c2cc3c(cc21)-c1ccccc1C3(C)C ; CC(C)(C)c1ccc2c(c1)C1(c3cc(C(C)(C)C)ccc3-2)c2ccccc2N(c2cccc([Si](c3ccccc3)(c3ccccc3)c3ccccc3)c2)c2cc3c(cc21)-c1ccccc1C3(C)C ; CC(C)(C)c1ccc2c(c1)C1(c3cc(C(C)(C)C)ccc3-2)c2ccccc2N(c2cccc([Si](c3ccccc3)(c3ccccc3)c3ccccc3)c2)c2cc3c(cc21)-c1ccccc1C3(C)C] 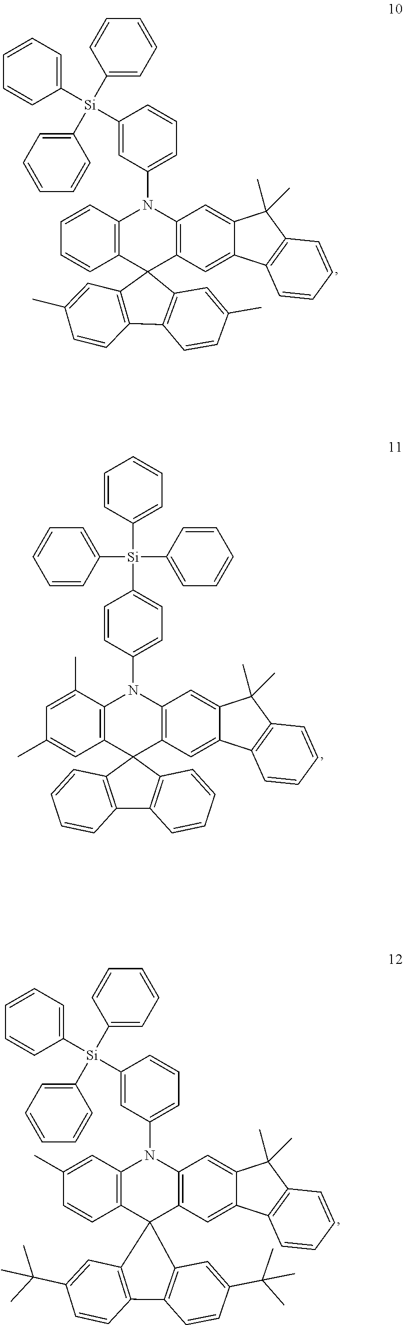 [SMILES: Cc1ccc2c(c1)C1(c3cc(C)ccc3-2)c2ccccc2N(c2cccc([Si](c3ccccc3)(c3ccccc3)c3ccccc3)c2)c2cc3c(cc21)-c1ccccc1C3(C)C ; Cc1cc(C)c2c(c1)C1(c3ccccc3-c3ccccc31)c1cc3c(cc1N2c1ccc([Si](c2ccccc2)(c2ccccc2)c2ccccc2)cc1)C(C)(C)c1ccccc1-3 ; Cc1ccc2c(c1)N(c1cccc([Si](c3ccccc3)(c3ccccc3)c3ccccc3)c1)c1cc3c(cc1C21c2cc(C(C)(C)C)ccc2-c2ccc(C(C)(C)C)cc21)-c1ccccc1C3(C)C] 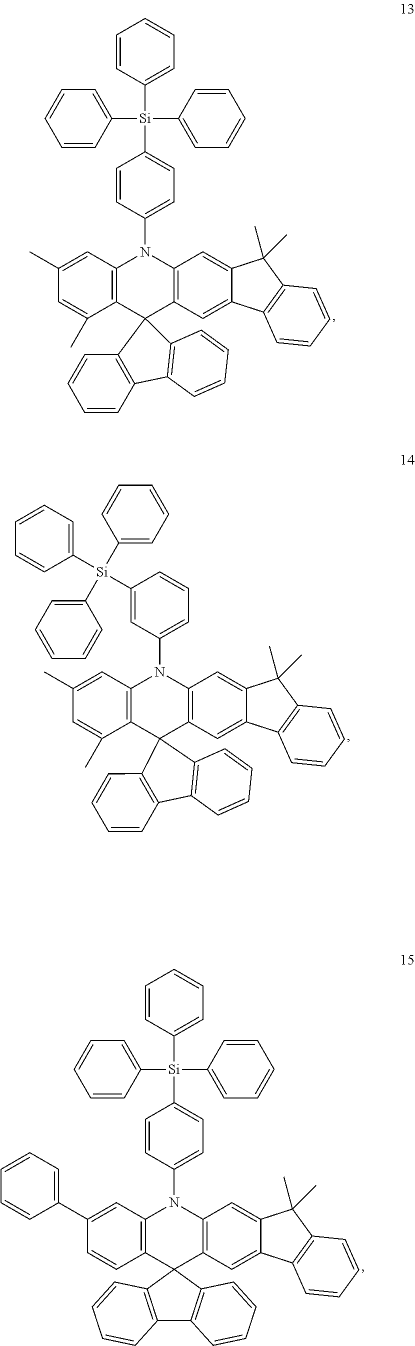 [SMILES: Cc1cc(C)c2c(c1)N(c1ccc([Si](c3ccccc3)(c3ccccc3)c3ccccc3)cc1)c1cc3c(cc1C21c2ccccc2-c2ccccc21)-c1ccccc1C3(C)C ; Cc1cc(C)c2c(c1)N(c1cccc([Si](c3ccccc3)(c3ccccc3)c3ccccc3)c1)c1cc3c(cc1C21c2ccccc2-c2ccccc21)-c1ccccc1C3(C)C ; CC1(C)c2ccccc2-c2cc3c(cc21)N(c1ccc([Si](c2ccccc2)(c2ccccc2)c2ccccc2)cc1)c1cc(-c2ccccc2)ccc1C31c2ccccc2-c2ccccc21] 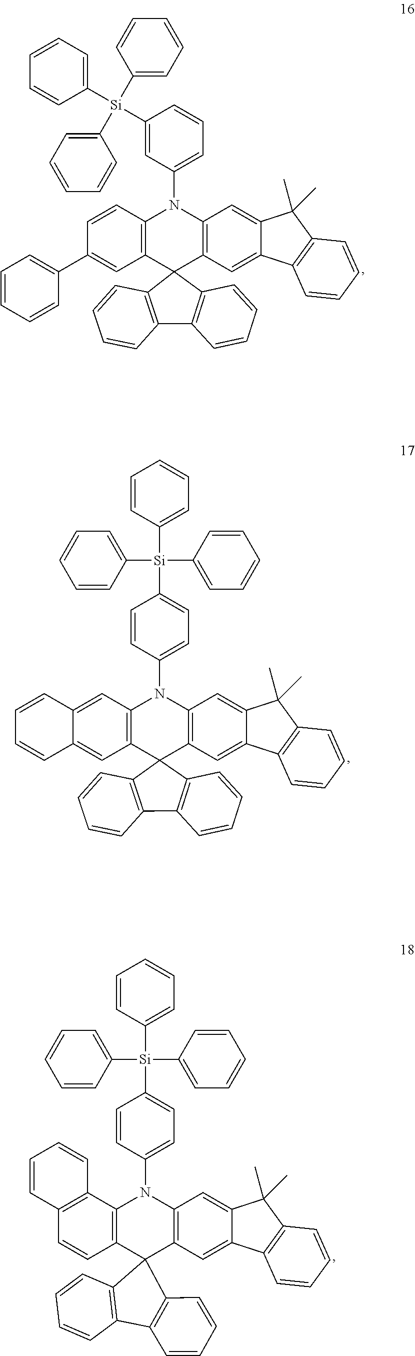 [SMILES: CC1(C)c2ccccc2-c2cc3c(cc21)N(c1cccc([Si](c2ccccc2)(c2ccccc2)c2ccccc2)c1)c1ccc(-c2ccccc2)cc1C31c2ccccc2-c2ccccc21 ; CC1(C)c2ccccc2-c2cc3c(cc21)N(c1ccc([Si](c2ccccc2)(c2ccccc2)c2ccccc2)cc1)c1cc2ccccc2cc1C31c2ccccc2-c2ccccc21 ; CC1(C)c2ccccc2-c2cc3c(cc21)N(c1ccc([Si](c2ccccc2)(c2ccccc2)c2ccccc2)cc1)c1c(ccc2ccccc12)C31c2ccccc2-c2ccccc21] 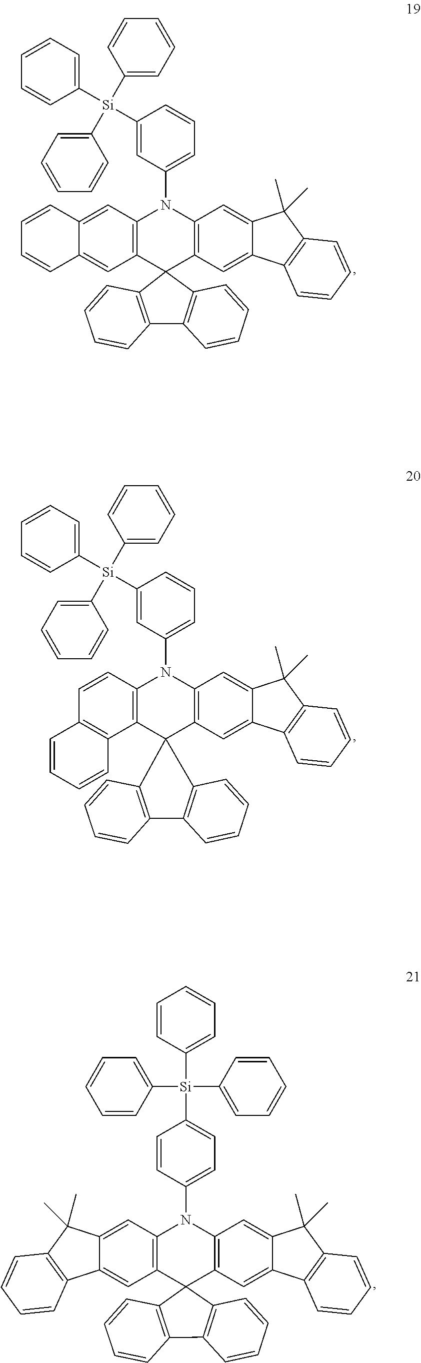 [SMILES: CC1(C)c2ccccc2-c2cc3c(cc21)N(c1cccc([Si](c2ccccc2)(c2ccccc2)c2ccccc2)c1)c1cc2ccccc2cc1C31c2ccccc2-c2ccccc21 ; CC1(C)c2ccccc2-c2cc3c(cc21)N(c1cccc([Si](c2ccccc2)(c2ccccc2)c2ccccc2)c1)c1ccc2ccccc2c1C31c2ccccc2-c2ccccc21 ; CC1(C)c2ccccc2-c2cc3c(cc21)N(c1ccc([Si](c2ccccc2)(c2ccccc2)c2ccccc2)cc1)c1cc2c(cc1C31c3ccccc3-c3ccccc31)-c1ccccc1C2(C)C] 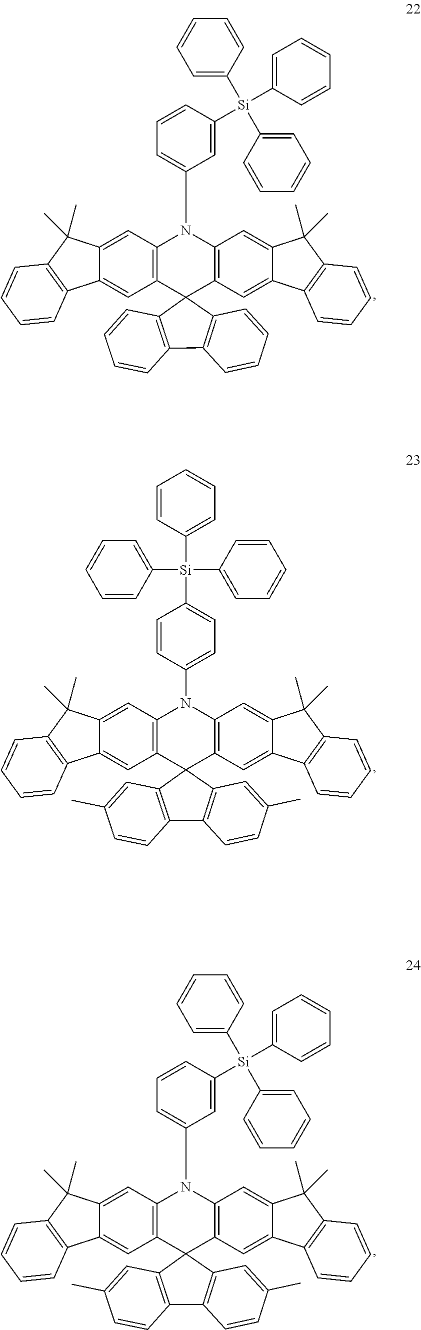 [SMILES: CC1(C)c2ccccc2-c2cc3c(cc21)N(c1cccc([Si](c2ccccc2)(c2ccccc2)c2ccccc2)c1)c1cc2c(cc1C31c3ccccc3-c3ccccc31)-c1ccccc1C2(C)C ; Cc1ccc2c(c1)C1(c3cc(C)ccc3-2)c2cc3c(cc2N(c2ccc([Si](c4ccccc4)(c4ccccc4)c4ccccc4)cc2)c2cc4c(cc21)-c1ccccc1C4(C)C)C(C)(C)c1ccccc1-3 ; Cc1ccc2c(c1)C1(c3cc(C)ccc3-2)c2cc3c(cc2N(c2cccc([Si](c4ccccc4)(c4ccccc4)c4ccccc4)c2)c2cc4c(cc21)-c1ccccc1C4(C)C)C(C)(C)c1ccccc1-3] 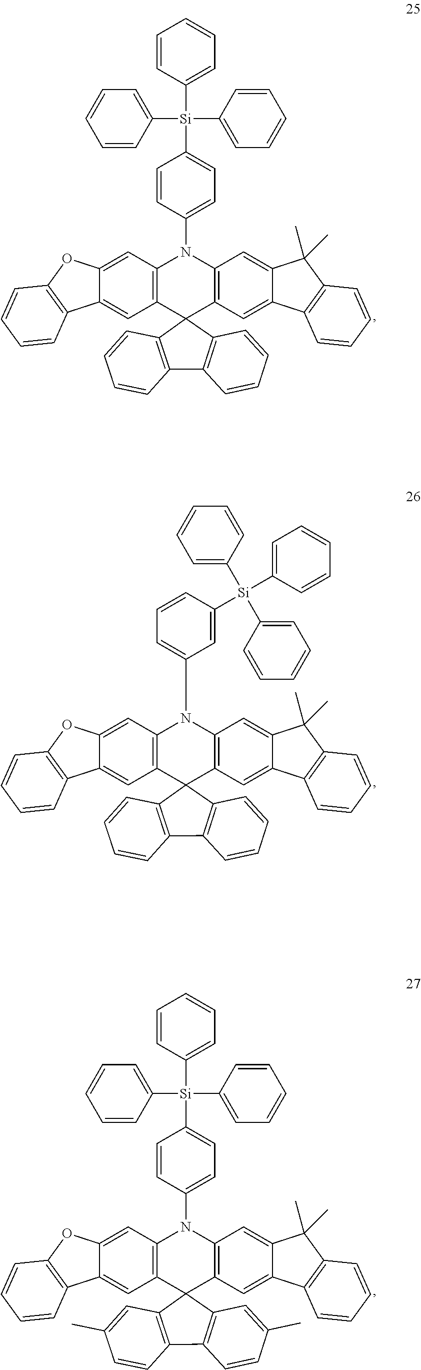 [SMILES: CC1(C)c2ccccc2-c2cc3c(cc21)N(c1ccc([Si](c2ccccc2)(c2ccccc2)c2ccccc2)cc1)c1cc2oc4ccccc4c2cc1C31c2ccccc2-c2ccccc21 ; CC1(C)c2ccccc2-c2cc3c(cc21)N(c1cccc([Si](c2ccccc2)(c2ccccc2)c2ccccc2)c1)c1cc2oc4ccccc4c2cc1C31c2ccccc2-c2ccccc21 ; Cc1ccc2c(c1)C1(c3cc(C)ccc3-2)c2cc3c(cc2N(c2ccc([Si](c4ccccc4)(c4ccccc4)c4ccccc4)cc2)c2cc4oc5ccccc5c4cc21)C(C)(C)c1ccccc1-3] 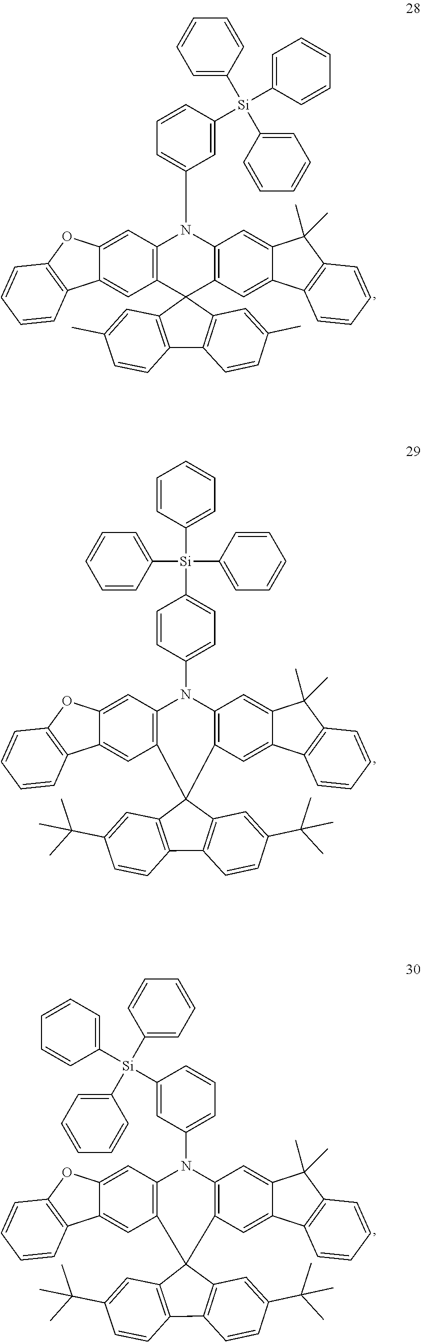 [SMILES: Cc1ccc2c(c1)C1(c3cc(C)ccc3-2)c2cc3c(cc2N(c2cccc([Si](c4ccccc4)(c4ccccc4)c4ccccc4)c2)c2cc4oc5ccccc5c4cc21)C(C)(C)c1ccccc1-3 ; CC(C)(C)c1ccc2c(c1)C1(c3cc(C(C)(C)C)ccc3-2)c2cc3c(cc2N(c2ccc([Si](c4ccccc4)(c4ccccc4)c4ccccc4)cc2)c2cc4oc5ccccc5c4cc21)C(C)(C)c1ccccc1-3 ; CC(C)(C)c1ccc2c(c1)C1(c3cc(C(C)(C)C)ccc3-2)c2cc3c(cc2N(c2cccc([Si](c4ccccc4)(c4ccccc4)c4ccccc4)c2)c2cc4oc5ccccc5c4cc21)C(C)(C)c1ccccc1-3] 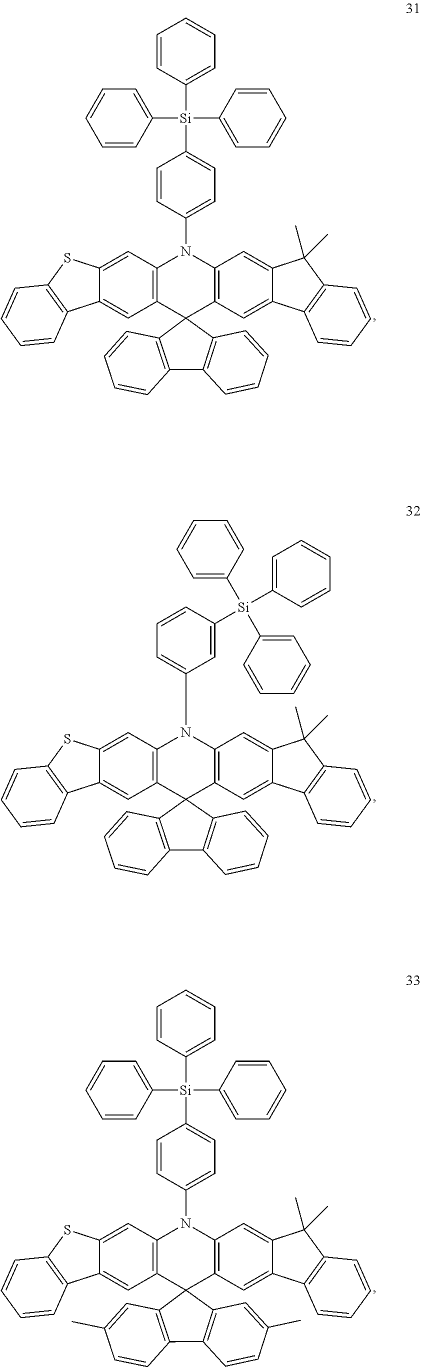 [SMILES: CC1(C)c2ccccc2-c2cc3c(cc21)N(c1ccc([Si](c2ccccc2)(c2ccccc2)c2ccccc2)cc1)c1cc2sc4ccccc4c2cc1C31c2ccccc2-c2ccccc21 ; CC1(C)c2ccccc2-c2cc3c(cc21)N(c1cccc([Si](c2ccccc2)(c2ccccc2)c2ccccc2)c1)c1cc2sc4ccccc4c2cc1C31c2ccccc2-c2ccccc21 ; Cc1ccc2c(c1)C1(c3cc(C)ccc3-2)c2cc3c(cc2N(c2ccc([Si](c4ccccc4)(c4ccccc4)c4ccccc4)cc2)c2cc4sc5ccccc5c4cc21)C(C)(C)c1ccccc1-3] 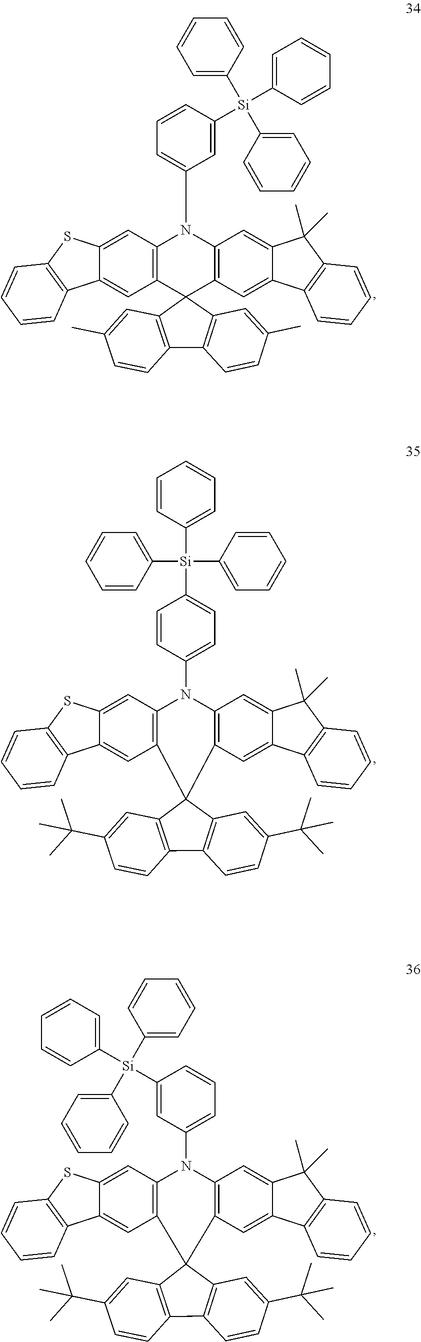 [SMILES: Cc1ccc2c(c1)C1(c3cc(C)ccc3-2)c2cc3c(cc2N(c2cccc([Si](c4ccccc4)(c4ccccc4)c4ccccc4)c2)c2cc4sc5ccccc5c4cc21)C(C)(C)c1ccccc1-3 ; CC(C)(C)c1ccc2c(c1)C1(c3cc(C(C)(C)C)ccc3-2)c2cc3c(cc2N(c2ccc([Si](c4ccccc4)(c4ccccc4)c4ccccc4)cc2)c2cc4sc5ccccc5c4cc21)C(C)(C)c1ccccc1-3 ; CC(C)(C)c1ccc2c(c1)C1(c3cc(C(C)(C)C)ccc3-2)c2cc3c(cc2N(c2cccc([Si](c4ccccc4)(c4ccccc4)c4ccccc4)c2)c2cc4sc5ccccc5c4cc21)C(C)(C)c1ccccc1-3] 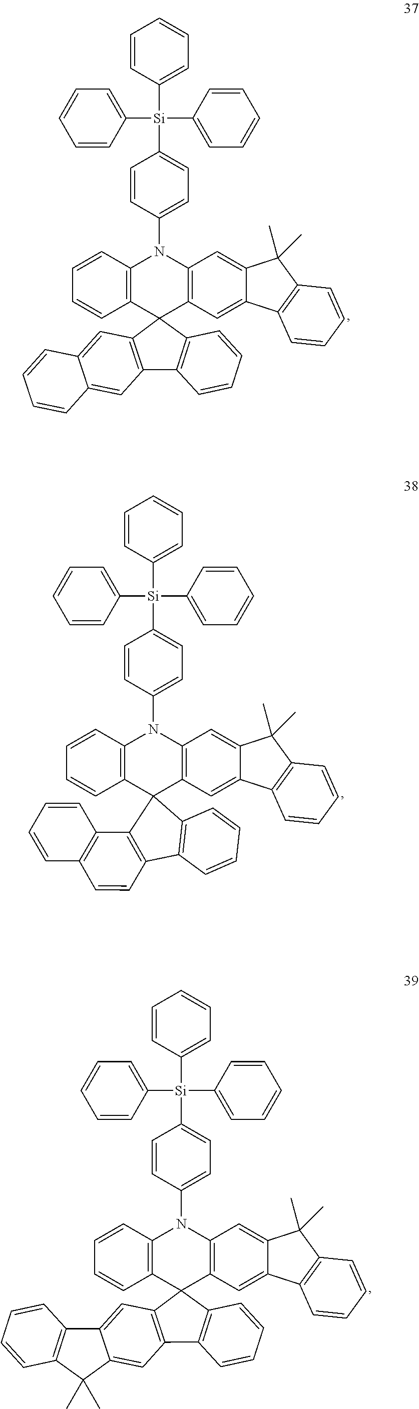 [SMILES: CC1(C)c2ccccc2-c2cc3c(cc21)N(c1ccc([Si](c2ccccc2)(c2ccccc2)c2ccccc2)cc1)c1ccccc1C31c2ccccc2-c2cc3ccccc3cc21 ; CC1(C)c2ccccc2-c2cc3c(cc21)N(c1ccc([Si](c2ccccc2)(c2ccccc2)c2ccccc2)cc1)c1ccccc1C31c2ccccc2-c2ccc3ccccc3c21 ; CC1(C)c2ccccc2-c2cc3c(cc21)-c1ccccc1C31c2ccccc2N(c2ccc([Si](c3ccccc3)(c3ccccc3)c3ccccc3)cc2)c2cc3c(cc21)-c1ccccc1C3(C)C] 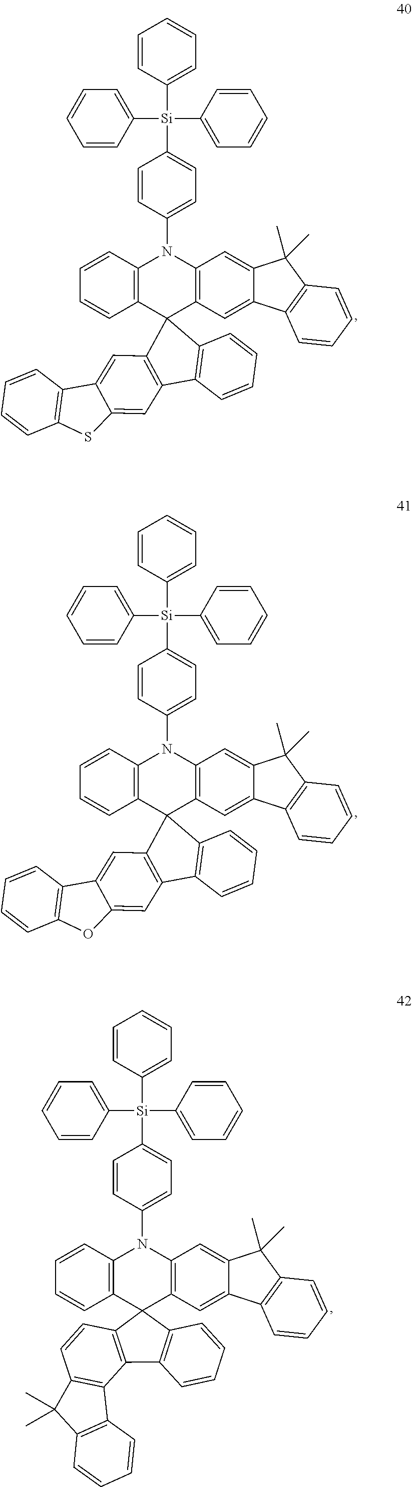 [SMILES: CC1(C)c2ccccc2-c2cc3c(cc21)N(c1ccc([Si](c2ccccc2)(c2ccccc2)c2ccccc2)cc1)c1ccccc1C31c2ccccc2-c2cc3sc4ccccc4c3cc21 ; CC1(C)c2ccccc2-c2cc3c(cc21)N(c1ccc([Si](c2ccccc2)(c2ccccc2)c2ccccc2)cc1)c1ccccc1C31c2ccccc2-c2cc3oc4ccccc4c3cc21 ; CC1(C)c2ccccc2-c2cc3c(cc21)N(c1ccc([Si](c2ccccc2)(c2ccccc2)c2ccccc2)cc1)c1ccccc1C31c2ccccc2-c2c1ccc1c2-c2ccccc2C1(C)C] 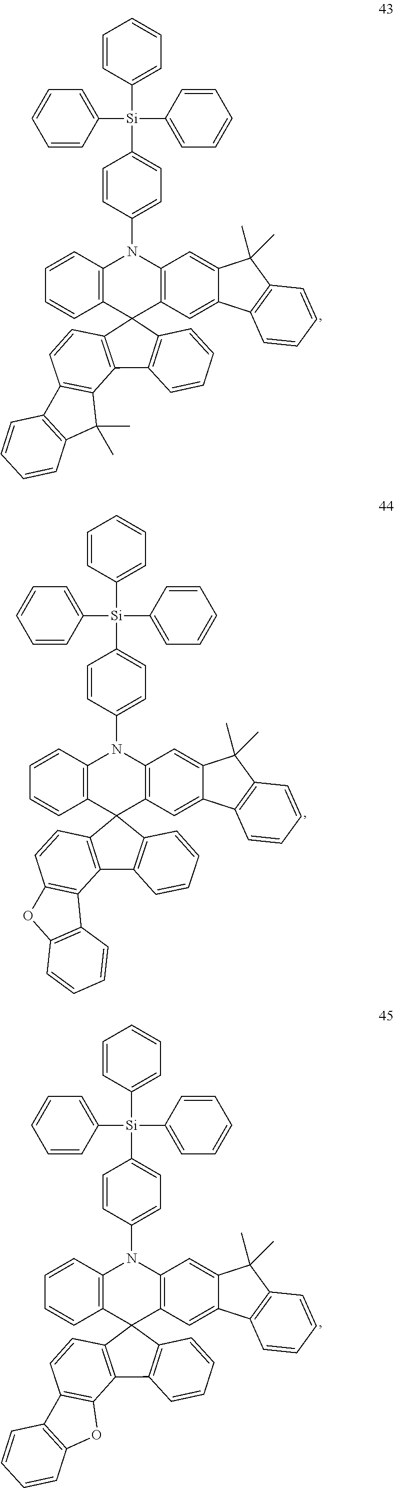 [SMILES: CC1(C)c2ccccc2-c2cc3c(cc21)N(c1ccc([Si](c2ccccc2)(c2ccccc2)c2ccccc2)cc1)c1ccccc1C31c2ccccc2-c2c1ccc1c2C(C)(C)c2ccccc2-1 ; CC1(C)c2ccccc2-c2cc3c(cc21)N(c1ccc([Si](c2ccccc2)(c2ccccc2)c2ccccc2)cc1)c1ccccc1C31c2ccccc2-c2c1ccc1oc3ccccc3c21 ; CC1(C)c2ccccc2-c2cc3c(cc21)N(c1ccc([Si](c2ccccc2)(c2ccccc2)c2ccccc2)cc1)c1ccccc1C31c2ccccc2-c2c1ccc1c2oc2ccccc21] 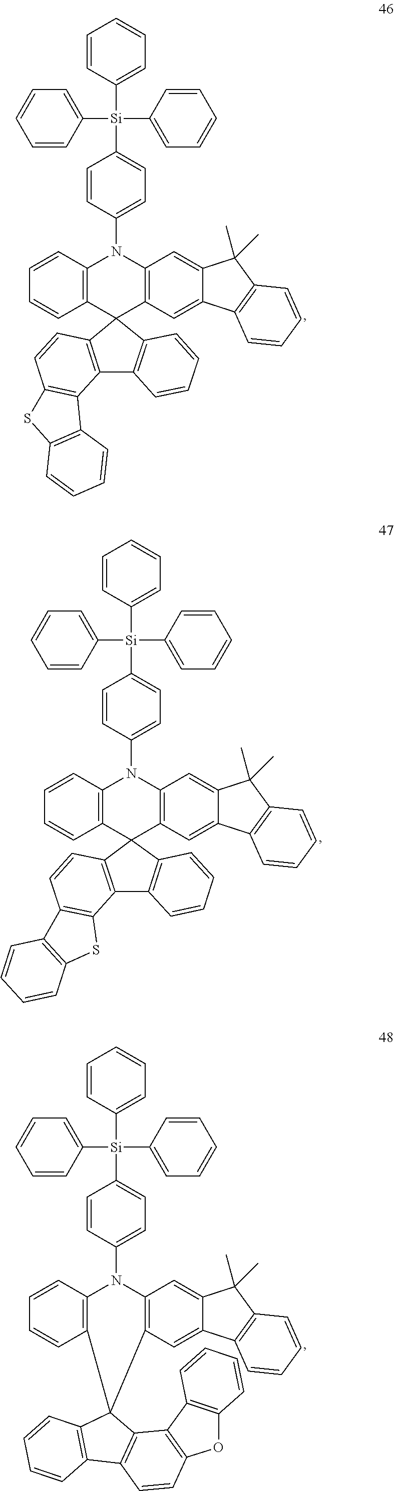 [SMILES: CC1(C)c2ccccc2-c2cc3c(cc21)N(c1ccc([Si](c2ccccc2)(c2ccccc2)c2ccccc2)cc1)c1ccccc1C31c2ccccc2-c2c1ccc1sc3ccccc3c21 ; CC1(C)c2ccccc2-c2cc3c(cc21)N(c1ccc([Si](c2ccccc2)(c2ccccc2)c2ccccc2)cc1)c1ccccc1C31c2ccccc2-c2c1ccc1c2sc2ccccc21 ; CC1(C)c2ccccc2-c2cc3c(cc21)N(c1ccc([Si](c2ccccc2)(c2ccccc2)c2ccccc2)cc1)c1ccccc1C31c2ccccc2-c2ccc3oc4ccccc4c3c21] 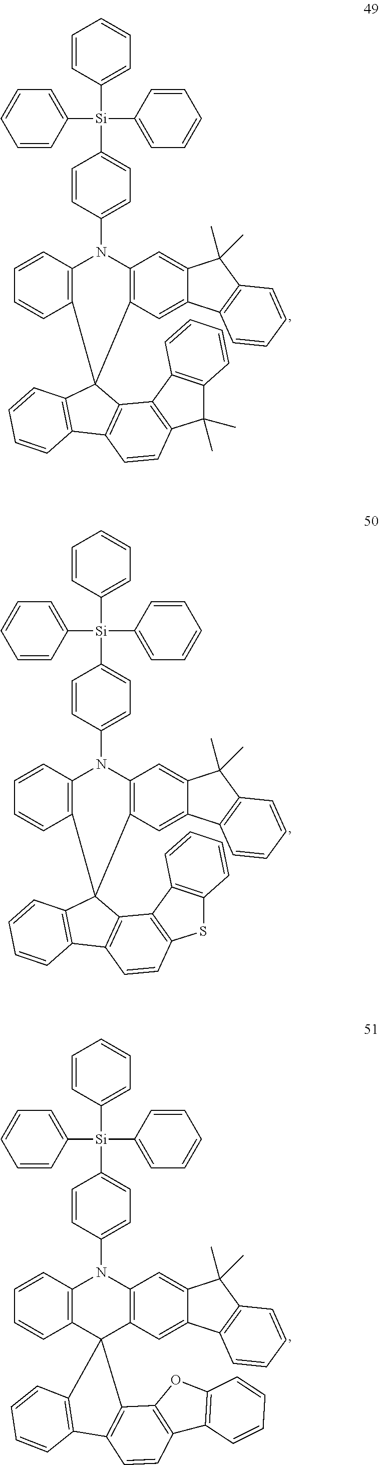 [SMILES: CC1(C)c2ccccc2-c2cc3c(cc21)N(c1ccc([Si](c2ccccc2)(c2ccccc2)c2ccccc2)cc1)c1ccccc1C31c2ccccc2-c2ccc3c(c21)-c1ccccc1C3(C)C ; CC1(C)c2ccccc2-c2cc3c(cc21)N(c1ccc([Si](c2ccccc2)(c2ccccc2)c2ccccc2)cc1)c1ccccc1C31c2ccccc2-c2ccc3sc4ccccc4c3c21 ; CC1(C)c2ccccc2-c2cc3c(cc21)N(c1ccc([Si](c2ccccc2)(c2ccccc2)c2ccccc2)cc1)c1ccccc1C31c2ccccc2-c2ccc3c(oc4ccccc43)c21] 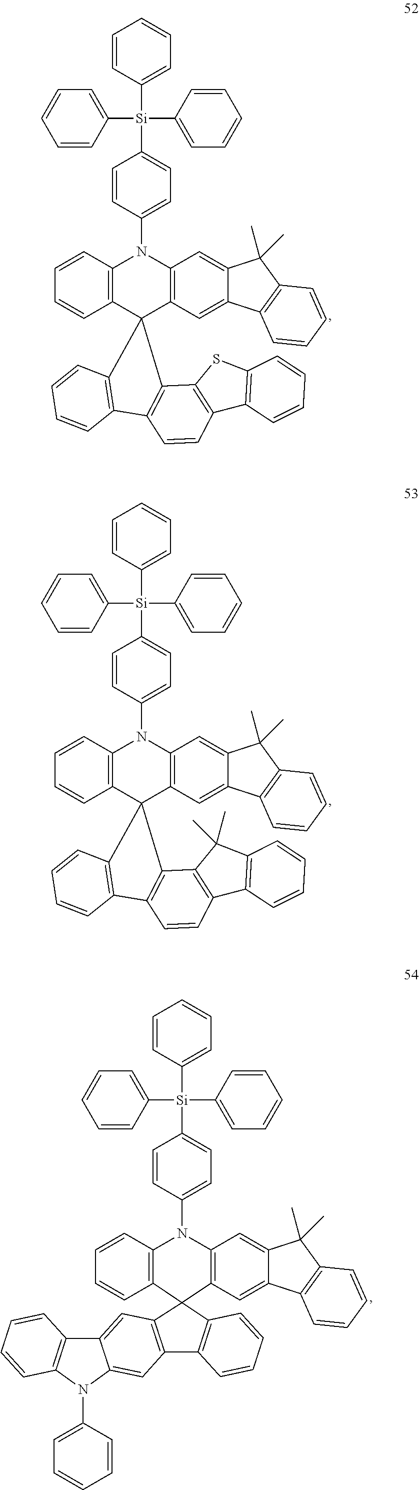 [SMILES: CC1(C)c2ccccc2-c2cc3c(cc21)N(c1ccc([Si](c2ccccc2)(c2ccccc2)c2ccccc2)cc1)c1ccccc1C31c2ccccc2-c2ccc3c(sc4ccccc43)c21 ; CC1(C)c2ccccc2-c2cc3c(cc21)N(c1ccc([Si](c2ccccc2)(c2ccccc2)c2ccccc2)cc1)c1ccccc1C31c2ccccc2-c2ccc3c(c21)C(C)(C)c1ccccc1-3 ; CC1(C)c2ccccc2-c2cc3c(cc21)N(c1ccc([Si](c2ccccc2)(c2ccccc2)c2ccccc2)cc1)c1ccccc1C31c2ccccc2-c2cc3c(cc21)c1ccccc1n3-c1ccccc1] 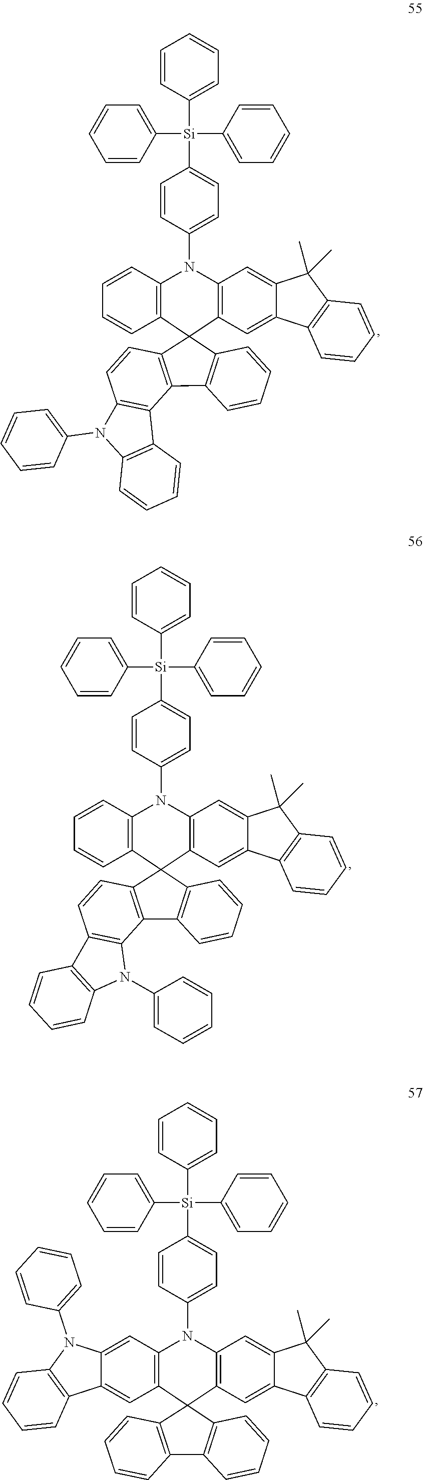 [SMILES: CC1(C)c2ccccc2-c2cc3c(cc21)N(c1ccc([Si](c2ccccc2)(c2ccccc2)c2ccccc2)cc1)c1ccccc1C31c2ccccc2-c2c1ccc1c2c2ccccc2n1-c1ccccc1 ; CC1(C)c2ccccc2-c2cc3c(cc21)N(c1ccc([Si](c2ccccc2)(c2ccccc2)c2ccccc2)cc1)c1ccccc1C31c2ccccc2-c2c1ccc1c3ccccc3n(-c3ccccc3)c21 ; CC1(C)c2ccccc2-c2cc3c(cc21)N(c1ccc([Si](c2ccccc2)(c2ccccc2)c2ccccc2)cc1)c1cc2c(cc1C31c3ccccc3-c3ccccc31)c1ccccc1n2-c1ccccc1] 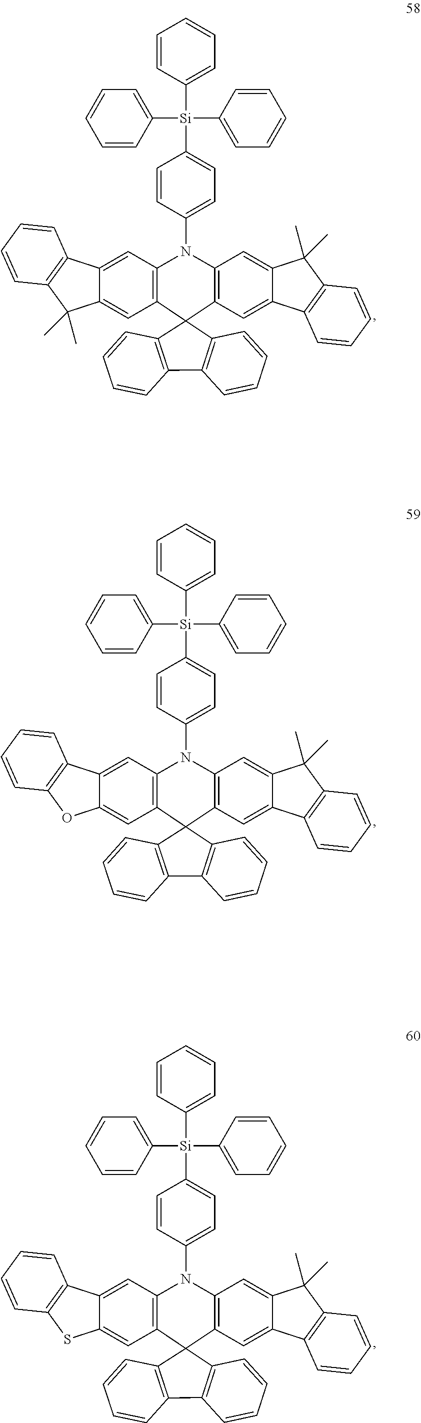 [SMILES: CC1(C)c2ccccc2-c2cc3c(cc21)N(c1ccc([Si](c2ccccc2)(c2ccccc2)c2ccccc2)cc1)c1cc2c(cc1C31c3ccccc3-c3ccccc31)C(C)(C)c1ccccc1-2 ; CC1(C)c2ccccc2-c2cc3c(cc21)N(c1ccc([Si](c2ccccc2)(c2ccccc2)c2ccccc2)cc1)c1cc2c(cc1C31c3ccccc3-c3ccccc31)oc1ccccc12 ; CC1(C)c2ccccc2-c2cc3c(cc21)N(c1ccc([Si](c2ccccc2)(c2ccccc2)c2ccccc2)cc1)c1cc2c(cc1C31c3ccccc3-c3ccccc31)sc1ccccc12] 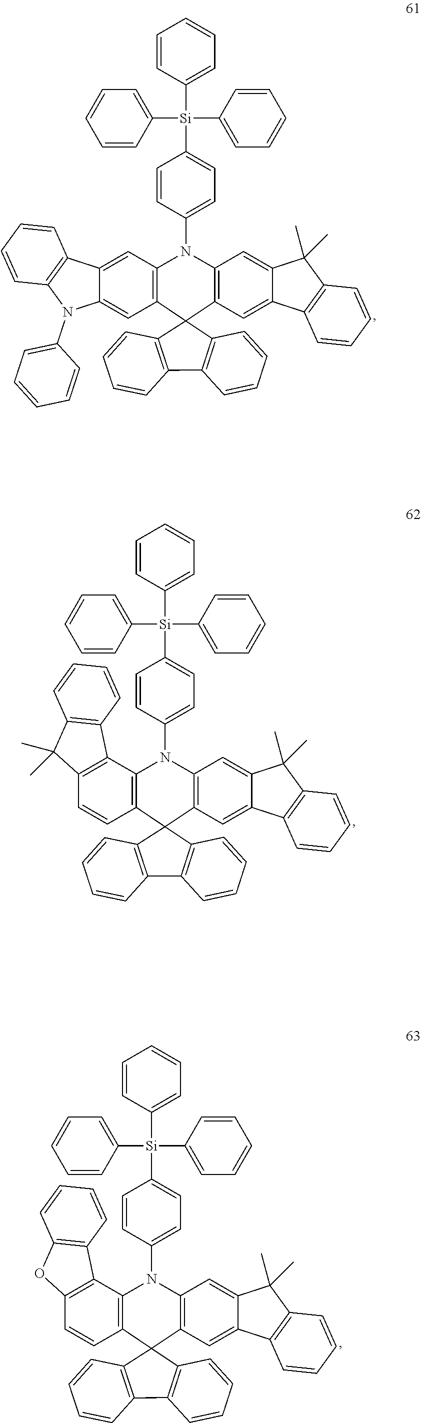 [SMILES: CC1(C)c2ccccc2-c2cc3c(cc21)N(c1ccc([Si](c2ccccc2)(c2ccccc2)c2ccccc2)cc1)c1cc2c4ccccc4n(-c4ccccc4)c2cc1C31c2ccccc2-c2ccccc21 ; CC1(C)c2ccccc2-c2cc3c(cc21)N(c1ccc([Si](c2ccccc2)(c2ccccc2)c2ccccc2)cc1)c1c(ccc2c1-c1ccccc1C2(C)C)C31c2ccccc2-c2ccccc21 ; CC1(C)c2ccccc2-c2cc3c(cc21)N(c1ccc([Si](c2ccccc2)(c2ccccc2)c2ccccc2)cc1)c1c(ccc2oc4ccccc4c12)C31c2ccccc2-c2ccccc21] 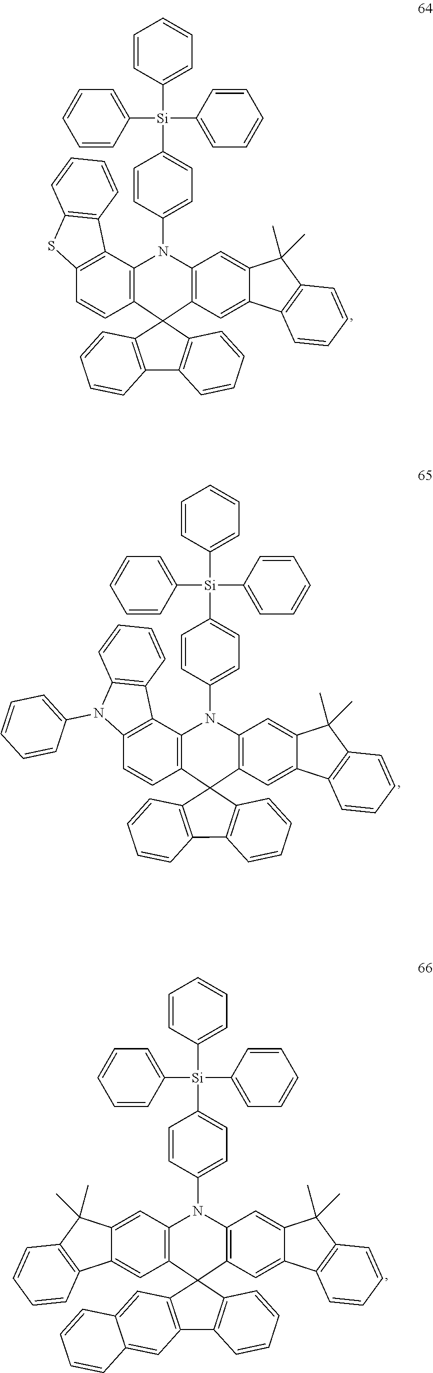 [SMILES: CC1(C)c2ccccc2-c2cc3c(cc21)N(c1ccc([Si](c2ccccc2)(c2ccccc2)c2ccccc2)cc1)c1c(ccc2sc4ccccc4c12)C31c2ccccc2-c2ccccc21 ; CC1(C)c2ccccc2-c2cc3c(cc21)N(c1ccc([Si](c2ccccc2)(c2ccccc2)c2ccccc2)cc1)c1c(ccc2c1c1ccccc1n2-c1ccccc1)C31c2ccccc2-c2ccccc21 ; CC1(C)c2ccccc2-c2cc3c(cc21)N(c1ccc([Si](c2ccccc2)(c2ccccc2)c2ccccc2)cc1)c1cc2c(cc1C31c3ccccc3-c3cc4ccccc4cc31)-c1ccccc1C2(C)C] 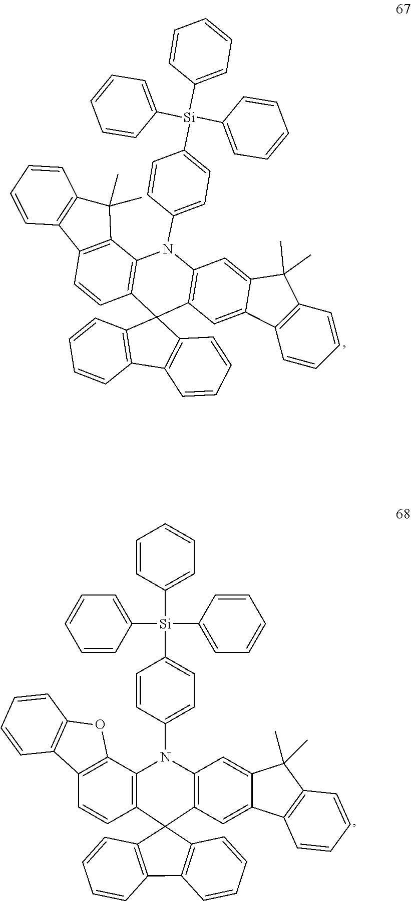 [SMILES: CC1(C)c2ccccc2-c2cc3c(cc21)N(c1ccc([Si](c2ccccc2)(c2ccccc2)c2ccccc2)cc1)c1c(ccc2c1C(C)(C)c1ccccc1-2)C31c2ccccc2-c2ccccc21 ; CC1(C)c2ccccc2-c2cc3c(cc21)N(c1ccc([Si](c2ccccc2)(c2ccccc2)c2ccccc2)cc1)c1c(ccc2c1oc1ccccc12)C31c2ccccc2-c2ccccc21] 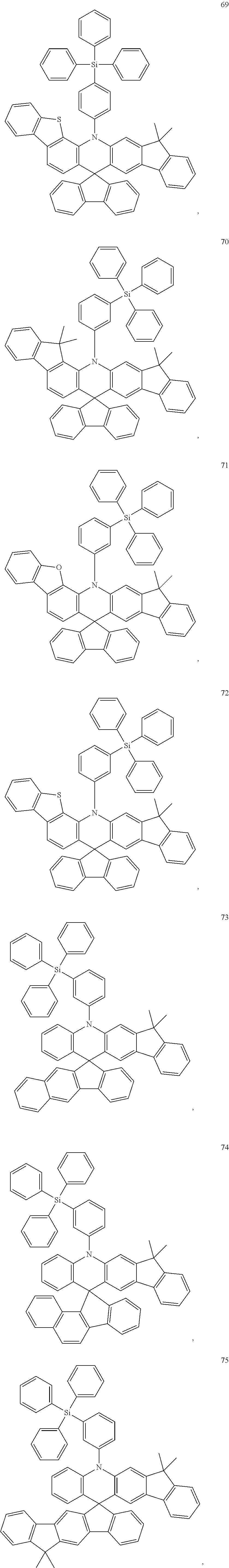 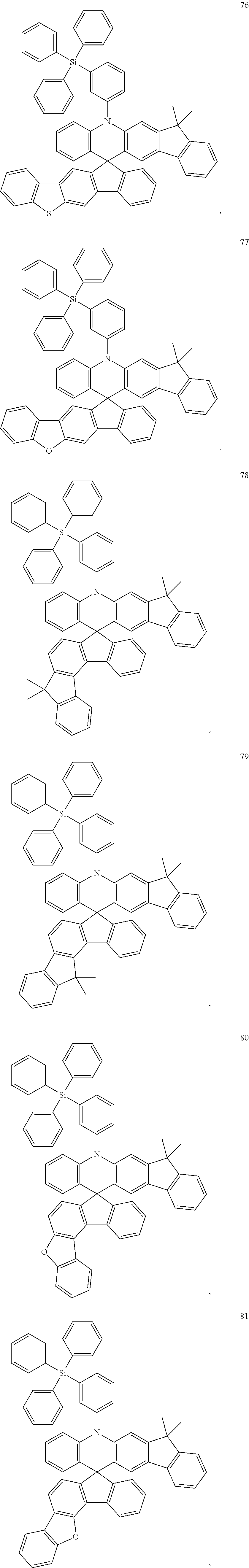 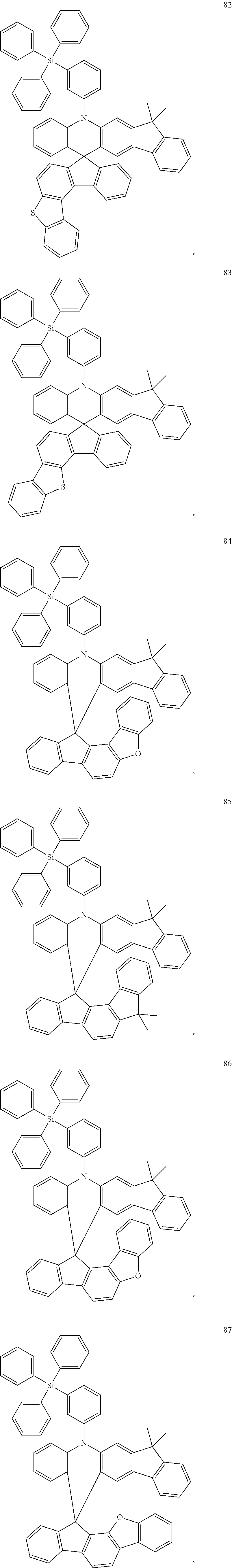 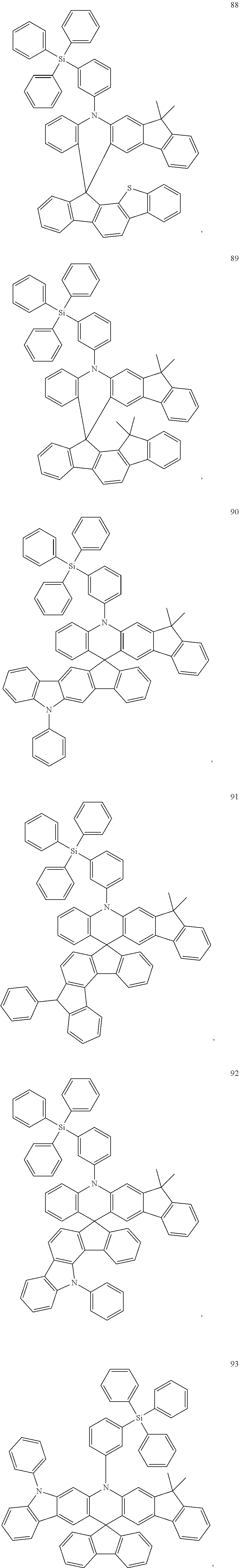 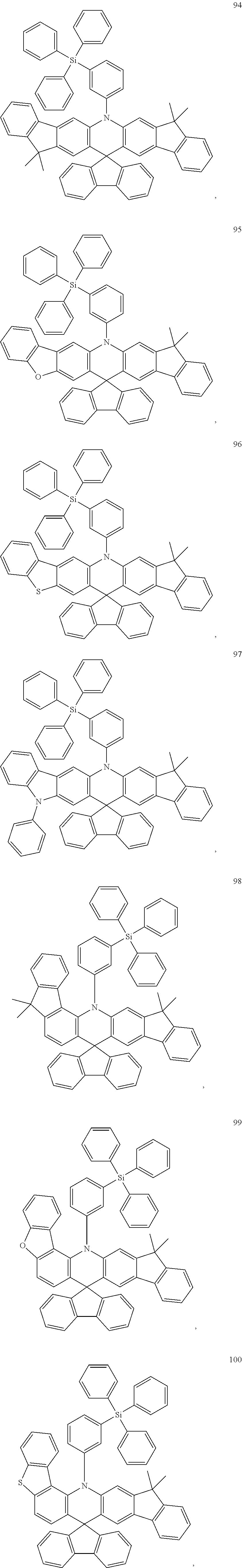 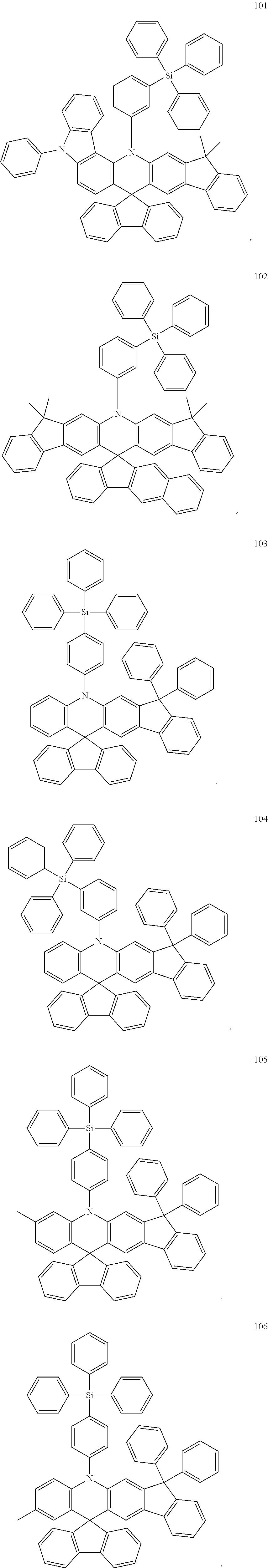 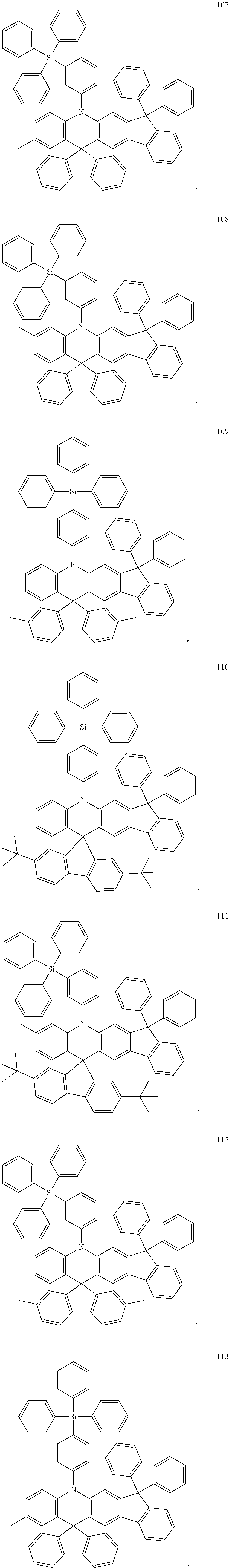 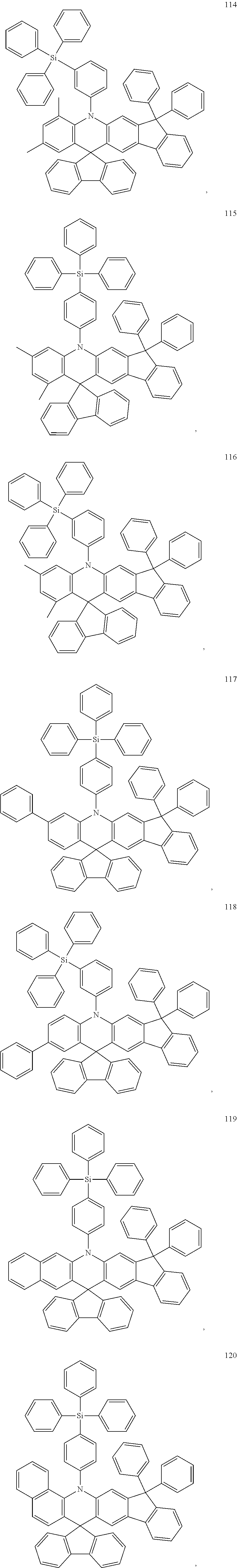 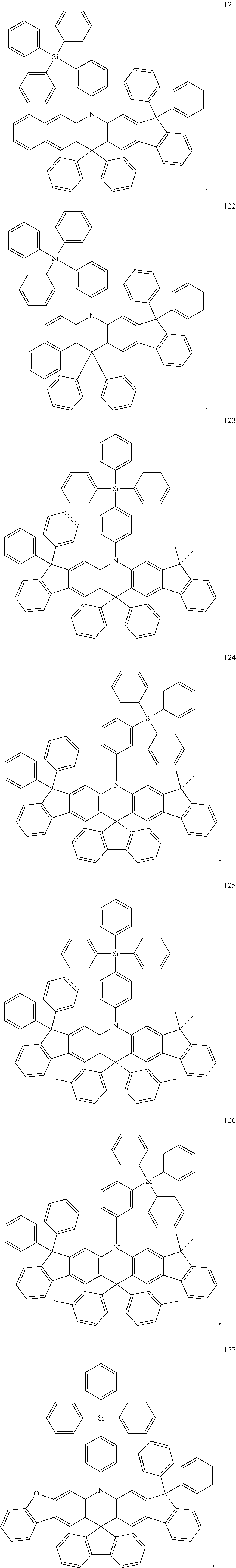 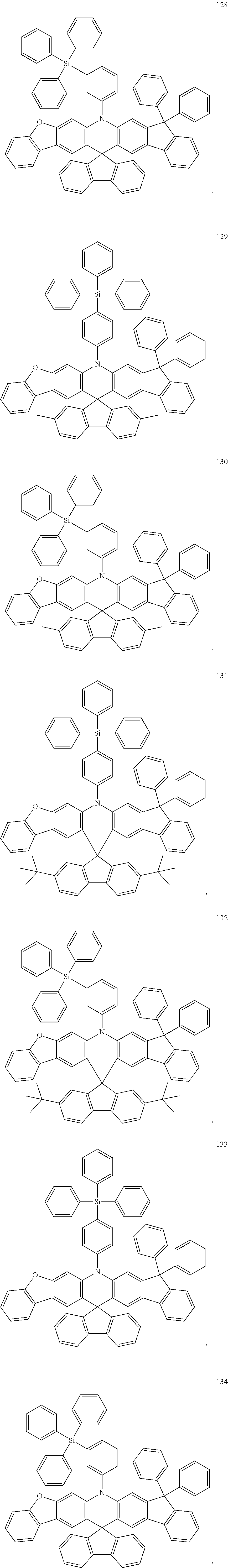 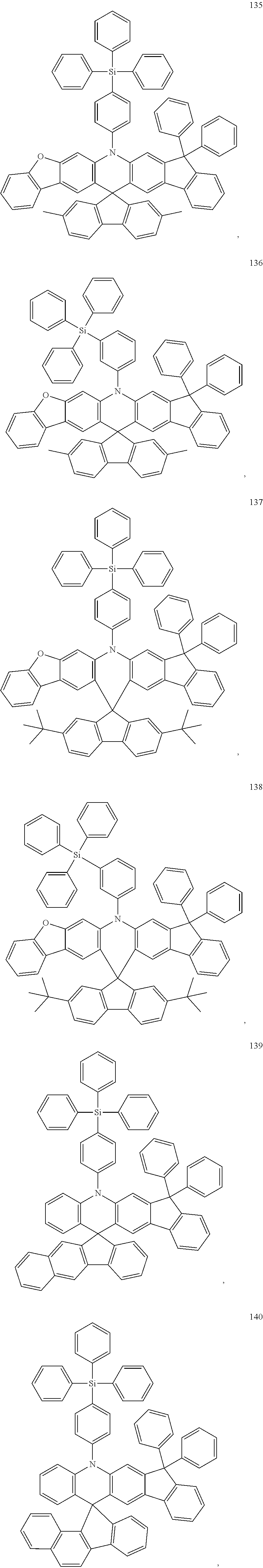 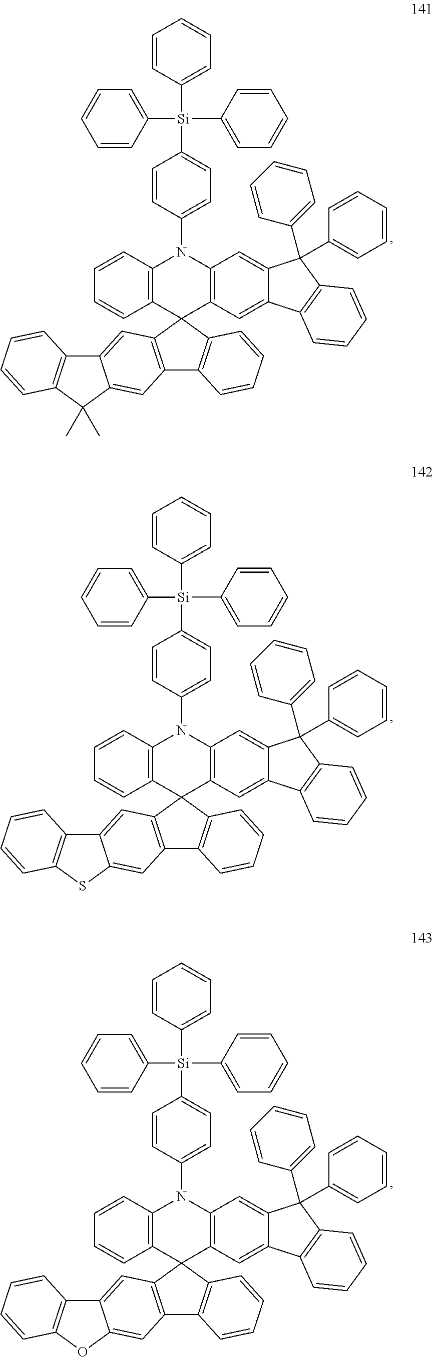 [SMILES: CC1(C)c2ccccc2-c2cc3c(cc21)-c1ccccc1C31c2ccccc2N(c2ccc([Si](c3ccccc3)(c3ccccc3)c3ccccc3)cc2)c2cc3c(cc21)-c1ccccc1C3(c1ccccc1)c1ccccc1 ; c1ccc(C2(c3ccccc3)c3ccccc3-c3cc4c(cc32)N(c2ccc([Si](c3ccccc3)(c3ccccc3)c3ccccc3)cc2)c2ccccc2C42c3ccccc3-c3cc4sc5ccccc5c4cc32)cc1 ; c1ccc(C2(c3ccccc3)c3ccccc3-c3cc4c(cc32)N(c2ccc([Si](c3ccccc3)(c3ccccc3)c3ccccc3)cc2)c2ccccc2C42c3ccccc3-c3cc4oc5ccccc5c4cc32)cc1] 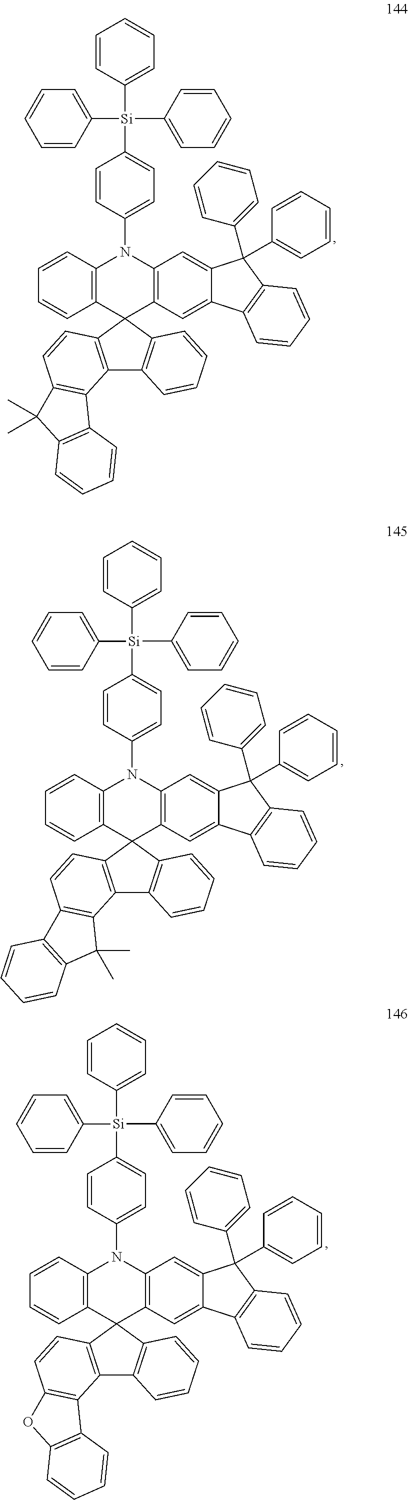 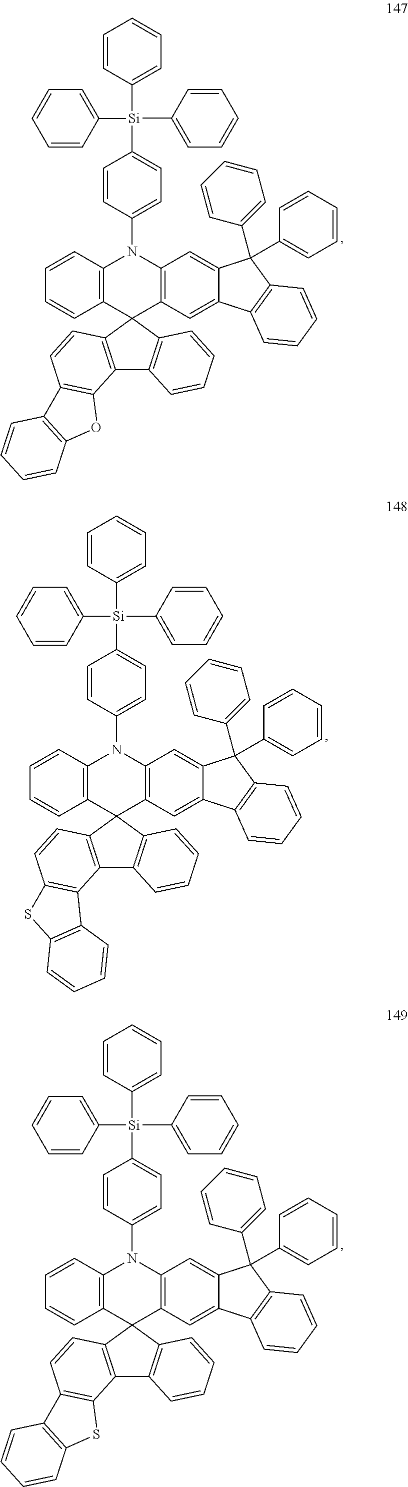 [SMILES: c1ccc(C2(c3ccccc3)c3ccccc3-c3cc4c(cc32)N(c2ccc([Si](c3ccccc3)(c3ccccc3)c3ccccc3)cc2)c2ccccc2C42c3ccccc3-c3c2ccc2c3oc3ccccc32)cc1 ; c1ccc(C2(c3ccccc3)c3ccccc3-c3cc4c(cc32)N(c2ccc([Si](c3ccccc3)(c3ccccc3)c3ccccc3)cc2)c2ccccc2C42c3ccccc3-c3c2ccc2sc4ccccc4c32)cc1 ; c1ccc(C2(c3ccccc3)c3ccccc3-c3cc4c(cc32)N(c2ccc([Si](c3ccccc3)(c3ccccc3)c3ccccc3)cc2)c2ccccc2C42c3ccccc3-c3c2ccc2c3sc3ccccc32)cc1] 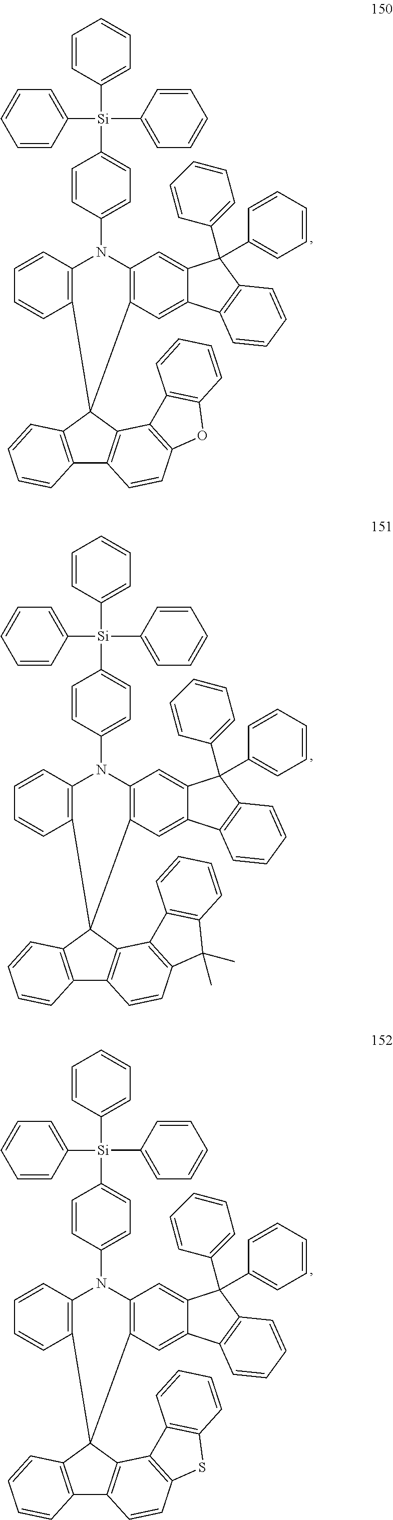 [SMILES: c1ccc(C2(c3ccccc3)c3ccccc3-c3cc4c(cc32)N(c2ccc([Si](c3ccccc3)(c3ccccc3)c3ccccc3)cc2)c2ccccc2C42c3ccccc3-c3ccc4oc5ccccc5c4c32)cc1 ; CC1(C)c2ccccc2-c2c1ccc1c2C2(c3ccccc3-1)c1ccccc1N(c1ccc([Si](c3ccccc3)(c3ccccc3)c3ccccc3)cc1)c1cc3c(cc12)-c1ccccc1C3(c1ccccc1)c1ccccc1 ; c1ccc(C2(c3ccccc3)c3ccccc3-c3cc4c(cc32)N(c2ccc([Si](c3ccccc3)(c3ccccc3)c3ccccc3)cc2)c2ccccc2C42c3ccccc3-c3ccc4sc5ccccc5c4c32)cc1] 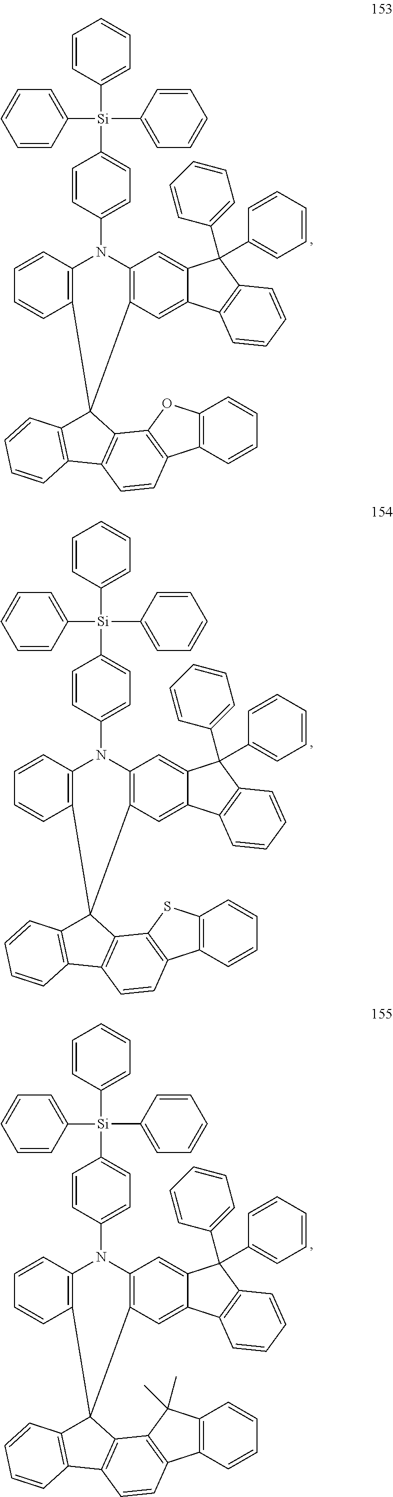 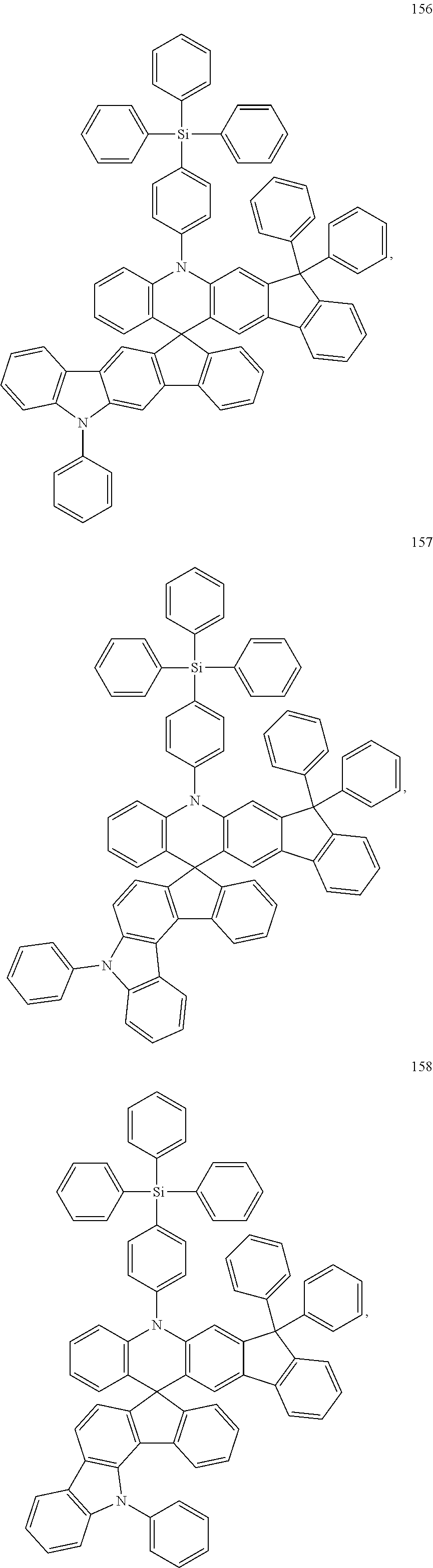 [SMILES: c1ccc(-n2c3ccccc3c3cc4c(cc32)-c2ccccc2C42c3ccccc3N(c3ccc([Si](c4ccccc4)(c4ccccc4)c4ccccc4)cc3)c3cc4c(cc32)-c2ccccc2C4(c2ccccc2)c2ccccc2)cc1 ; c1ccc(-n2c3ccccc3c3c4c(ccc32)C2(c3ccccc3-4)c3ccccc3N(c3ccc([Si](c4ccccc4)(c4ccccc4)c4ccccc4)cc3)c3cc4c(cc32)-c2ccccc2C4(c2ccccc2)c2ccccc2)cc1 ; c1ccc(-n2c3ccccc3c3ccc4c(c32)-c2ccccc2C42c3ccccc3N(c3ccc([Si](c4ccccc4)(c4ccccc4)c4ccccc4)cc3)c3cc4c(cc32)-c2ccccc2C4(c2ccccc2)c2ccccc2)cc1] 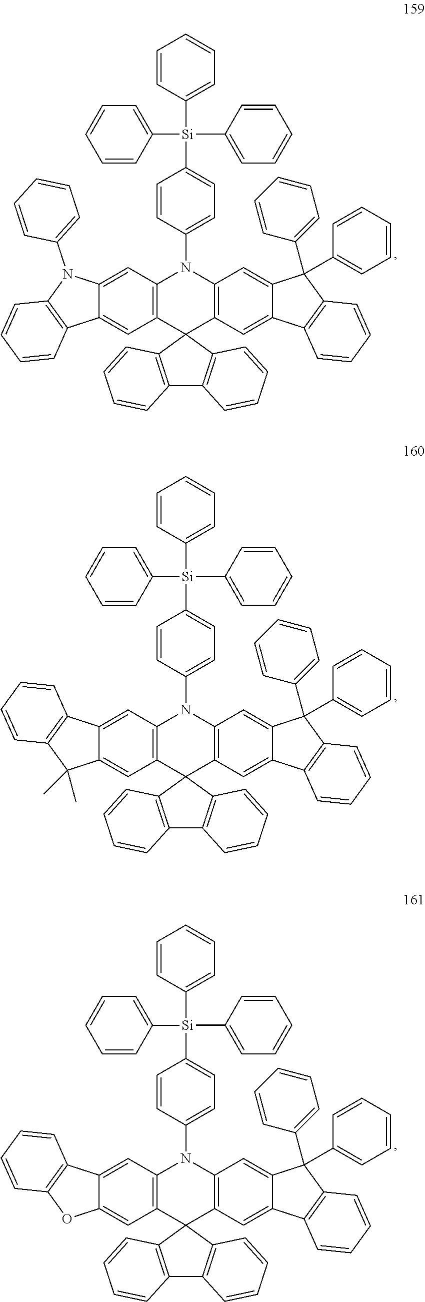 [SMILES: c1ccc(-n2c3ccccc3c3cc4c(cc32)N(c2ccc([Si](c3ccccc3)(c3ccccc3)c3ccccc3)cc2)c2cc3c(cc2C42c4ccccc4-c4ccccc42)-c2ccccc2C3(c2ccccc2)c2ccccc2)cc1 ; CC1(C)c2ccccc2-c2cc3c(cc21)C1(c2ccccc2-c2ccccc21)c1cc2c(cc1N3c1ccc([Si](c3ccccc3)(c3ccccc3)c3ccccc3)cc1)C(c1ccccc1)(c1ccccc1)c1ccccc1-2 ; c1ccc(C2(c3ccccc3)c3ccccc3-c3cc4c(cc32)N(c2ccc([Si](c3ccccc3)(c3ccccc3)c3ccccc3)cc2)c2cc3c(cc2C42c4ccccc4-c4ccccc42)oc2ccccc23)cc1] 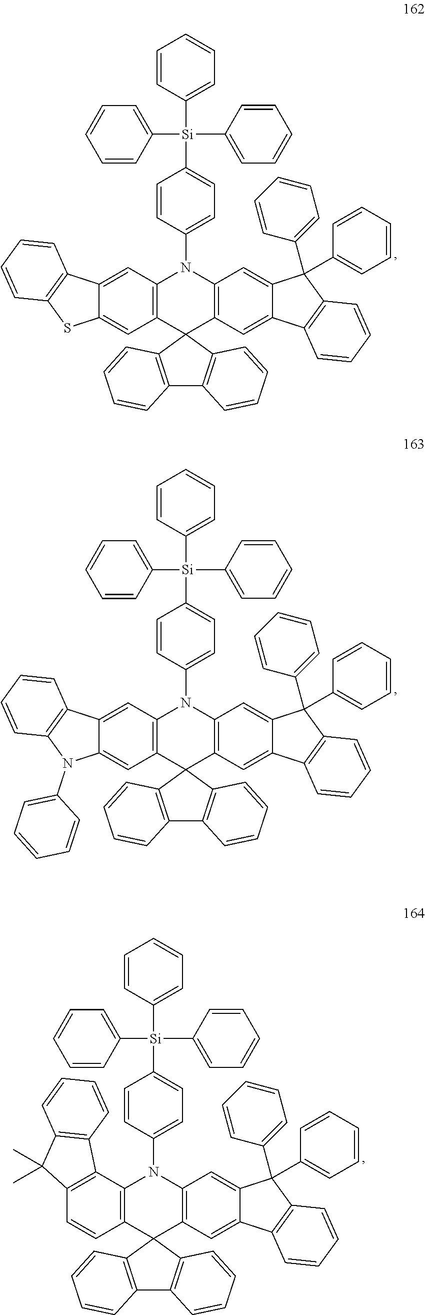 [SMILES: c1ccc(C2(c3ccccc3)c3ccccc3-c3cc4c(cc32)N(c2ccc([Si](c3ccccc3)(c3ccccc3)c3ccccc3)cc2)c2cc3c(cc2C42c4ccccc4-c4ccccc42)sc2ccccc23)cc1 ; c1ccc(-n2c3ccccc3c3cc4c(cc32)C2(c3ccccc3-c3ccccc32)c2cc3c(cc2N4c2ccc([Si](c4ccccc4)(c4ccccc4)c4ccccc4)cc2)C(c2ccccc2)(c2ccccc2)c2ccccc2-3)cc1 ; CC1(C)c2ccccc2-c2c1ccc1c2N(c2ccc([Si](c3ccccc3)(c3ccccc3)c3ccccc3)cc2)c2cc3c(cc2C12c1ccccc1-c1ccccc12)-c1ccccc1C3(c1ccccc1)c1ccccc1] 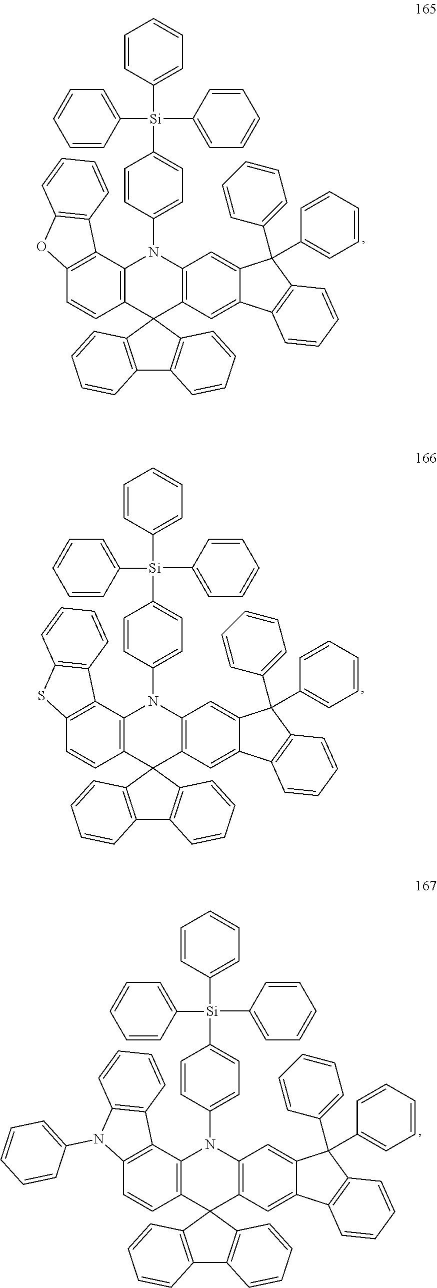 [SMILES: c1ccc(C2(c3ccccc3)c3ccccc3-c3cc4c(cc32)N(c2ccc([Si](c3ccccc3)(c3ccccc3)c3ccccc3)cc2)c2c(ccc3oc5ccccc5c23)C42c3ccccc3-c3ccccc32)cc1 ; c1ccc(C2(c3ccccc3)c3ccccc3-c3cc4c(cc32)N(c2ccc([Si](c3ccccc3)(c3ccccc3)c3ccccc3)cc2)c2c(ccc3sc5ccccc5c23)C42c3ccccc3-c3ccccc32)cc1 ; c1ccc(-n2c3ccccc3c3c4c(ccc32)C2(c3ccccc3-c3ccccc32)c2cc3c(cc2N4c2ccc([Si](c4ccccc4)(c4ccccc4)c4ccccc4)cc2)C(c2ccccc2)(c2ccccc2)c2ccccc2-3)cc1] 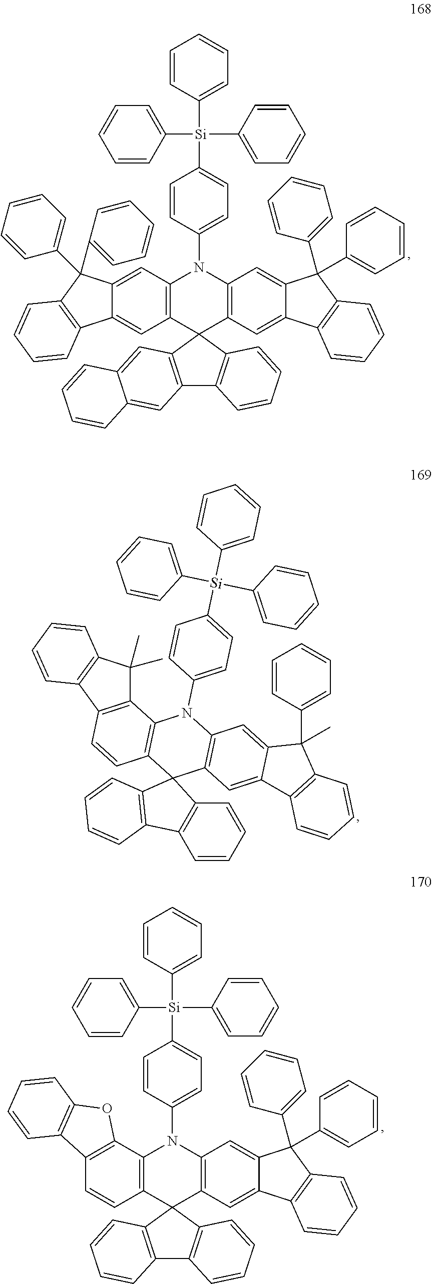 [SMILES: c1ccc(C2(c3ccccc3)c3ccccc3-c3cc4c(cc32)N(c2ccc([Si](c3ccccc3)(c3ccccc3)c3ccccc3)cc2)c2cc3c(cc2C42c4ccccc4-c4cc5ccccc5cc42)-c2ccccc2C3(c2ccccc2)c2ccccc2)cc1 ; CC1(C)c2ccccc2-c2ccc3c(c21)N(c1ccc([Si](c2ccccc2)(c2ccccc2)c2ccccc2)cc1)c1cc2c(cc1C31c3ccccc3-c3ccccc31)-c1ccccc1C2(C)c1ccccc1 ; c1ccc(C2(c3ccccc3)c3ccccc3-c3cc4c(cc32)N(c2ccc([Si](c3ccccc3)(c3ccccc3)c3ccccc3)cc2)c2c(ccc3c2oc2ccccc23)C42c3ccccc3-c3ccccc32)cc1] 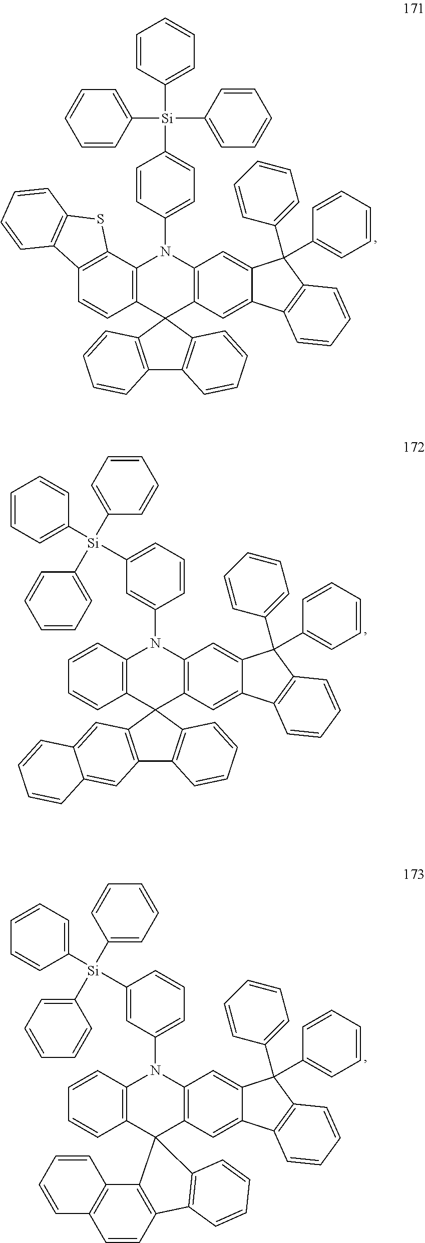 [SMILES: c1ccc(C2(c3ccccc3)c3ccccc3-c3cc4c(cc32)N(c2ccc([Si](c3ccccc3)(c3ccccc3)c3ccccc3)cc2)c2c(ccc3c2sc2ccccc23)C42c3ccccc3-c3ccccc32)cc1 ; c1ccc(C2(c3ccccc3)c3ccccc3-c3cc4c(cc32)N(c2cccc([Si](c3ccccc3)(c3ccccc3)c3ccccc3)c2)c2ccccc2C42c3ccccc3-c3cc4ccccc4cc32)cc1 ; c1ccc(C2(c3ccccc3)c3ccccc3-c3cc4c(cc32)N(c2cccc([Si](c3ccccc3)(c3ccccc3)c3ccccc3)c2)c2ccccc2C42c3ccccc3-c3ccc4ccccc4c32)cc1] 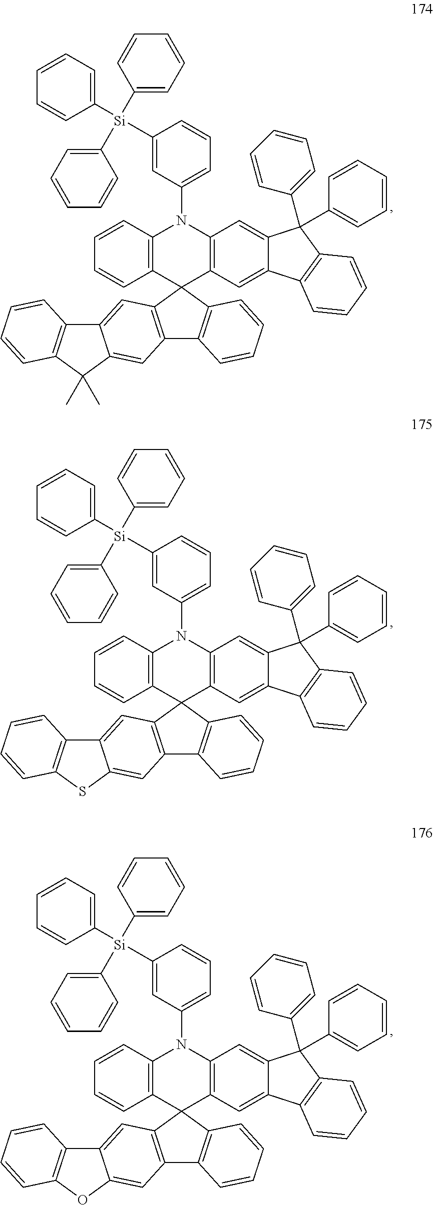 [SMILES: CC1(C)c2ccccc2-c2cc3c(cc21)-c1ccccc1C31c2ccccc2N(c2cccc([Si](c3ccccc3)(c3ccccc3)c3ccccc3)c2)c2cc3c(cc21)-c1ccccc1C3(c1ccccc1)c1ccccc1 ; c1ccc(C2(c3ccccc3)c3ccccc3-c3cc4c(cc32)N(c2cccc([Si](c3ccccc3)(c3ccccc3)c3ccccc3)c2)c2ccccc2C42c3ccccc3-c3cc4sc5ccccc5c4cc32)cc1 ; c1ccc(C2(c3ccccc3)c3ccccc3-c3cc4c(cc32)N(c2cccc([Si](c3ccccc3)(c3ccccc3)c3ccccc3)c2)c2ccccc2C42c3ccccc3-c3cc4oc5ccccc5c4cc32)cc1] 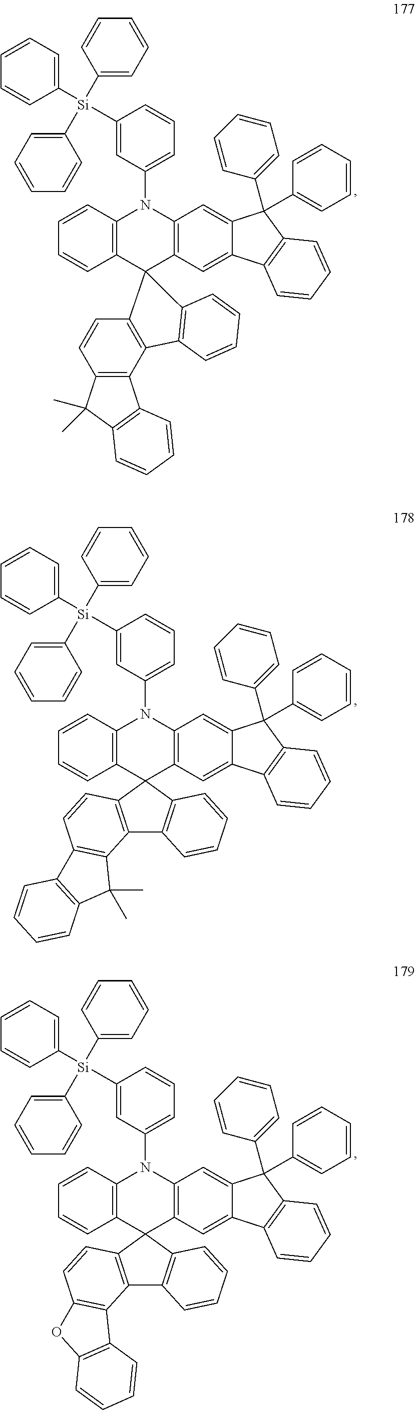 [SMILES: CC1(C)c2ccccc2-c2c1ccc1c2-c2ccccc2C12c1ccccc1N(c1cccc([Si](c3ccccc3)(c3ccccc3)c3ccccc3)c1)c1cc3c(cc12)-c1ccccc1C3(c1ccccc1)c1ccccc1 ; CC1(C)c2ccccc2-c2ccc3c(c21)-c1ccccc1C31c2ccccc2N(c2cccc([Si](c3ccccc3)(c3ccccc3)c3ccccc3)c2)c2cc3c(cc21)-c1ccccc1C3(c1ccccc1)c1ccccc1 ; c1ccc(C2(c3ccccc3)c3ccccc3-c3cc4c(cc32)N(c2cccc([Si](c3ccccc3)(c3ccccc3)c3ccccc3)c2)c2ccccc2C42c3ccccc3-c3c2ccc2oc4ccccc4c32)cc1] 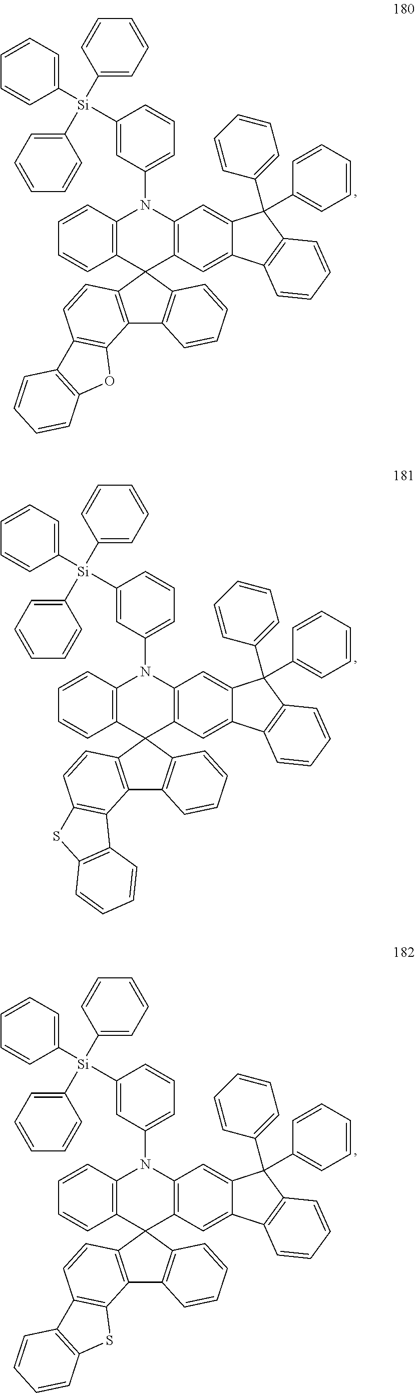 [SMILES: c1ccc(C2(c3ccccc3)c3ccccc3-c3cc4c(cc32)N(c2cccc([Si](c3ccccc3)(c3ccccc3)c3ccccc3)c2)c2ccccc2C42c3ccccc3-c3c2ccc2c3oc3ccccc32)cc1 ; c1ccc(C2(c3ccccc3)c3ccccc3-c3cc4c(cc32)N(c2cccc([Si](c3ccccc3)(c3ccccc3)c3ccccc3)c2)c2ccccc2C42c3ccccc3-c3c2ccc2sc4ccccc4c32)cc1 ; c1ccc(C2(c3ccccc3)c3ccccc3-c3cc4c(cc32)N(c2cccc([Si](c3ccccc3)(c3ccccc3)c3ccccc3)c2)c2ccccc2C42c3ccccc3-c3c2ccc2c3sc3ccccc32)cc1] 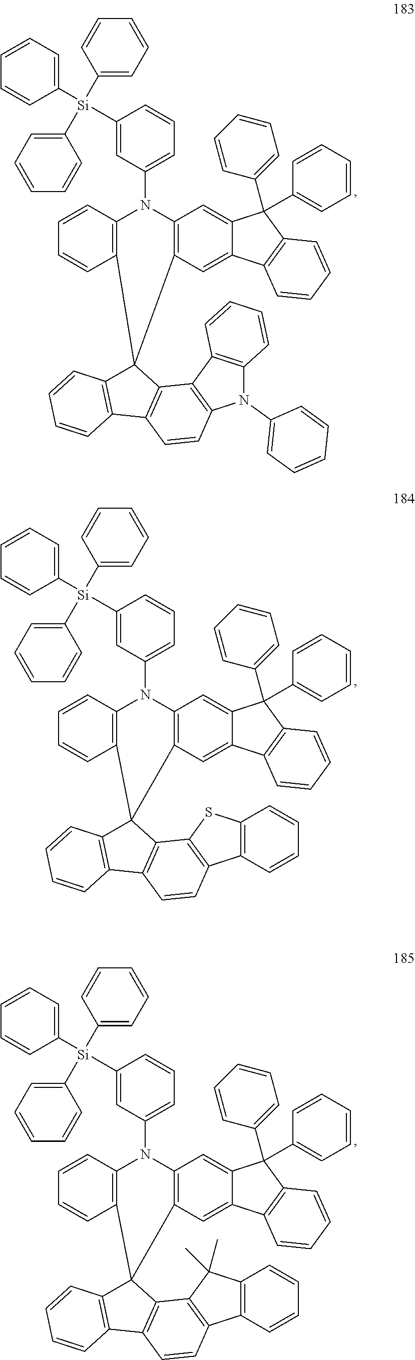 [SMILES: c1ccc(-n2c3ccccc3c3c4c(ccc32)-c2ccccc2C42c3ccccc3N(c3cccc([Si](c4ccccc4)(c4ccccc4)c4ccccc4)c3)c3cc4c(cc32)-c2ccccc2C4(c2ccccc2)c2ccccc2)cc1 ; c1ccc(C2(c3ccccc3)c3ccccc3-c3cc4c(cc32)N(c2cccc([Si](c3ccccc3)(c3ccccc3)c3ccccc3)c2)c2ccccc2C42c3ccccc3-c3ccc4c(sc5ccccc54)c32)cc1 ; CC1(C)c2ccccc2-c2ccc3c(c21)C1(c2ccccc2-3)c2ccccc2N(c2cccc([Si](c3ccccc3)(c3ccccc3)c3ccccc3)c2)c2cc3c(cc21)-c1ccccc1C3(c1ccccc1)c1ccccc1] 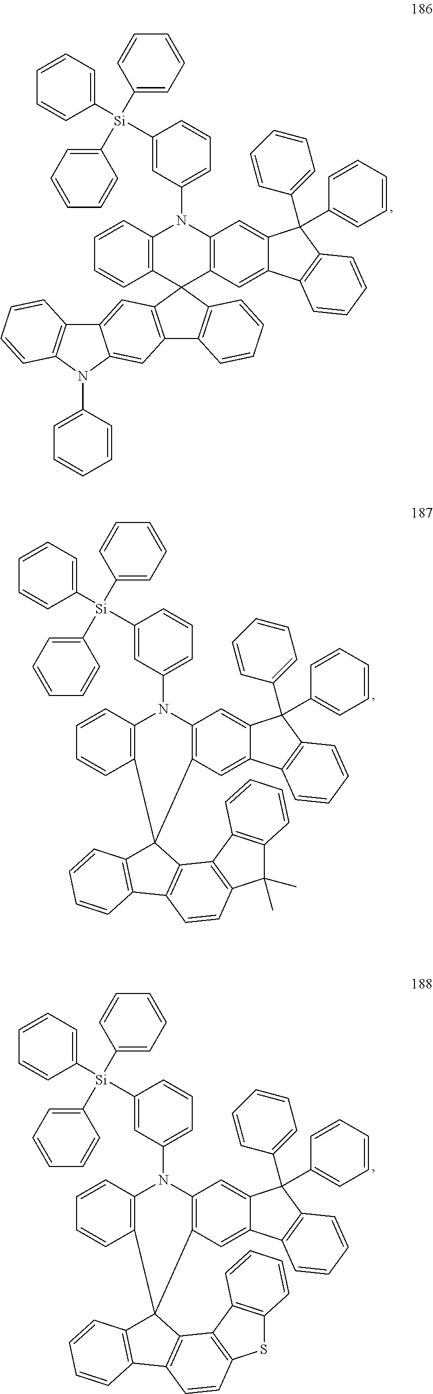 [SMILES: c1ccc(-n2c3ccccc3c3cc4c(cc32)-c2ccccc2C42c3ccccc3N(c3cccc([Si](c4ccccc4)(c4ccccc4)c4ccccc4)c3)c3cc4c(cc32)-c2ccccc2C4(c2ccccc2)c2ccccc2)cc1 ; CC1(C)c2ccccc2-c2c1ccc1c2C2(c3ccccc3-1)c1ccccc1N(c1cccc([Si](c3ccccc3)(c3ccccc3)c3ccccc3)c1)c1cc3c(cc12)-c1ccccc1C3(c1ccccc1)c1ccccc1 ; c1ccc(C2(c3ccccc3)c3ccccc3-c3cc4c(cc32)N(c2cccc([Si](c3ccccc3)(c3ccccc3)c3ccccc3)c2)c2ccccc2C42c3ccccc3-c3ccc4sc5ccccc5c4c32)cc1] 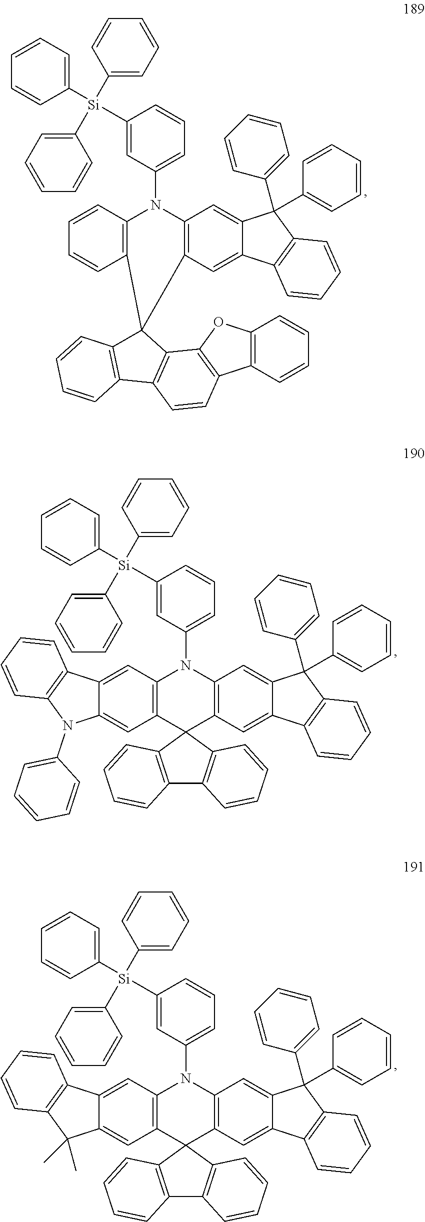 [SMILES: c1ccc(C2(c3ccccc3)c3ccccc3-c3cc4c(cc32)N(c2cccc([Si](c3ccccc3)(c3ccccc3)c3ccccc3)c2)c2ccccc2C42c3ccccc3-c3ccc4c(oc5ccccc54)c32)cc1 ; c1ccc(-n2c3ccccc3c3cc4c(cc32)C2(c3ccccc3-c3ccccc32)c2cc3c(cc2N4c2cccc([Si](c4ccccc4)(c4ccccc4)c4ccccc4)c2)C(c2ccccc2)(c2ccccc2)c2ccccc2-3)cc1 ; CC1(C)c2ccccc2-c2cc3c(cc21)C1(c2ccccc2-c2ccccc21)c1cc2c(cc1N3c1cccc([Si](c3ccccc3)(c3ccccc3)c3ccccc3)c1)C(c1ccccc1)(c1ccccc1)c1ccccc1-2] 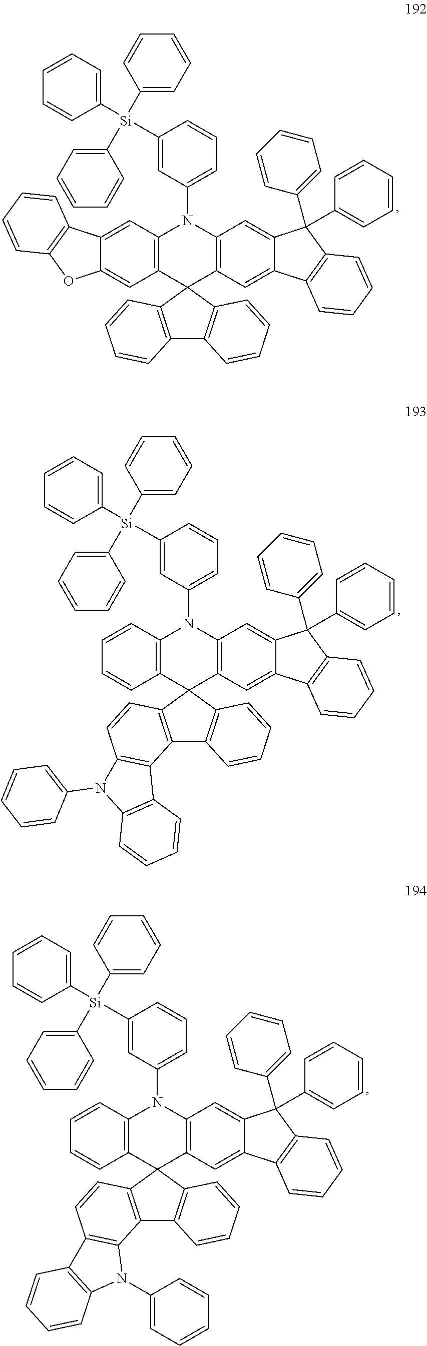 [SMILES: c1ccc(C2(c3ccccc3)c3ccccc3-c3cc4c(cc32)N(c2cccc([Si](c3ccccc3)(c3ccccc3)c3ccccc3)c2)c2cc3c(cc2C42c4ccccc4-c4ccccc42)oc2ccccc23)cc1 ; c1ccc(-n2c3ccccc3c3c4c(ccc32)C2(c3ccccc3-4)c3ccccc3N(c3cccc([Si](c4ccccc4)(c4ccccc4)c4ccccc4)c3)c3cc4c(cc32)-c2ccccc2C4(c2ccccc2)c2ccccc2)cc1 ; c1ccc(-n2c3ccccc3c3ccc4c(c32)-c2ccccc2C42c3ccccc3N(c3cccc([Si](c4ccccc4)(c4ccccc4)c4ccccc4)c3)c3cc4c(cc32)-c2ccccc2C4(c2ccccc2)c2ccccc2)cc1] 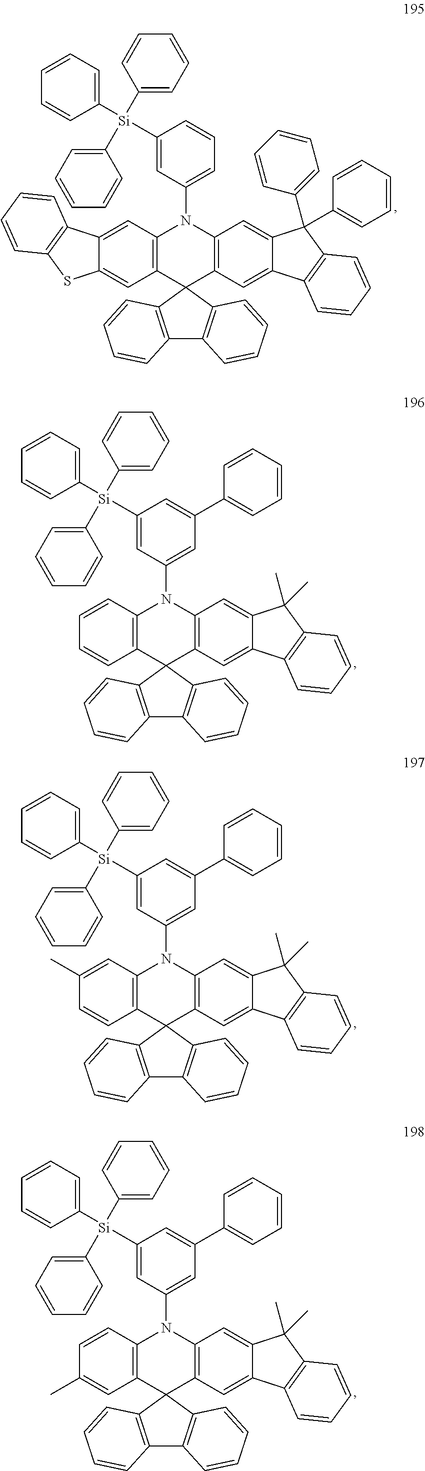 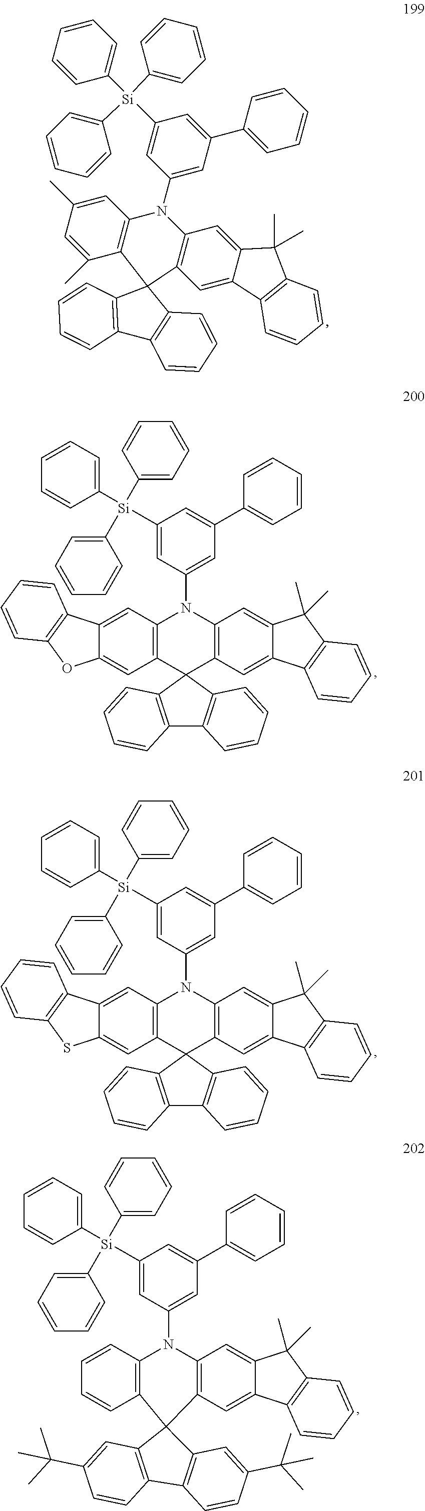 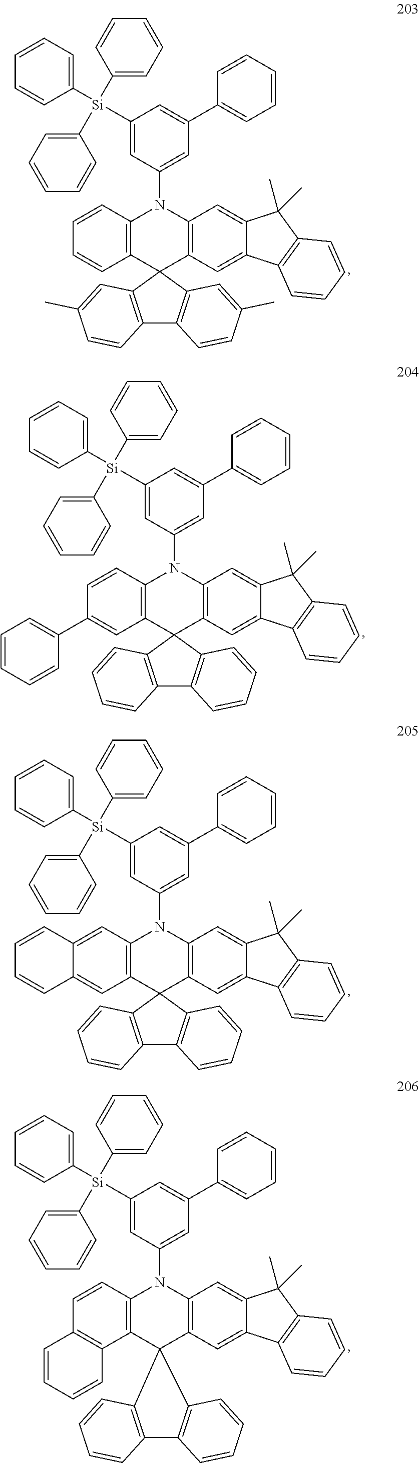 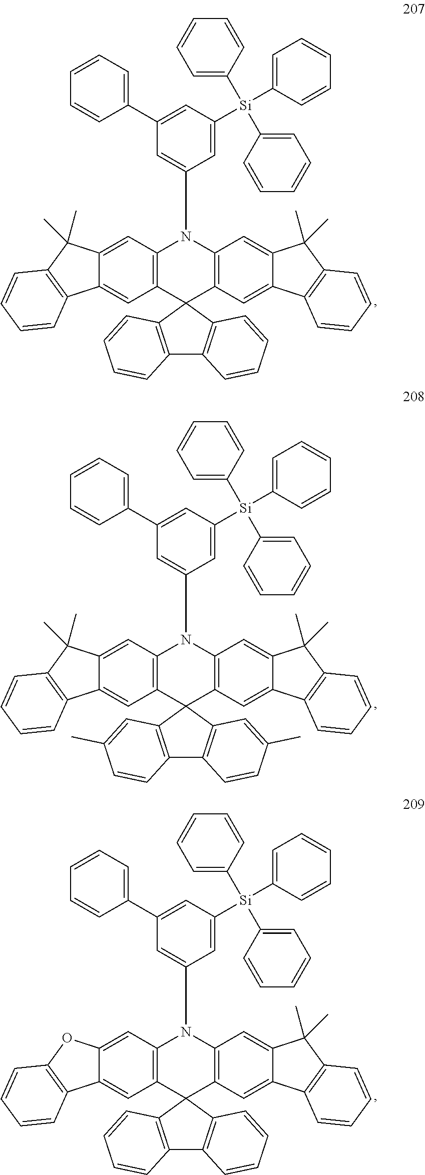 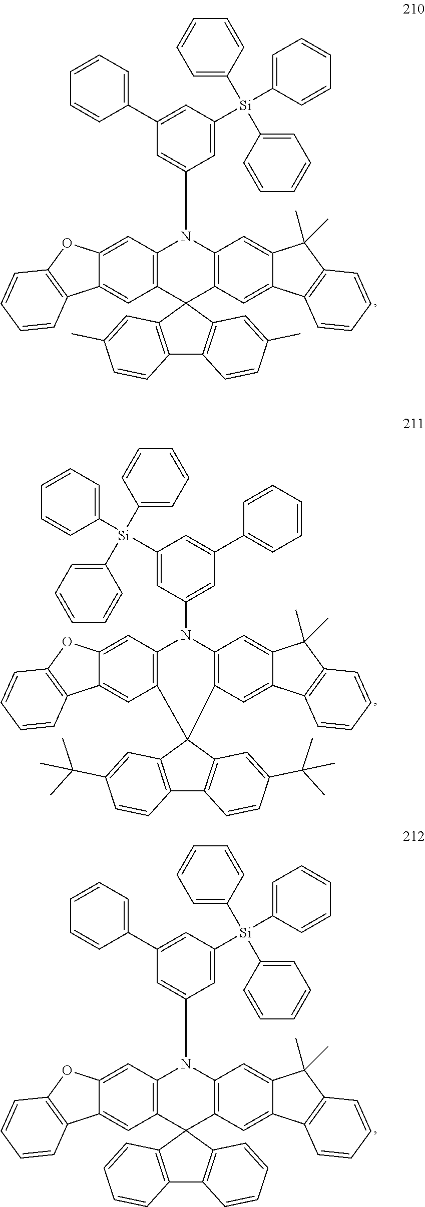 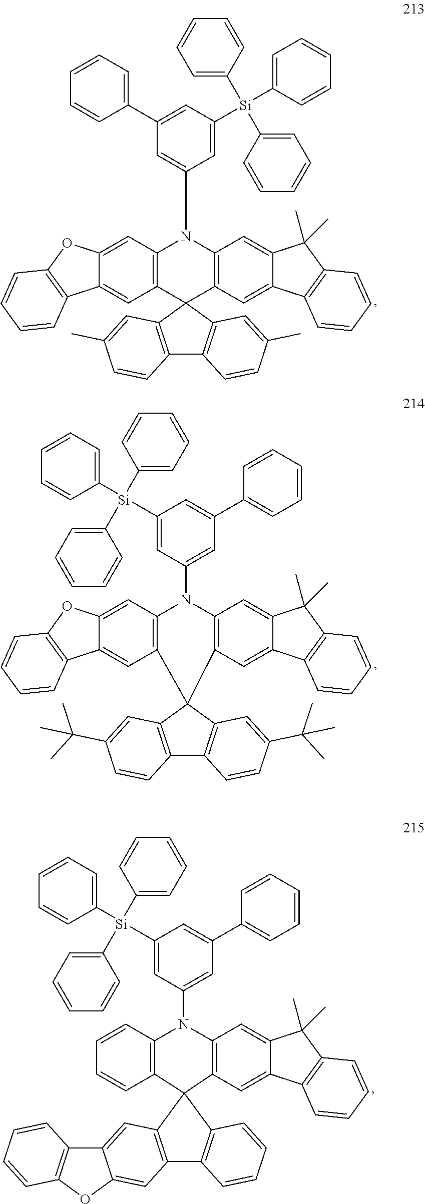 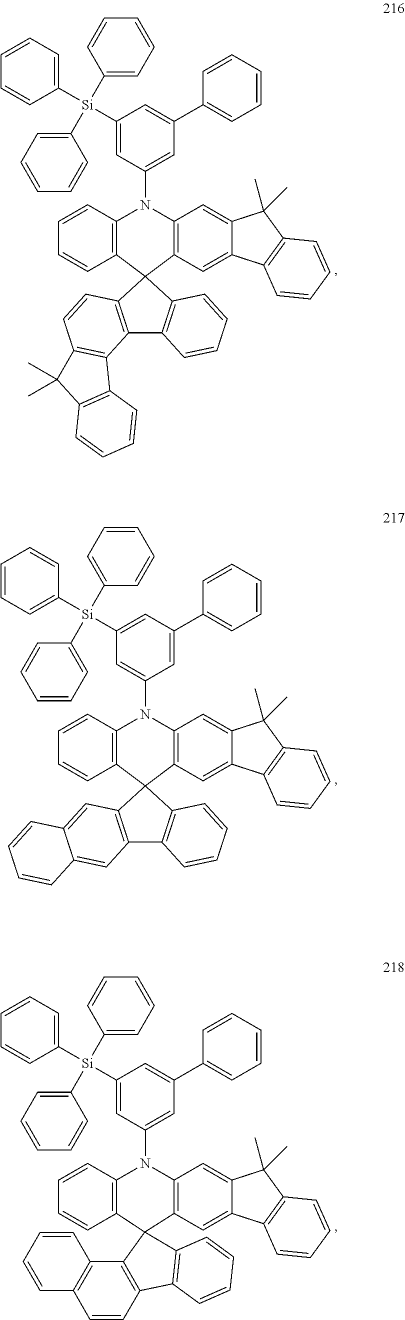 [SMILES: CC1(C)c2ccccc2-c2cc3c(cc21)N(c1cc(-c2ccccc2)cc([Si](c2ccccc2)(c2ccccc2)c2ccccc2)c1)c1ccccc1C31c2ccccc2-c2c1ccc1c2-c2ccccc2C1(C)C ; CC1(C)c2ccccc2-c2cc3c(cc21)N(c1cc(-c2ccccc2)cc([Si](c2ccccc2)(c2ccccc2)c2ccccc2)c1)c1ccccc1C31c2ccccc2-c2cc3ccccc3cc21 ; CC1(C)c2ccccc2-c2cc3c(cc21)N(c1cc(-c2ccccc2)cc([Si](c2ccccc2)(c2ccccc2)c2ccccc2)c1)c1ccccc1C31c2ccccc2-c2ccc3ccccc3c21] 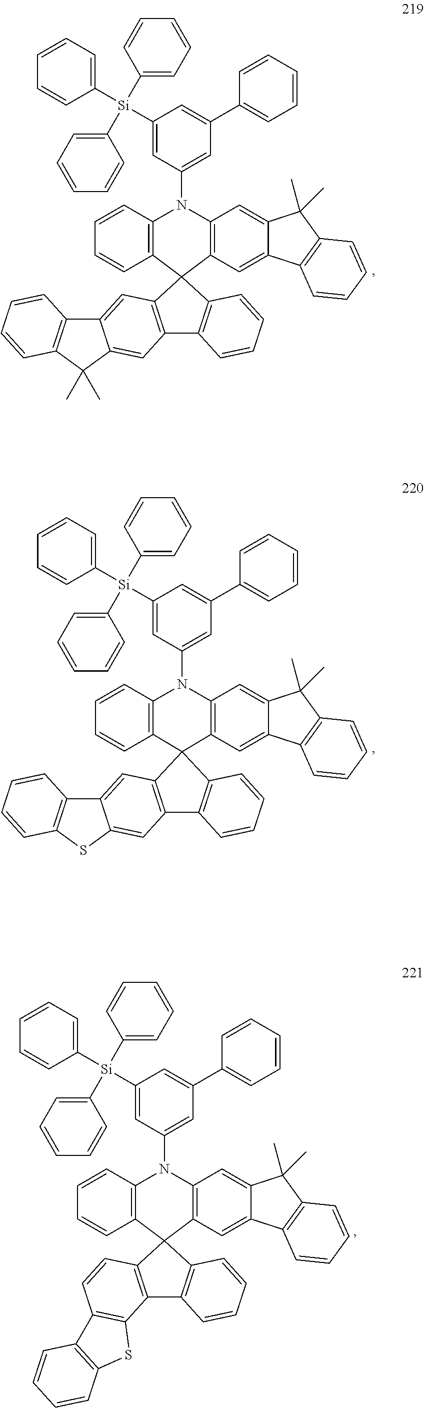 [SMILES: CC1(C)c2ccccc2-c2cc3c(cc21)-c1ccccc1C31c2ccccc2N(c2cc(-c3ccccc3)cc([Si](c3ccccc3)(c3ccccc3)c3ccccc3)c2)c2cc3c(cc21)-c1ccccc1C3(C)C ; CC1(C)c2ccccc2-c2cc3c(cc21)N(c1cc(-c2ccccc2)cc([Si](c2ccccc2)(c2ccccc2)c2ccccc2)c1)c1ccccc1C31c2ccccc2-c2cc3sc4ccccc4c3cc21 ; CC1(C)c2ccccc2-c2cc3c(cc21)N(c1cc(-c2ccccc2)cc([Si](c2ccccc2)(c2ccccc2)c2ccccc2)c1)c1ccccc1C31c2ccccc2-c2c1ccc1c2sc2ccccc21] 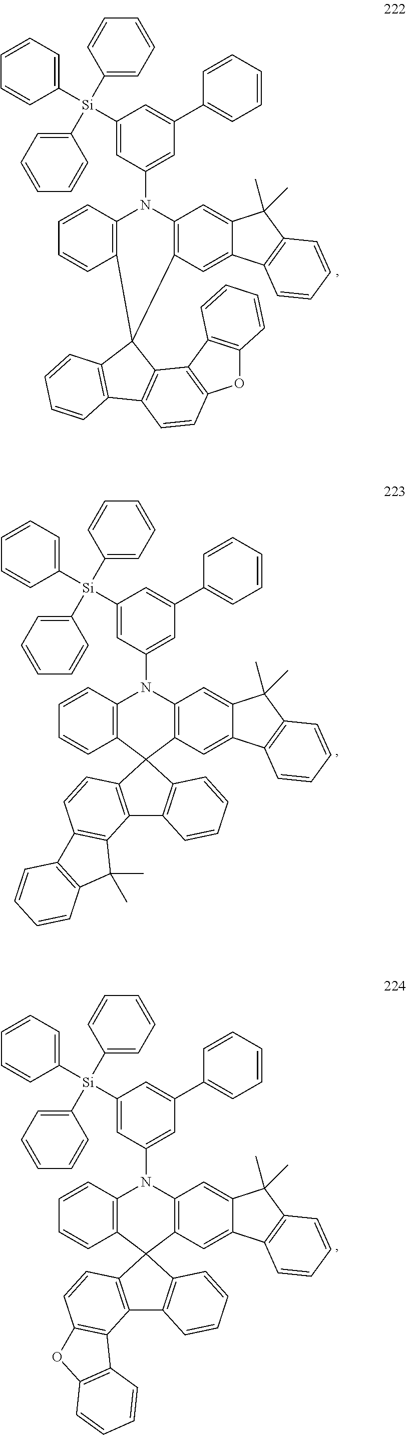 [SMILES: CC1(C)c2ccccc2-c2cc3c(cc21)N(c1cc(-c2ccccc2)cc([Si](c2ccccc2)(c2ccccc2)c2ccccc2)c1)c1ccccc1C31c2ccccc2-c2ccc3oc4ccccc4c3c21 ; CC1(C)c2ccccc2-c2cc3c(cc21)N(c1cc(-c2ccccc2)cc([Si](c2ccccc2)(c2ccccc2)c2ccccc2)c1)c1ccccc1C31c2ccccc2-c2c1ccc1c2C(C)(C)c2ccccc2-1 ; CC1(C)c2ccccc2-c2cc3c(cc21)N(c1cc(-c2ccccc2)cc([Si](c2ccccc2)(c2ccccc2)c2ccccc2)c1)c1ccccc1C31c2ccccc2-c2c1ccc1oc3ccccc3c21] 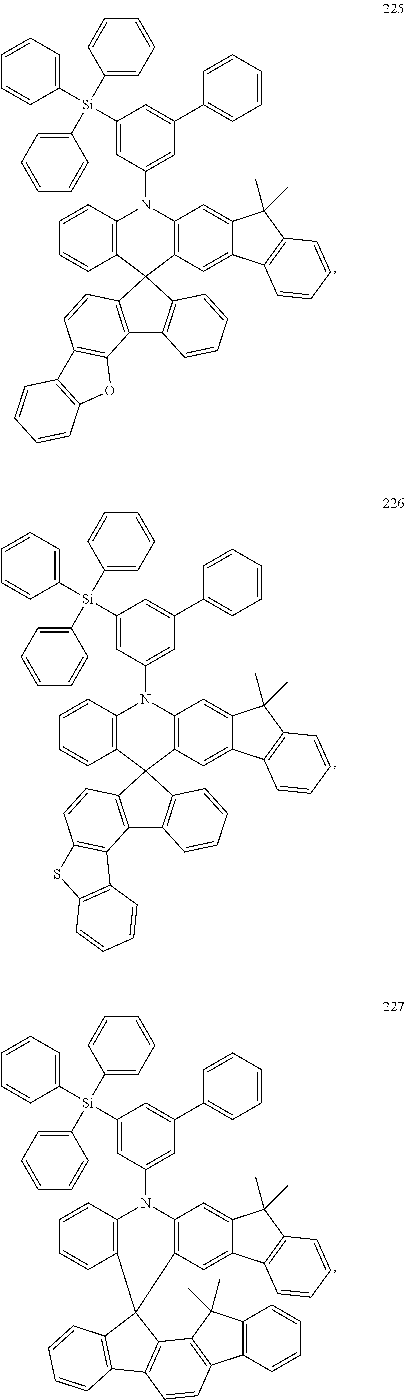 [SMILES: CC1(C)c2ccccc2-c2cc3c(cc21)N(c1cc(-c2ccccc2)cc([Si](c2ccccc2)(c2ccccc2)c2ccccc2)c1)c1ccccc1C31c2ccccc2-c2c1ccc1c2oc2ccccc21 ; CC1(C)c2ccccc2-c2cc3c(cc21)N(c1cc(-c2ccccc2)cc([Si](c2ccccc2)(c2ccccc2)c2ccccc2)c1)c1ccccc1C31c2ccccc2-c2c1ccc1sc3ccccc3c21 ; CC1(C)c2ccccc2-c2cc3c(cc21)N(c1cc(-c2ccccc2)cc([Si](c2ccccc2)(c2ccccc2)c2ccccc2)c1)c1ccccc1C31c2ccccc2-c2ccc3c(c21)C(C)(C)c1ccccc1-3] 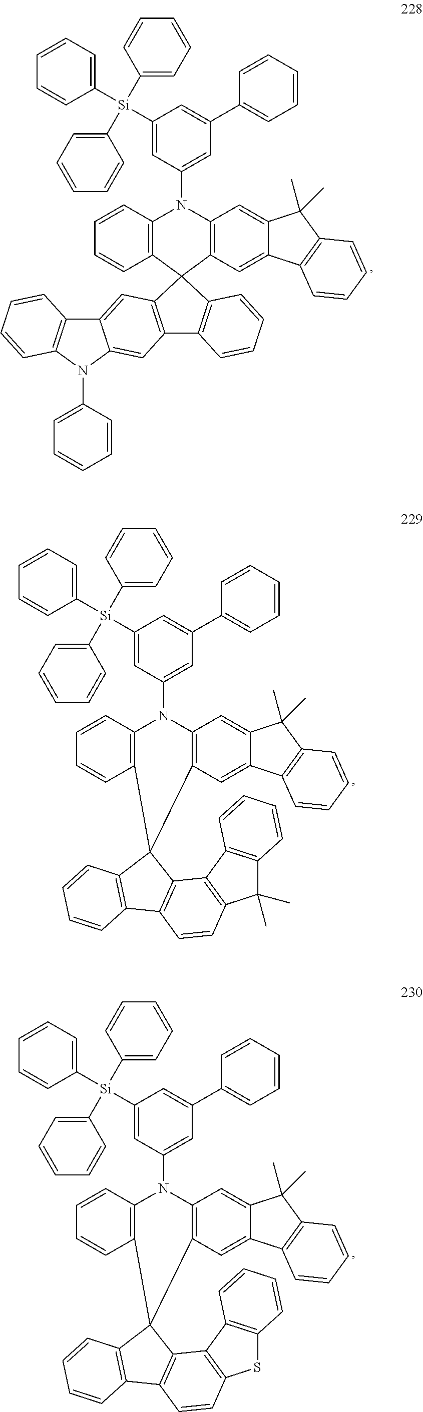 [SMILES: CC1(C)c2ccccc2-c2cc3c(cc21)N(c1cc(-c2ccccc2)cc([Si](c2ccccc2)(c2ccccc2)c2ccccc2)c1)c1ccccc1C31c2ccccc2-c2cc3c(cc21)c1ccccc1n3-c1ccccc1 ; CC1(C)c2ccccc2-c2cc3c(cc21)N(c1cc(-c2ccccc2)cc([Si](c2ccccc2)(c2ccccc2)c2ccccc2)c1)c1ccccc1C31c2ccccc2-c2ccc3c(c21)-c1ccccc1C3(C)C ; CC1(C)c2ccccc2-c2cc3c(cc21)N(c1cc(-c2ccccc2)cc([Si](c2ccccc2)(c2ccccc2)c2ccccc2)c1)c1ccccc1C31c2ccccc2-c2ccc3sc4ccccc4c3c21] 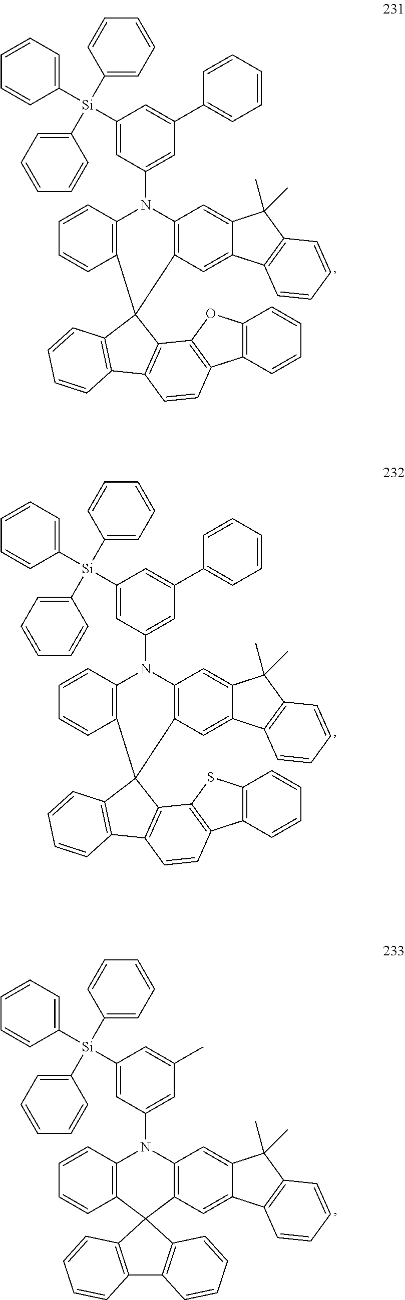 [SMILES: CC1(C)c2ccccc2-c2cc3c(cc21)N(c1cc(-c2ccccc2)cc([Si](c2ccccc2)(c2ccccc2)c2ccccc2)c1)c1ccccc1C31c2ccccc2-c2ccc3c(oc4ccccc43)c21 ; CC1(C)c2ccccc2-c2cc3c(cc21)N(c1cc(-c2ccccc2)cc([Si](c2ccccc2)(c2ccccc2)c2ccccc2)c1)c1ccccc1C31c2ccccc2-c2ccc3c(sc4ccccc43)c21 ; Cc1cc(N2c3ccccc3C3(c4ccccc4-c4ccccc43)c3cc4c(cc32)C(C)(C)c2ccccc2-4)cc([Si](c2ccccc2)(c2ccccc2)c2ccccc2)c1] 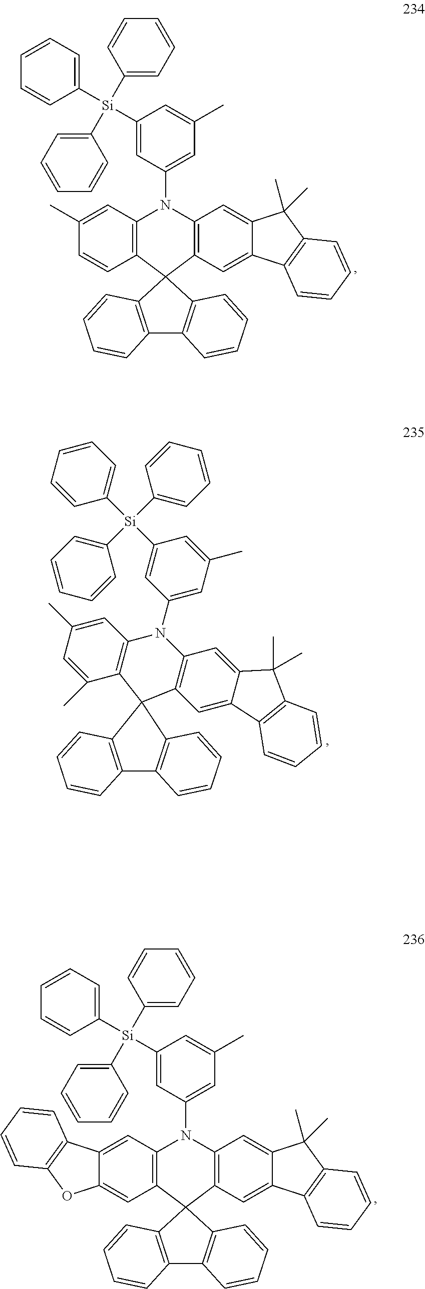 [SMILES: Cc1cc(N2c3cc(C)ccc3C3(c4ccccc4-c4ccccc43)c3cc4c(cc32)C(C)(C)c2ccccc2-4)cc([Si](c2ccccc2)(c2ccccc2)c2ccccc2)c1 ; Cc1cc(N2c3cc4c(cc3C3(c5ccccc5-c5ccccc53)c3c(C)cc(C)cc32)-c2ccccc2C4(C)C)cc([Si](c2ccccc2)(c2ccccc2)c2ccccc2)c1 ; Cc1cc(N2c3cc4c(cc3C3(c5ccccc5-c5ccccc53)c3cc5oc6ccccc6c5cc32)-c2ccccc2C4(C)C)cc([Si](c2ccccc2)(c2ccccc2)c2ccccc2)c1] 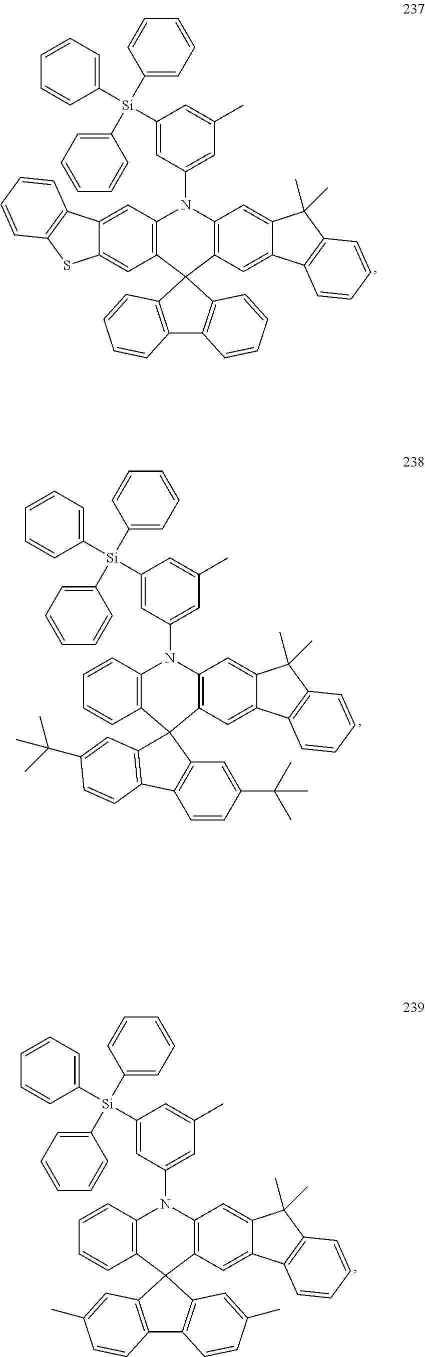 [SMILES: Cc1cc(N2c3cc4c(cc3C3(c5ccccc5-c5ccccc53)c3cc5sc6ccccc6c5cc32)-c2ccccc2C4(C)C)cc([Si](c2ccccc2)(c2ccccc2)c2ccccc2)c1 ; Cc1cc(N2c3ccccc3C3(c4cc(C(C)(C)C)ccc4-c4ccc(C(C)(C)C)cc43)c3cc4c(cc32)C(C)(C)c2ccccc2-4)cc([Si](c2ccccc2)(c2ccccc2)c2ccccc2)c1 ; Cc1cc(N2c3ccccc3C3(c4cc(C)ccc4-c4ccc(C)cc43)c3cc4c(cc32)C(C)(C)c2ccccc2-4)cc([Si](c2ccccc2)(c2ccccc2)c2ccccc2)c1] 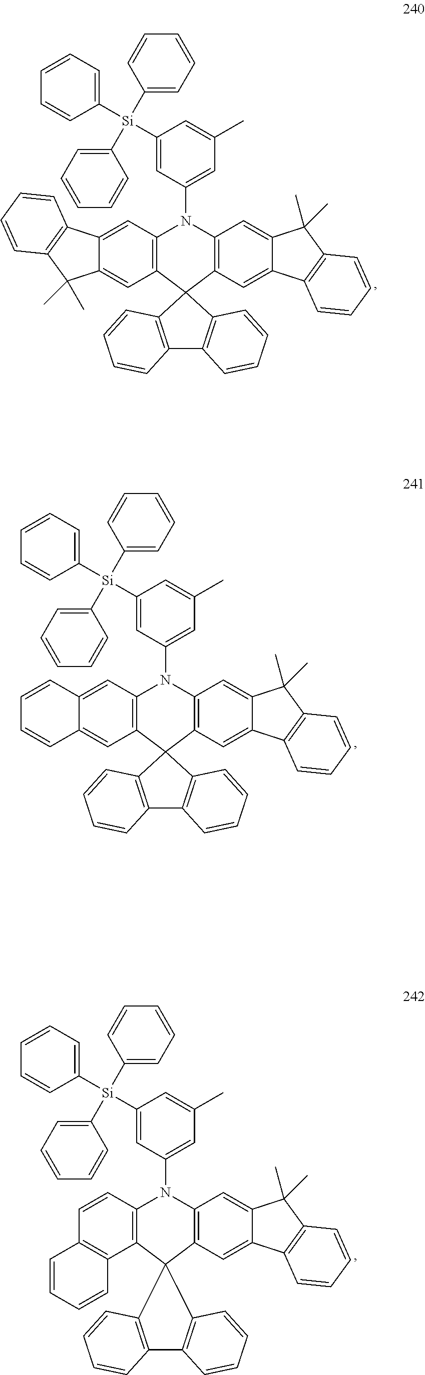 [SMILES: Cc1cc(N2c3cc4c(cc3C3(c5ccccc5-c5ccccc53)c3cc5c(cc32)-c2ccccc2C5(C)C)-c2ccccc2C4(C)C)cc([Si](c2ccccc2)(c2ccccc2)c2ccccc2)c1 ; Cc1cc(N2c3cc4c(cc3C3(c5ccccc5-c5ccccc53)c3cc5ccccc5cc32)-c2ccccc2C4(C)C)cc([Si](c2ccccc2)(c2ccccc2)c2ccccc2)c1 ; Cc1cc(N2c3cc4c(cc3C3(c5ccccc5-c5ccccc53)c3c2ccc2ccccc32)-c2ccccc2C4(C)C)cc([Si](c2ccccc2)(c2ccccc2)c2ccccc2)c1] 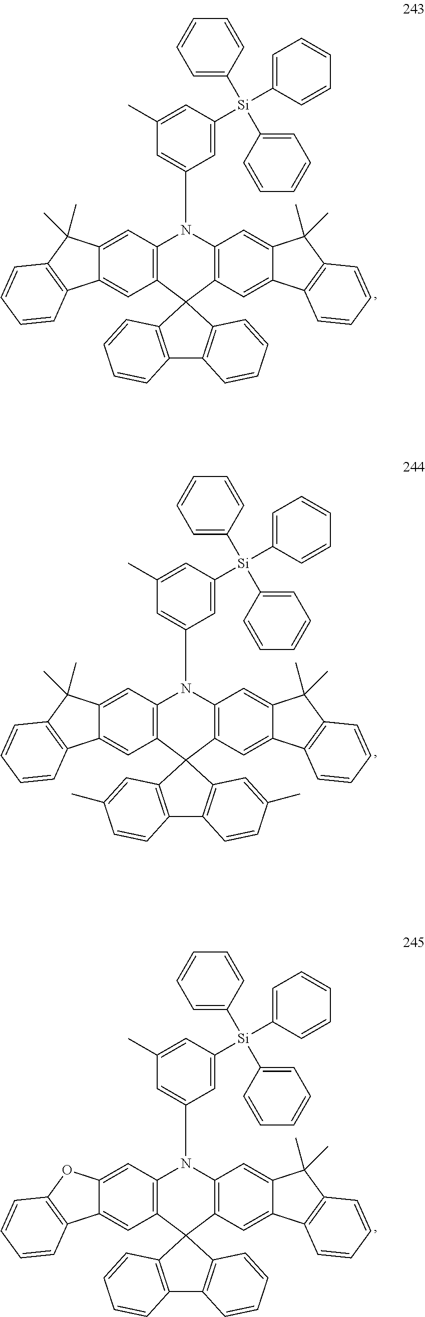 [SMILES: Cc1cc(N2c3cc4c(cc3C3(c5ccccc5-c5ccccc53)c3cc5c(cc32)C(C)(C)c2ccccc2-5)-c2ccccc2C4(C)C)cc([Si](c2ccccc2)(c2ccccc2)c2ccccc2)c1 ; Cc1cc(N2c3cc4c(cc3C3(c5cc(C)ccc5-c5ccc(C)cc53)c3cc5c(cc32)C(C)(C)c2ccccc2-5)-c2ccccc2C4(C)C)cc([Si](c2ccccc2)(c2ccccc2)c2ccccc2)c1 ; Cc1cc(N2c3cc4c(cc3C3(c5ccccc5-c5ccccc53)c3cc5c(cc32)oc2ccccc25)-c2ccccc2C4(C)C)cc([Si](c2ccccc2)(c2ccccc2)c2ccccc2)c1] 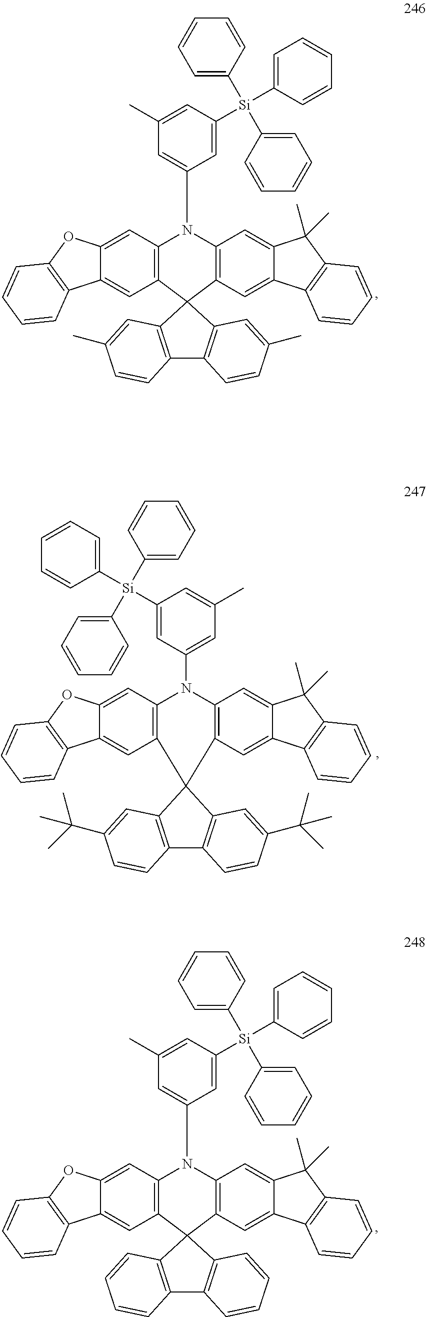 [SMILES: Cc1cc(N2c3cc4c(cc3C3(c5cc(C)ccc5-c5ccc(C)cc53)c3cc5c(cc32)oc2ccccc25)-c2ccccc2C4(C)C)cc([Si](c2ccccc2)(c2ccccc2)c2ccccc2)c1 ; Cc1cc(N2c3cc4c(cc3C3(c5cc(C(C)(C)C)ccc5-c5ccc(C(C)(C)C)cc53)c3cc5c(cc32)oc2ccccc25)-c2ccccc2C4(C)C)cc([Si](c2ccccc2)(c2ccccc2)c2ccccc2)c1 ; Cc1cc(N2c3cc4c(cc3C3(c5ccccc5-c5ccccc53)c3cc5c(cc32)oc2ccccc25)-c2ccccc2C4(C)C)cc([Si](c2ccccc2)(c2ccccc2)c2ccccc2)c1] 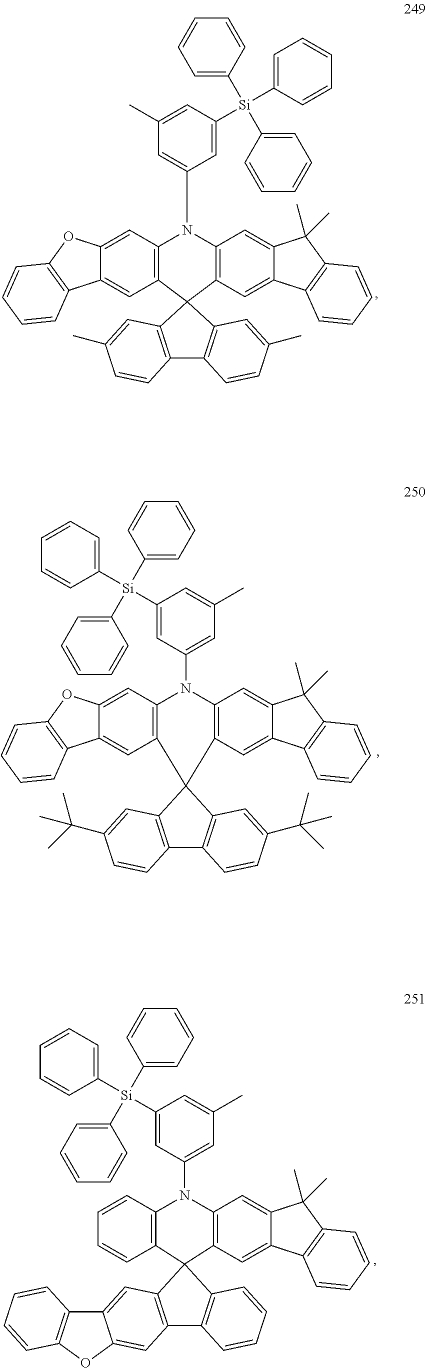 [SMILES: Cc1cc(N2c3cc4c(cc3C3(c5cc(C)ccc5-c5ccc(C)cc53)c3cc5c(cc32)oc2ccccc25)-c2ccccc2C4(C)C)cc([Si](c2ccccc2)(c2ccccc2)c2ccccc2)c1 ; Cc1cc(N2c3cc4c(cc3C3(c5cc(C(C)(C)C)ccc5-c5ccc(C(C)(C)C)cc53)c3cc5c(cc32)oc2ccccc25)-c2ccccc2C4(C)C)cc([Si](c2ccccc2)(c2ccccc2)c2ccccc2)c1 ; Cc1cc(N2c3ccccc3C3(c4ccccc4-c4cc5oc6ccccc6c5cc43)c3cc4c(cc32)C(C)(C)c2ccccc2-4)cc([Si](c2ccccc2)(c2ccccc2)c2ccccc2)c1] 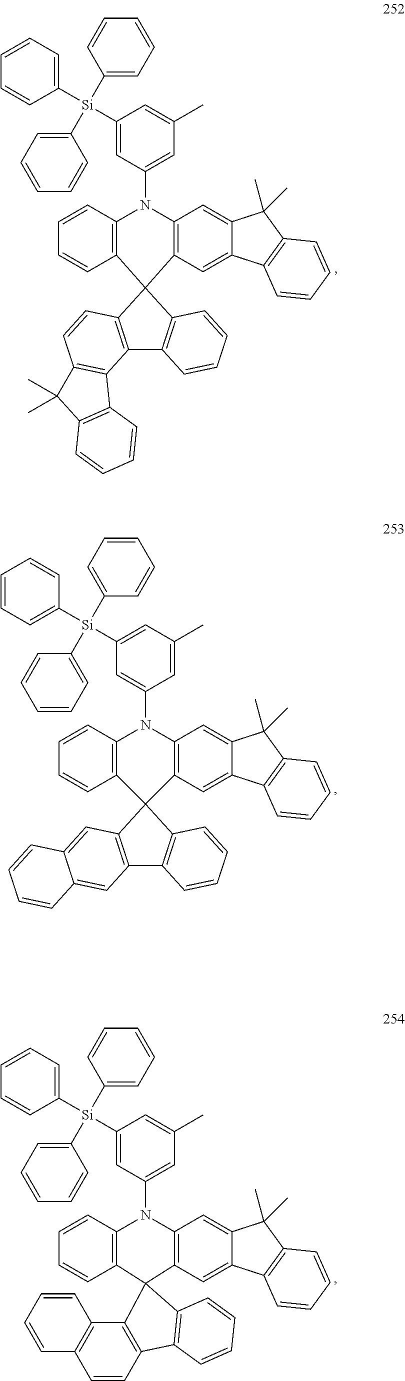 [SMILES: Cc1cc(N2c3ccccc3C3(c4ccccc4-c4c3ccc3c4-c4ccccc4C3(C)C)c3cc4c(cc32)C(C)(C)c2ccccc2-4)cc([Si](c2ccccc2)(c2ccccc2)c2ccccc2)c1 ; Cc1cc(N2c3ccccc3C3(c4ccccc4-c4cc5ccccc5cc43)c3cc4c(cc32)C(C)(C)c2ccccc2-4)cc([Si](c2ccccc2)(c2ccccc2)c2ccccc2)c1 ; Cc1cc(N2c3ccccc3C3(c4ccccc4-c4ccc5ccccc5c43)c3cc4c(cc32)C(C)(C)c2ccccc2-4)cc([Si](c2ccccc2)(c2ccccc2)c2ccccc2)c1] 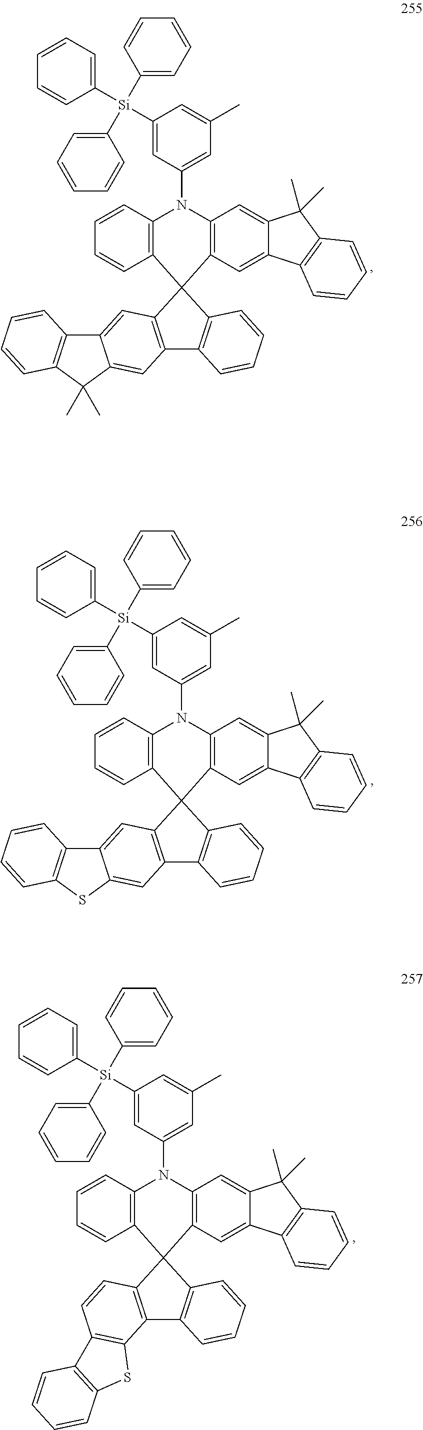 [SMILES: Cc1cc(N2c3ccccc3C3(c4ccccc4-c4cc5c(cc43)-c3ccccc3C5(C)C)c3cc4c(cc32)C(C)(C)c2ccccc2-4)cc([Si](c2ccccc2)(c2ccccc2)c2ccccc2)c1 ; Cc1cc(N2c3ccccc3C3(c4ccccc4-c4cc5sc6ccccc6c5cc43)c3cc4c(cc32)C(C)(C)c2ccccc2-4)cc([Si](c2ccccc2)(c2ccccc2)c2ccccc2)c1 ; Cc1cc(N2c3ccccc3C3(c4ccccc4-c4c3ccc3c4sc4ccccc43)c3cc4c(cc32)C(C)(C)c2ccccc2-4)cc([Si](c2ccccc2)(c2ccccc2)c2ccccc2)c1] 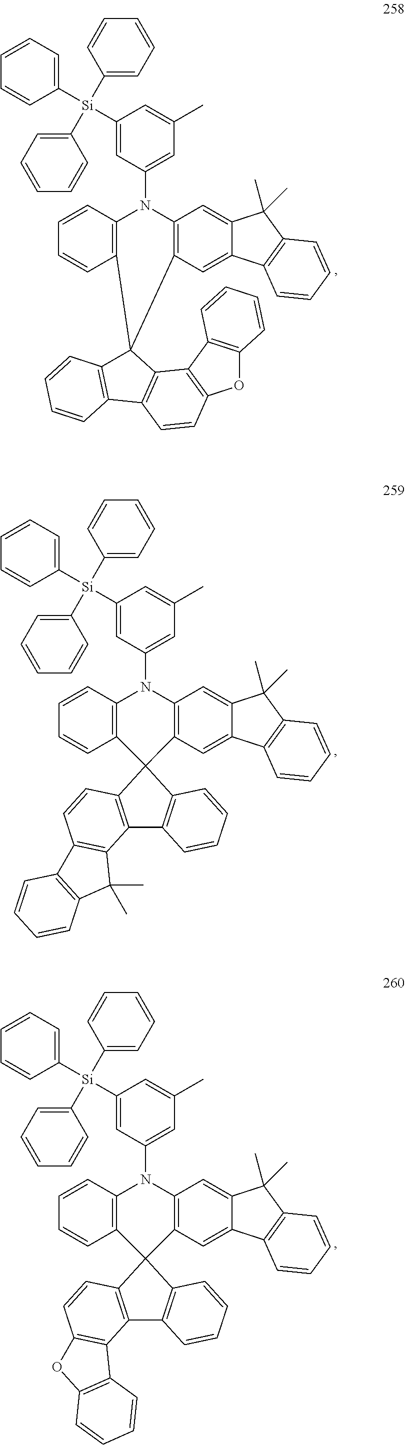 [SMILES: Cc1cc(N2c3ccccc3C3(c4ccccc4-c4ccc5oc6ccccc6c5c43)c3cc4c(cc32)C(C)(C)c2ccccc2-4)cc([Si](c2ccccc2)(c2ccccc2)c2ccccc2)c1 ; Cc1cc(N2c3ccccc3C3(c4ccccc4-c4c3ccc3c4C(C)(C)c4ccccc4-3)c3cc4c(cc32)C(C)(C)c2ccccc2-4)cc([Si](c2ccccc2)(c2ccccc2)c2ccccc2)c1 ; Cc1cc(N2c3ccccc3C3(c4ccccc4-c4c3ccc3oc5ccccc5c43)c3cc4c(cc32)C(C)(C)c2ccccc2-4)cc([Si](c2ccccc2)(c2ccccc2)c2ccccc2)c1] 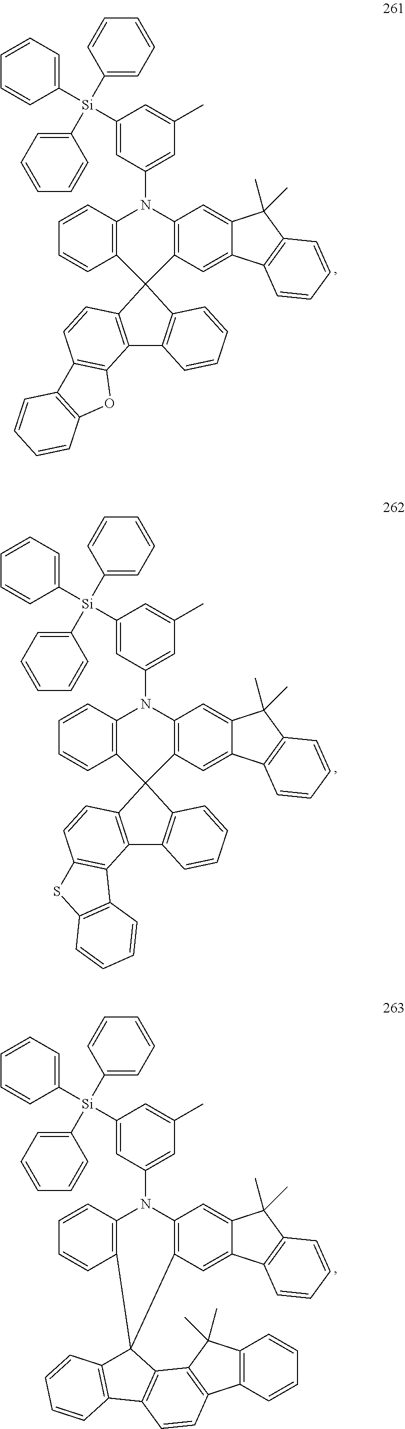 [SMILES: Cc1cc(N2c3ccccc3C3(c4ccccc4-c4c3ccc3c4oc4ccccc43)c3cc4c(cc32)C(C)(C)c2ccccc2-4)cc([Si](c2ccccc2)(c2ccccc2)c2ccccc2)c1 ; Cc1cc(N2c3ccccc3C3(c4ccccc4-c4c3ccc3sc5ccccc5c43)c3cc4c(cc32)C(C)(C)c2ccccc2-4)cc([Si](c2ccccc2)(c2ccccc2)c2ccccc2)c1 ; Cc1cc(N2c3ccccc3C3(c4ccccc4-c4ccc5c(c43)C(C)(C)c3ccccc3-5)c3cc4c(cc32)C(C)(C)c2ccccc2-4)cc([Si](c2ccccc2)(c2ccccc2)c2ccccc2)c1] 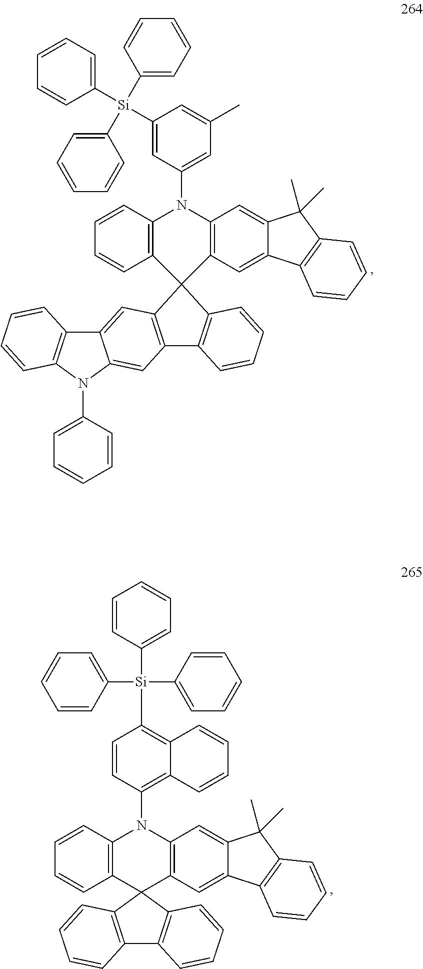 [SMILES: Cc1cc(N2c3ccccc3C3(c4ccccc4-c4cc5c(cc43)c3ccccc3n5-c3ccccc3)c3cc4c(cc32)C(C)(C)c2ccccc2-4)cc([Si](c2ccccc2)(c2ccccc2)c2ccccc2)c1 ; CC1(C)c2ccccc2-c2cc3c(cc21)N(c1ccc([Si](c2ccccc2)(c2ccccc2)c2ccccc2)c2ccccc12)c1ccccc1C31c2ccccc2-c2ccccc21] 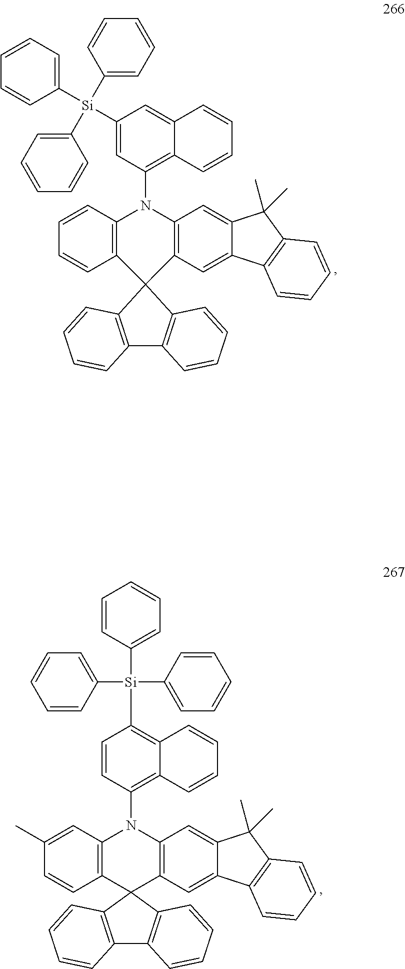 [SMILES: CC1(C)c2ccccc2-c2cc3c(cc21)N(c1cc([Si](c2ccccc2)(c2ccccc2)c2ccccc2)cc2ccccc12)c1ccccc1C31c2ccccc2-c2ccccc21 ; Cc1ccc2c(c1)N(c1ccc([Si](c3ccccc3)(c3ccccc3)c3ccccc3)c3ccccc13)c1cc3c(cc1C21c2ccccc2-c2ccccc21)-c1ccccc1C3(C)C] 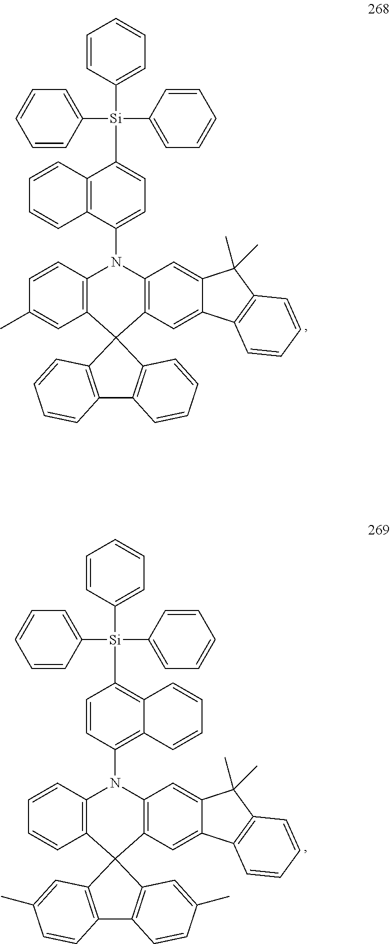 [SMILES: Cc1ccc2c(c1)C1(c3ccccc3-c3ccccc31)c1cc3c(cc1N2c1ccc([Si](c2ccccc2)(c2ccccc2)c2ccccc2)c2ccccc12)C(C)(C)c1ccccc1-3 ; Cc1ccc2c(c1)C1(c3cc(C)ccc3-2)c2ccccc2N(c2ccc([Si](c3ccccc3)(c3ccccc3)c3ccccc3)c3ccccc23)c2cc3c(cc21)-c1ccccc1C3(C)C] 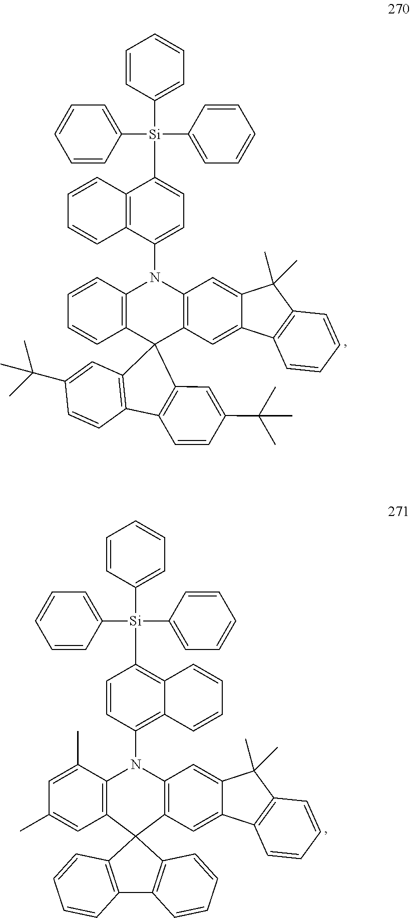 [SMILES: CC(C)(C)c1ccc2c(c1)C1(c3cc(C(C)(C)C)ccc3-2)c2ccccc2N(c2ccc([Si](c3ccccc3)(c3ccccc3)c3ccccc3)c3ccccc23)c2cc3c(cc21)-c1ccccc1C3(C)C ; Cc1cc(C)c2c(c1)C1(c3ccccc3-c3ccccc31)c1cc3c(cc1N2c1ccc([Si](c2ccccc2)(c2ccccc2)c2ccccc2)c2ccccc12)C(C)(C)c1ccccc1-3] 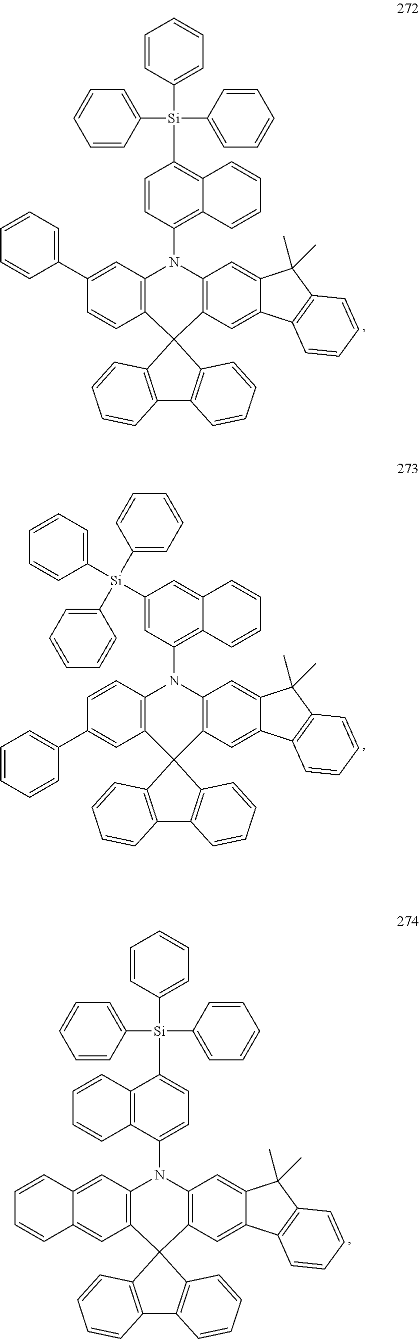 [SMILES: CC1(C)c2ccccc2-c2cc3c(cc21)N(c1ccc([Si](c2ccccc2)(c2ccccc2)c2ccccc2)c2ccccc12)c1cc(-c2ccccc2)ccc1C31c2ccccc2-c2ccccc21 ; CC1(C)c2ccccc2-c2cc3c(cc21)N(c1cc([Si](c2ccccc2)(c2ccccc2)c2ccccc2)cc2ccccc12)c1ccc(-c2ccccc2)cc1C31c2ccccc2-c2ccccc21 ; CC1(C)c2ccccc2-c2cc3c(cc21)N(c1ccc([Si](c2ccccc2)(c2ccccc2)c2ccccc2)c2ccccc12)c1cc2ccccc2cc1C31c2ccccc2-c2ccccc21] 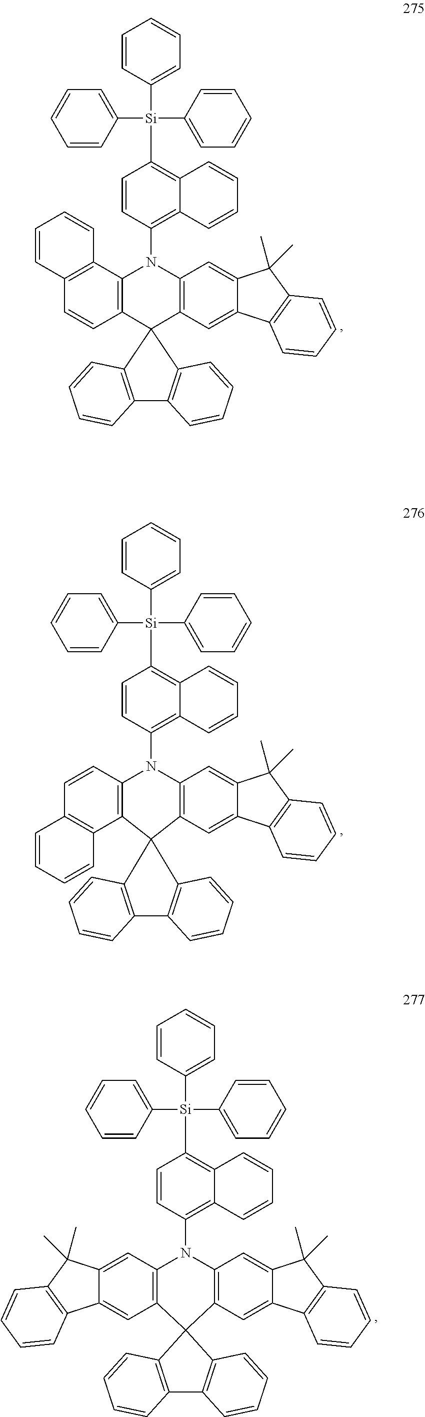 [SMILES: CC1(C)c2ccccc2-c2cc3c(cc21)N(c1ccc([Si](c2ccccc2)(c2ccccc2)c2ccccc2)c2ccccc12)c1c(ccc2ccccc12)C31c2ccccc2-c2ccccc21 ; CC1(C)c2ccccc2-c2cc3c(cc21)N(c1ccc([Si](c2ccccc2)(c2ccccc2)c2ccccc2)c2ccccc12)c1ccc2ccccc2c1C31c2ccccc2-c2ccccc21 ; CC1(C)c2ccccc2-c2cc3c(cc21)N(c1ccc([Si](c2ccccc2)(c2ccccc2)c2ccccc2)c2ccccc12)c1cc2c(cc1C31c3ccccc3-c3ccccc31)-c1ccccc1C2(C)C] 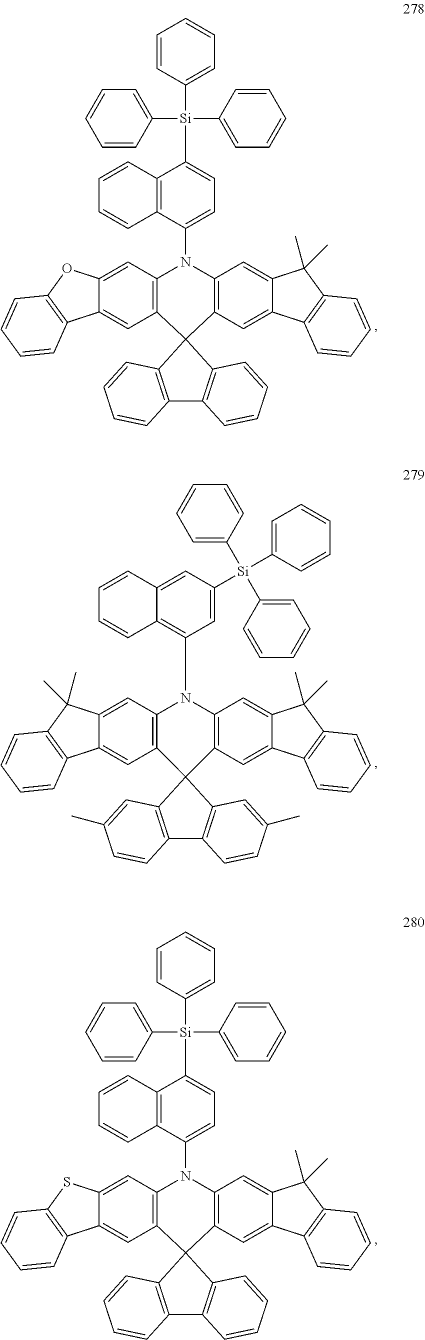 [SMILES: CC1(C)c2ccccc2-c2cc3c(cc21)N(c1ccc([Si](c2ccccc2)(c2ccccc2)c2ccccc2)c2ccccc12)c1cc2oc4ccccc4c2cc1C31c2ccccc2-c2ccccc21 ; Cc1ccc2c(c1)C1(c3cc(C)ccc3-2)c2cc3c(cc2N(c2cc([Si](c4ccccc4)(c4ccccc4)c4ccccc4)cc4ccccc24)c2cc4c(cc21)-c1ccccc1C4(C)C)C(C)(C)c1ccccc1-3 ; CC1(C)c2ccccc2-c2cc3c(cc21)N(c1ccc([Si](c2ccccc2)(c2ccccc2)c2ccccc2)c2ccccc12)c1cc2sc4ccccc4c2cc1C31c2ccccc2-c2ccccc21] 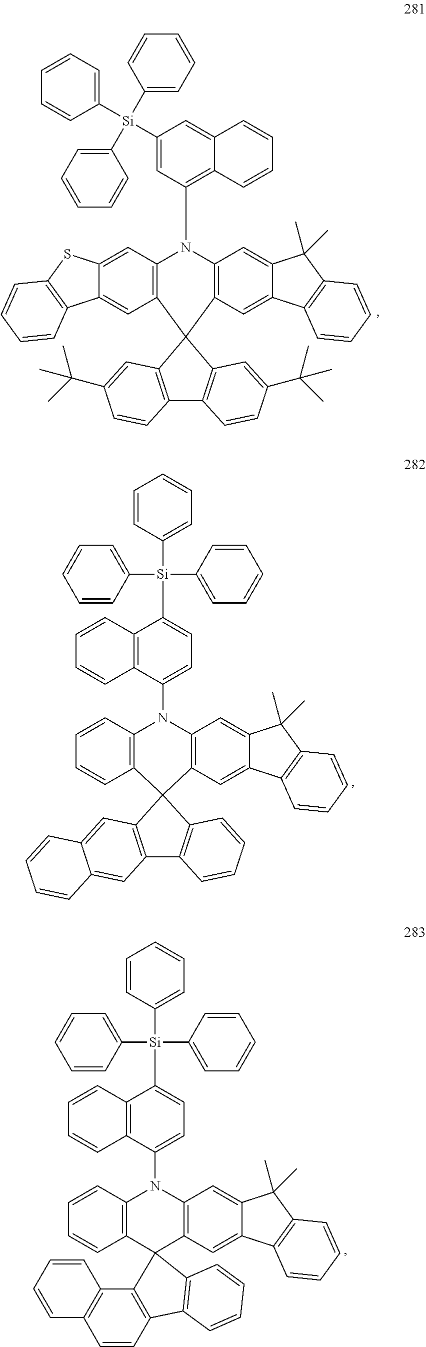 [SMILES: CC(C)(C)c1ccc2c(c1)C1(c3cc(C(C)(C)C)ccc3-2)c2cc3c(cc2N(c2cc([Si](c4ccccc4)(c4ccccc4)c4ccccc4)cc4ccccc24)c2cc4sc5ccccc5c4cc21)C(C)(C)c1ccccc1-3 ; CC1(C)c2ccccc2-c2cc3c(cc21)N(c1ccc([Si](c2ccccc2)(c2ccccc2)c2ccccc2)c2ccccc12)c1ccccc1C31c2ccccc2-c2cc3ccccc3cc21 ; CC1(C)c2ccccc2-c2cc3c(cc21)N(c1ccc([Si](c2ccccc2)(c2ccccc2)c2ccccc2)c2ccccc12)c1ccccc1C31c2ccccc2-c2ccc3ccccc3c21] 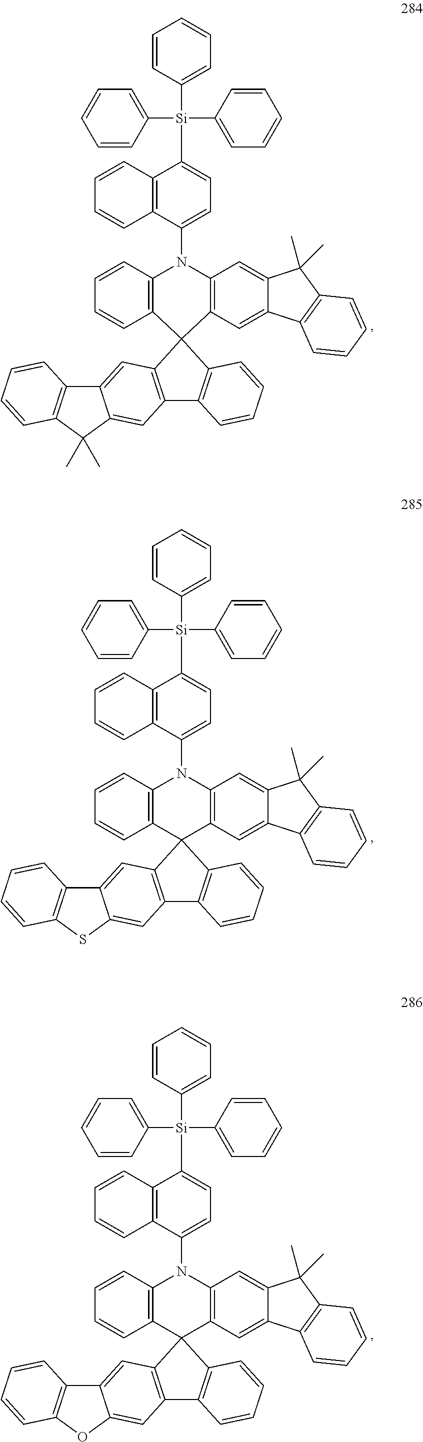 [SMILES: CC1(C)c2ccccc2-c2cc3c(cc21)-c1ccccc1C31c2ccccc2N(c2ccc([Si](c3ccccc3)(c3ccccc3)c3ccccc3)c3ccccc23)c2cc3c(cc21)-c1ccccc1C3(C)C ; CC1(C)c2ccccc2-c2cc3c(cc21)N(c1ccc([Si](c2ccccc2)(c2ccccc2)c2ccccc2)c2ccccc12)c1ccccc1C31c2ccccc2-c2cc3sc4ccccc4c3cc21 ; CC1(C)c2ccccc2-c2cc3c(cc21)N(c1ccc([Si](c2ccccc2)(c2ccccc2)c2ccccc2)c2ccccc12)c1ccccc1C31c2ccccc2-c2cc3oc4ccccc4c3cc21] 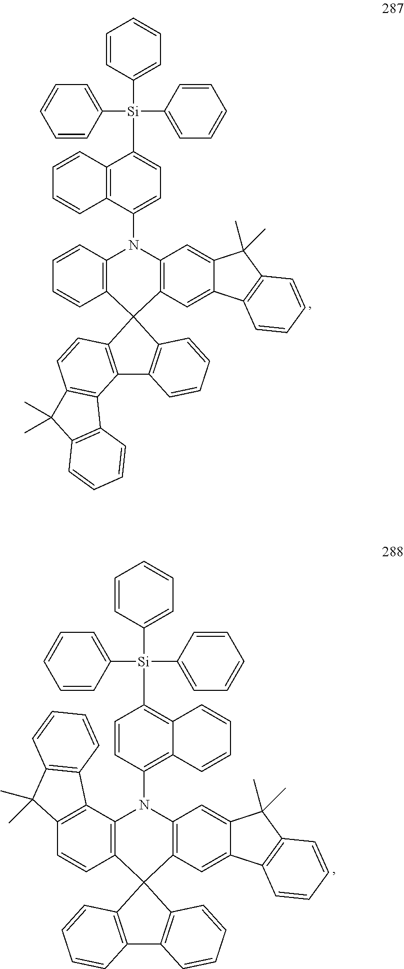 [SMILES: CC1(C)c2ccccc2-c2cc3c(cc21)N(c1ccc([Si](c2ccccc2)(c2ccccc2)c2ccccc2)c2ccccc12)c1ccccc1C31c2ccccc2-c2c1ccc1c2-c2ccccc2C1(C)C ; CC1(C)c2ccccc2-c2cc3c(cc21)N(c1ccc([Si](c2ccccc2)(c2ccccc2)c2ccccc2)c2ccccc12)c1c(ccc2c1-c1ccccc1C2(C)C)C31c2ccccc2-c2ccccc21] 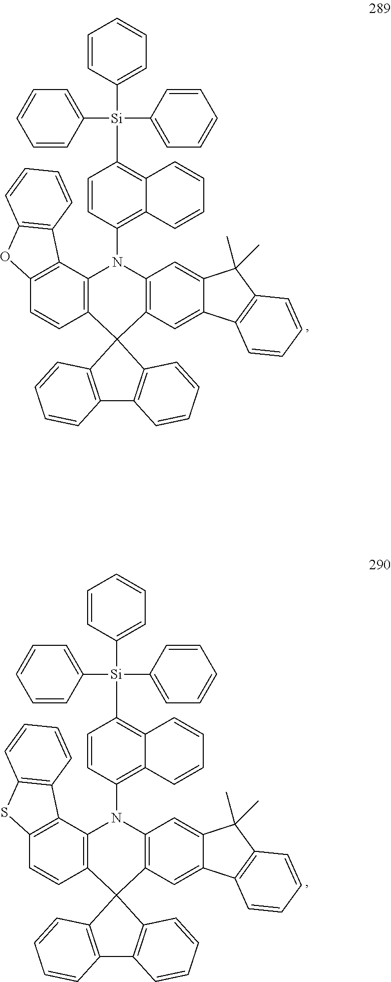 [SMILES: CC1(C)c2ccccc2-c2cc3c(cc21)N(c1ccc([Si](c2ccccc2)(c2ccccc2)c2ccccc2)c2ccccc12)c1c(ccc2oc4ccccc4c12)C31c2ccccc2-c2ccccc21 ; CC1(C)c2ccccc2-c2cc3c(cc21)N(c1ccc([Si](c2ccccc2)(c2ccccc2)c2ccccc2)c2ccccc12)c1c(ccc2sc4ccccc4c12)C31c2ccccc2-c2ccccc21] 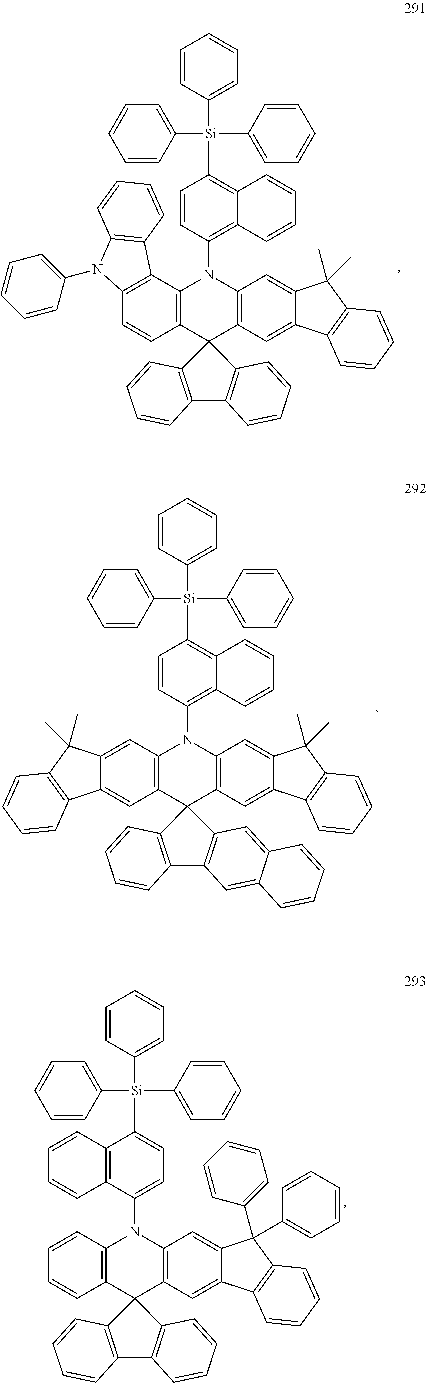 [SMILES: CC1(C)c2ccccc2-c2cc3c(cc21)N(c1ccc([Si](c2ccccc2)(c2ccccc2)c2ccccc2)c2ccccc12)c1c(ccc2c1c1ccccc1n2-c1ccccc1)C31c2ccccc2-c2ccccc21 ; CC1(C)c2ccccc2-c2cc3c(cc21)N(c1ccc([Si](c2ccccc2)(c2ccccc2)c2ccccc2)c2ccccc12)c1cc2c(cc1C31c3ccccc3-c3cc4ccccc4cc31)-c1ccccc1C2(C)C ; c1ccc(C2(c3ccccc3)c3ccccc3-c3cc4c(cc32)N(c2ccc([Si](c3ccccc3)(c3ccccc3)c3ccccc3)c3ccccc23)c2ccccc2C42c3ccccc3-c3ccccc32)cc1] 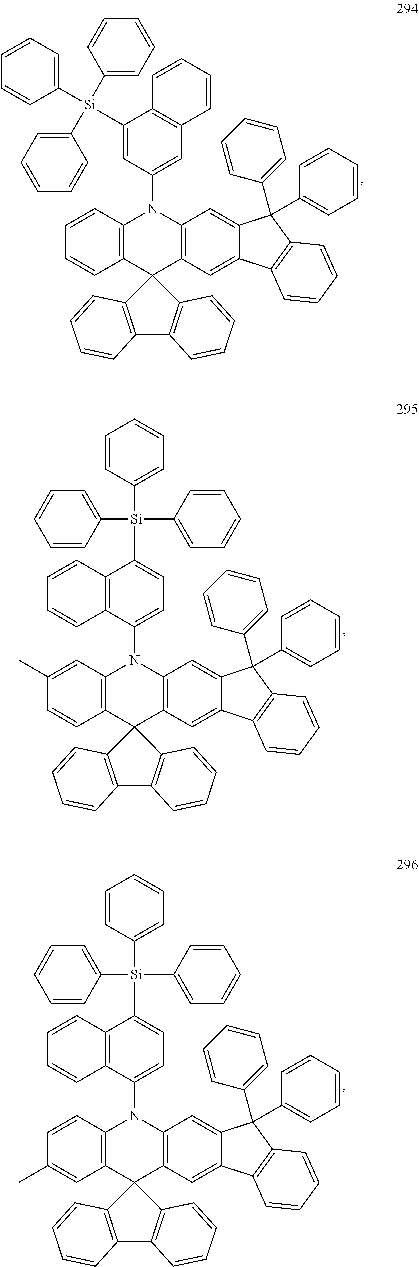 [SMILES: c1ccc(C2(c3ccccc3)c3ccccc3-c3cc4c(cc32)N(c2cc([Si](c3ccccc3)(c3ccccc3)c3ccccc3)c3ccccc3c2)c2ccccc2C42c3ccccc3-c3ccccc32)cc1 ; Cc1ccc2c(c1)N(c1ccc([Si](c3ccccc3)(c3ccccc3)c3ccccc3)c3ccccc13)c1cc3c(cc1C21c2ccccc2-c2ccccc21)-c1ccccc1C3(c1ccccc1)c1ccccc1 ; Cc1ccc2c(c1)C1(c3ccccc3-c3ccccc31)c1cc3c(cc1N2c1ccc([Si](c2ccccc2)(c2ccccc2)c2ccccc2)c2ccccc12)C(c1ccccc1)(c1ccccc1)c1ccccc1-3] 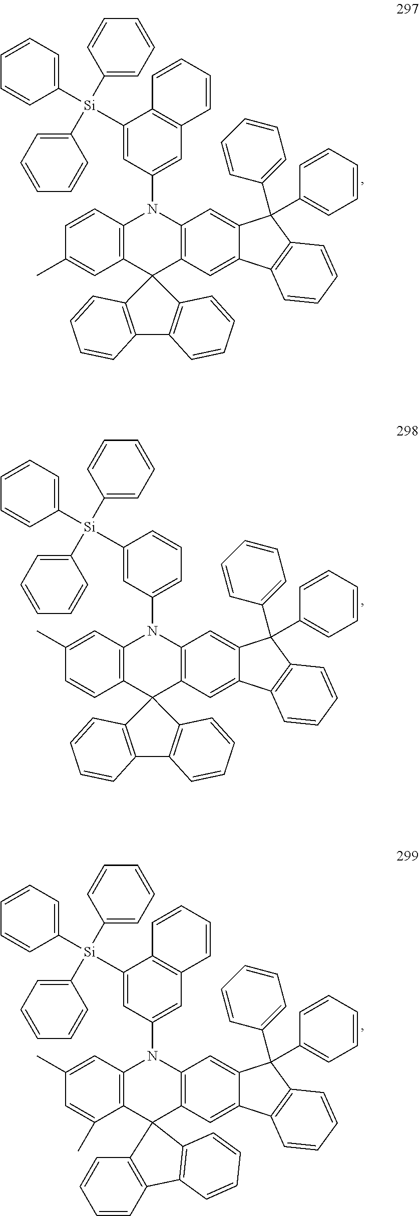 [SMILES: Cc1ccc2c(c1)C1(c3ccccc3-c3ccccc31)c1cc3c(cc1N2c1cc([Si](c2ccccc2)(c2ccccc2)c2ccccc2)c2ccccc2c1)C(c1ccccc1)(c1ccccc1)c1ccccc1-3 ; Cc1ccc2c(c1)N(c1cccc([Si](c3ccccc3)(c3ccccc3)c3ccccc3)c1)c1cc3c(cc1C21c2ccccc2-c2ccccc21)-c1ccccc1C3(c1ccccc1)c1ccccc1 ; Cc1cc(C)c2c(c1)N(c1cc([Si](c3ccccc3)(c3ccccc3)c3ccccc3)c3ccccc3c1)c1cc3c(cc1C21c2ccccc2-c2ccccc21)-c1ccccc1C3(c1ccccc1)c1ccccc1] 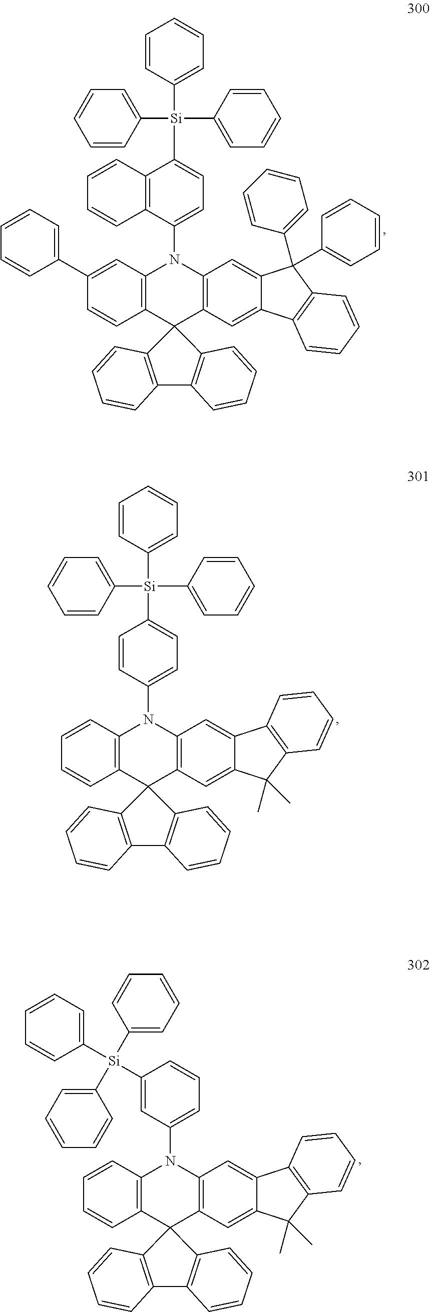 [SMILES: c1ccc(-c2ccc3c(c2)N(c2ccc([Si](c4ccccc4)(c4ccccc4)c4ccccc4)c4ccccc24)c2cc4c(cc2C32c3ccccc3-c3ccccc32)-c2ccccc2C4(c2ccccc2)c2ccccc2)cc1 ; CC1(C)c2ccccc2-c2cc3c(cc21)C1(c2ccccc2-c2ccccc21)c1ccccc1N3c1ccc([Si](c2ccccc2)(c2ccccc2)c2ccccc2)cc1 ; CC1(C)c2ccccc2-c2cc3c(cc21)C1(c2ccccc2-c2ccccc21)c1ccccc1N3c1cccc([Si](c2ccccc2)(c2ccccc2)c2ccccc2)c1] 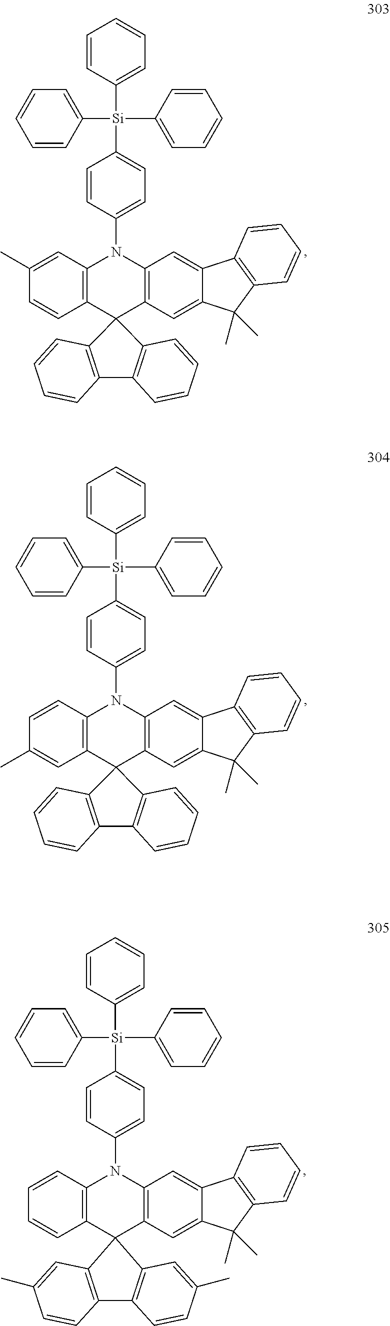 [SMILES: Cc1ccc2c(c1)N(c1ccc([Si](c3ccccc3)(c3ccccc3)c3ccccc3)cc1)c1cc3c(cc1C21c2ccccc2-c2ccccc21)C(C)(C)c1ccccc1-3 ; Cc1ccc2c(c1)C1(c3ccccc3-c3ccccc31)c1cc3c(cc1N2c1ccc([Si](c2ccccc2)(c2ccccc2)c2ccccc2)cc1)-c1ccccc1C3(C)C ; Cc1ccc2c(c1)C1(c3cc(C)ccc3-2)c2ccccc2N(c2ccc([Si](c3ccccc3)(c3ccccc3)c3ccccc3)cc2)c2cc3c(cc21)C(C)(C)c1ccccc1-3] 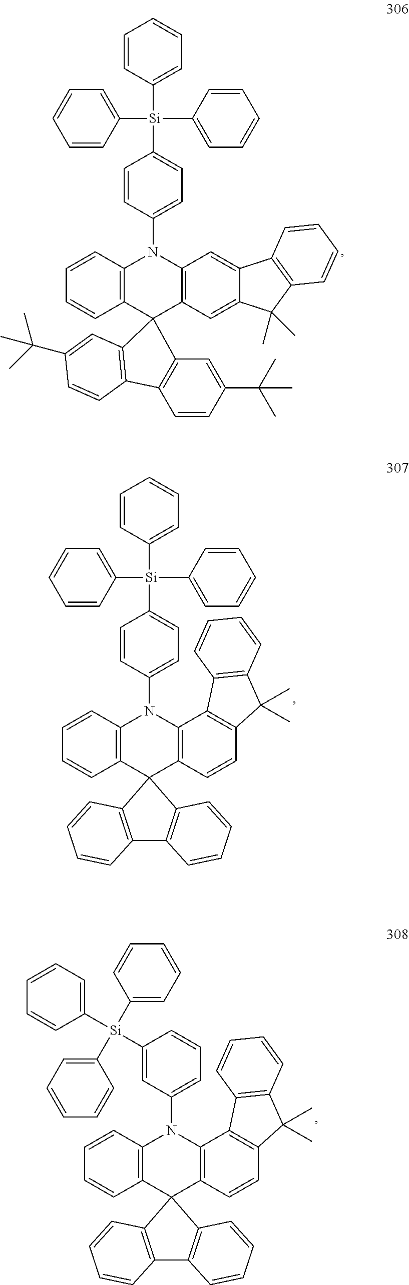 [SMILES: CC(C)(C)c1ccc2c(c1)C1(c3cc(C(C)(C)C)ccc3-2)c2ccccc2N(c2ccc([Si](c3ccccc3)(c3ccccc3)c3ccccc3)cc2)c2cc3c(cc21)C(C)(C)c1ccccc1-3 ; CC1(C)c2ccccc2-c2c1ccc1c2N(c2ccc([Si](c3ccccc3)(c3ccccc3)c3ccccc3)cc2)c2ccccc2C12c1ccccc1-c1ccccc12 ; CC1(C)c2ccccc2-c2c1ccc1c2N(c2cccc([Si](c3ccccc3)(c3ccccc3)c3ccccc3)c2)c2ccccc2C12c1ccccc1-c1ccccc12] 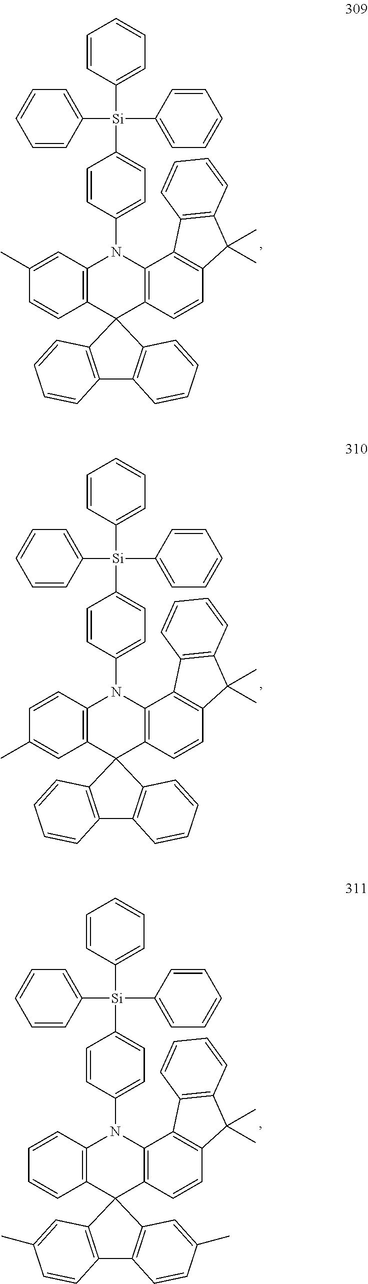 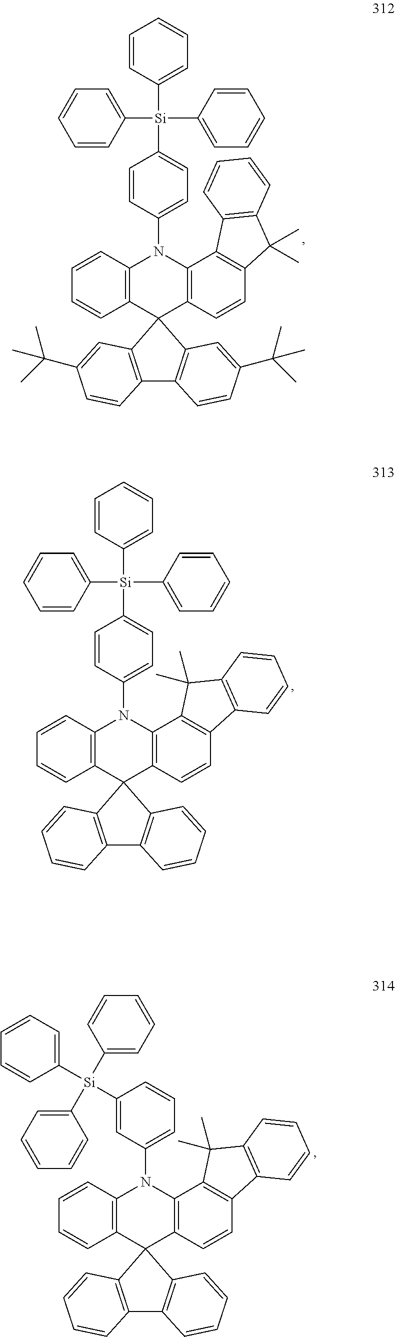 [SMILES: CC(C)(C)c1ccc2c(c1)C1(c3cc(C(C)(C)C)ccc3-2)c2ccccc2N(c2ccc([Si](c3ccccc3)(c3ccccc3)c3ccccc3)cc2)c2c1ccc1c2-c2ccccc2C1(C)C ; CC1(C)c2ccccc2-c2ccc3c(c21)N(c1ccc([Si](c2ccccc2)(c2ccccc2)c2ccccc2)cc1)c1ccccc1C31c2ccccc2-c2ccccc21 ; CC1(C)c2ccccc2-c2ccc3c(c21)N(c1cccc([Si](c2ccccc2)(c2ccccc2)c2ccccc2)c1)c1ccccc1C31c2ccccc2-c2ccccc21] 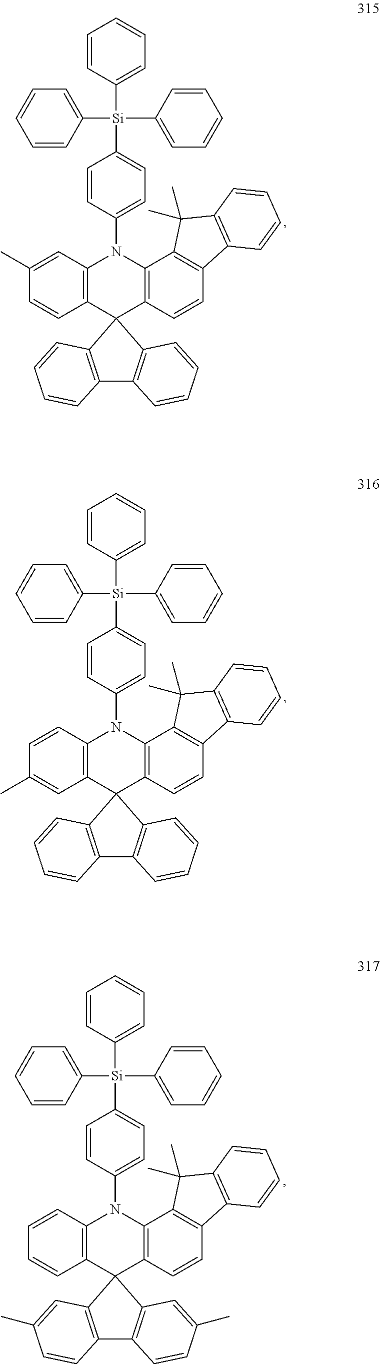 [SMILES: Cc1ccc2c(c1)N(c1ccc([Si](c3ccccc3)(c3ccccc3)c3ccccc3)cc1)c1c(ccc3c1C(C)(C)c1ccccc1-3)C21c2ccccc2-c2ccccc21 ; Cc1ccc2c(c1)C1(c3ccccc3-c3ccccc31)c1ccc3c(c1N2c1ccc([Si](c2ccccc2)(c2ccccc2)c2ccccc2)cc1)C(C)(C)c1ccccc1-3 ; Cc1ccc2c(c1)C1(c3cc(C)ccc3-2)c2ccccc2N(c2ccc([Si](c3ccccc3)(c3ccccc3)c3ccccc3)cc2)c2c1ccc1c2C(C)(C)c2ccccc2-1] 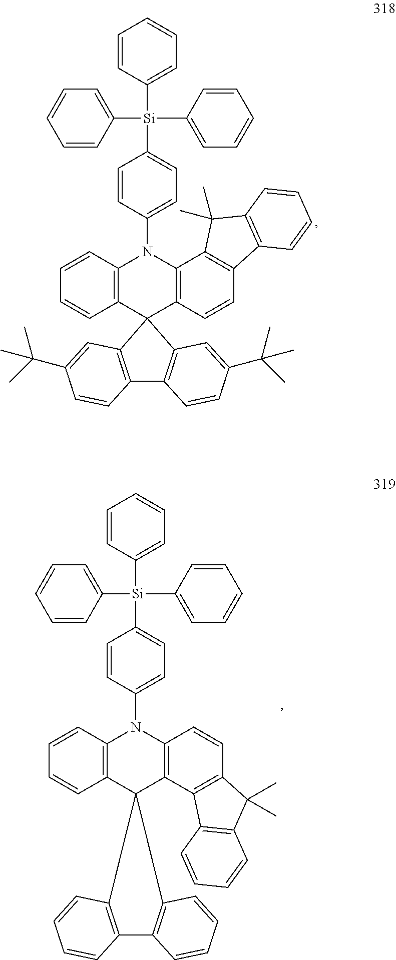 [SMILES: CC(C)(C)c1ccc2c(c1)C1(c3cc(C(C)(C)C)ccc3-2)c2ccccc2N(c2ccc([Si](c3ccccc3)(c3ccccc3)c3ccccc3)cc2)c2c1ccc1c2C(C)(C)c2ccccc2-1 ; CC1(C)c2ccccc2-c2c1ccc1c2C2(c3ccccc3-c3ccccc32)c2ccccc2N1c1ccc([Si](c2ccccc2)(c2ccccc2)c2ccccc2)cc1] 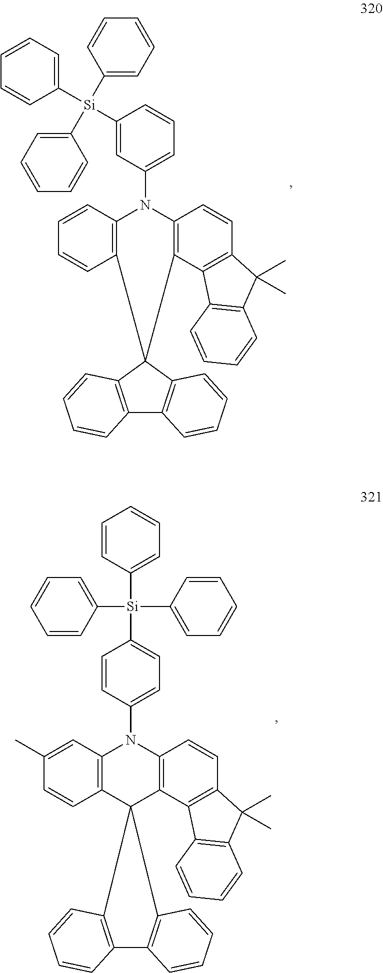 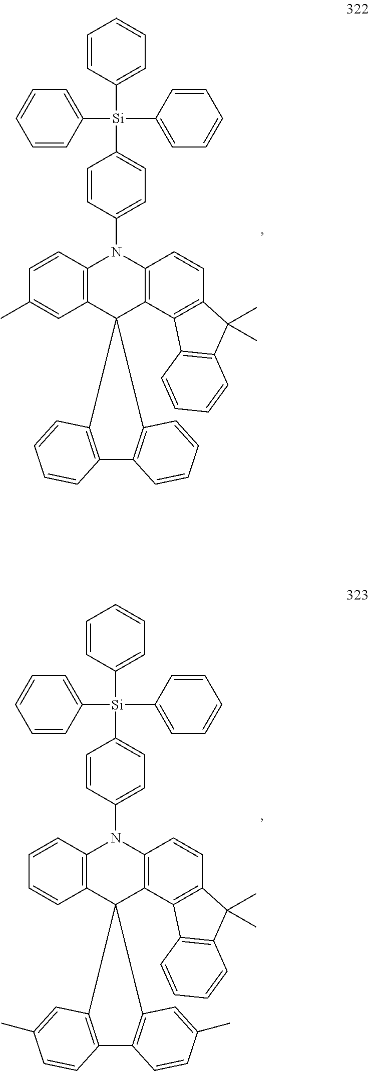 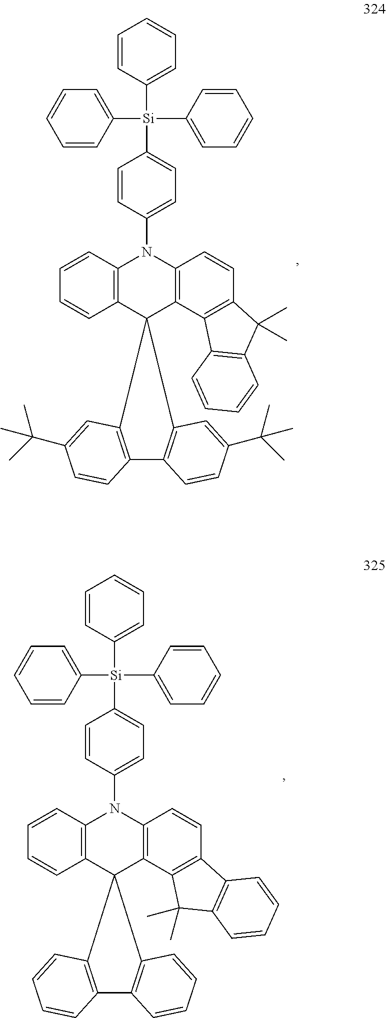 [SMILES: CC(C)(C)c1ccc2c(c1)C1(c3cc(C(C)(C)C)ccc3-2)c2ccccc2N(c2ccc([Si](c3ccccc3)(c3ccccc3)c3ccccc3)cc2)c2ccc3c(c21)-c1ccccc1C3(C)C ; CC1(C)c2ccccc2-c2ccc3c(c21)C1(c2ccccc2-c2ccccc21)c1ccccc1N3c1ccc([Si](c2ccccc2)(c2ccccc2)c2ccccc2)cc1] 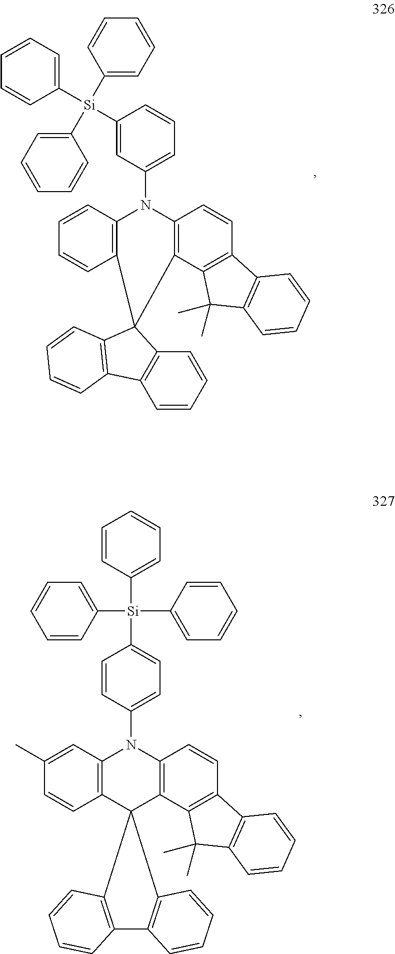 [SMILES: CC1(C)c2ccccc2-c2ccc3c(c21)C1(c2ccccc2-c2ccccc21)c1ccccc1N3c1cccc([Si](c2ccccc2)(c2ccccc2)c2ccccc2)c1 ; Cc1ccc2c(c1)N(c1ccc([Si](c3ccccc3)(c3ccccc3)c3ccccc3)cc1)c1ccc3c(c1C21c2ccccc2-c2ccccc21)C(C)(C)c1ccccc1-3] 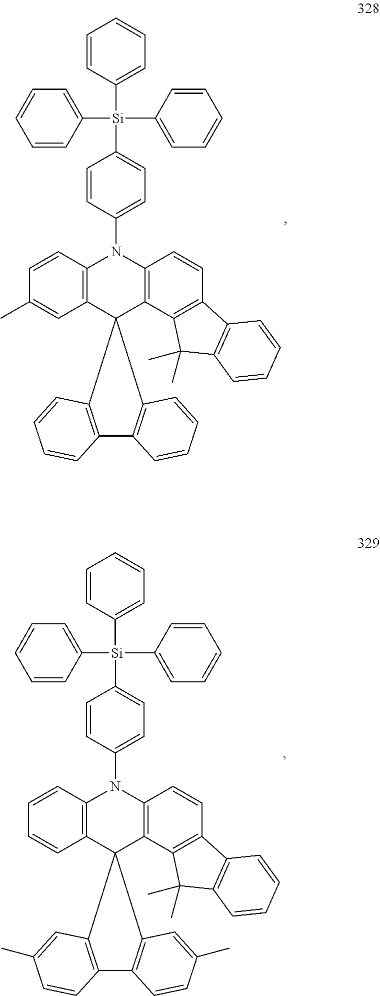 [SMILES: Cc1ccc2c(c1)C1(c3ccccc3-c3ccccc31)c1c(ccc3c1C(C)(C)c1ccccc1-3)N2c1ccc([Si](c2ccccc2)(c2ccccc2)c2ccccc2)cc1 ; Cc1ccc2c(c1)C1(c3cc(C)ccc3-2)c2ccccc2N(c2ccc([Si](c3ccccc3)(c3ccccc3)c3ccccc3)cc2)c2ccc3c(c21)C(C)(C)c1ccccc1-3] 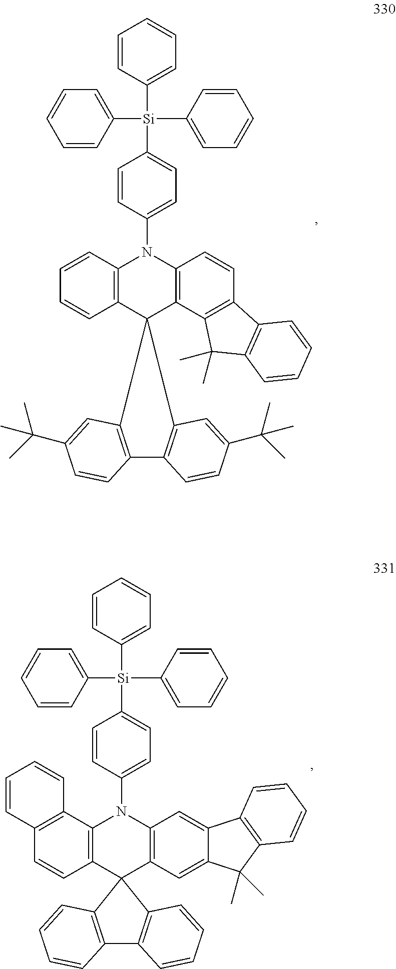 [SMILES: CC(C)(C)c1ccc2c(c1)C1(c3cc(C(C)(C)C)ccc3-2)c2ccccc2N(c2ccc([Si](c3ccccc3)(c3ccccc3)c3ccccc3)cc2)c2ccc3c(c21)C(C)(C)c1ccccc1-3 ; CC1(C)c2ccccc2-c2cc3c(cc21)C1(c2ccccc2-c2ccccc21)c1ccc2ccccc2c1N3c1ccc([Si](c2ccccc2)(c2ccccc2)c2ccccc2)cc1] 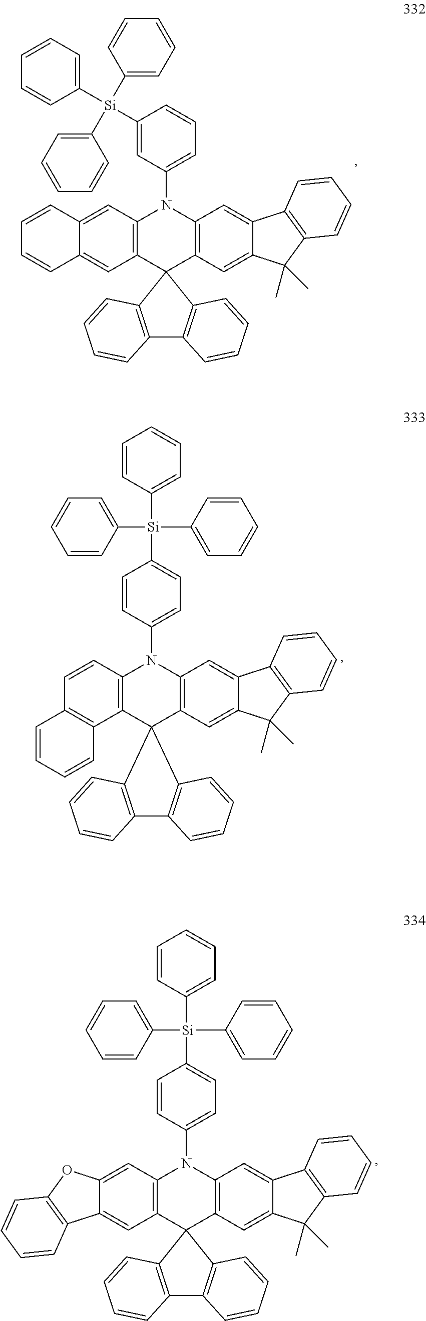 [SMILES: CC1(C)c2ccccc2-c2cc3c(cc21)C1(c2ccccc2-c2ccccc21)c1cc2ccccc2cc1N3c1cccc([Si](c2ccccc2)(c2ccccc2)c2ccccc2)c1 ; CC1(C)c2ccccc2-c2cc3c(cc21)C1(c2ccccc2-c2ccccc21)c1c(ccc2ccccc12)N3c1ccc([Si](c2ccccc2)(c2ccccc2)c2ccccc2)cc1 ; CC1(C)c2ccccc2-c2cc3c(cc21)C1(c2ccccc2-c2ccccc21)c1cc2c(cc1N3c1ccc([Si](c3ccccc3)(c3ccccc3)c3ccccc3)cc1)oc1ccccc12] 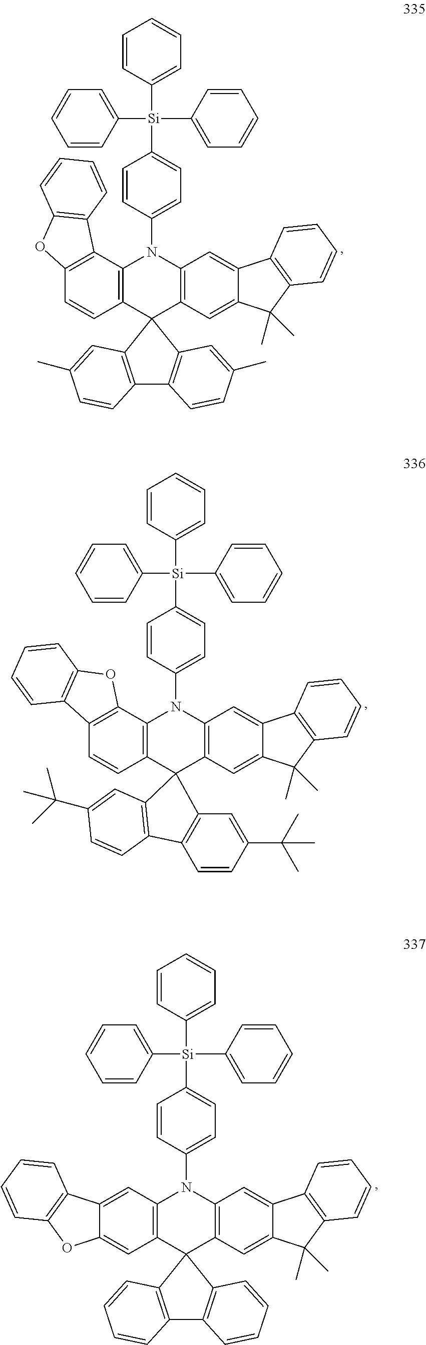 [SMILES: Cc1ccc2c(c1)C1(c3cc(C)ccc3-2)c2cc3c(cc2N(c2ccc([Si](c4ccccc4)(c4ccccc4)c4ccccc4)cc2)c2c1ccc1oc4ccccc4c21)-c1ccccc1C3(C)C ; CC(C)(C)c1ccc2c(c1)C1(c3cc(C(C)(C)C)ccc3-2)c2cc3c(cc2N(c2ccc([Si](c4ccccc4)(c4ccccc4)c4ccccc4)cc2)c2c1ccc1c2oc2ccccc21)-c1ccccc1C3(C)C ; CC1(C)c2ccccc2-c2cc3c(cc21)C1(c2ccccc2-c2ccccc21)c1cc2oc4ccccc4c2cc1N3c1ccc([Si](c2ccccc2)(c2ccccc2)c2ccccc2)cc1] 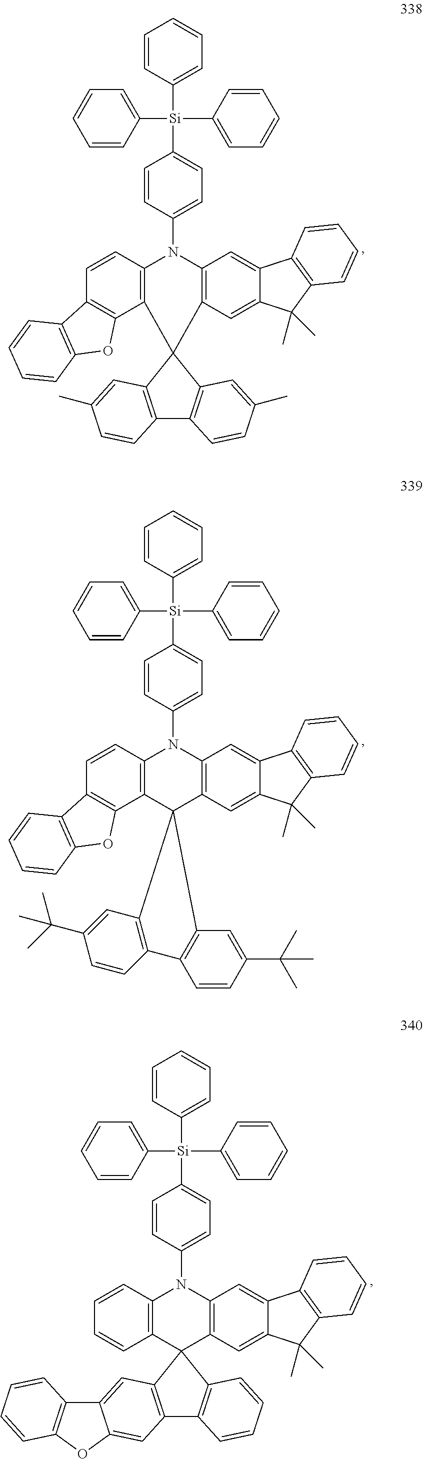 [SMILES: Cc1ccc2c(c1)C1(c3cc(C)ccc3-2)c2cc3c(cc2N(c2ccc([Si](c4ccccc4)(c4ccccc4)c4ccccc4)cc2)c2ccc4c(oc5ccccc54)c21)-c1ccccc1C3(C)C ; CC(C)(C)c1ccc2c(c1)C1(c3cc(C(C)(C)C)ccc3-2)c2cc3c(cc2N(c2ccc([Si](c4ccccc4)(c4ccccc4)c4ccccc4)cc2)c2ccc4c(oc5ccccc54)c21)-c1ccccc1C3(C)C ; CC1(C)c2ccccc2-c2cc3c(cc21)C1(c2ccccc2-c2cc4oc5ccccc5c4cc21)c1ccccc1N3c1ccc([Si](c2ccccc2)(c2ccccc2)c2ccccc2)cc1] 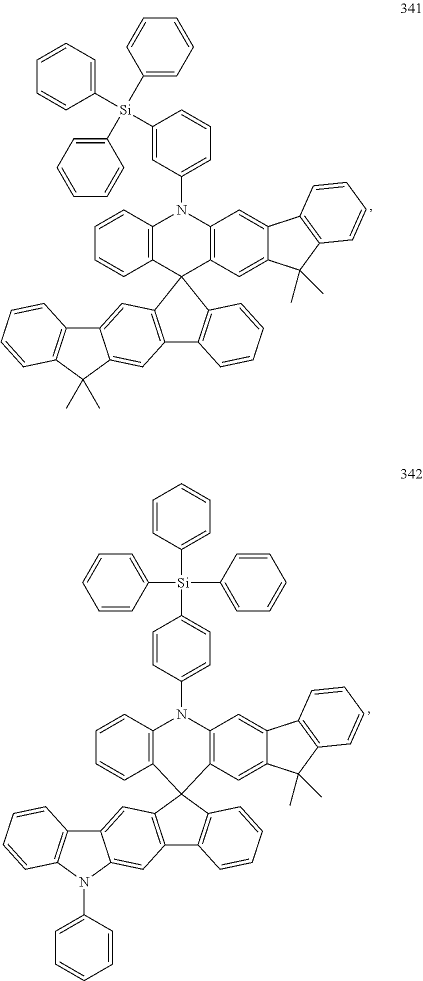 [SMILES: CC1(C)c2ccccc2-c2cc3c(cc21)-c1ccccc1C31c2ccccc2N(c2cccc([Si](c3ccccc3)(c3ccccc3)c3ccccc3)c2)c2cc3c(cc21)C(C)(C)c1ccccc1-3 ; CC1(C)c2ccccc2-c2cc3c(cc21)C1(c2ccccc2-c2cc4c(cc21)c1ccccc1n4-c1ccccc1)c1ccccc1N3c1ccc([Si](c2ccccc2)(c2ccccc2)c2ccccc2)cc1] 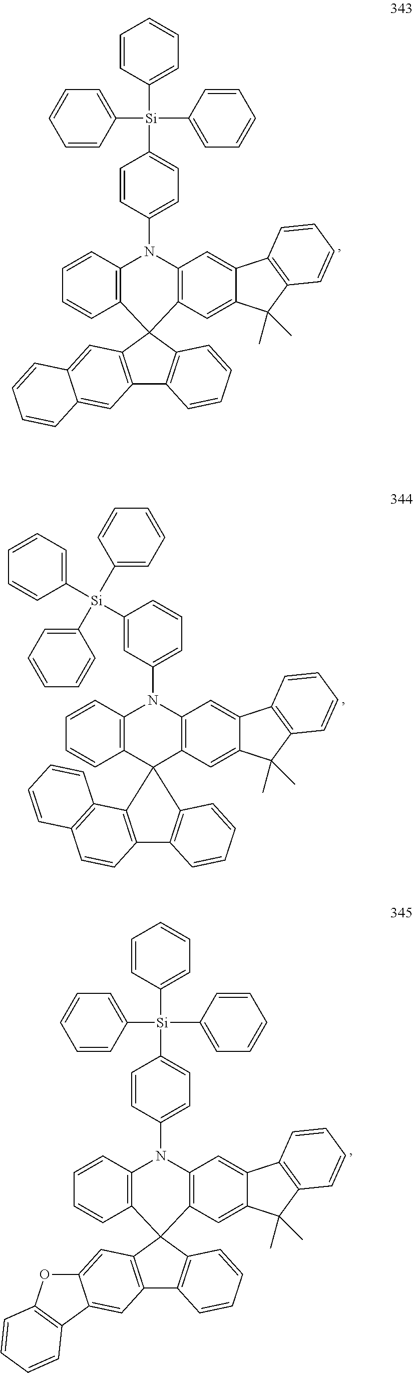 [SMILES: CC1(C)c2ccccc2-c2cc3c(cc21)C1(c2ccccc2-c2cc4ccccc4cc21)c1ccccc1N3c1ccc([Si](c2ccccc2)(c2ccccc2)c2ccccc2)cc1 ; CC1(C)c2ccccc2-c2cc3c(cc21)C1(c2ccccc2-c2ccc4ccccc4c21)c1ccccc1N3c1cccc([Si](c2ccccc2)(c2ccccc2)c2ccccc2)c1 ; CC1(C)c2ccccc2-c2cc3c(cc21)C1(c2ccccc2-c2cc4c(cc21)oc1ccccc14)c1ccccc1N3c1ccc([Si](c2ccccc2)(c2ccccc2)c2ccccc2)cc1] 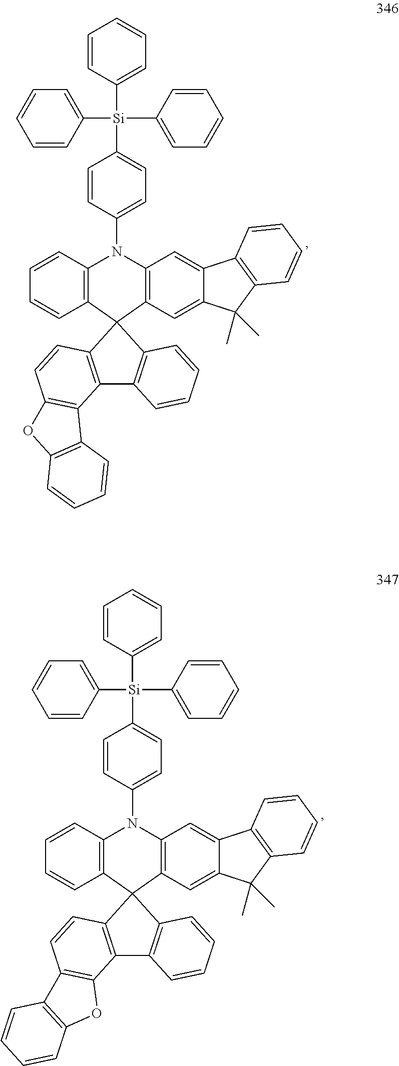 [SMILES: CC1(C)c2ccccc2-c2cc3c(cc21)C1(c2ccccc2-c2c1ccc1oc4ccccc4c21)c1ccccc1N3c1ccc([Si](c2ccccc2)(c2ccccc2)c2ccccc2)cc1 ; CC1(C)c2ccccc2-c2cc3c(cc21)C1(c2ccccc2-c2c1ccc1c2oc2ccccc21)c1ccccc1N3c1ccc([Si](c2ccccc2)(c2ccccc2)c2ccccc2)cc1] 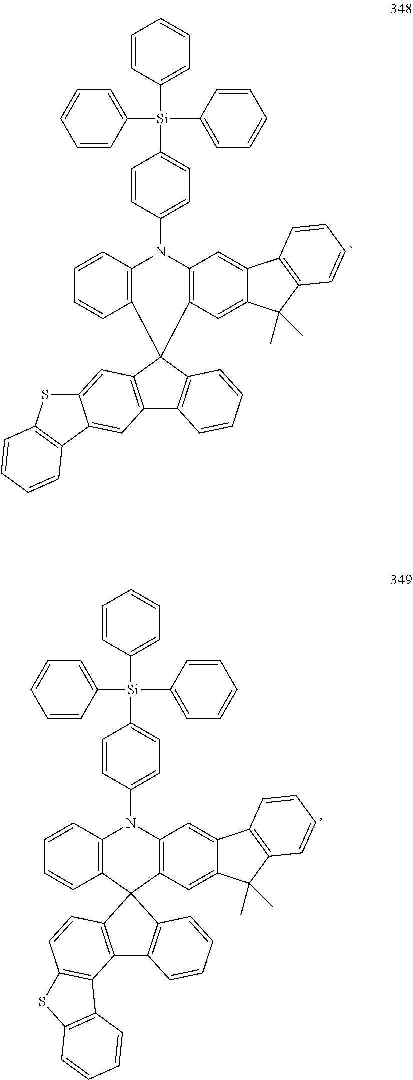 [SMILES: CC1(C)c2ccccc2-c2cc3c(cc21)C1(c2ccccc2-c2cc4c(cc21)sc1ccccc14)c1ccccc1N3c1ccc([Si](c2ccccc2)(c2ccccc2)c2ccccc2)cc1 ; CC1(C)c2ccccc2-c2cc3c(cc21)C1(c2ccccc2-c2c1ccc1sc4ccccc4c21)c1ccccc1N3c1ccc([Si](c2ccccc2)(c2ccccc2)c2ccccc2)cc1] 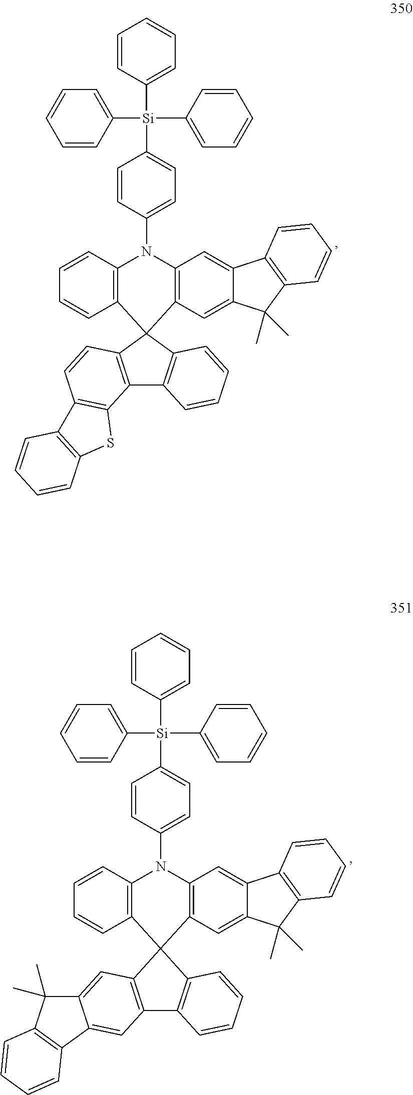 [SMILES: CC1(C)c2ccccc2-c2cc3c(cc21)C1(c2ccccc2-c2c1ccc1c2sc2ccccc21)c1ccccc1N3c1ccc([Si](c2ccccc2)(c2ccccc2)c2ccccc2)cc1 ; CC1(C)c2ccccc2-c2cc3c(cc21)C1(c2ccccc2-3)c2ccccc2N(c2ccc([Si](c3ccccc3)(c3ccccc3)c3ccccc3)cc2)c2cc3c(cc21)C(C)(C)c1ccccc1-3] 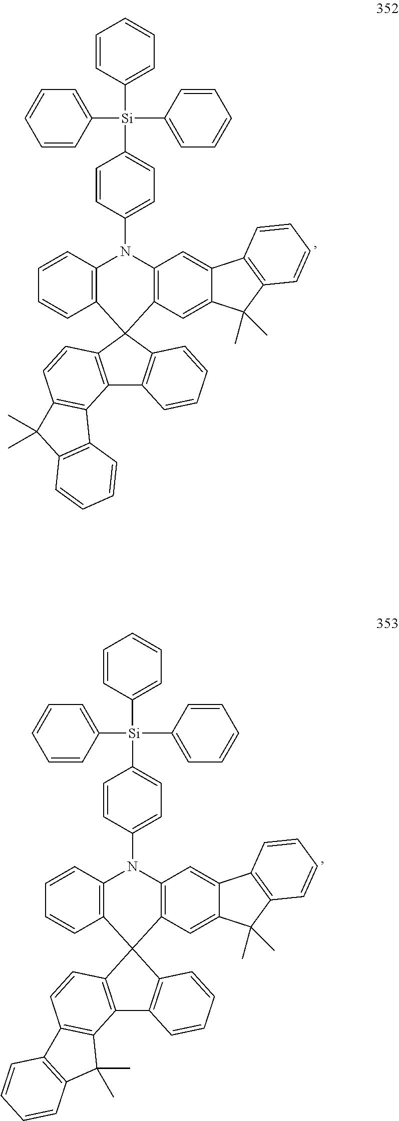 [SMILES: CC1(C)c2ccccc2-c2cc3c(cc21)C1(c2ccccc2-c2c1ccc1c2-c2ccccc2C1(C)C)c1ccccc1N3c1ccc([Si](c2ccccc2)(c2ccccc2)c2ccccc2)cc1 ; CC1(C)c2ccccc2-c2cc3c(cc21)C1(c2ccccc2-c2c1ccc1c2C(C)(C)c2ccccc2-1)c1ccccc1N3c1ccc([Si](c2ccccc2)(c2ccccc2)c2ccccc2)cc1] 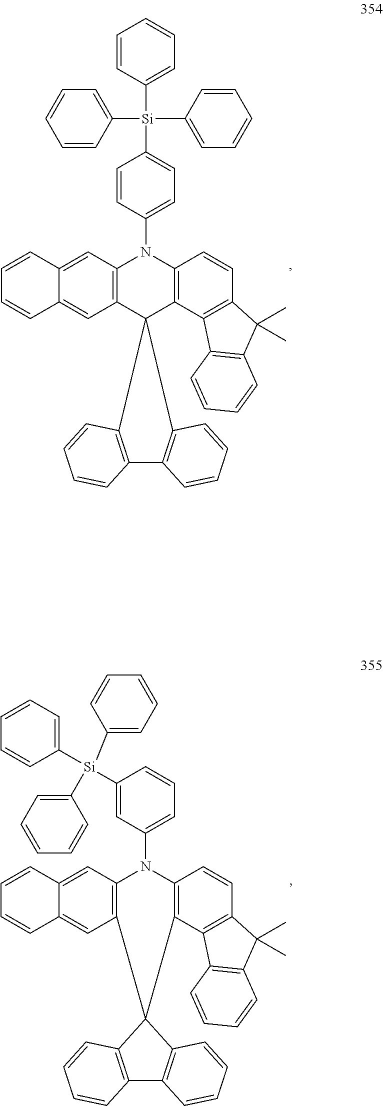 [SMILES: CC1(C)c2ccccc2-c2c1ccc1c2C2(c3ccccc3-c3ccccc32)c2cc3ccccc3cc2N1c1ccc([Si](c2ccccc2)(c2ccccc2)c2ccccc2)cc1 ; CC1(C)c2ccccc2-c2c1ccc1c2C2(c3ccccc3-c3ccccc32)c2cc3ccccc3cc2N1c1cccc([Si](c2ccccc2)(c2ccccc2)c2ccccc2)c1] 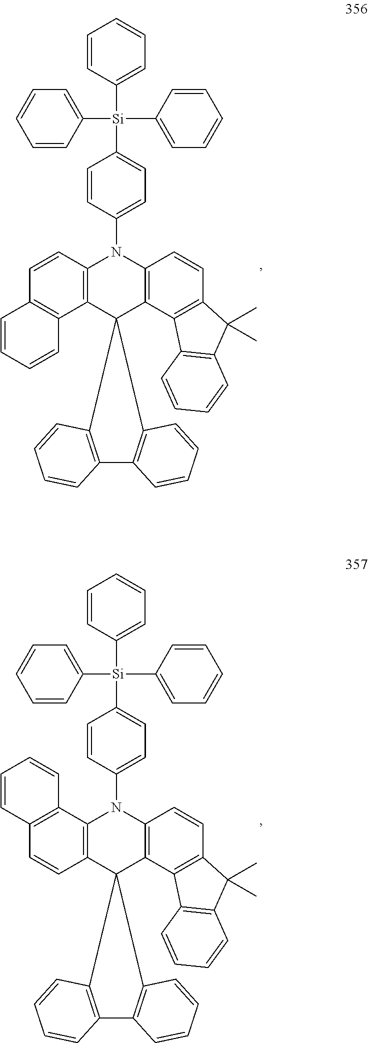 [SMILES: CC1(C)c2ccccc2-c2c1ccc1c2C2(c3ccccc3-c3ccccc32)c2c(ccc3ccccc23)N1c1ccc([Si](c2ccccc2)(c2ccccc2)c2ccccc2)cc1 ; CC1(C)c2ccccc2-c2c1ccc1c2C2(c3ccccc3-c3ccccc32)c2ccc3ccccc3c2N1c1ccc([Si](c2ccccc2)(c2ccccc2)c2ccccc2)cc1] 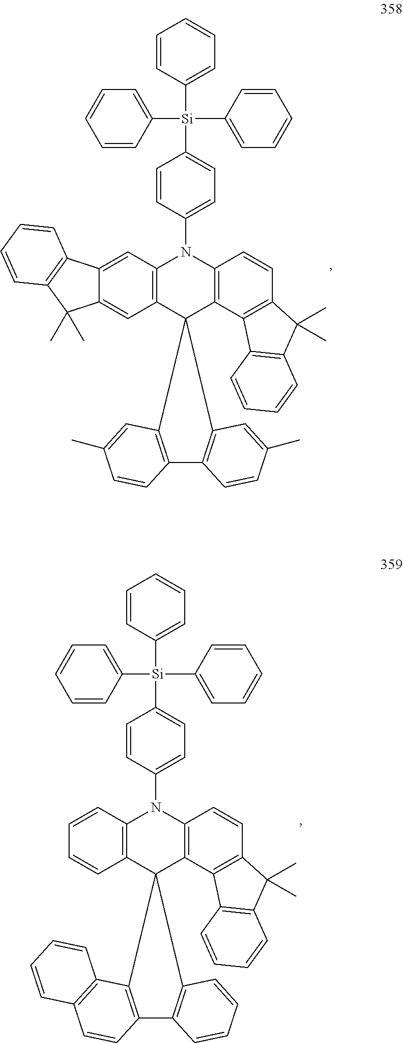 [SMILES: Cc1ccc2c(c1)C1(c3cc(C)ccc3-2)c2cc3c(cc2N(c2ccc([Si](c4ccccc4)(c4ccccc4)c4ccccc4)cc2)c2ccc4c(c21)-c1ccccc1C4(C)C)-c1ccccc1C3(C)C ; CC1(C)c2ccccc2-c2c1ccc1c2C2(c3ccccc3-c3ccc4ccccc4c32)c2ccccc2N1c1ccc([Si](c2ccccc2)(c2ccccc2)c2ccccc2)cc1] 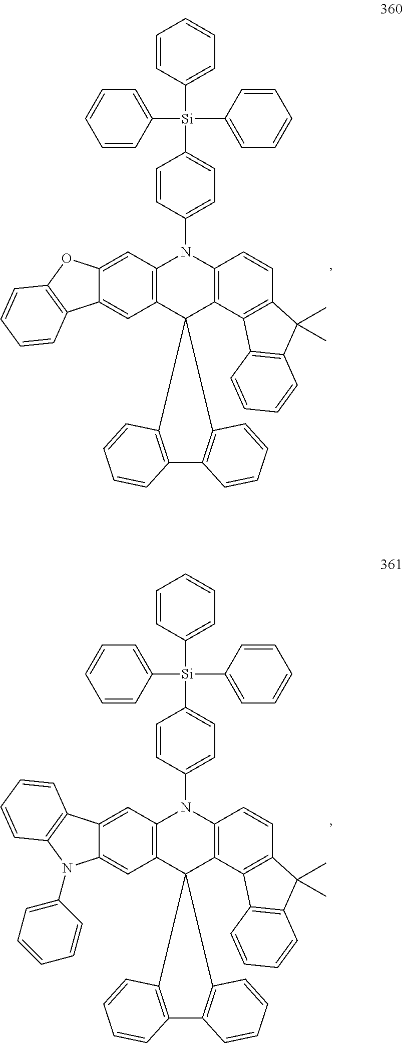 [SMILES: CC1(C)c2ccccc2-c2c1ccc1c2C2(c3ccccc3-c3ccccc32)c2cc3c(cc2N1c1ccc([Si](c2ccccc2)(c2ccccc2)c2ccccc2)cc1)oc1ccccc13 ; CC1(C)c2ccccc2-c2c1ccc1c2C2(c3ccccc3-c3ccccc32)c2cc3c(cc2N1c1ccc([Si](c2ccccc2)(c2ccccc2)c2ccccc2)cc1)c1ccccc1n3-c1ccccc1] 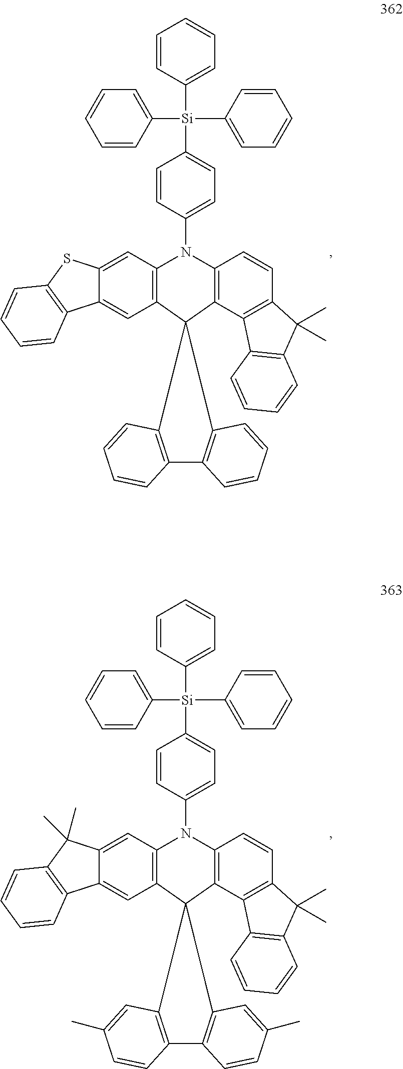 [SMILES: CC1(C)c2ccccc2-c2c1ccc1c2C2(c3ccccc3-c3ccccc32)c2cc3c(cc2N1c1ccc([Si](c2ccccc2)(c2ccccc2)c2ccccc2)cc1)sc1ccccc13 ; Cc1ccc2c(c1)C1(c3cc(C)ccc3-2)c2cc3c(cc2N(c2ccc([Si](c4ccccc4)(c4ccccc4)c4ccccc4)cc2)c2ccc4c(c21)-c1ccccc1C4(C)C)C(C)(C)c1ccccc1-3] 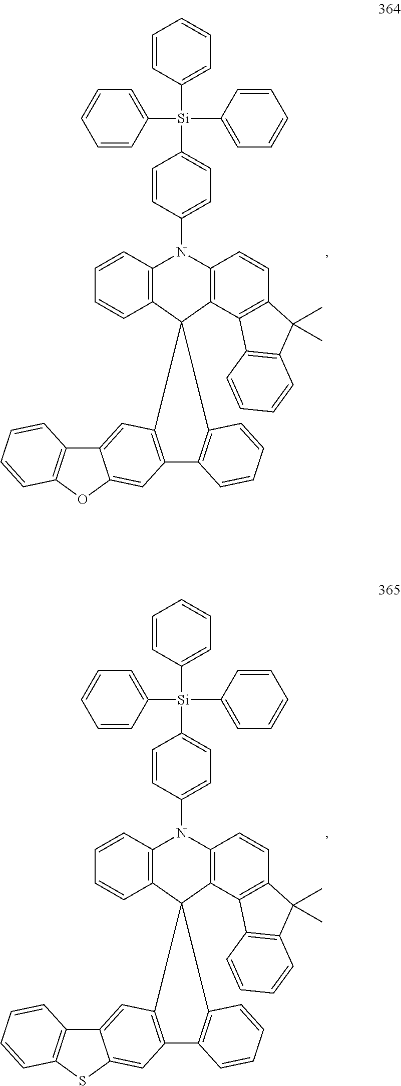 [SMILES: CC1(C)c2ccccc2-c2c1ccc1c2C2(c3ccccc3-c3cc4oc5ccccc5c4cc32)c2ccccc2N1c1ccc([Si](c2ccccc2)(c2ccccc2)c2ccccc2)cc1 ; CC1(C)c2ccccc2-c2c1ccc1c2C2(c3ccccc3-c3cc4sc5ccccc5c4cc32)c2ccccc2N1c1ccc([Si](c2ccccc2)(c2ccccc2)c2ccccc2)cc1] 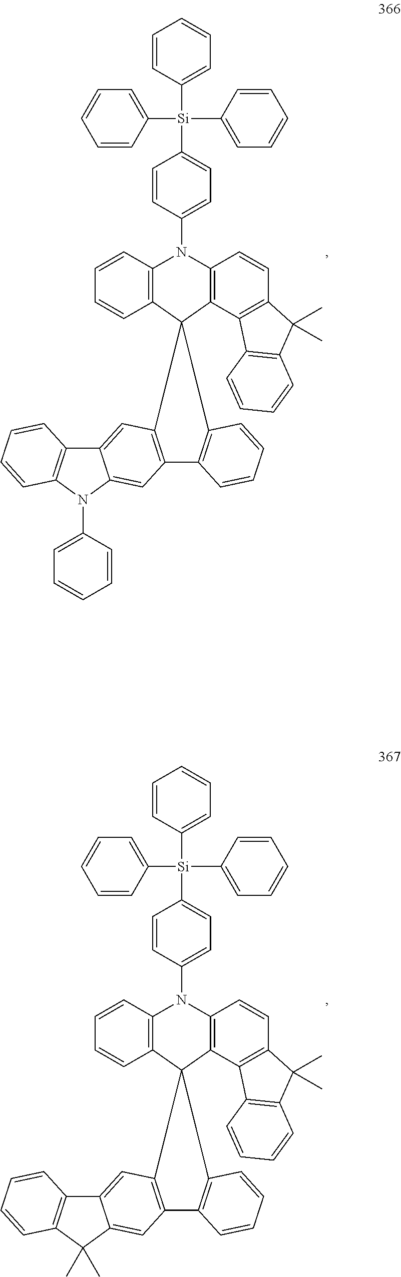 [SMILES: CC1(C)c2ccccc2-c2c1ccc1c2C2(c3ccccc3-c3cc4c(cc32)c2ccccc2n4-c2ccccc2)c2ccccc2N1c1ccc([Si](c2ccccc2)(c2ccccc2)c2ccccc2)cc1 ; CC1(C)c2ccccc2-c2cc3c(cc21)-c1ccccc1C31c2ccccc2N(c2ccc([Si](c3ccccc3)(c3ccccc3)c3ccccc3)cc2)c2ccc3c(c21)-c1ccccc1C3(C)C] 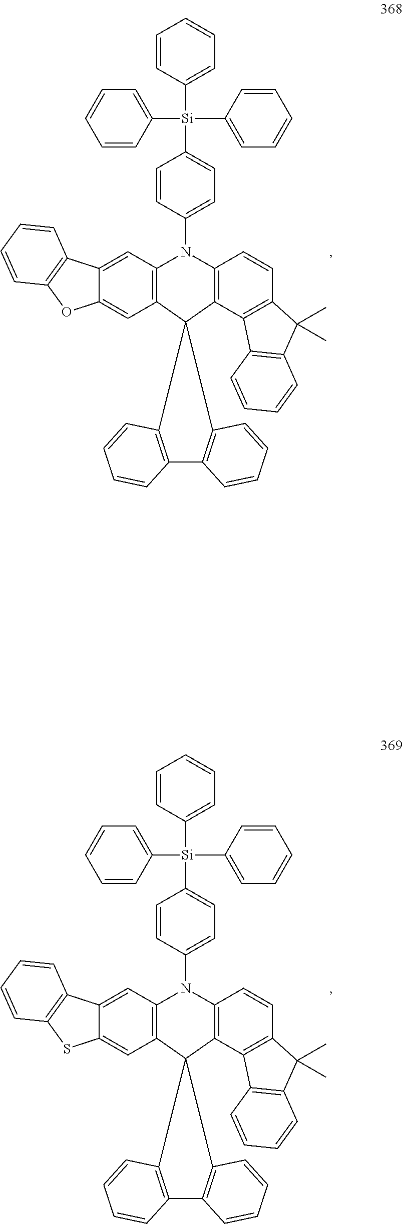 [SMILES: CC1(C)c2ccccc2-c2c1ccc1c2C2(c3ccccc3-c3ccccc32)c2cc3oc4ccccc4c3cc2N1c1ccc([Si](c2ccccc2)(c2ccccc2)c2ccccc2)cc1 ; CC1(C)c2ccccc2-c2c1ccc1c2C2(c3ccccc3-c3ccccc32)c2cc3sc4ccccc4c3cc2N1c1ccc([Si](c2ccccc2)(c2ccccc2)c2ccccc2)cc1] 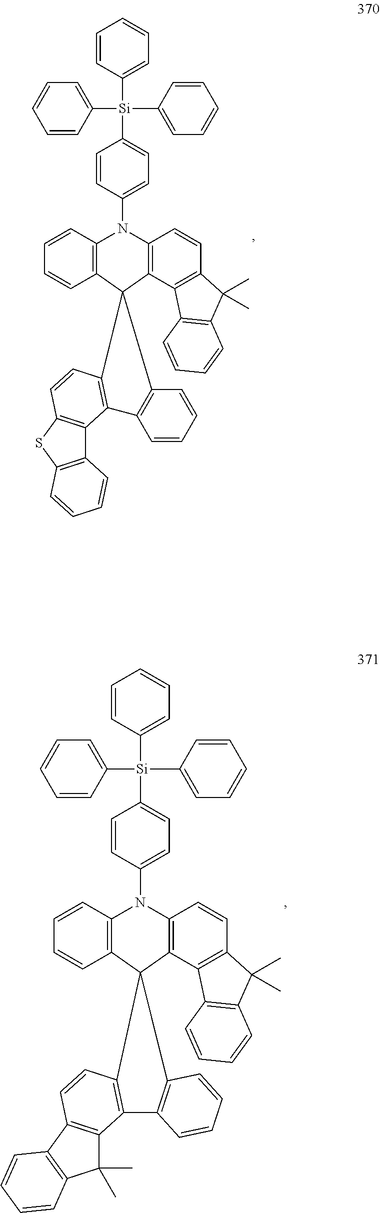 [SMILES: CC1(C)c2ccccc2-c2c1ccc1c2C2(c3ccccc3-c3c2ccc2sc4ccccc4c32)c2ccccc2N1c1ccc([Si](c2ccccc2)(c2ccccc2)c2ccccc2)cc1 ; CC1(C)c2ccccc2-c2c1ccc1c2C2(c3ccccc3-c3c2ccc2c3C(C)(C)c3ccccc3-2)c2ccccc2N1c1ccc([Si](c2ccccc2)(c2ccccc2)c2ccccc2)cc1] 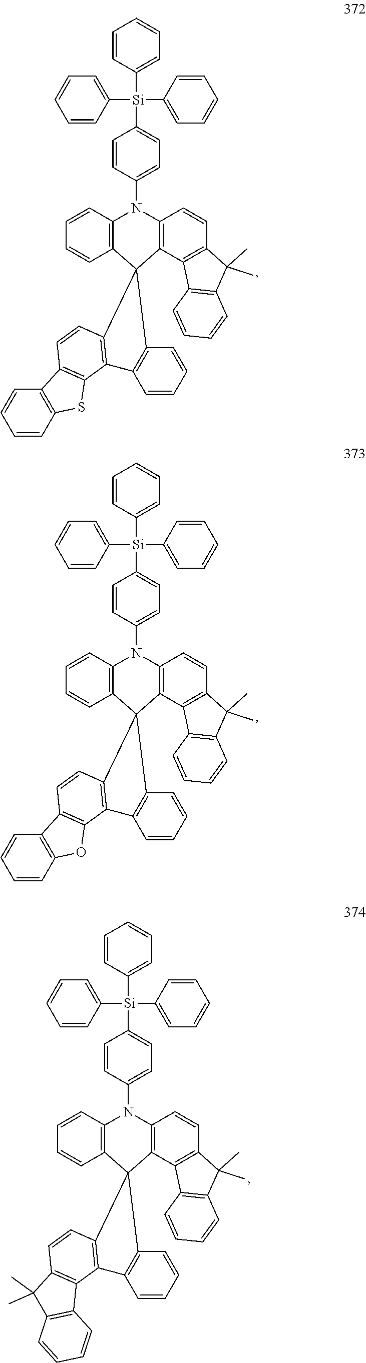 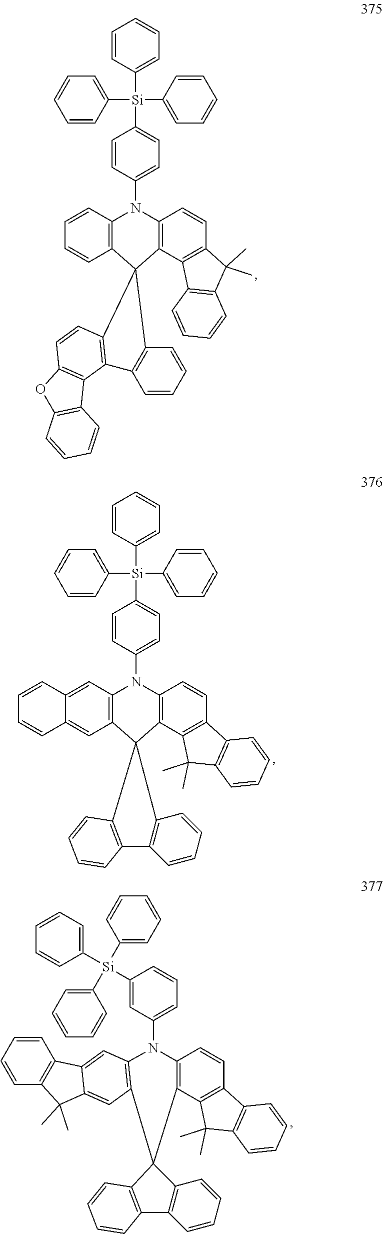 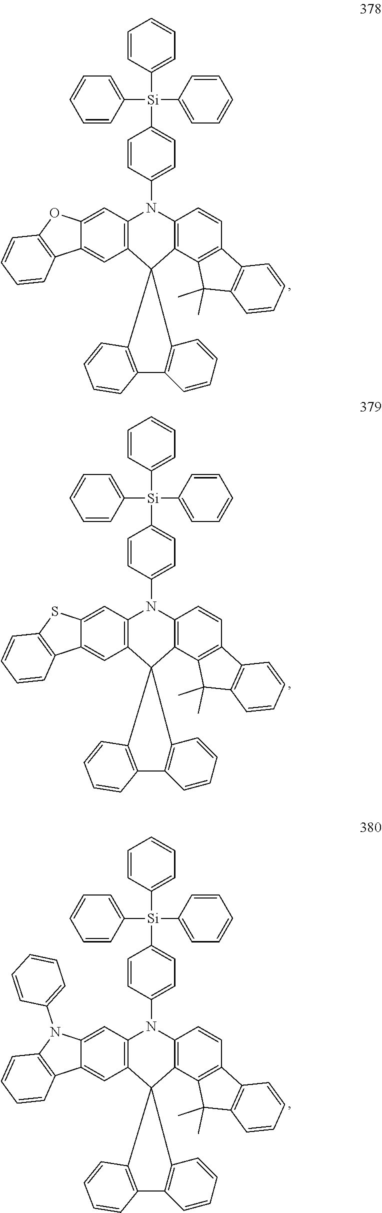 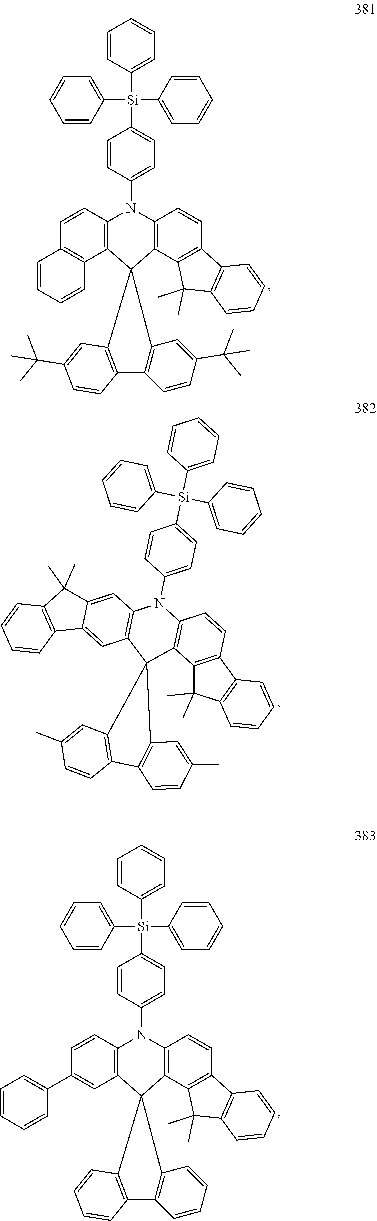 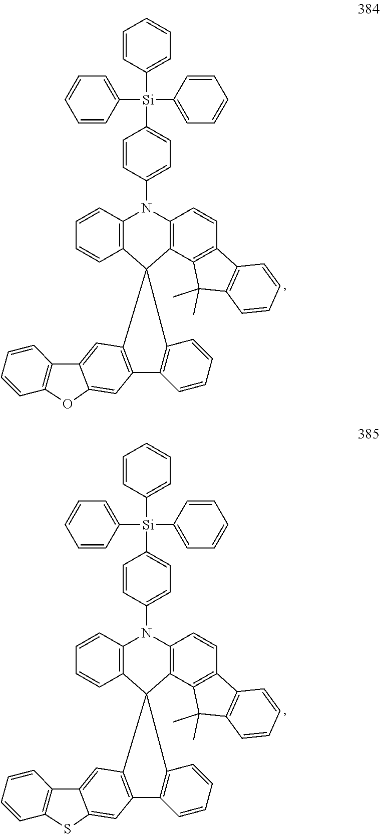 [SMILES: CC1(C)c2ccccc2-c2ccc3c(c21)C1(c2ccccc2-c2cc4oc5ccccc5c4cc21)c1ccccc1N3c1ccc([Si](c2ccccc2)(c2ccccc2)c2ccccc2)cc1 ; CC1(C)c2ccccc2-c2ccc3c(c21)C1(c2ccccc2-c2cc4sc5ccccc5c4cc21)c1ccccc1N3c1ccc([Si](c2ccccc2)(c2ccccc2)c2ccccc2)cc1] 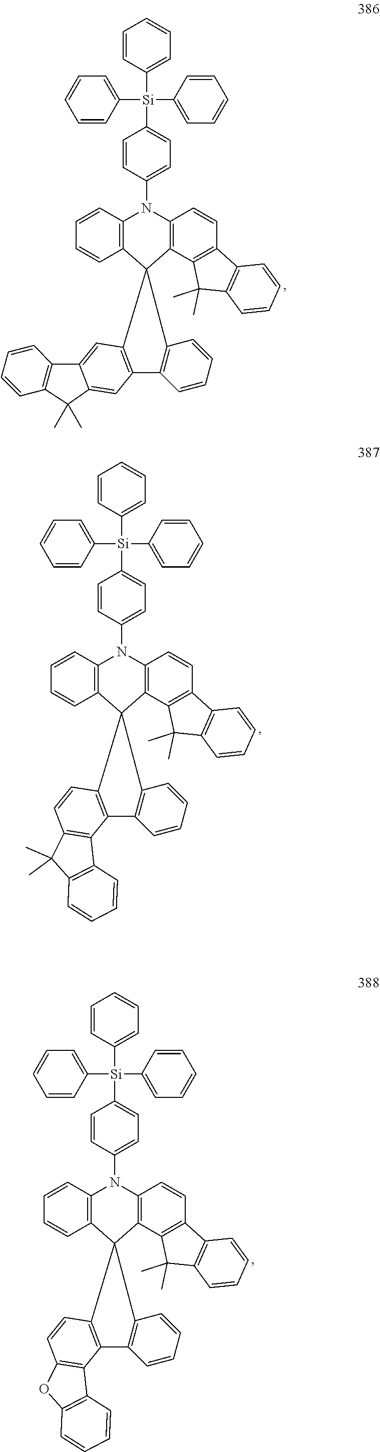 [SMILES: CC1(C)c2ccccc2-c2cc3c(cc21)-c1ccccc1C31c2ccccc2N(c2ccc([Si](c3ccccc3)(c3ccccc3)c3ccccc3)cc2)c2ccc3c(c21)C(C)(C)c1ccccc1-3 ; CC1(C)c2ccccc2-c2c1ccc1c2-c2ccccc2C12c1ccccc1N(c1ccc([Si](c3ccccc3)(c3ccccc3)c3ccccc3)cc1)c1ccc3c(c12)C(C)(C)c1ccccc1-3 ; CC1(C)c2ccccc2-c2ccc3c(c21)C1(c2ccccc2-c2c1ccc1oc4ccccc4c21)c1ccccc1N3c1ccc([Si](c2ccccc2)(c2ccccc2)c2ccccc2)cc1] 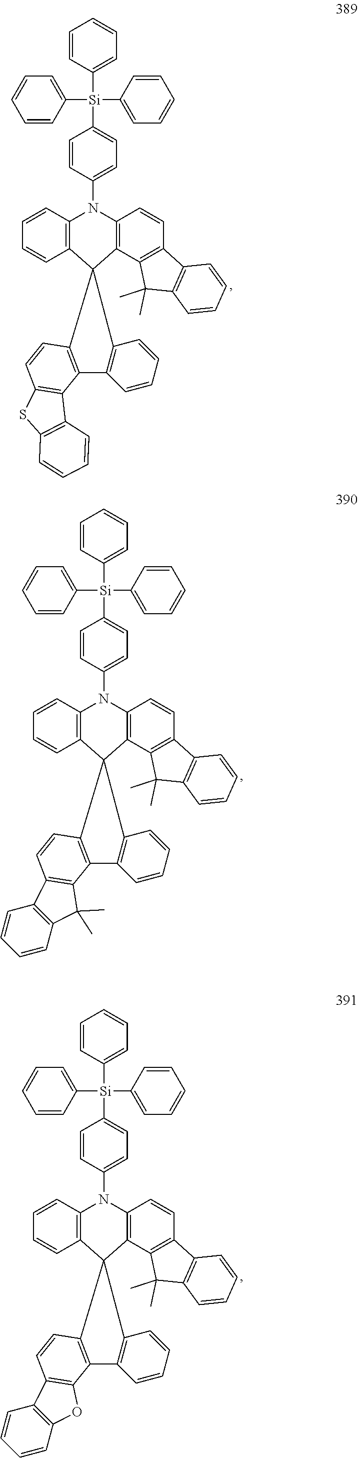 [SMILES: CC1(C)c2ccccc2-c2ccc3c(c21)C1(c2ccccc2-c2c1ccc1sc4ccccc4c21)c1ccccc1N3c1ccc([Si](c2ccccc2)(c2ccccc2)c2ccccc2)cc1 ; CC1(C)c2ccccc2-c2ccc3c(c21)-c1ccccc1C31c2ccccc2N(c2ccc([Si](c3ccccc3)(c3ccccc3)c3ccccc3)cc2)c2ccc3c(c21)C(C)(C)c1ccccc1-3 ; CC1(C)c2ccccc2-c2ccc3c(c21)C1(c2ccccc2-c2c1ccc1c2oc2ccccc21)c1ccccc1N3c1ccc([Si](c2ccccc2)(c2ccccc2)c2ccccc2)cc1] 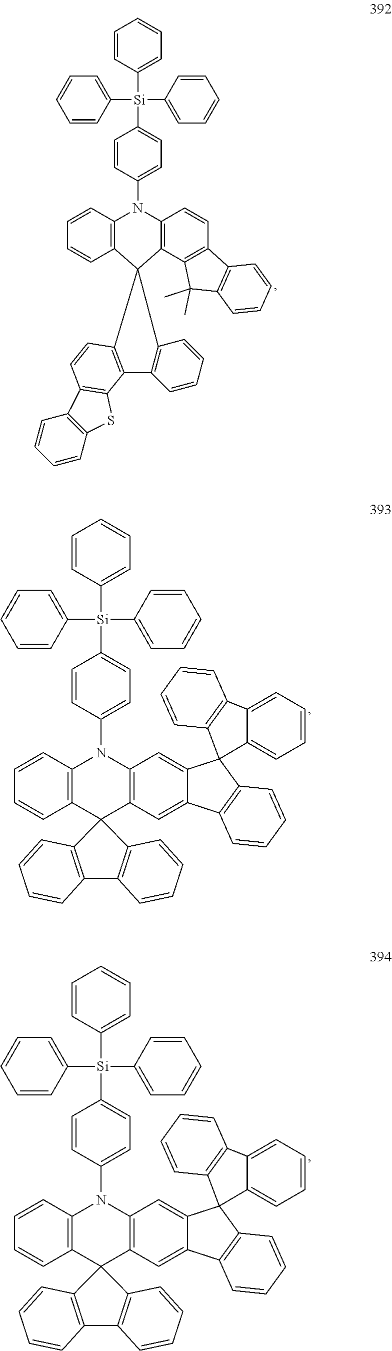 [SMILES: CC1(C)c2ccccc2-c2ccc3c(c21)C1(c2ccccc2-c2c1ccc1c2sc2ccccc21)c1ccccc1N3c1ccc([Si](c2ccccc2)(c2ccccc2)c2ccccc2)cc1 ; c1ccc([Si](c2ccccc2)(c2ccccc2)c2ccc(N3c4ccccc4C4(c5ccccc5-c5ccccc54)c4cc5c(cc43)C3(c4ccccc4-c4ccccc43)c3ccccc3-5)cc2)cc1 ; c1ccc([Si](c2ccccc2)(c2ccccc2)c2ccc(N3c4ccccc4C4(c5ccccc5-c5ccccc54)c4cc5c(cc43)C3(c4ccccc4-c4ccccc43)c3ccccc3-5)cc2)cc1] 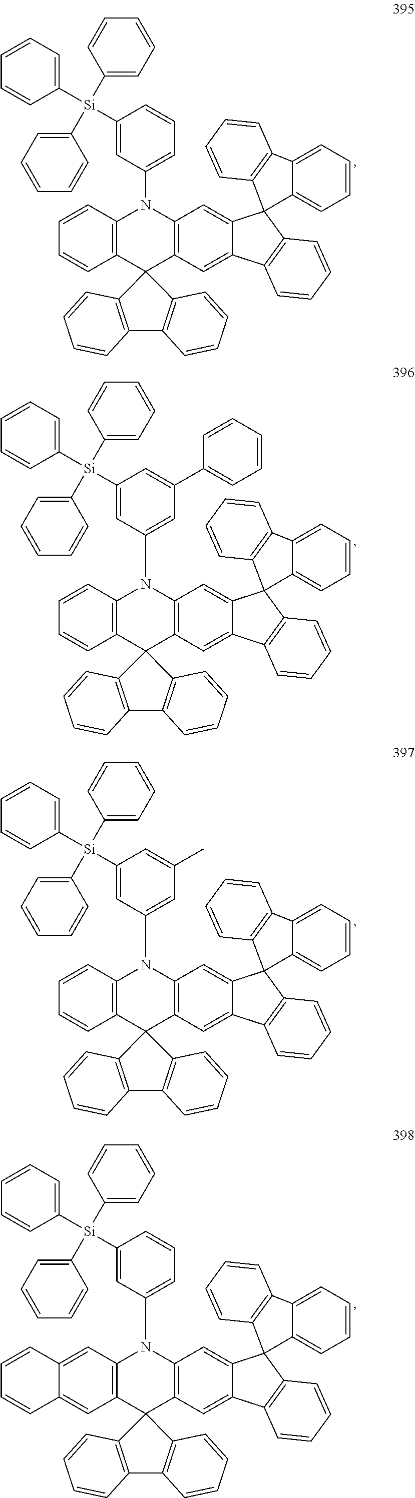 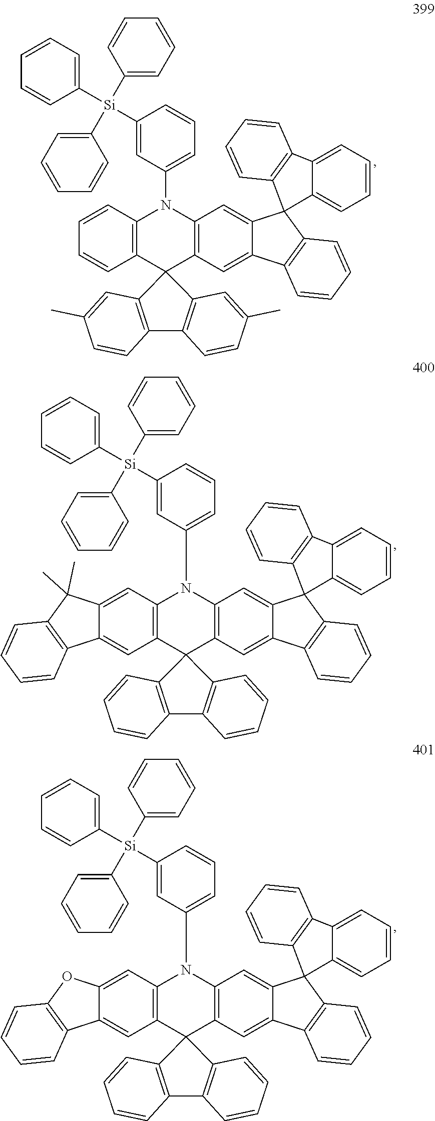 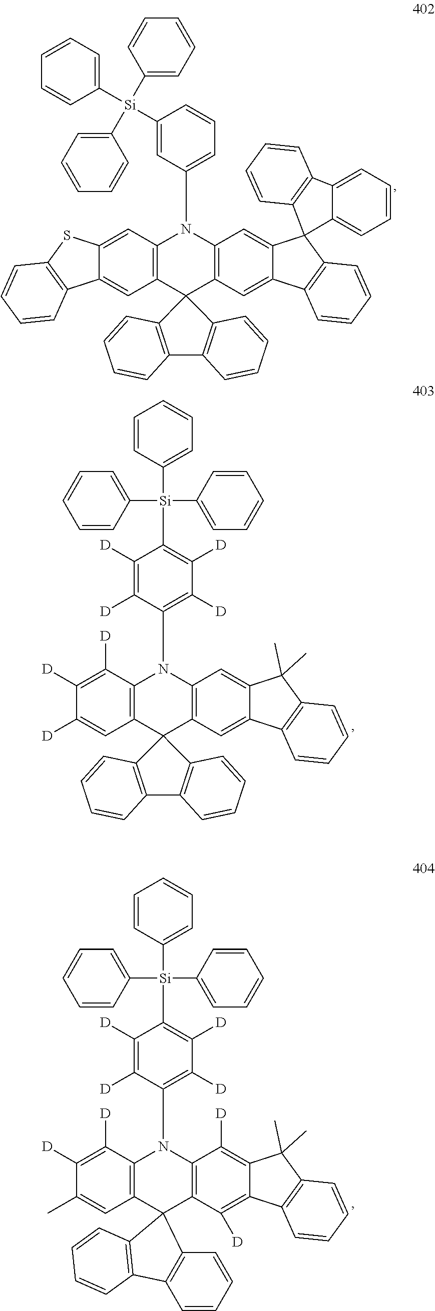 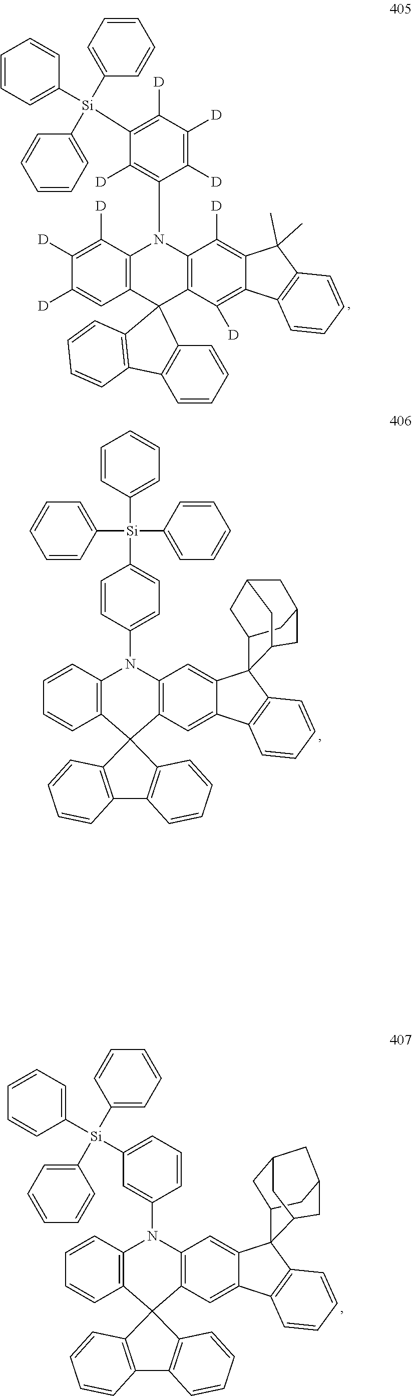 [SMILES: [2H]c1cc2c(c([2H])c1[2H])N(c1c([2H])c([2H])c([2H])c([Si](c3ccccc3)(c3ccccc3)c3ccccc3)c1[2H])c1c([2H])c3c(c([2H])c1C21c2ccccc2-c2ccccc21)-c1ccccc1C3(C)C ; c1ccc([Si](c2ccccc2)(c2ccccc2)c2ccc(N3c4ccccc4C4(c5ccccc5-c5ccccc54)c4cc5c(cc43)C3(c4ccccc4-5)C4CC5CC(C4)CC3C5)cc2)cc1 ; c1ccc([Si](c2ccccc2)(c2ccccc2)c2cccc(N3c4ccccc4C4(c5ccccc5-c5ccccc54)c4cc5c(cc43)C3(c4ccccc4-5)C4CC5CC(C4)CC3C5)c2)cc1] 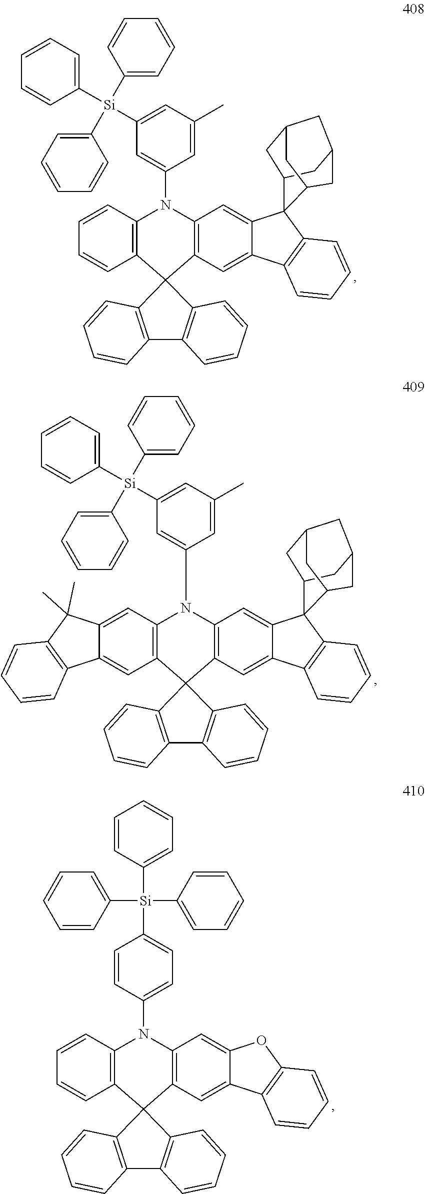 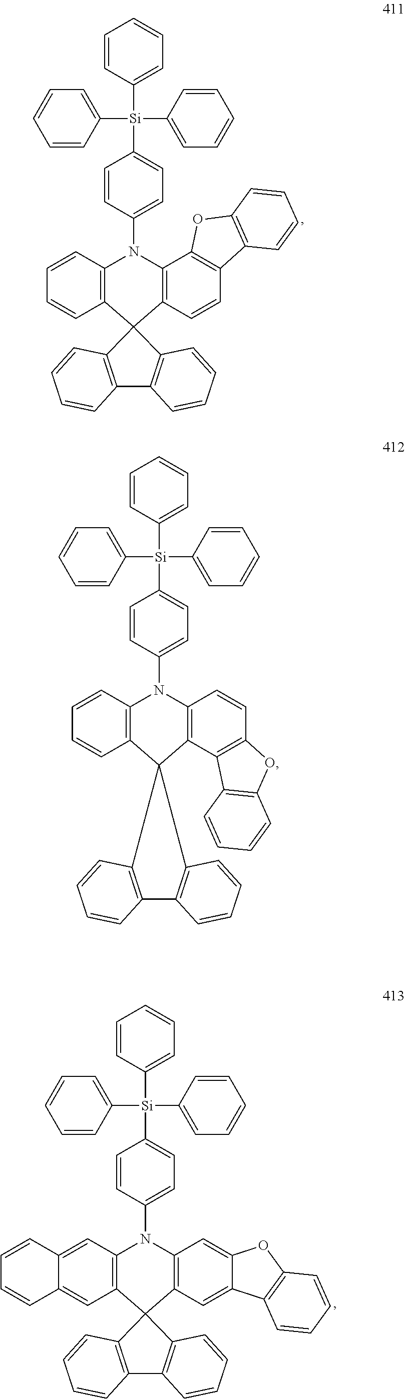 [SMILES: c1ccc([Si](c2ccccc2)(c2ccccc2)c2ccc(N3c4ccccc4C4(c5ccccc5-c5ccccc54)c4ccc5c(oc6ccccc65)c43)cc2)cc1 ; c1ccc([Si](c2ccccc2)(c2ccccc2)c2ccc(N3c4ccccc4C4(c5ccccc5-c5ccccc54)c4c3ccc3oc5ccccc5c43)cc2)cc1 ; c1ccc([Si](c2ccccc2)(c2ccccc2)c2ccc(N3c4cc5ccccc5cc4C4(c5ccccc5-c5ccccc54)c4cc5c(cc43)oc3ccccc35)cc2)cc1] 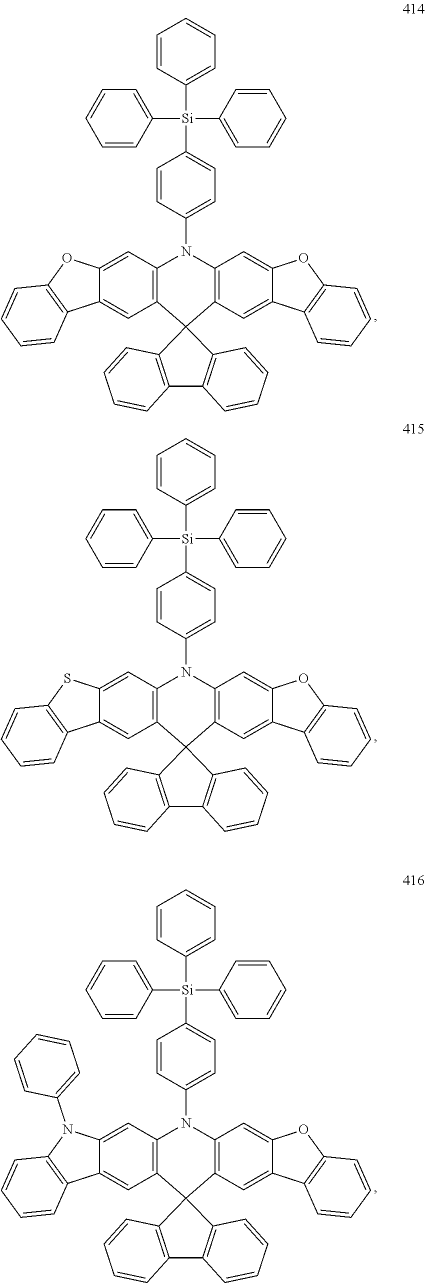 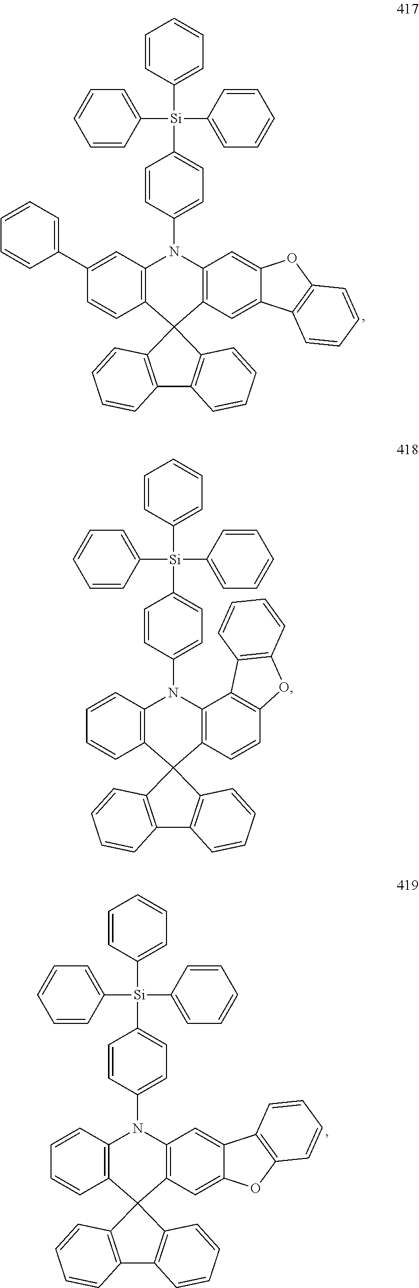 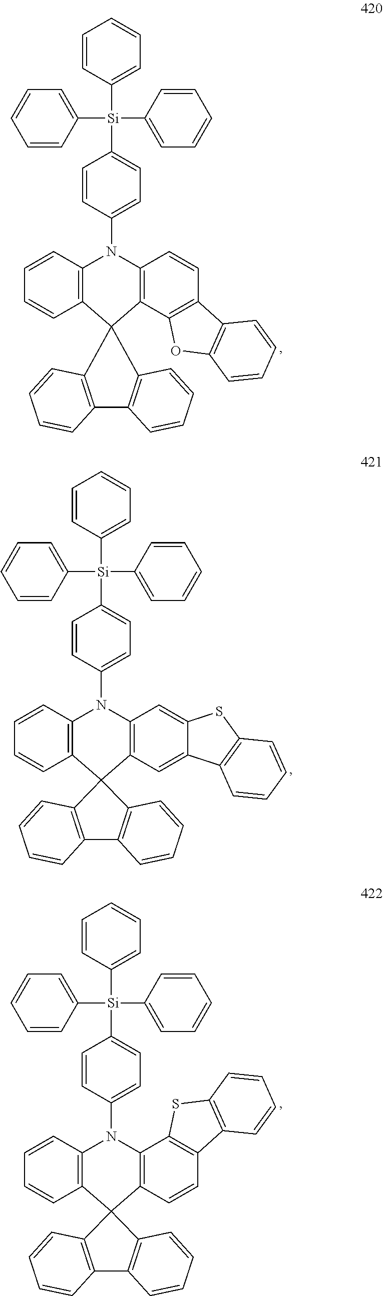 [SMILES: c1ccc([Si](c2ccccc2)(c2ccccc2)c2ccc(N3c4ccccc4C4(c5ccccc5-c5ccccc54)c4c3ccc3c4oc4ccccc43)cc2)cc1 ; c1ccc([Si](c2ccccc2)(c2ccccc2)c2ccc(N3c4ccccc4C4(c5ccccc5-c5ccccc54)c4cc5c(cc43)sc3ccccc35)cc2)cc1 ; c1ccc([Si](c2ccccc2)(c2ccccc2)c2ccc(N3c4ccccc4C4(c5ccccc5-c5ccccc54)c4ccc5c(sc6ccccc65)c43)cc2)cc1] 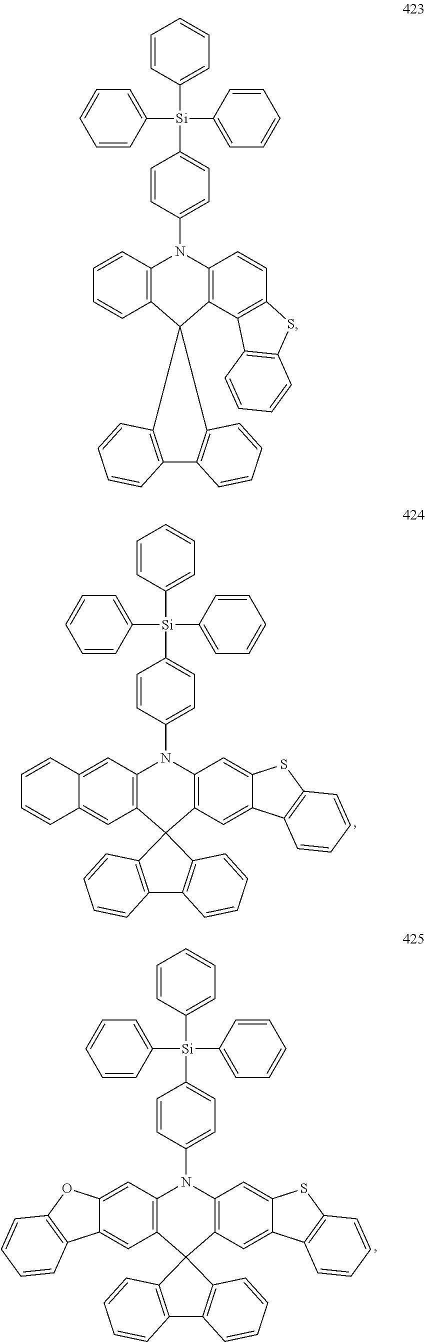 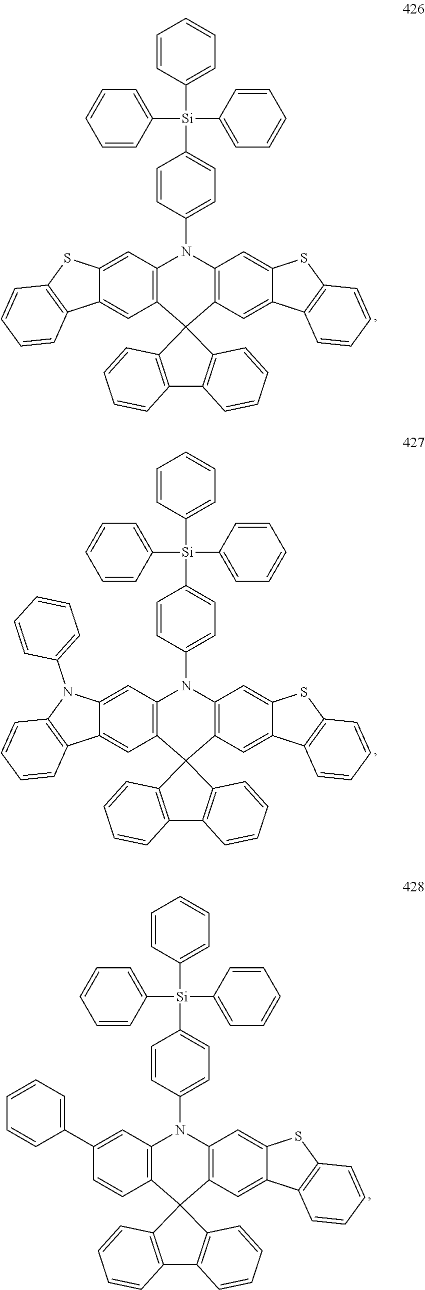 [SMILES: c1ccc([Si](c2ccccc2)(c2ccccc2)c2ccc(N3c4cc5sc6ccccc6c5cc4C4(c5ccccc5-c5ccccc54)c4cc5c(cc43)sc3ccccc35)cc2)cc1 ; c1ccc(-n2c3ccccc3c3cc4c(cc32)N(c2ccc([Si](c3ccccc3)(c3ccccc3)c3ccccc3)cc2)c2cc3sc5ccccc5c3cc2C42c3ccccc3-c3ccccc32)cc1 ; c1ccc(-c2ccc3c(c2)N(c2ccc([Si](c4ccccc4)(c4ccccc4)c4ccccc4)cc2)c2cc4sc5ccccc5c4cc2C32c3ccccc3-c3ccccc32)cc1] 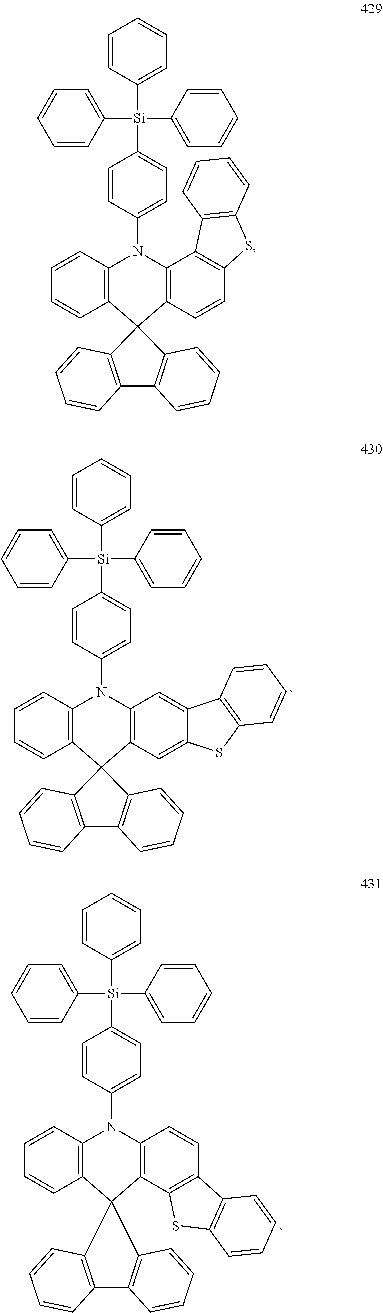 [SMILES: c1ccc([Si](c2ccccc2)(c2ccccc2)c2ccc(N3c4ccccc4C4(c5ccccc5-c5ccccc54)c4ccc5sc6ccccc6c5c43)cc2)cc1 ; c1ccc([Si](c2ccccc2)(c2ccccc2)c2ccc(N3c4ccccc4C4(c5ccccc5-c5ccccc54)c4cc5sc6ccccc6c5cc43)cc2)cc1 ; c1ccc([Si](c2ccccc2)(c2ccccc2)c2ccc(N3c4ccccc4C4(c5ccccc5-c5ccccc54)c4c3ccc3c4sc4ccccc43)cc2)cc1] 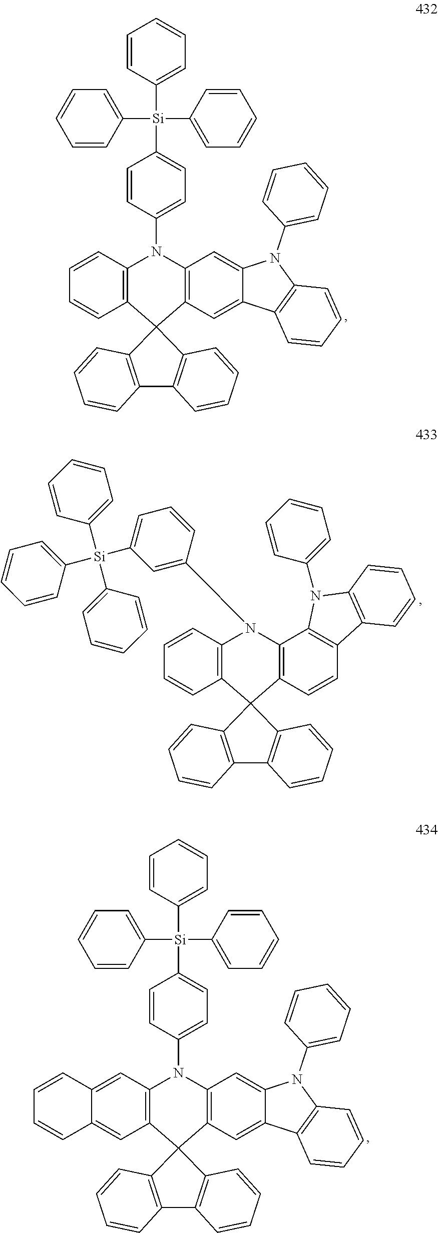 [SMILES: c1ccc(-n2c3ccccc3c3cc4c(cc32)N(c2ccc([Si](c3ccccc3)(c3ccccc3)c3ccccc3)cc2)c2ccccc2C42c3ccccc3-c3ccccc32)cc1 ; c1ccc(-n2c3ccccc3c3ccc4c(c32)N(c2cccc([Si](c3ccccc3)(c3ccccc3)c3ccccc3)c2)c2ccccc2C42c3ccccc3-c3ccccc32)cc1 ; c1ccc(-n2c3ccccc3c3cc4c(cc32)N(c2ccc([Si](c3ccccc3)(c3ccccc3)c3ccccc3)cc2)c2cc3ccccc3cc2C42c3ccccc3-c3ccccc32)cc1] 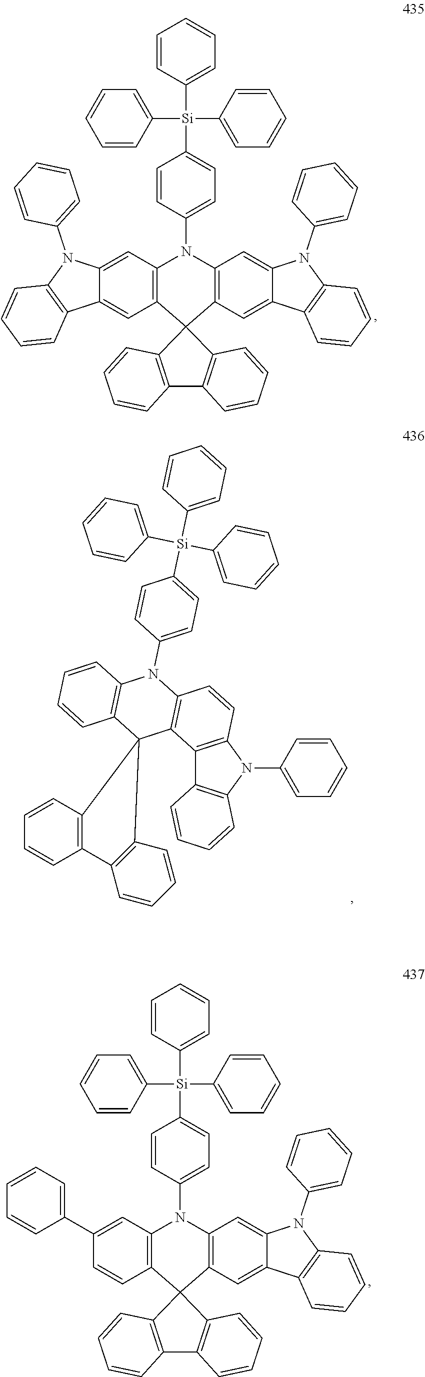 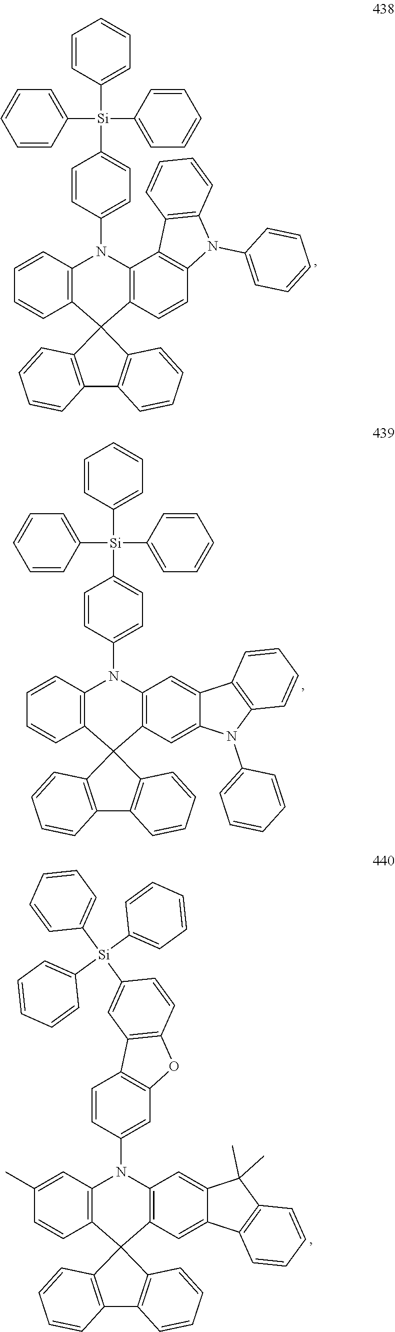 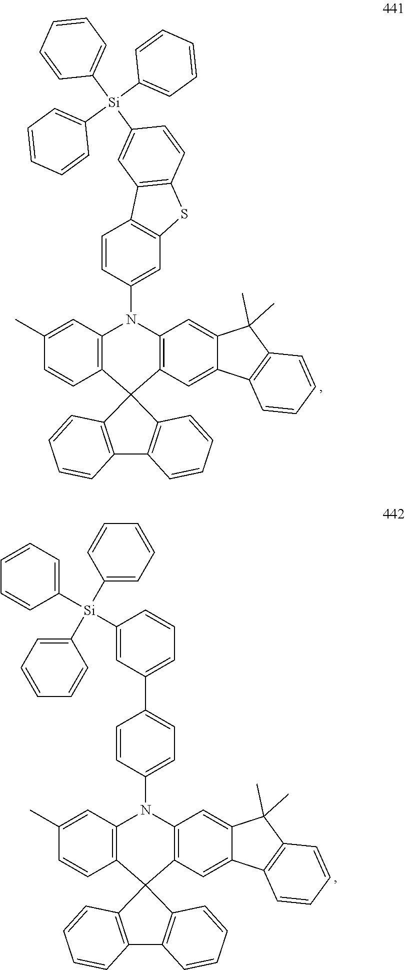 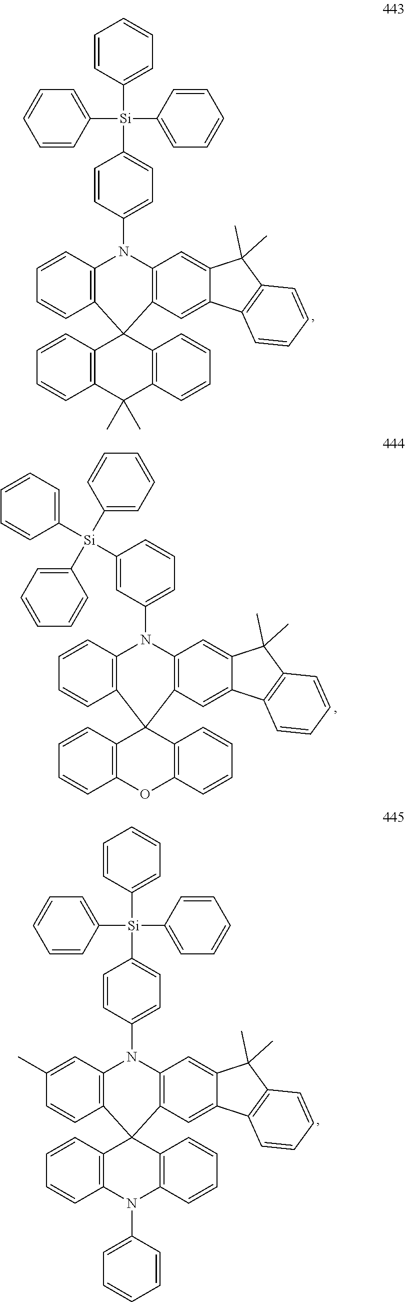 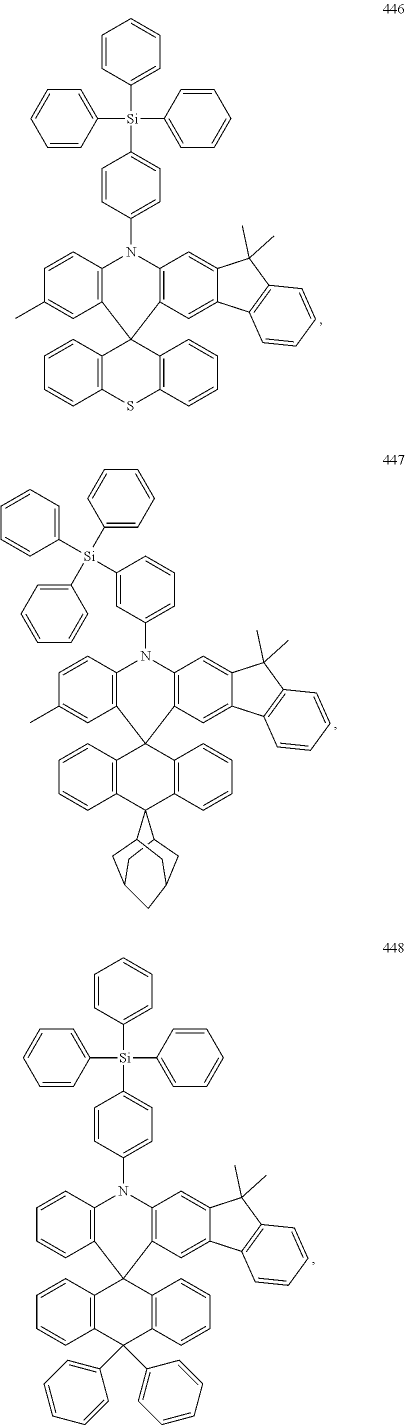 [SMILES: Cc1ccc2c(c1)C1(c3ccccc3Sc3ccccc31)c1cc3c(cc1N2c1ccc([Si](c2ccccc2)(c2ccccc2)c2ccccc2)cc1)C(C)(C)c1ccccc1-3 ; Cc1ccc2c(c1)C1(c3cc4c(cc3N2c2cccc([Si](c3ccccc3)(c3ccccc3)c3ccccc3)c2)C(C)(C)c2ccccc2-4)c2ccccc2C2(c3ccccc31)C1CC3CC(C1)CC2C3 ; CC1(C)c2ccccc2-c2cc3c(cc21)N(c1ccc([Si](c2ccccc2)(c2ccccc2)c2ccccc2)cc1)c1ccccc1C31c2ccccc2C(c2ccccc2)(c2ccccc2)c2ccccc21] 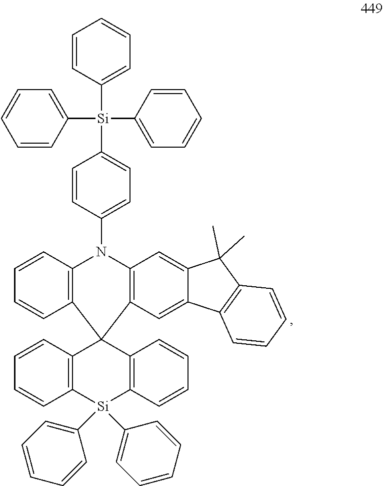 [SMILES: CC1(C)c2ccccc2-c2cc3c(cc21)N(c1ccc([Si](c2ccccc2)(c2ccccc2)c2ccccc2)cc1)c1ccccc1C31c2ccccc2[Si](c2ccccc2)(c2ccccc2)c2ccccc21] 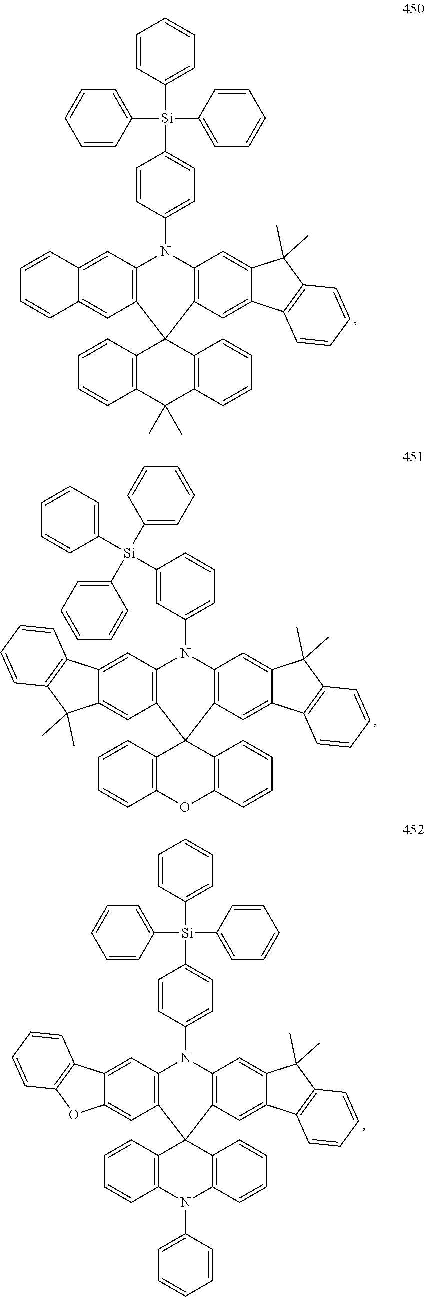 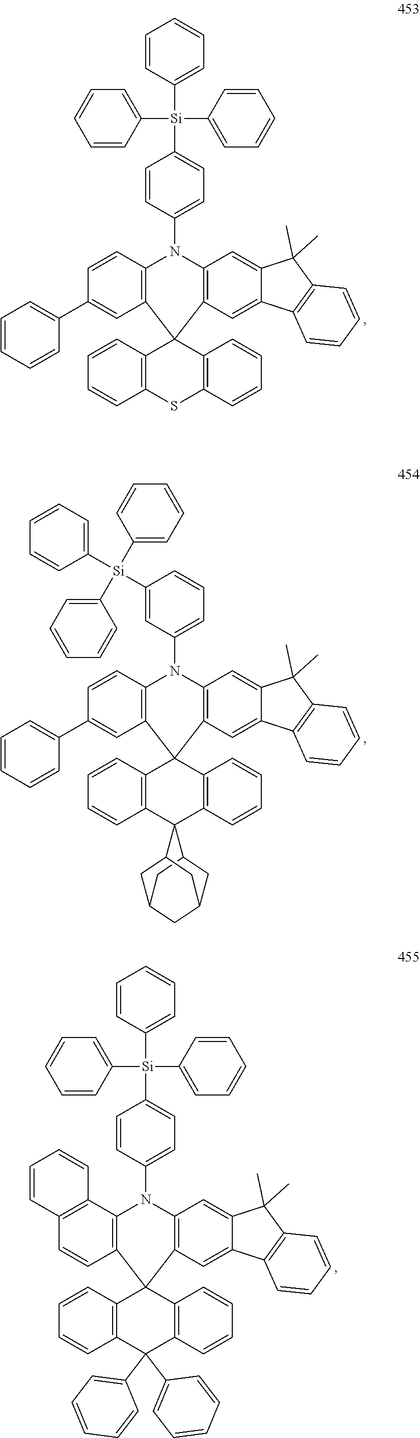 [SMILES: CC1(C)c2ccccc2-c2cc3c(cc21)N(c1ccc([Si](c2ccccc2)(c2ccccc2)c2ccccc2)cc1)c1ccc(-c2ccccc2)cc1C31c2ccccc2Sc2ccccc21 ; CC1(C)c2ccccc2-c2cc3c(cc21)N(c1cccc([Si](c2ccccc2)(c2ccccc2)c2ccccc2)c1)c1ccc(-c2ccccc2)cc1C31c2ccccc2C2(c3ccccc31)C1CC3CC(C1)CC2C3 ; CC1(C)c2ccccc2-c2cc3c(cc21)N(c1ccc([Si](c2ccccc2)(c2ccccc2)c2ccccc2)cc1)c1c(ccc2ccccc12)C31c2ccccc2C(c2ccccc2)(c2ccccc2)c2ccccc21] 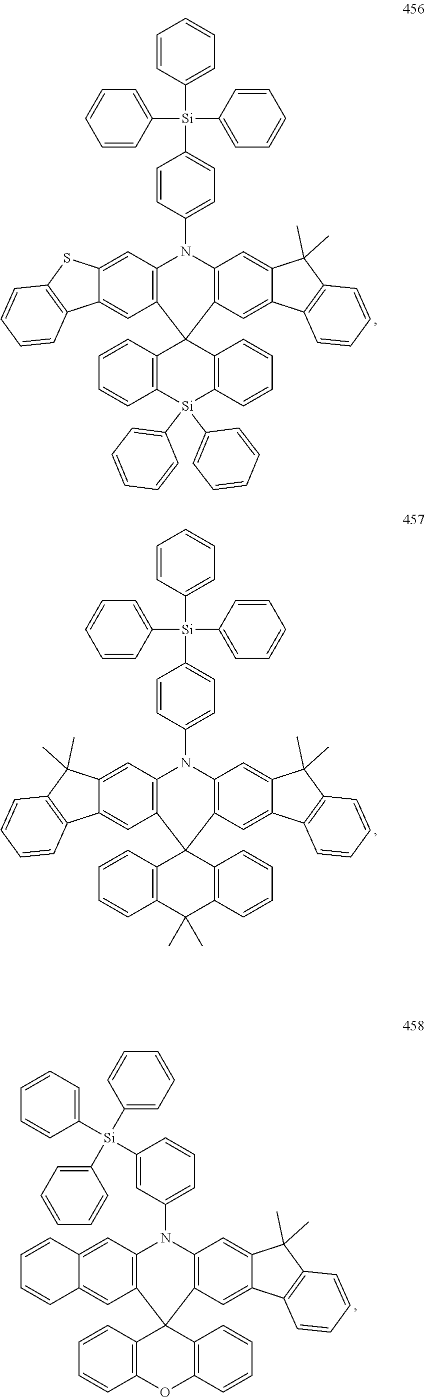 [SMILES: CC1(C)c2ccccc2-c2cc3c(cc21)N(c1ccc([Si](c2ccccc2)(c2ccccc2)c2ccccc2)cc1)c1cc2sc4ccccc4c2cc1C31c2ccccc2[Si](c2ccccc2)(c2ccccc2)c2ccccc21 ; CC1(C)c2ccccc2-c2cc3c(cc21)N(c1ccc([Si](c2ccccc2)(c2ccccc2)c2ccccc2)cc1)c1cc2c(cc1C31c3ccccc3C(C)(C)c3ccccc31)-c1ccccc1C2(C)C ; CC1(C)c2ccccc2-c2cc3c(cc21)N(c1cccc([Si](c2ccccc2)(c2ccccc2)c2ccccc2)c1)c1cc2ccccc2cc1C31c2ccccc2Oc2ccccc21] 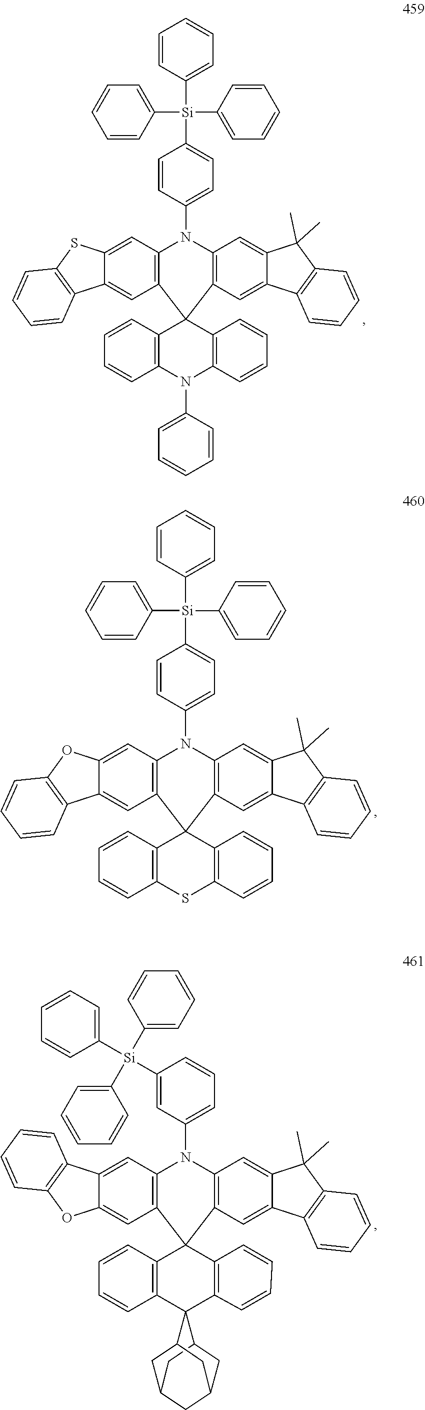 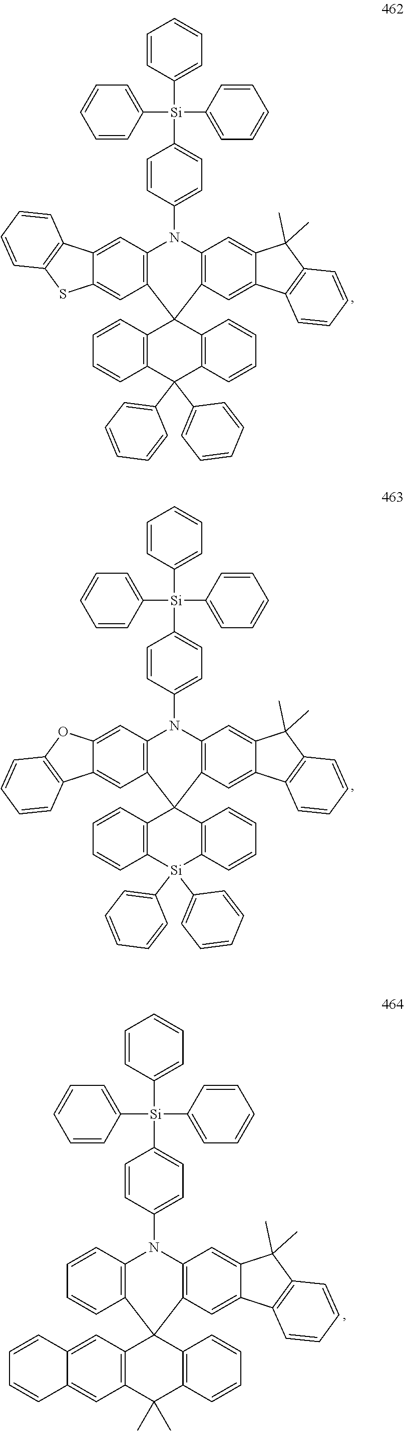 [SMILES: CC1(C)c2ccccc2-c2cc3c(cc21)N(c1ccc([Si](c2ccccc2)(c2ccccc2)c2ccccc2)cc1)c1cc2c(cc1C31c3ccccc3C(c3ccccc3)(c3ccccc3)c3ccccc31)sc1ccccc12 ; CC1(C)c2ccccc2-c2cc3c(cc21)N(c1ccc([Si](c2ccccc2)(c2ccccc2)c2ccccc2)cc1)c1cc2oc4ccccc4c2cc1C31c2ccccc2[Si](c2ccccc2)(c2ccccc2)c2ccccc21 ; CC1(C)c2ccccc2-c2cc3c(cc21)N(c1ccc([Si](c2ccccc2)(c2ccccc2)c2ccccc2)cc1)c1ccccc1C31c2ccccc2C(C)(C)c2cc3ccccc3cc21] 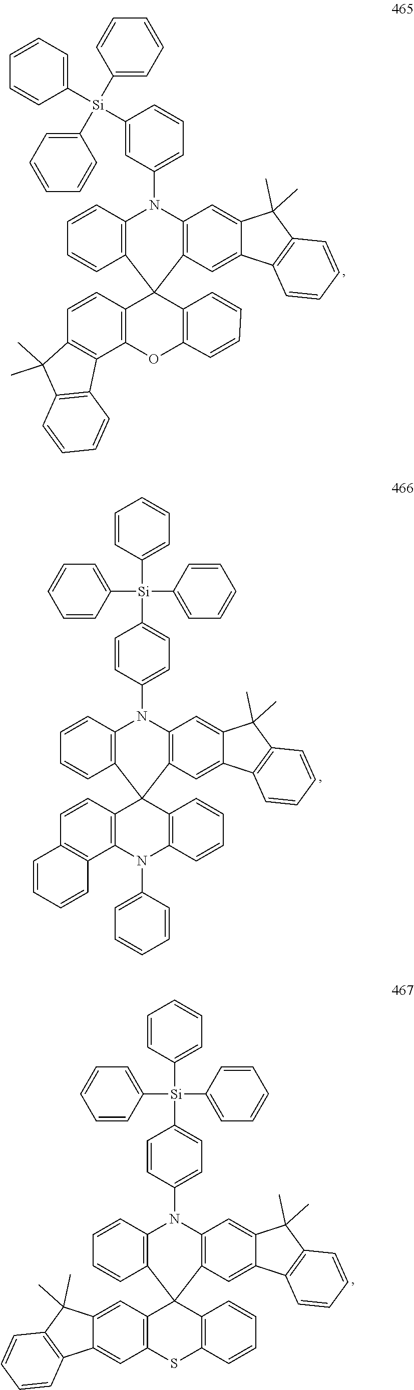 [SMILES: CC1(C)c2ccccc2-c2cc3c(cc21)N(c1cccc([Si](c2ccccc2)(c2ccccc2)c2ccccc2)c1)c1ccccc1C31c2ccccc2Oc2c1ccc1c2-c2ccccc2C1(C)C ; CC1(C)c2ccccc2-c2cc3c(cc21)N(c1ccc([Si](c2ccccc2)(c2ccccc2)c2ccccc2)cc1)c1ccccc1C31c2ccccc2N(c2ccccc2)c2c1ccc1ccccc21 ; CC1(C)c2ccccc2-c2cc3c(cc21)N(c1ccc([Si](c2ccccc2)(c2ccccc2)c2ccccc2)cc1)c1ccccc1C31c2ccccc2Sc2cc3c(cc21)C(C)(C)c1ccccc1-3] 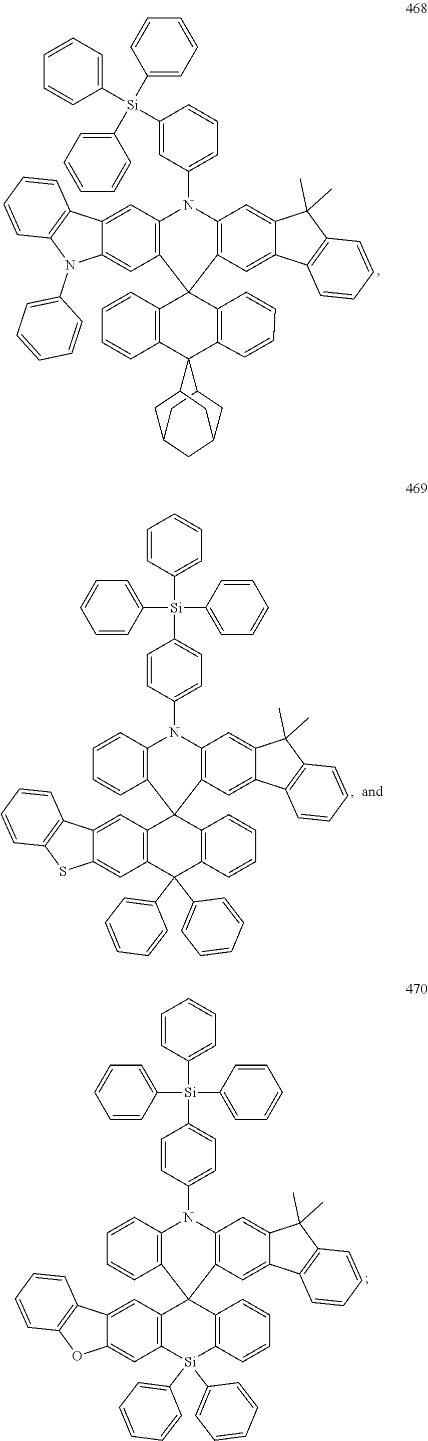 [SMILES: CC1(C)c2ccccc2-c2cc3c(cc21)N(c1cccc([Si](c2ccccc2)(c2ccccc2)c2ccccc2)c1)c1cc2c4ccccc4n(-c4ccccc4)c2cc1C31c2ccccc2C2(c3ccccc31)C1CC3CC(C1)CC2C3 ; CC1(C)c2ccccc2-c2cc3c(cc21)N(c1ccc([Si](c2ccccc2)(c2ccccc2)c2ccccc2)cc1)c1ccccc1C31c2ccccc2C(c2ccccc2)(c2ccccc2)c2cc3sc4ccccc4c3cc21 ; CC1(C)c2ccccc2-c2cc3c(cc21)N(c1ccc([Si](c2ccccc2)(c2ccccc2)c2ccccc2)cc1)c1ccccc1C31c2ccccc2[Si](c2ccccc2)(c2ccccc2)c2cc3oc4ccccc4c3cc21]
wherein optionally, hydrogens in Compound 1 to Compound 470 can be partially or fully substituted with deuterium.

12. An organic electroluminescent device, comprising:
an anode,
a cathode, and
an organic layer disposed between the anode and the cathode, wherein the organic layer comprises the compound of claim 1.

13. The organic electroluminescent device of claim 12, wherein the organic layer is an electron blocking layer, a hole injection layer, a hole transport layer or an emissive layer;
preferably, the organic layer is an electron blocking layer, and the compound is an electron blocking material.

14. A compound composition, comprising the compound of claim 1.
